(19) United States
(12) Patent Application Publication
(10) Pub. No.: US 2025/0059438 A1
(43) Pub. Date: Feb. 20, 2025

(54) CYCLIC TETRADENTATE METAL PLATINUM COMPLEX PHOSPHORESCENT MATERIAL AND USE THEREOF

(71) Applicants: ZHEJIANG UNIVERSITY OF TECHNOLOGY, Hangzhou (CN); ZHEJIANG HUAXIAN PHOTOELECTRICITY TECHNOLOGY CO.,LTD, Jiaxing (CN)

(72) Inventors: Guijie LI, Hangzhou (CN); Jiaoying LIN, Hangzhou (CN); Yuanbin SHE, Hangzhou (CN); Yulu SUN, Hangzhou (CN); Xiaoyu ZHAO, Jiaxing (CN)

(73) Assignees: ZHEJIANG UNIVERSITY OF TECHNOLOGY, Hangzhou (CN); ZHEJIANG HUAXIAN PHOTOELECTRICITY TECHNOLOGY CO.,LTD, Jiaxing (CN)

(21) Appl. No.: 18/796,561

(22) Filed: Aug. 7, 2024

(30) Foreign Application Priority Data
Aug. 17, 2023 (CN) 2023110435634

(51) Int. Cl. C09K 11/06; H10K 50/11; H10K 85/30

(52) U.S. Cl. CPC C09K 11/06; H10K 50/11; H10K 85/346; C09K 2211/185

(57) ABSTRACT

The present invention provides a cyclic tetradentate metal platinum complex phosphorescent material based on pyridine heterocycle, benzoxazole, and carbazole derivatives. It is a novel tetradentate platinum (II) complex with a 6/6/6 metal fused ring phenoxy coordination structure. The phosphorescent material of the N—C—N—N tetradentate fused ring structure system of the present invention have the characteristics of easy modulation of HOMO and LUMO orbital energy levels and strong luminescence. It has good chemical stability and thermal stability, and is easy to fabricate evaporation-type OLED devices.

### CROSS-REFERENCE TO RELATED APPLICATIONS

The application claims priority to Chinese patent application No. 2023110435634, filed on Aug. 17, 2023, the entire contents of which are incorporated herein by reference.

### TECHNICAL FIELD

The present invention relates to a phosphorescent material and the use thereof, and more particularly to a cyclic tetradentate metal platinum complex phosphorescent material and the use thereof.

### BACKGROUND

Organic light-emitting diode (OLED) refers to a sandwich-type device structure in which electrons and holes respectively enter the light-emitting layer to recombine and form excitons under the action of an applied electric field, which are then transited to the ground state to generate radiative transition luminescence. Compared with traditional Liquid Crystal Display (LCD), OLED has many advantages, such as low power consumption, good performance, high brightness, self-luminescence and wide visibility. It is widely used in the field of display lighting.

In electroluminescence, 25% singlet excitons and 75% triplet excitons are formed according to spin statistics. In the first OLED devices, the main fluorescent materials were used, and theoretically, only 25% of the single-line state excitons could be applied, and the remaining 75% of triplet excitons were lost by nonradiative transitions, resulting in extremely low external quantum efficiency, which severely limited the development of OLEDs. Phosphorescent materials break the transition forbidden by introducing heavy metal atoms to induce a self-selective orbital coupling effect, so that triplet excitons can also transition down to the ground state, achieving 100% exciton utilization. In general, cyclic metal platinum complex phosphorescent material is formed by coordinating a suitable ligand structure with a metal platinum atom and modifying the chemical structure of the ligand can effectively change the luminescent properties of the metal complex. Compared with the bidentate and tridentate ligand structures, the rigid structure of the tetradentate complex can suppress vibrational coupling, reduce nonradiative transitions, improve the luminescence quantum efficiency, and achieve efficient phosphorescent emission. Although the development trend of cyclic tetradentate metal platinum complexes is strong, efficient and stable platinum complexes need to be developed. Therefore, the development of novel cyclic tetradentate metal platinum complex is still the top priority in the field of OLED.

### SUMMARY

In order to develop a wider variety of phosphorescent materials with higher performance, it is an object of the present invention to provide a cyclic tetradentate metal platinum complex phosphorescent material and uses thereof. The present invention develops a novel 6/6/6 metal fused-ring structure using tetradentate ligands of pyridine heterocycle, benzoxazole, and carbazole derivatives, resulting in a novel cyclic tetradentate metal platinum complex phosphorescent material. The complex provided can be prepared as an organic electroluminescent device as a light-emitting layer so that the device has excellent properties. It can increase the external quantum efficiency and reduce the start-up voltage in organic electroluminescent devices.

In order to achieve the technical objectives above, the technical solution of the present invention is as follows.

The present invention provides a cyclic tetradentate metal platinum complex phosphorescent material having the general structure shown in formula (I),

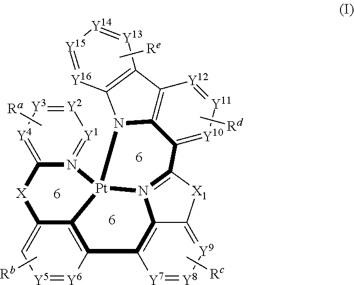

where X is CR₁R₂ or NR₃; X₁ is selected from NR₄, O or S; each of R₁-R₄ is independently selected from hydrogen, halogen, substituted or unsubstituted C1-C30 alkyl, substituted or unsubstituted C1-C30 cycloalkyl, substituted or unsubstituted C1-C30 heterocycloalkyl, substituted or unsubstituted C1-C30 cycloalkyl, substituted or unsubstituted C6-C60 aryl, substituted or unsubstituted C6-C18 arylamine, substituted or unsubstituted C6-C18 heterocycloamine, and combination thereof;
Y¹-Y¹⁶ are each independently selected from C or N;
R^{a}, R^{b}, R^{c}, R^{d} and R^{e} each independently represent mono-to maximum substitution, or no substitution, and are each independently selected from hydrogen, halogen, substituted or unsubstituted C1-C30 alkyl, substituted or unsubstituted C1-C30 cycloalkyl, substituted or unsubstituted C1-C30 heterocycloalkyl, substituted or unsubstituted C1-C30 cycloalkyl, substituted or unsubstituted C6-C60 aryl, substituted or unsubstituted C6-C60 heteroaryl, and combination thereof; at least one hydrogen in R₁-R₄, R^{a}, R^{b}, R^{c}, R^{d} and R^{e} is substitutable by deuterium; the substituent in the “substituted or unsubstituted” radical is selected from one or more of deuterium, halogen, methyl, ethyl, propyl, isopropyl, butyl, t-butyl, pentyl, phenyl, in case of substituted by multiple substituents; the multiple substituents are the same or different from each other; when containing a heteroatom, the heteroatom is selected from O or N; the two or more adjacent substituents of R₁-R₄, R^{a}, R^{b}, R^{c}, R^{d} and R^{e} are independently or optionally linkable to form a fused ring.

Preferably, the cyclic tetradentate metal platinum complex phosphorescent material has a general structure according to Formula (I-1) or Formula (I-2):

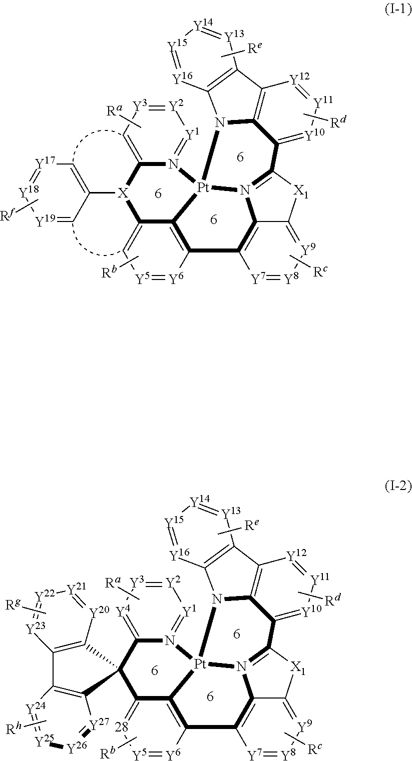

where Y¹⁷-Y²⁷ are each independently selected from C or N;
R^{f}, R^{g} and R^{h} each independently represent mono-to maximum substitution, or no substitution, and are each independently selected from hydrogen, halogen, substituted or unsubstituted C1-C30 alkyl, C1-C30 haloalkyl, substituted or unsubstituted C1-C30 cycloalkyl, substituted or unsubstituted C1-C30 heterocycloalkyl, substituted or unsubstituted C6-C60 aryl, substituted or unsubstituted C6-C60 heteroaryl, and combination thereof;
wherein the substituent in the “substituted or unsubstituted” radical is selected from one or more of deuterium, trifluoromethyl, halogen, methyl, ethyl, propyl, isopropyl, butyl, t-butyl, pentyl, hexyl, phenyl, biphenyl; in case of substitution by a plurality of substituents, the plurality of substituents are the same as or different from each other; when containing a heteroatom, the heteroatom is selected from O or N; at least one hydrogen of the R^{f}, R^{g}, and R^{h} is substitutable with deuterium; and two or more adjacent substituents are independently or optionally linkable to form a fused ring.

Preferably, in formula (I), (I-1), and (I-2), R^{a}, R^{b}, R^{c}, R^{d} and R^{e} are each independently selected from hydrogen, deuterium, F, methyl, ethyl, propyl, isopropyl, n-butyl, isobutyl, sec-butyl, t-butyl, 2-methylbutyl, trifluoromethyl, phenyl, furyl, benzofuranyl, pyridyl, and combination thereof.

Preferably, in formula (I-1) and (I-2), R^{f}, R^{g} and R^{h} are each independently selected from hydrogen, deuterium, F, methyl, ethyl, propyl, isopropyl, n-butyl, isobutyl, sec-butyl, t-butyl, 2-methylbutyl, phenyl, furyl, benzofuranyl, pyridyl, and combination thereof.

Preferably, R⁴ is selected from hydrogen, deuterium, F, methyl, ethyl, propyl, t-butyl, phenyl, biphenyl, methylbenzene, t-butylphenyl, benzofuranyl, pyridyl, and combination thereof.

Preferably, R^{g} and R^{h} are each independently selected from hydrogen, methyl, t-butyl, t-butylbenzene, and combination thereof.

Preferably, the cyclic tetradentate metal platinum complex phosphorescent material is selected from any one of the following structural formulae:

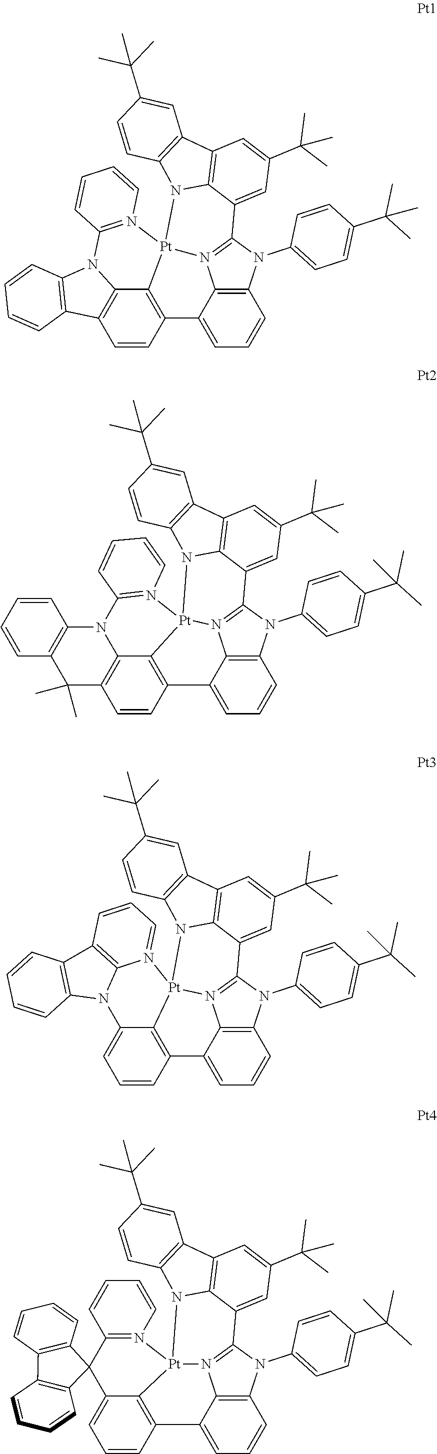

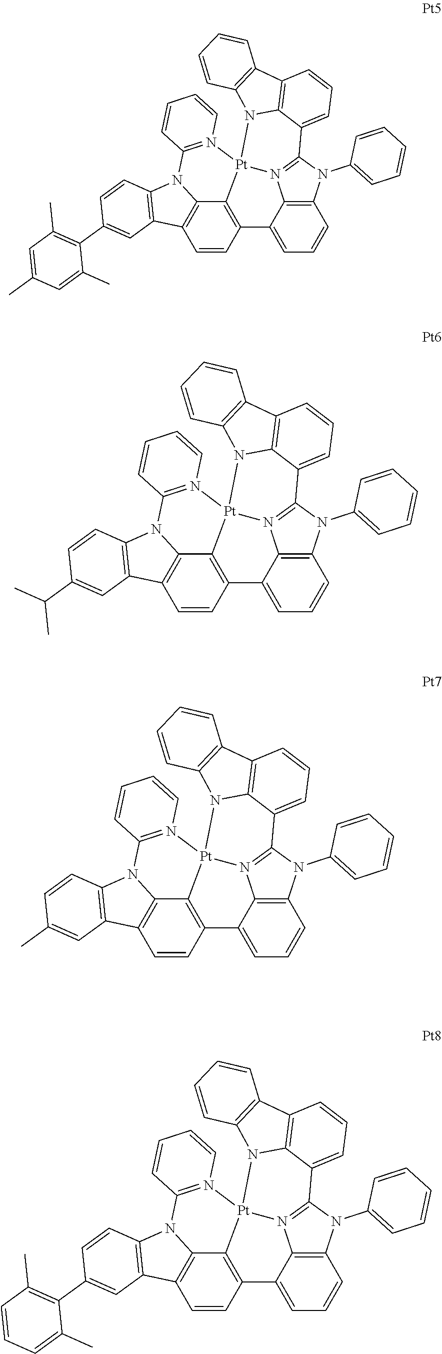

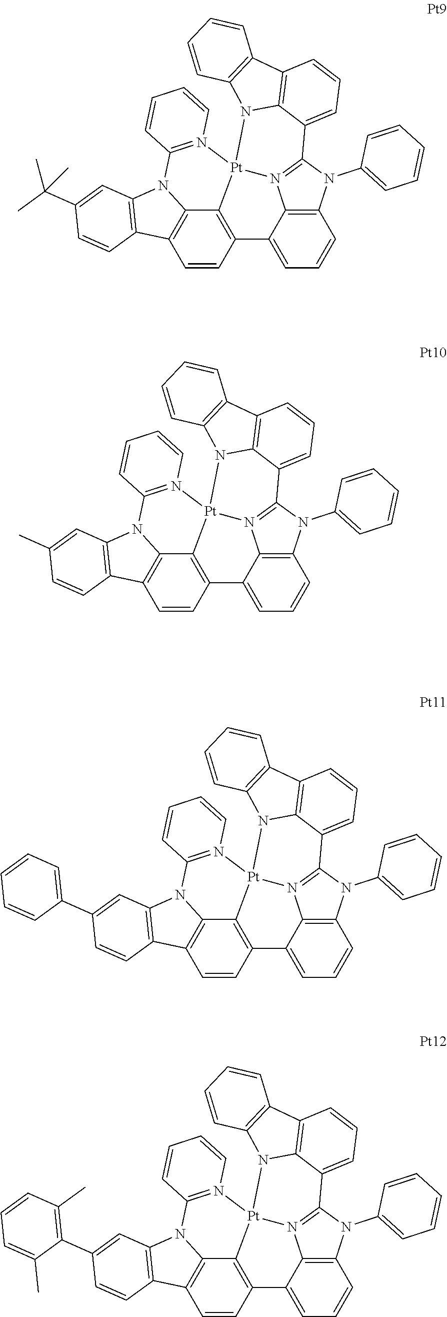

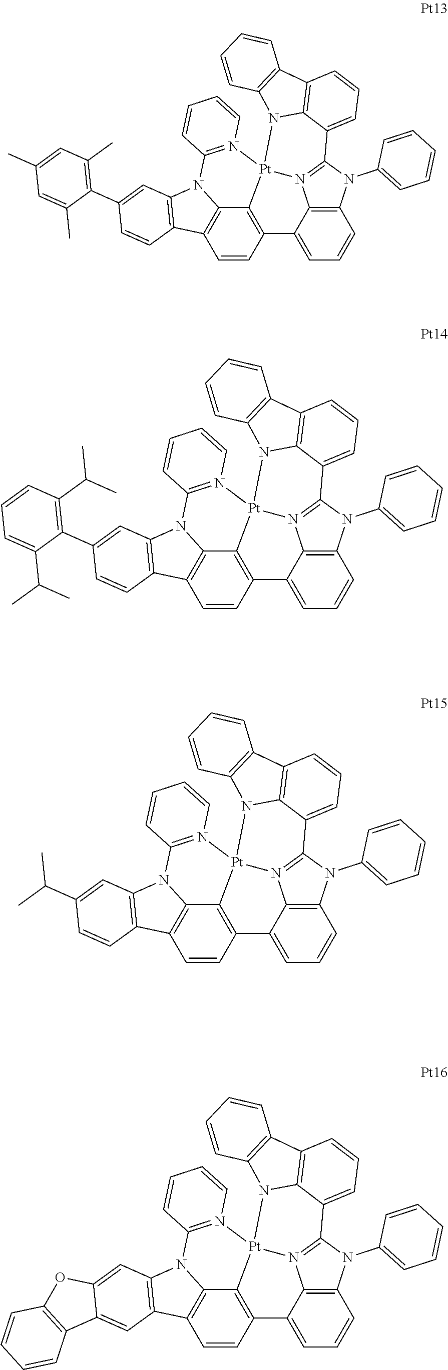

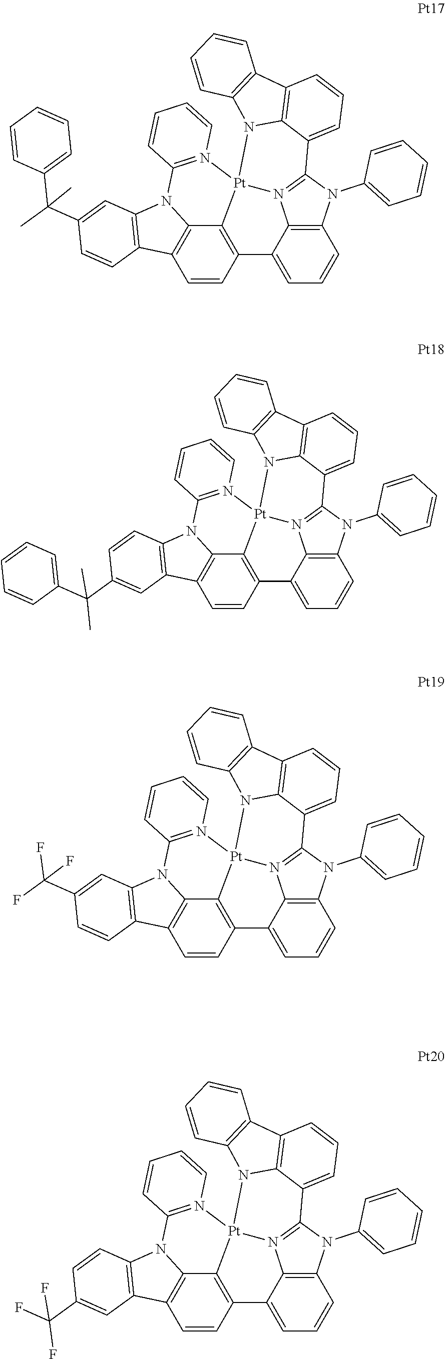

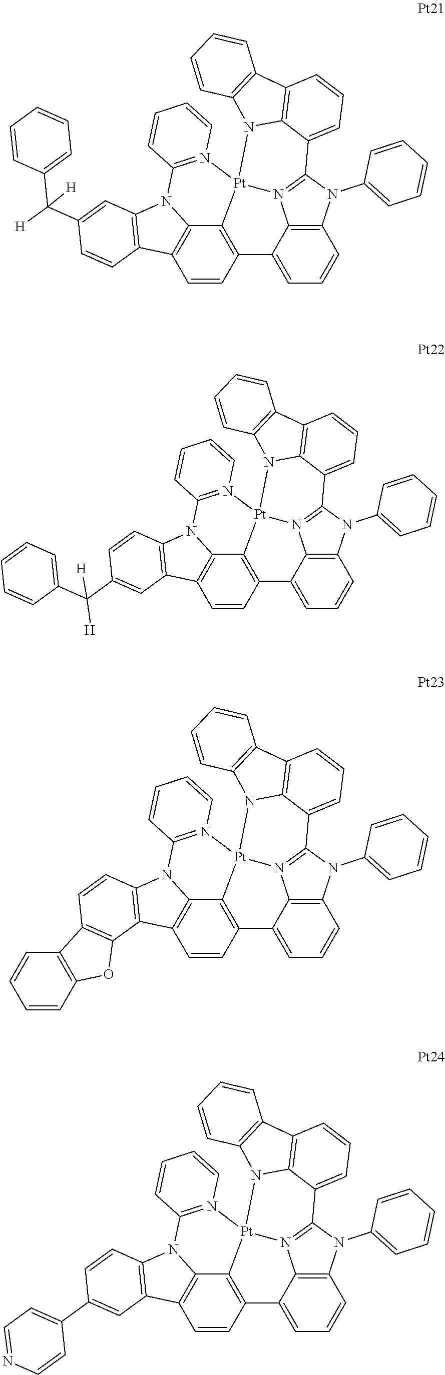

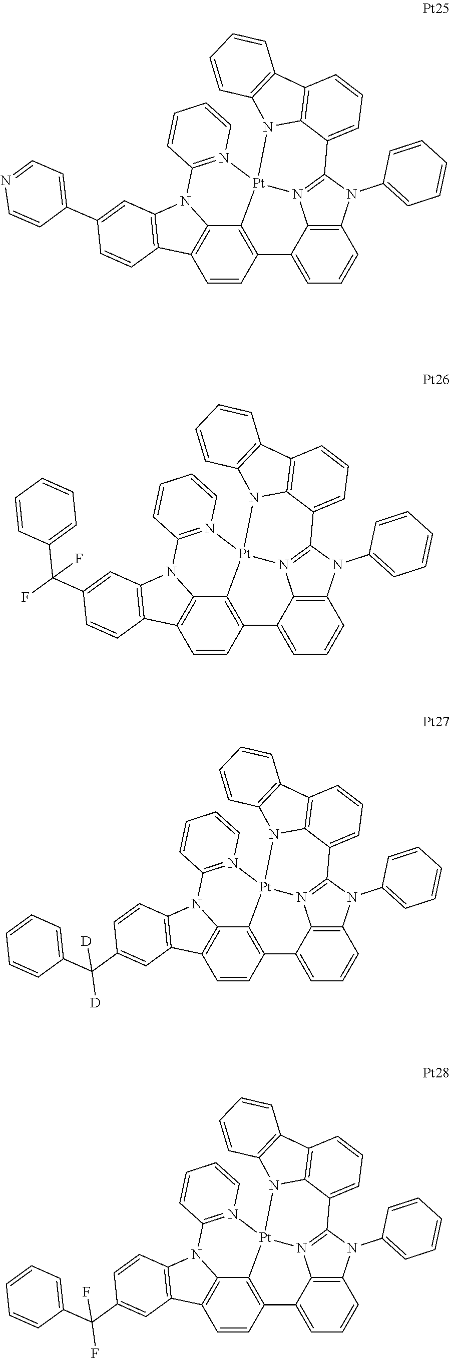

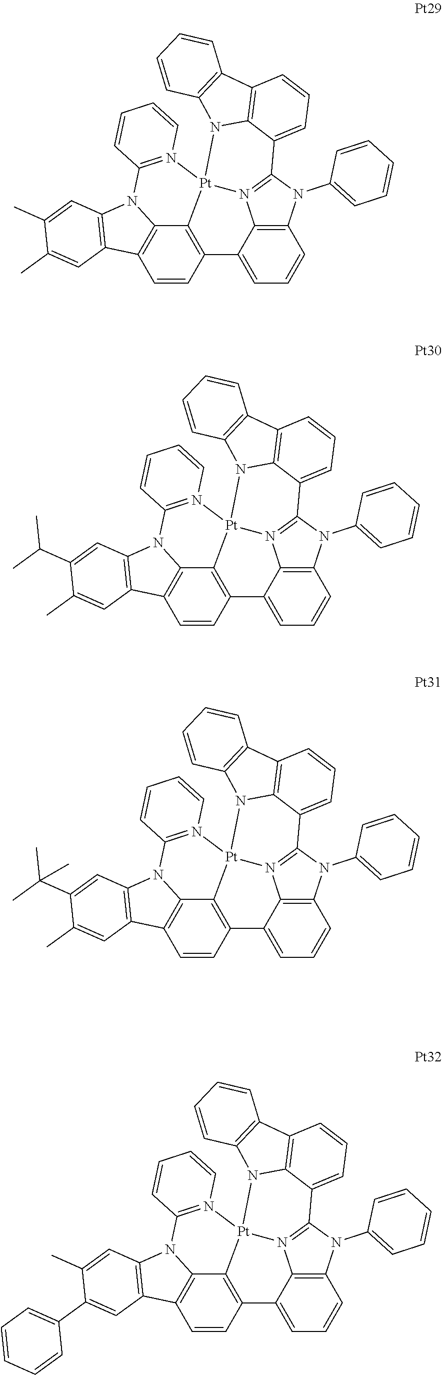

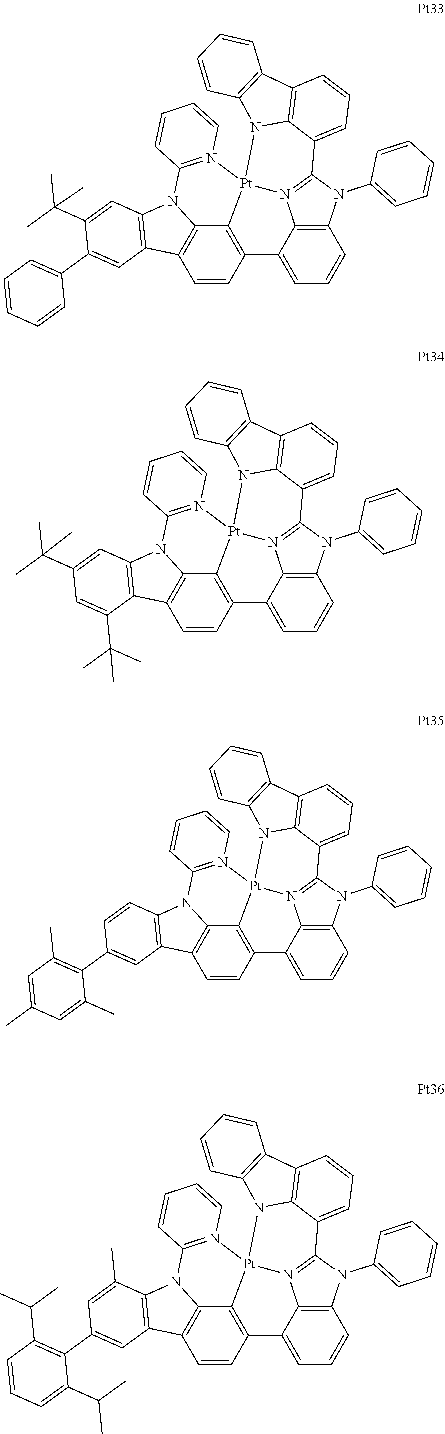

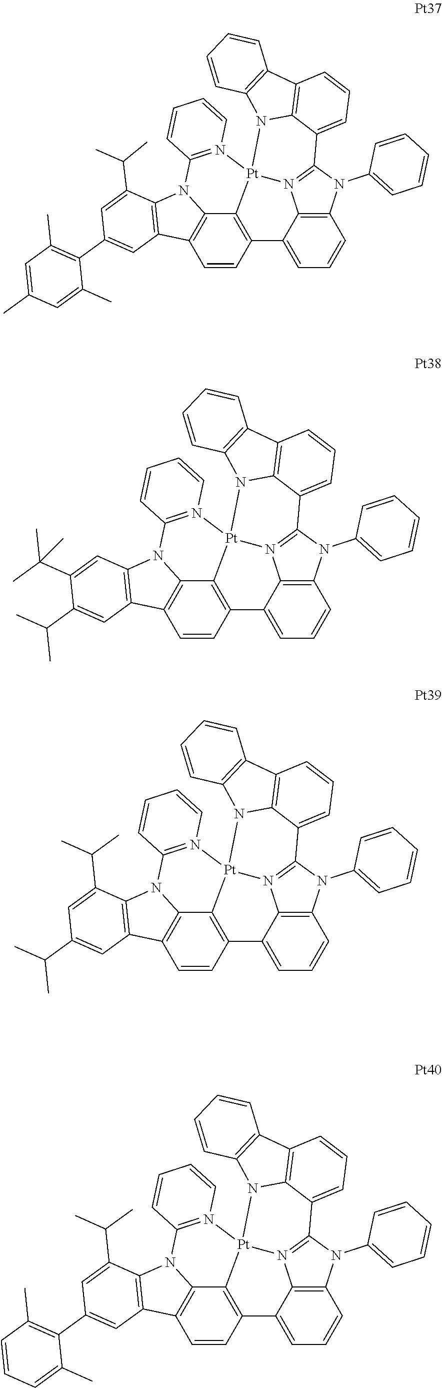

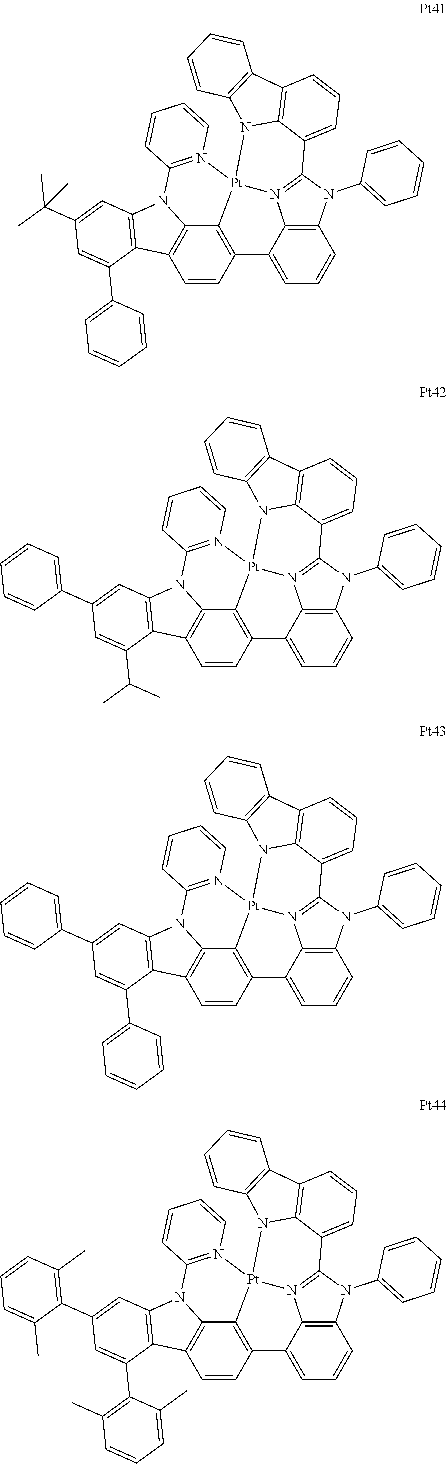

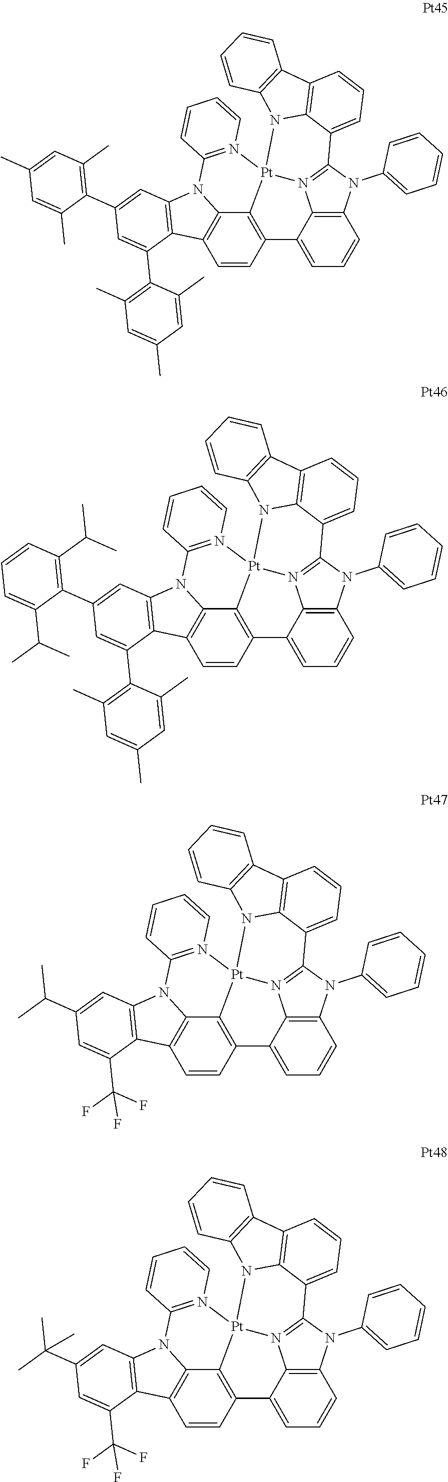

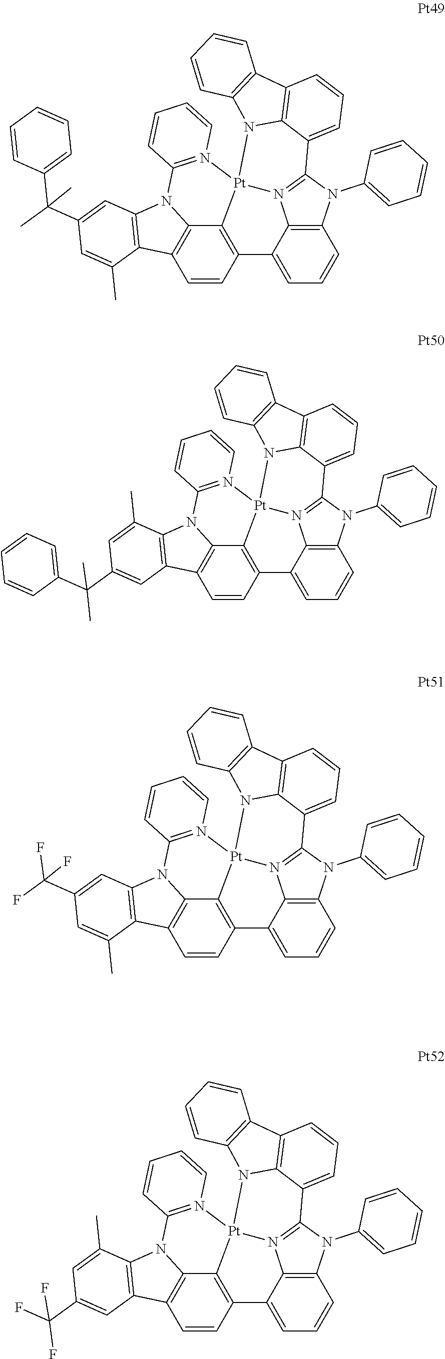

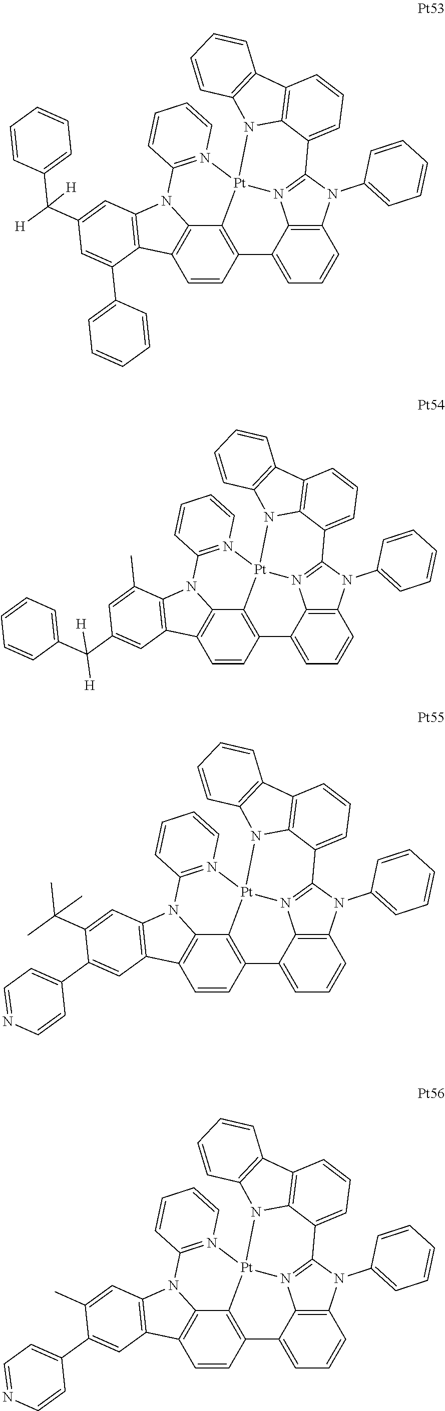

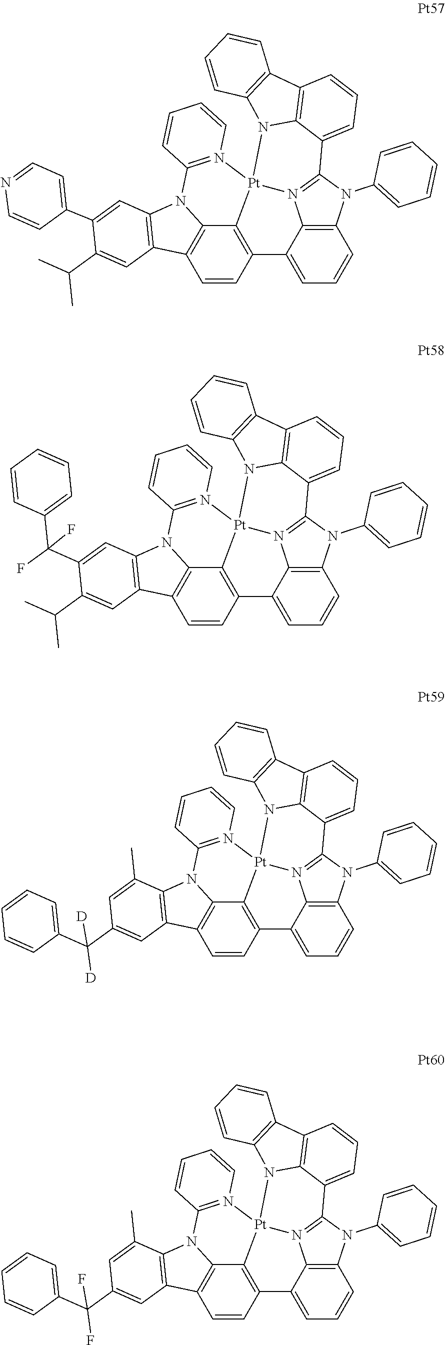

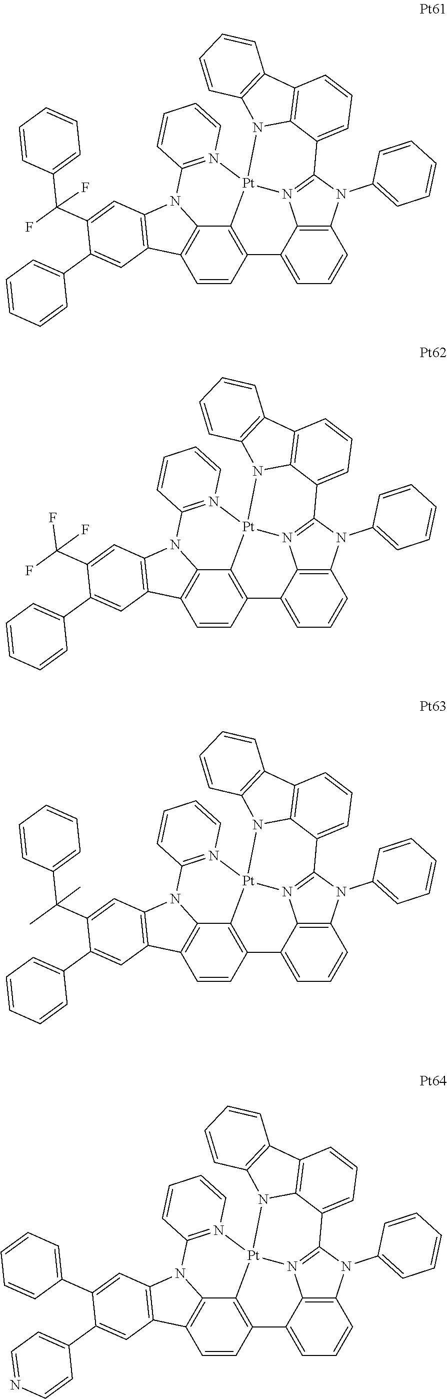

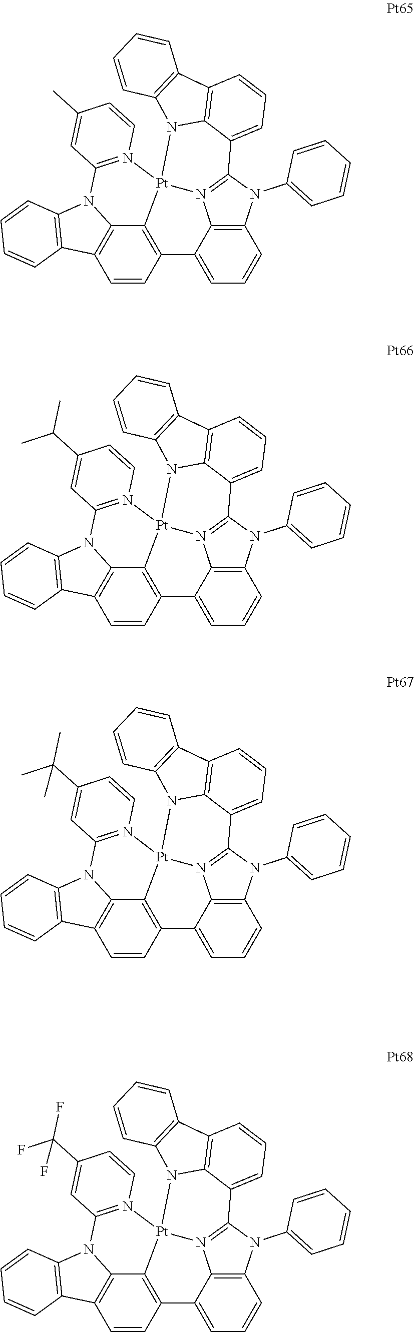

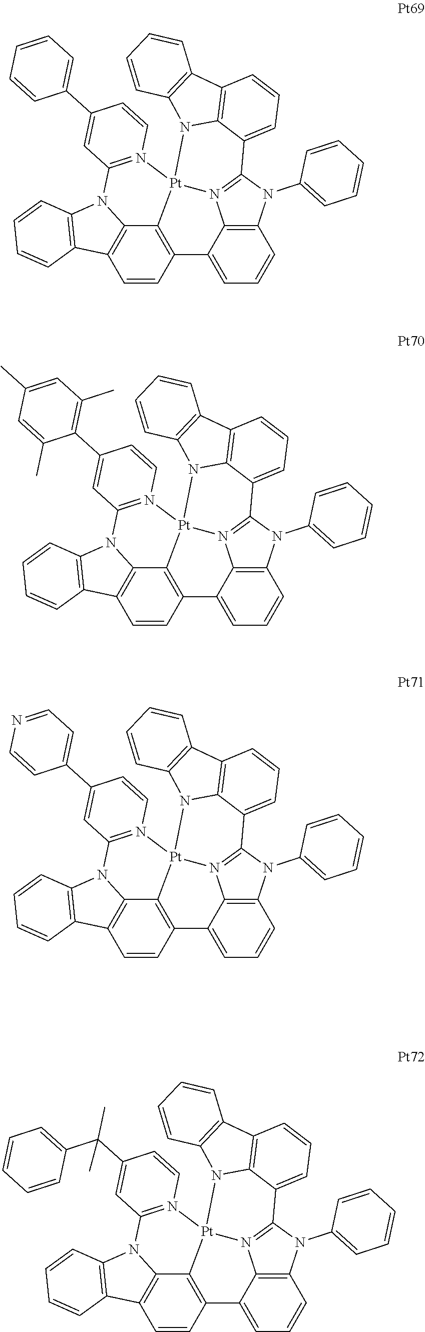

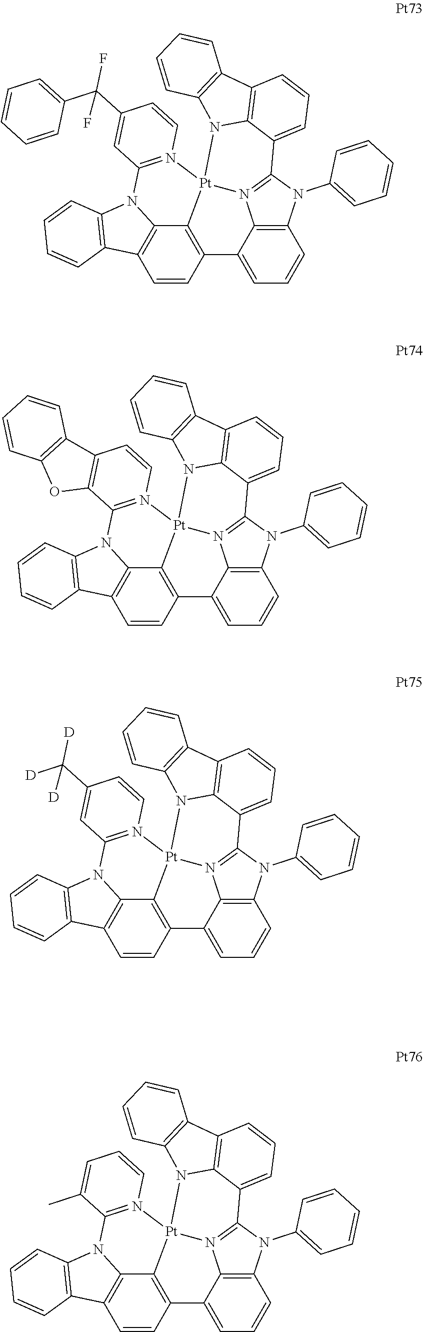

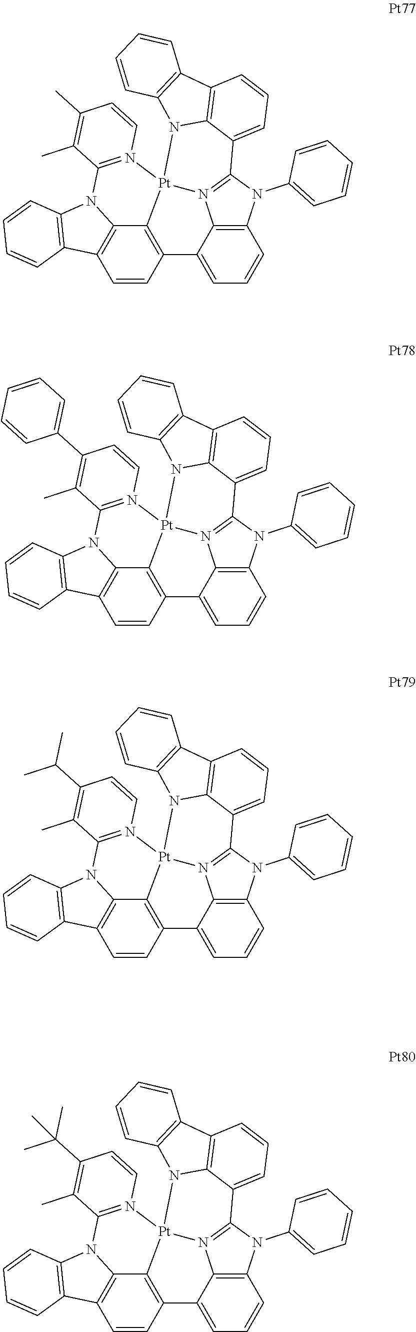

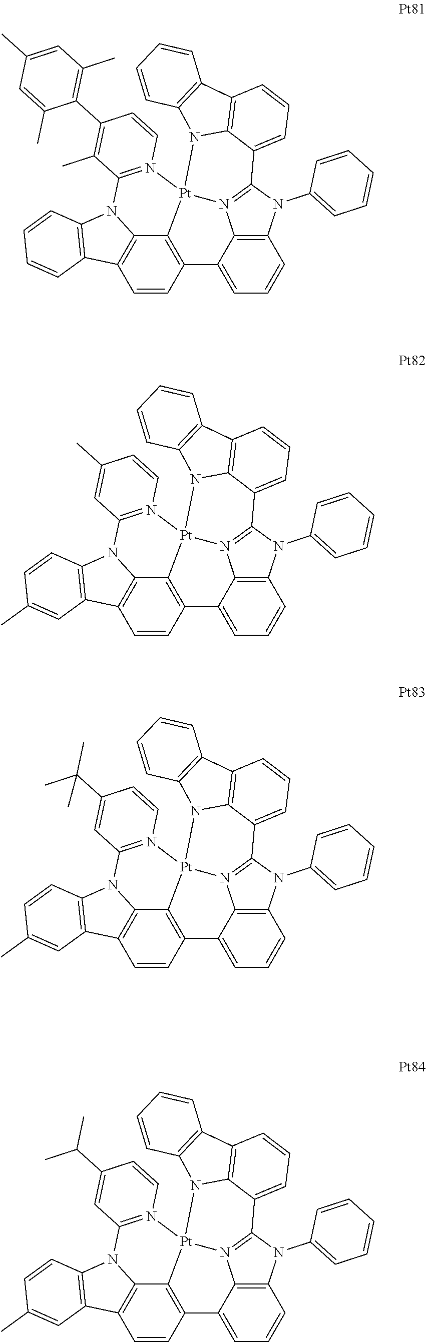

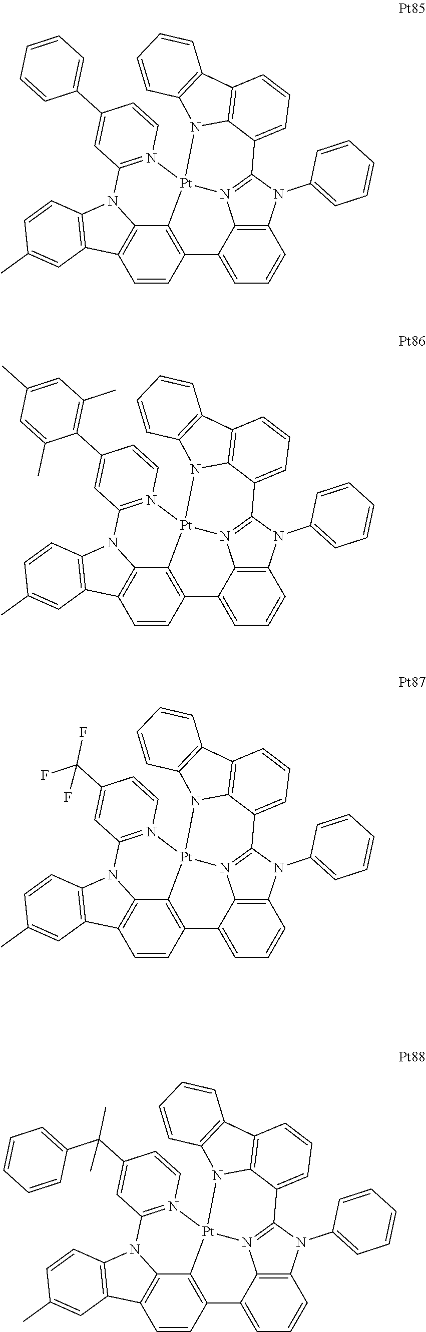

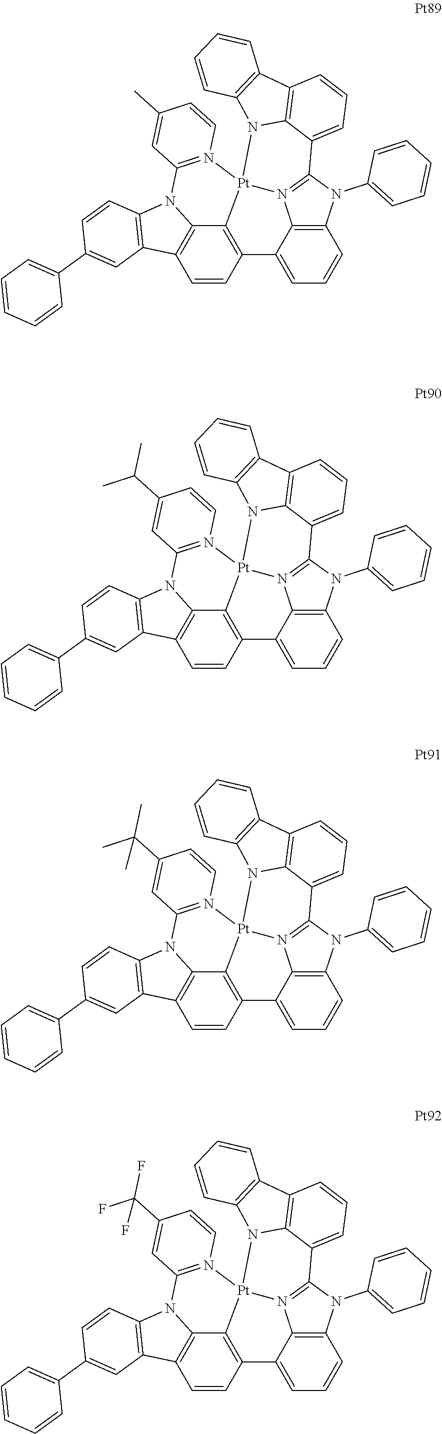

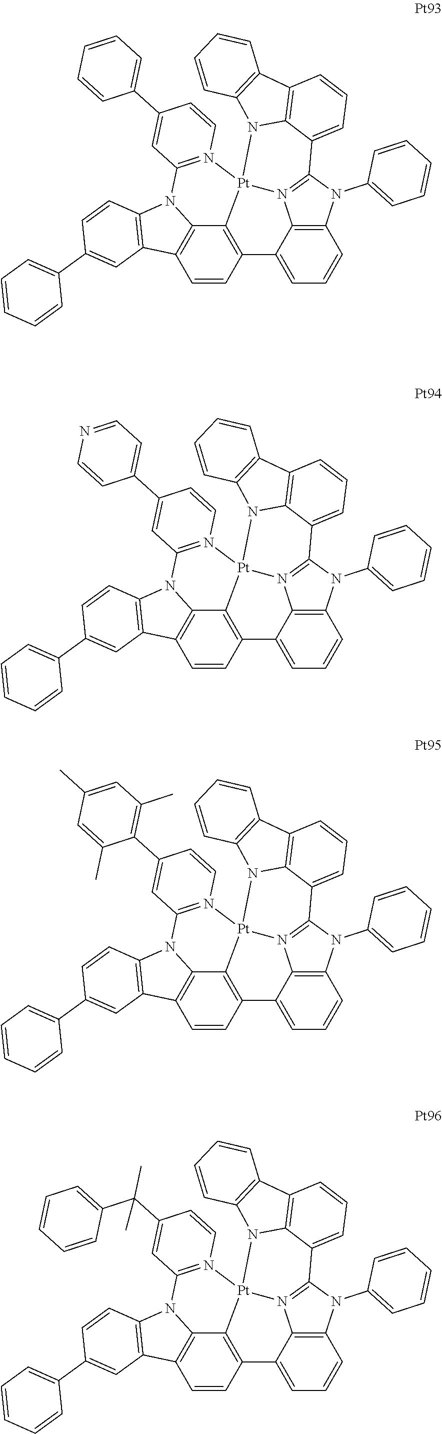

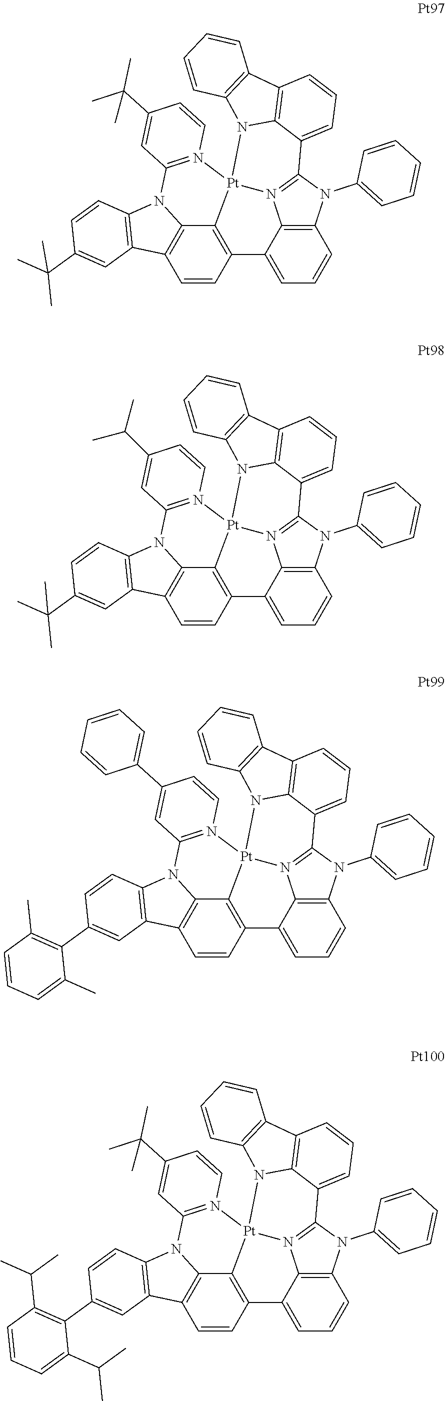

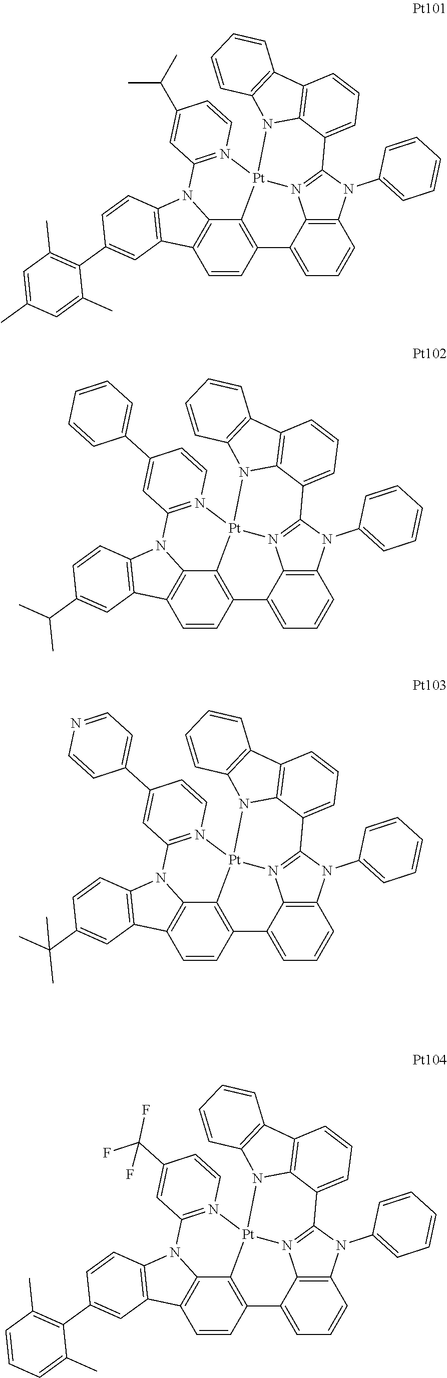

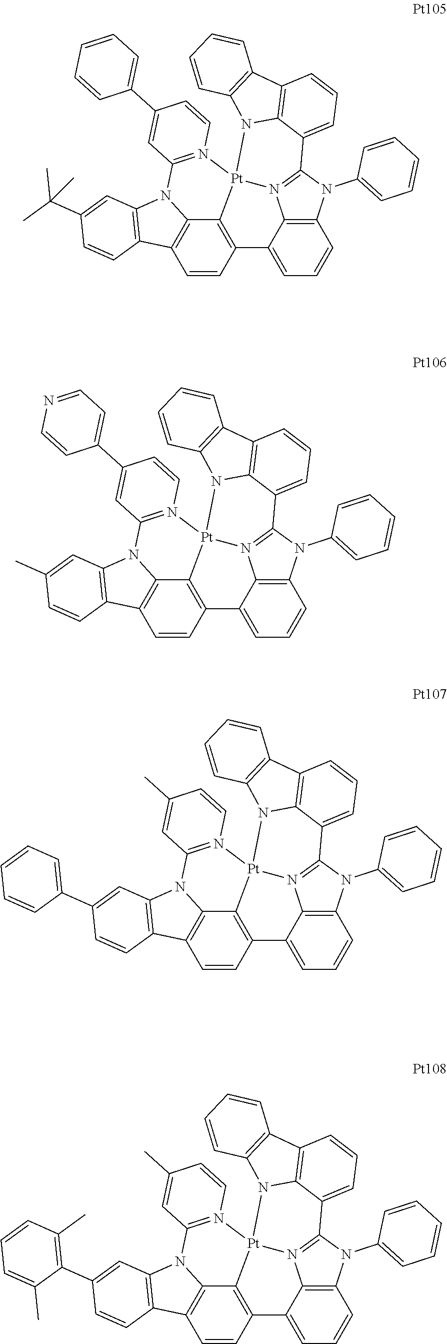

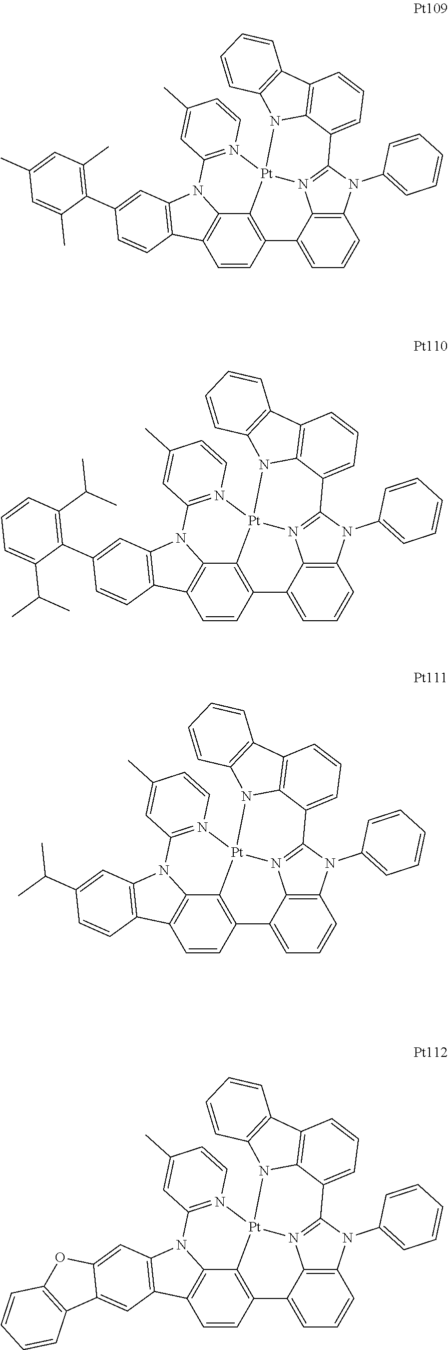

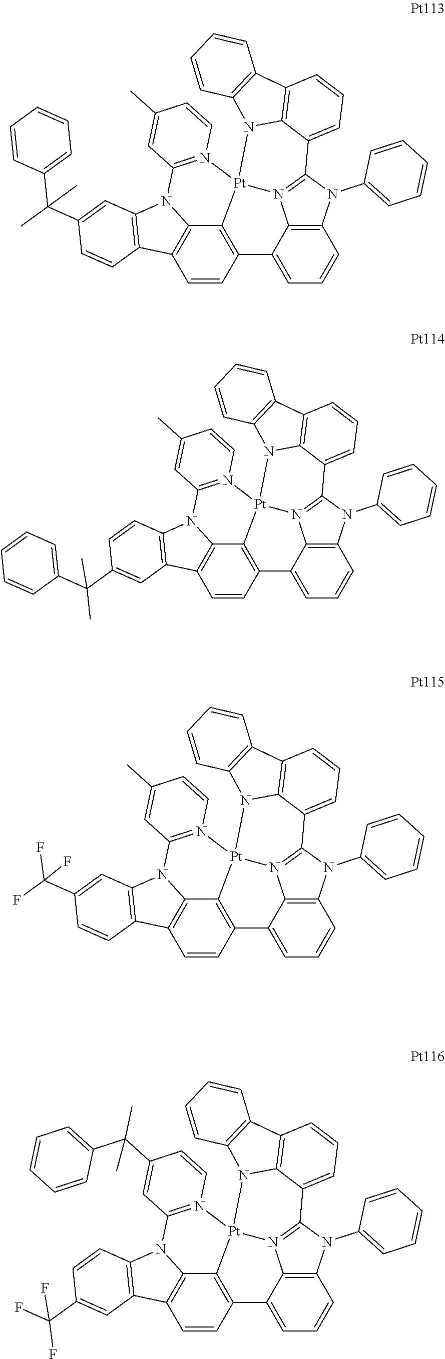

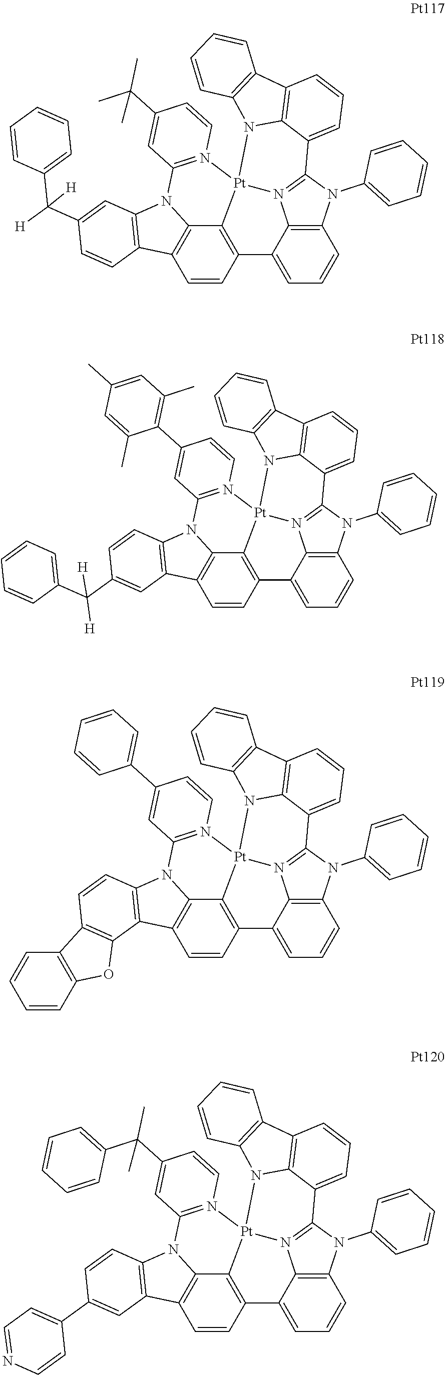

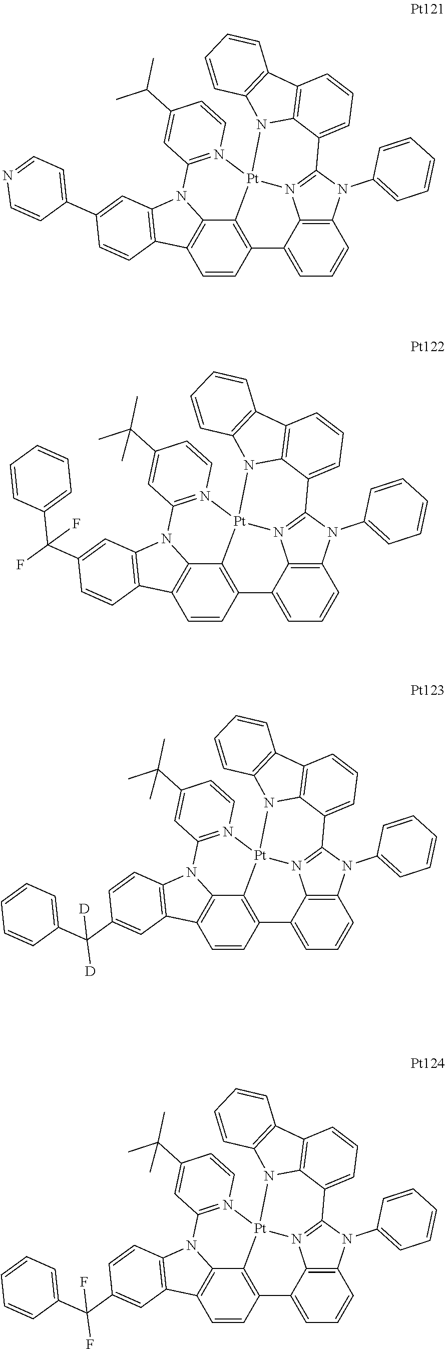

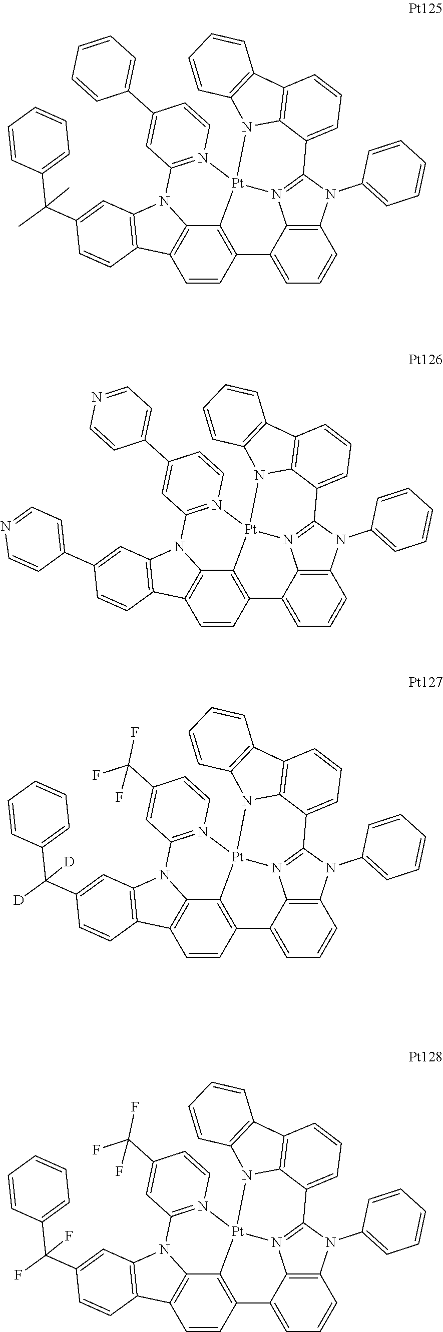

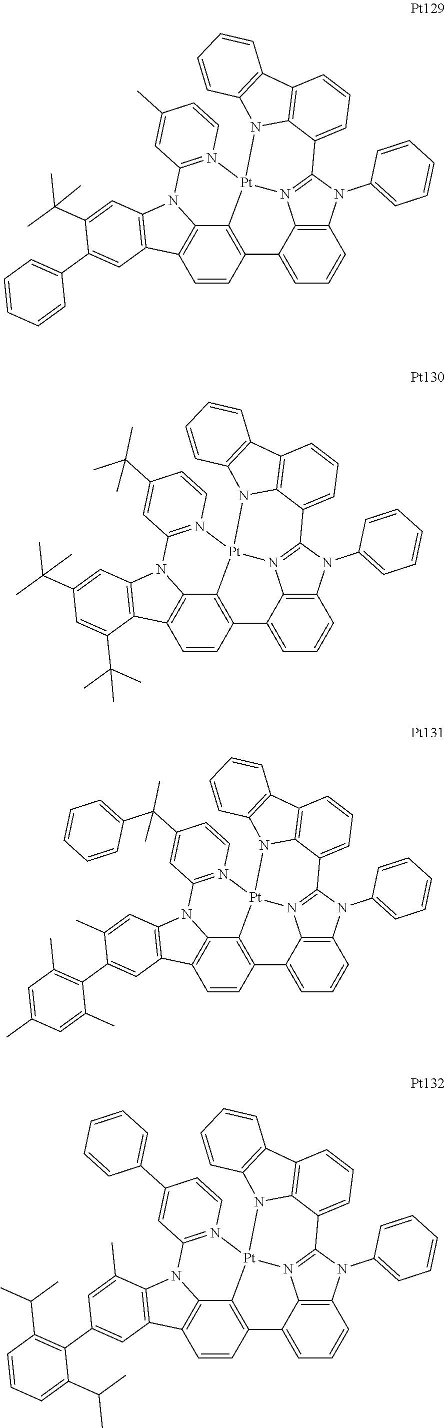

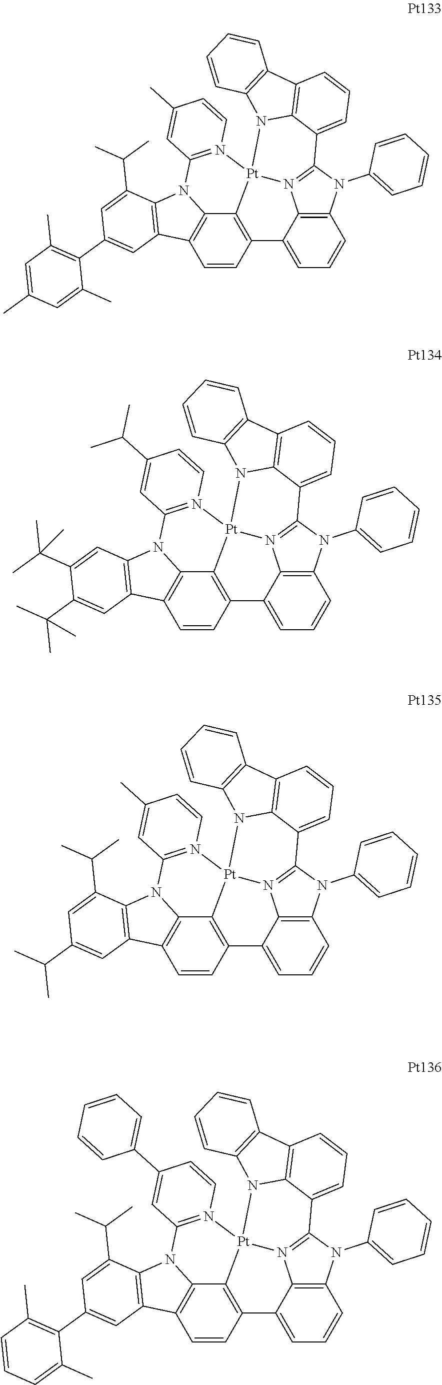

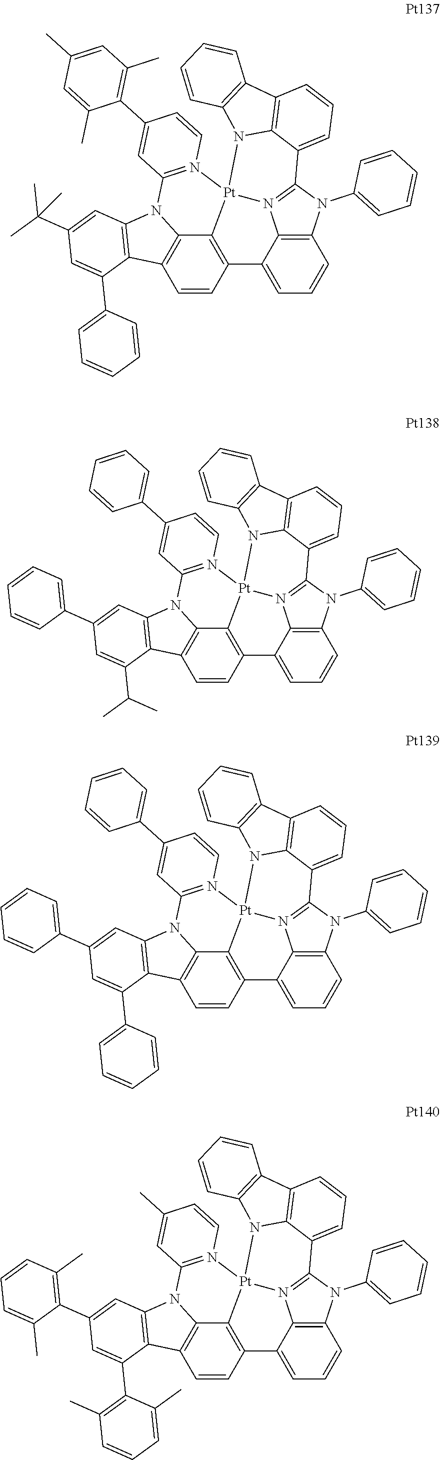

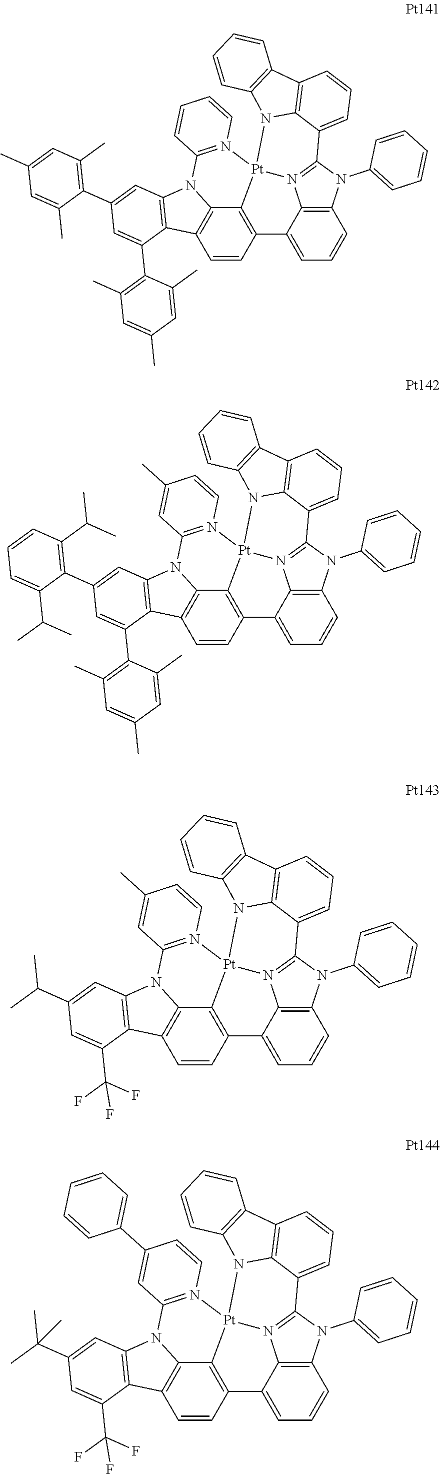

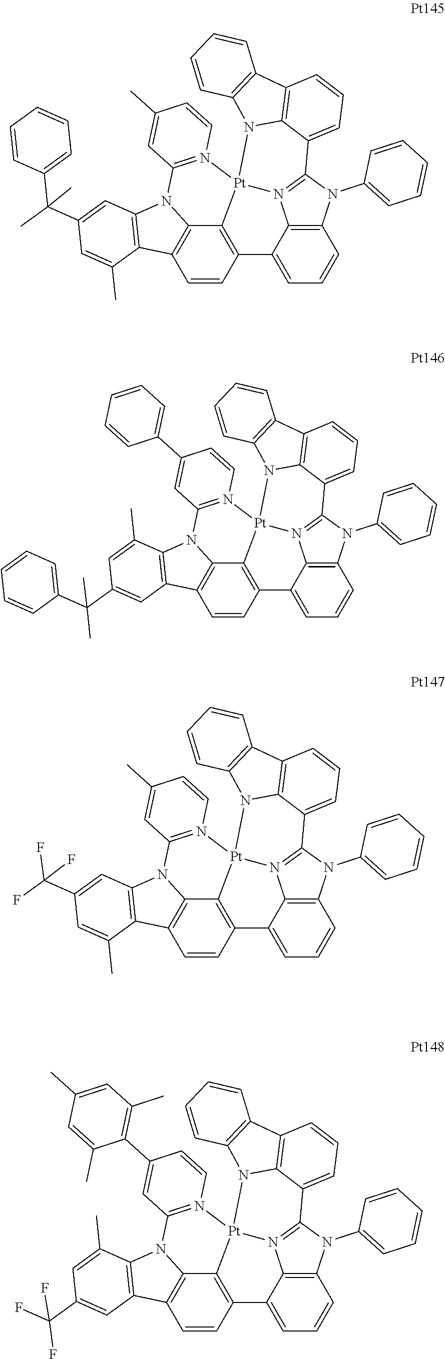

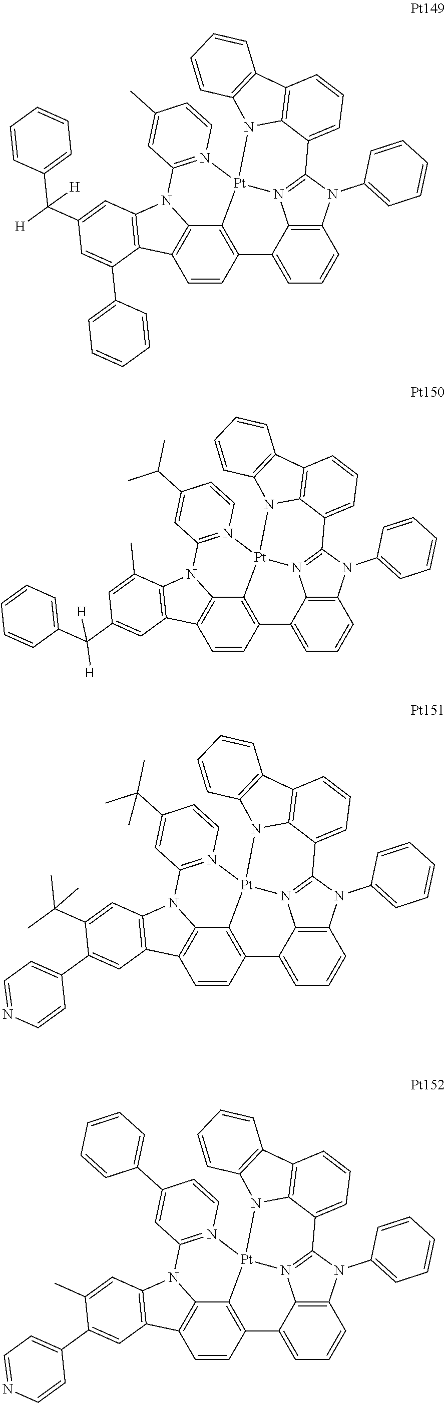

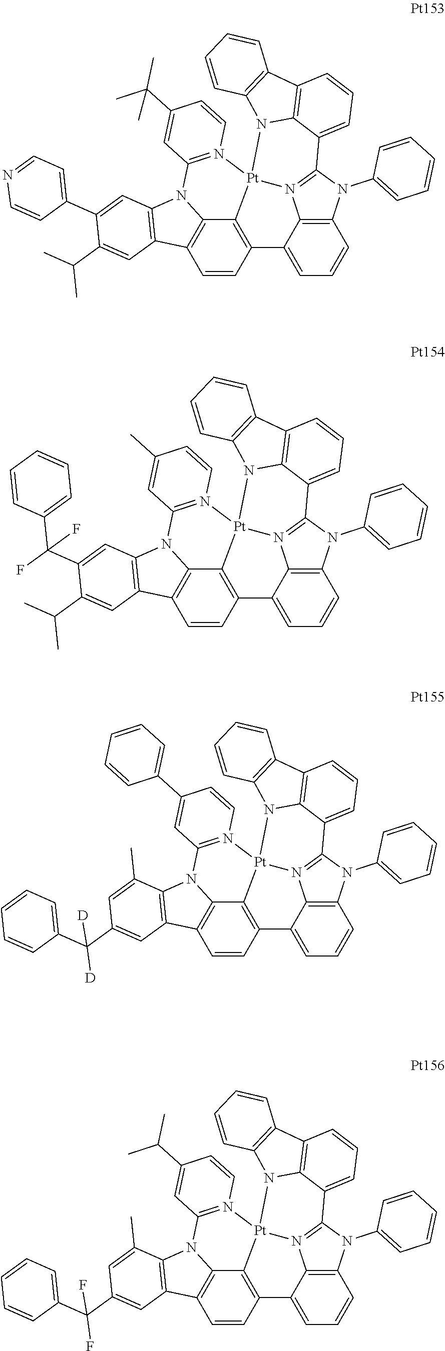

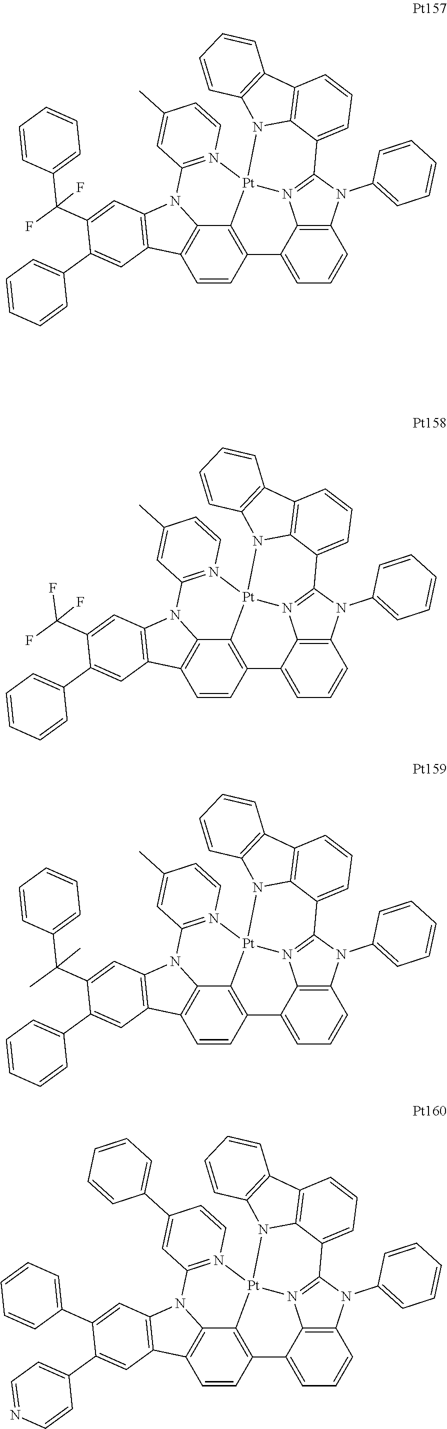

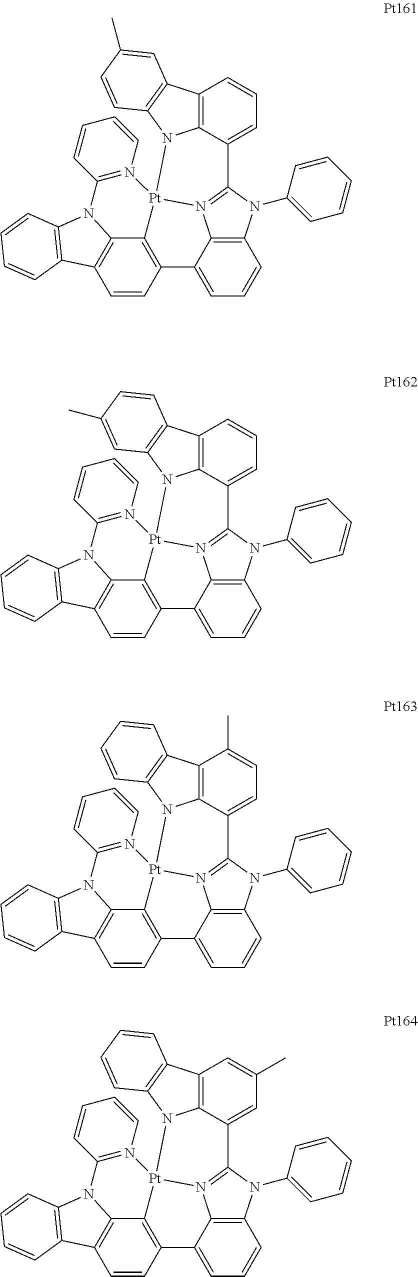

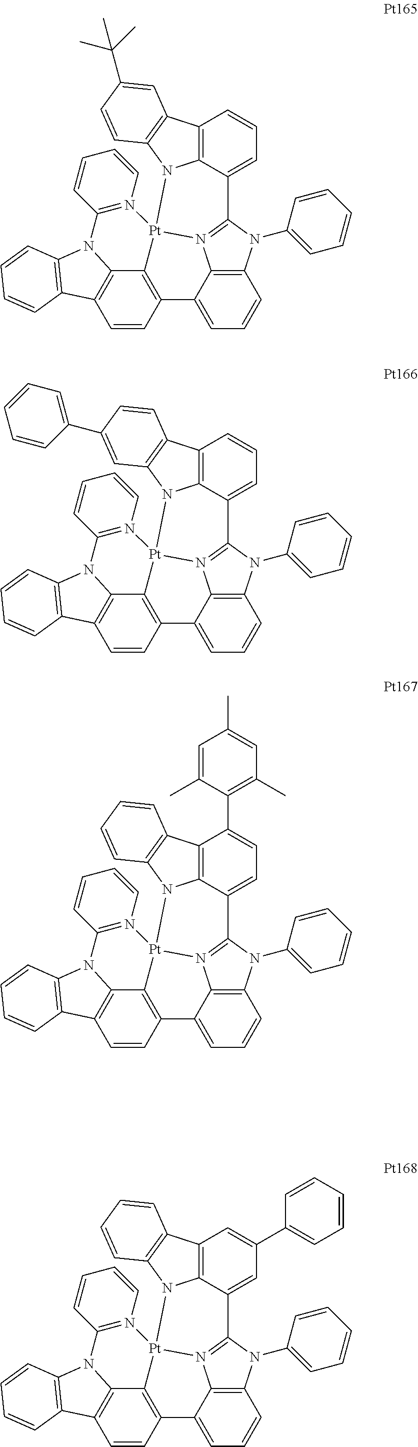

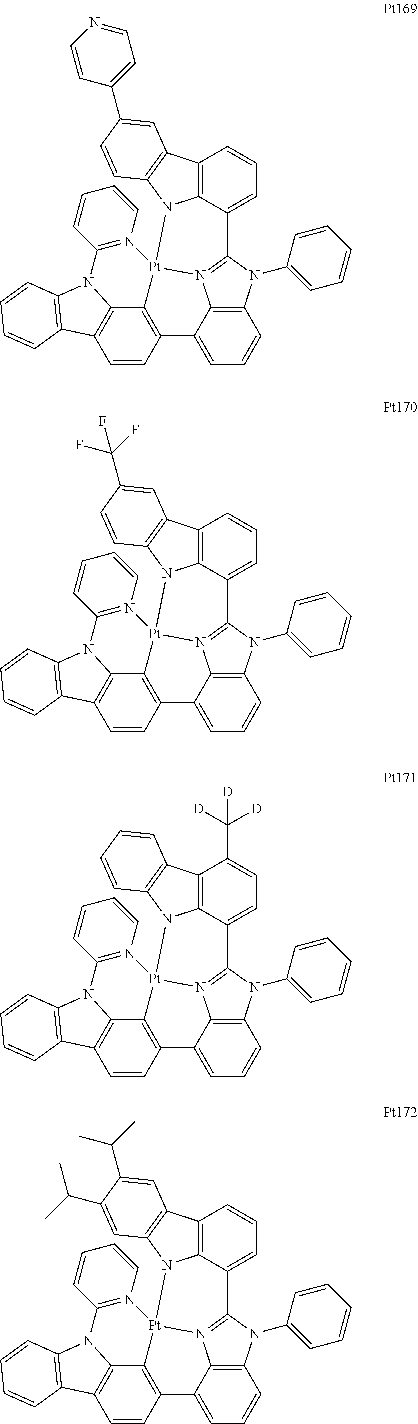

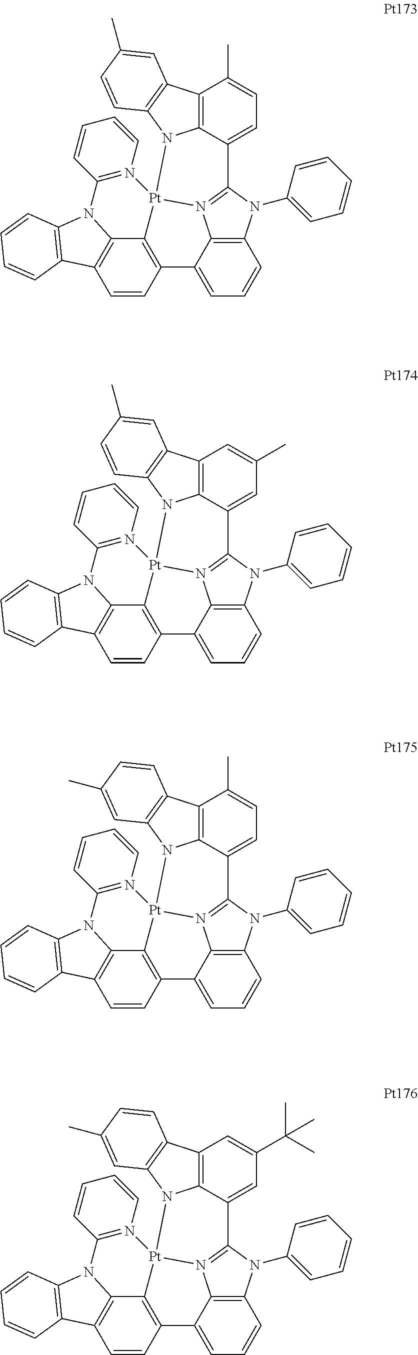

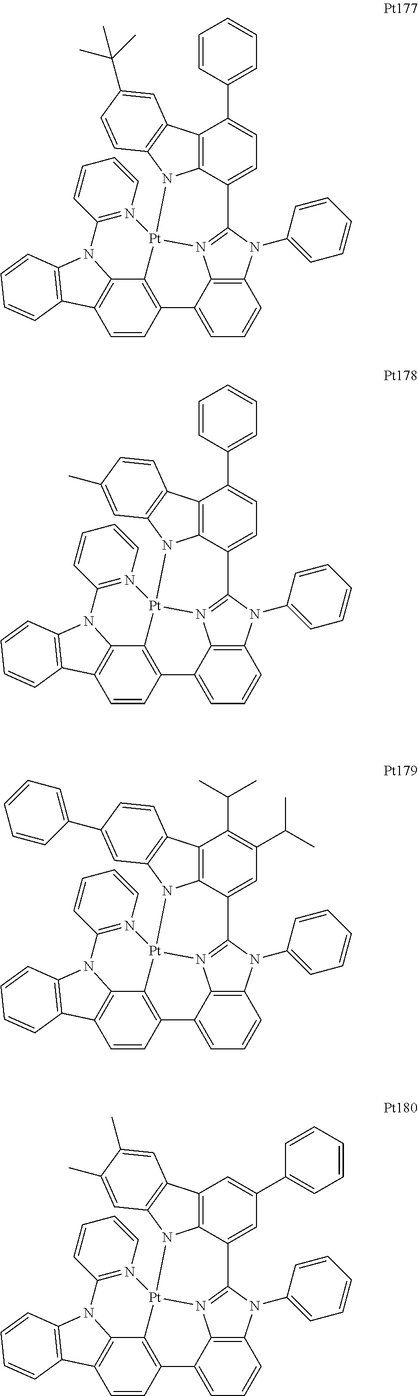

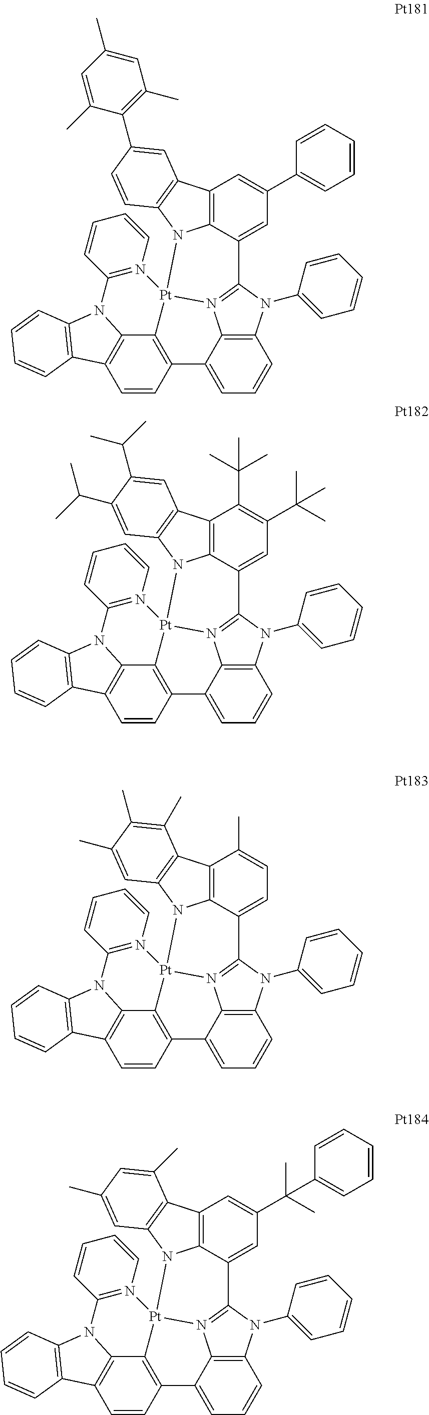

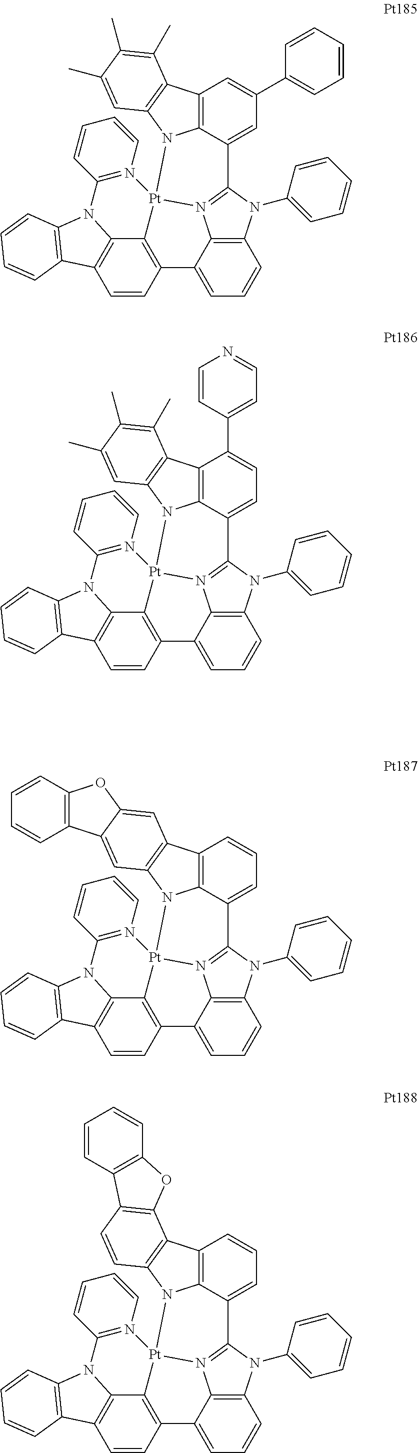

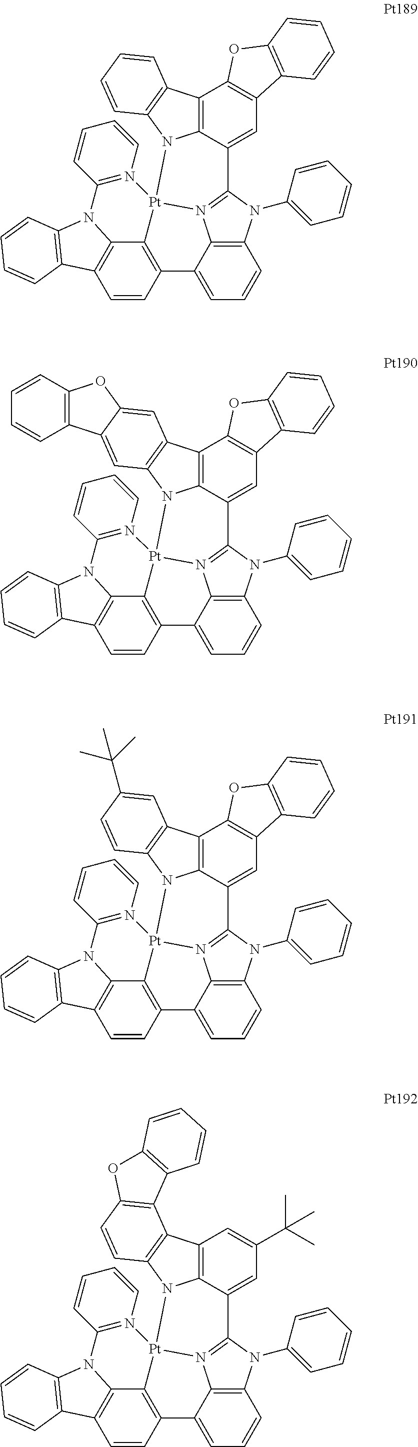

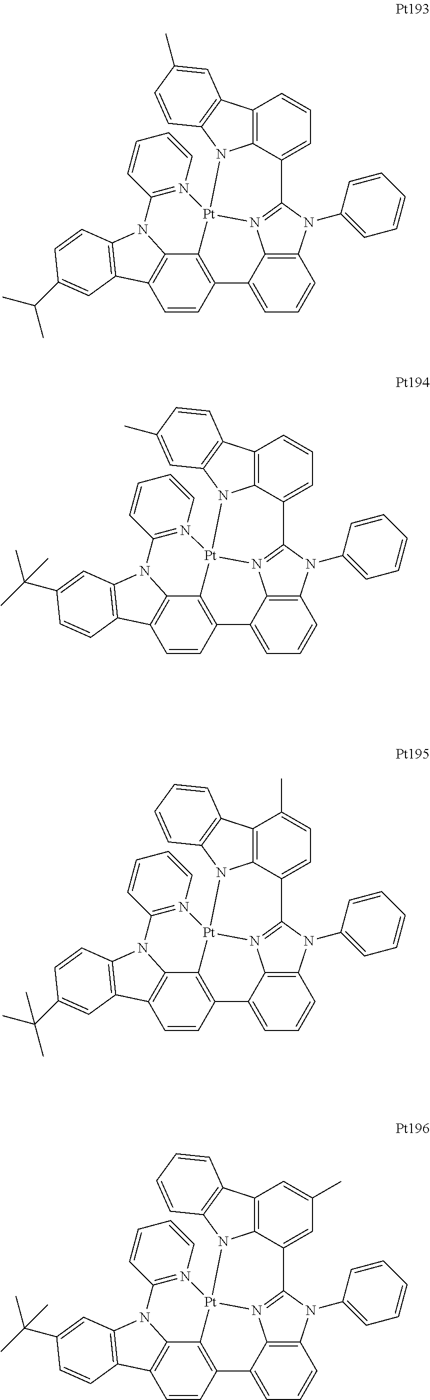

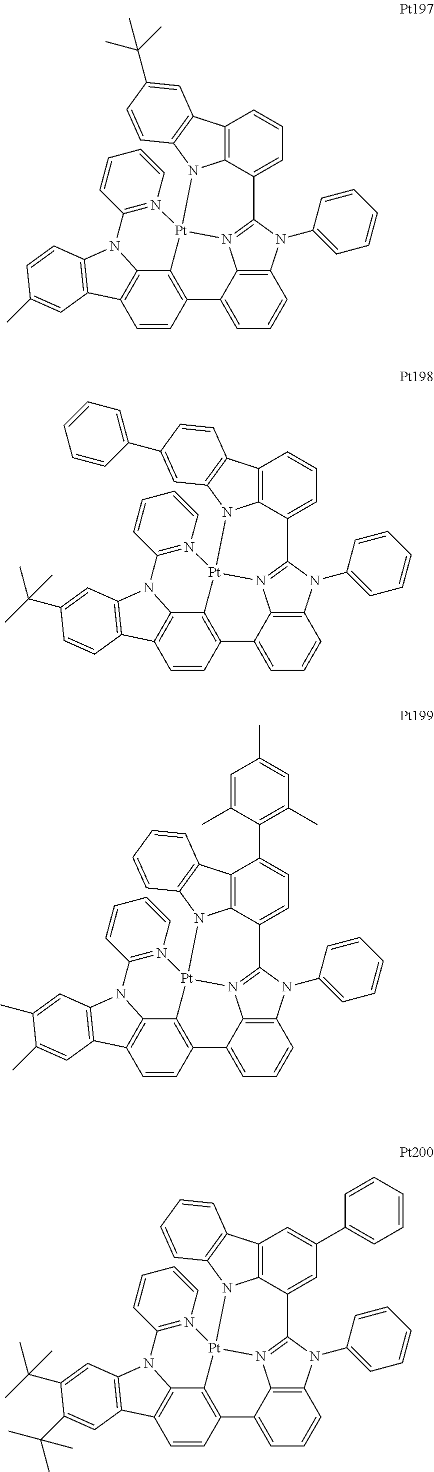

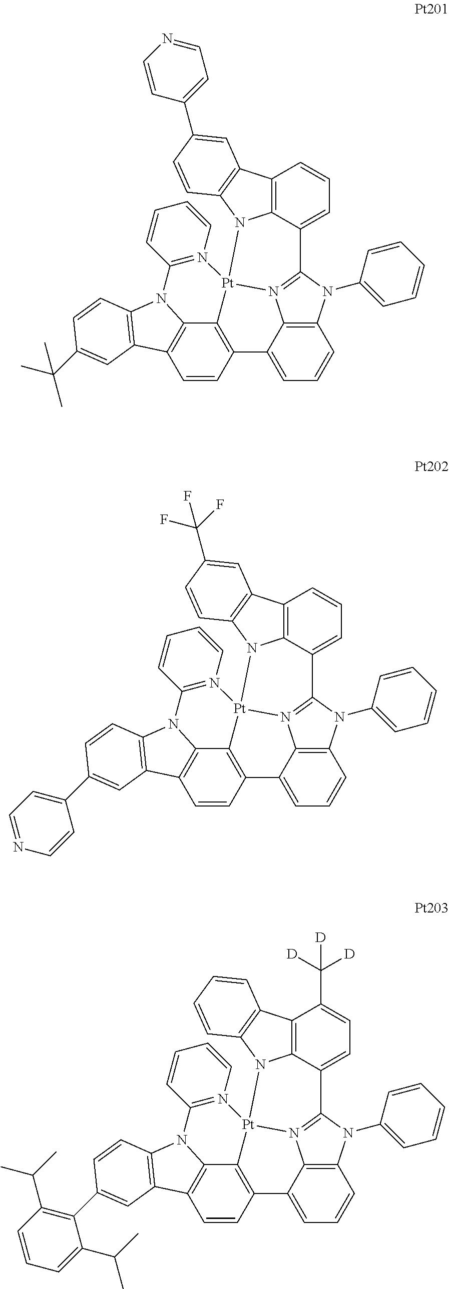

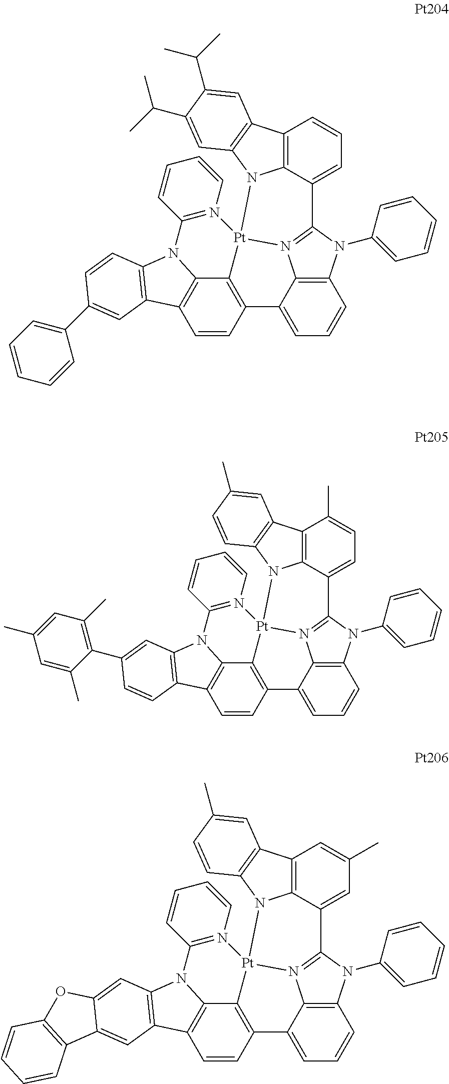

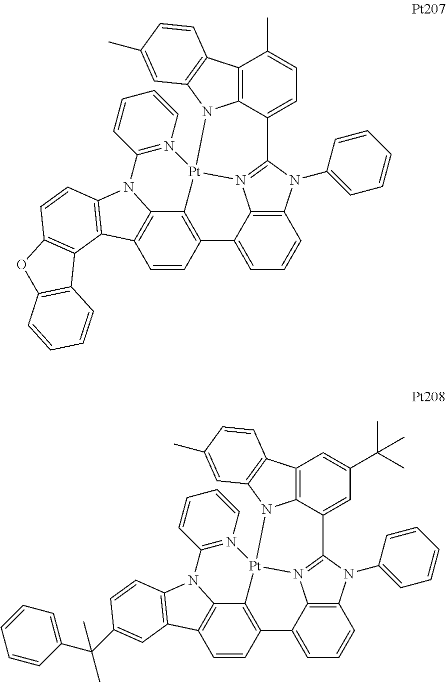

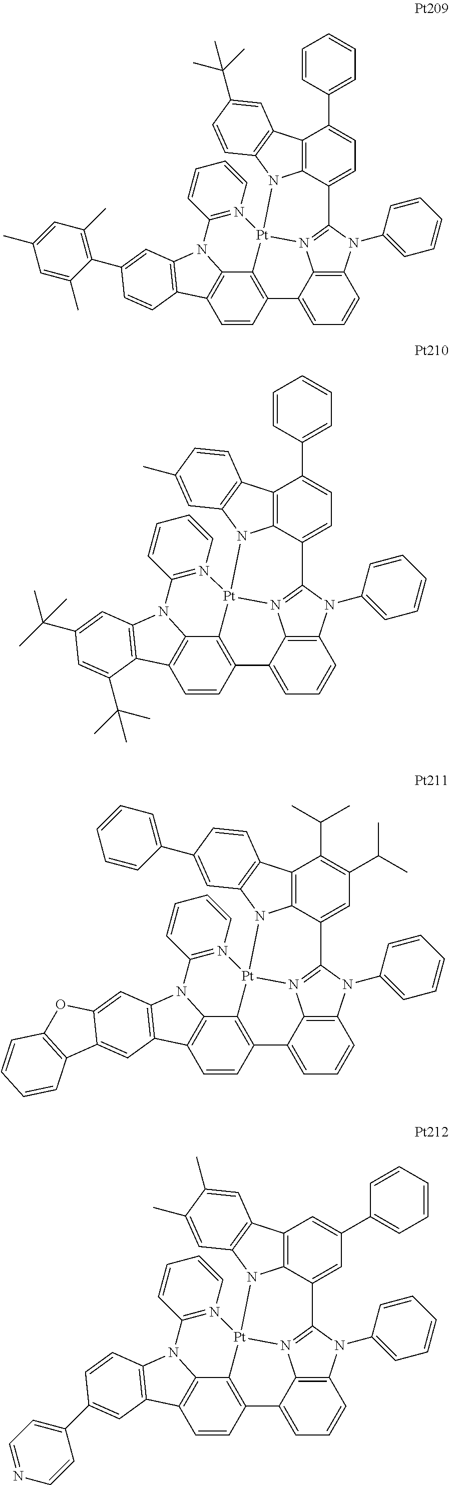

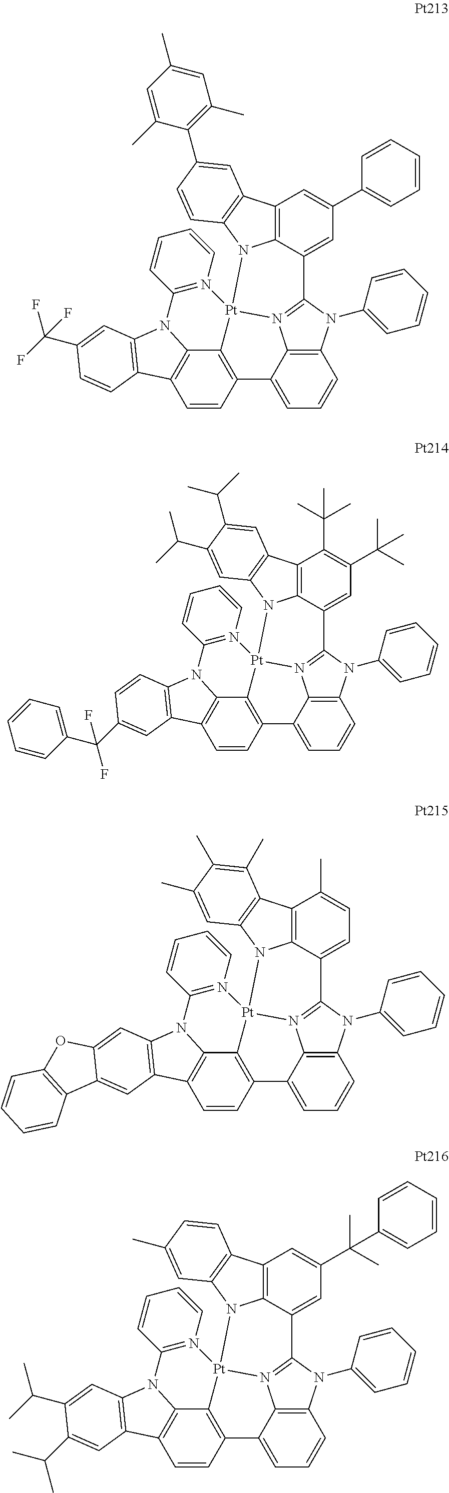

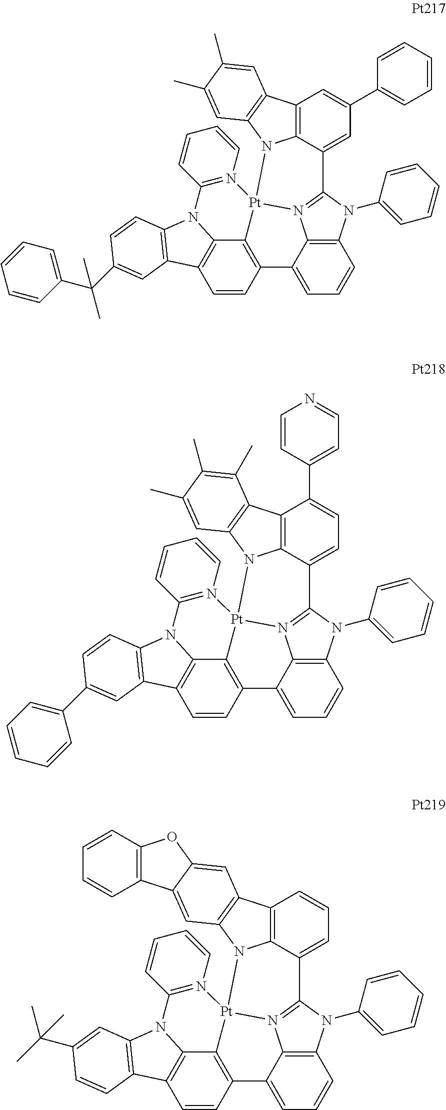

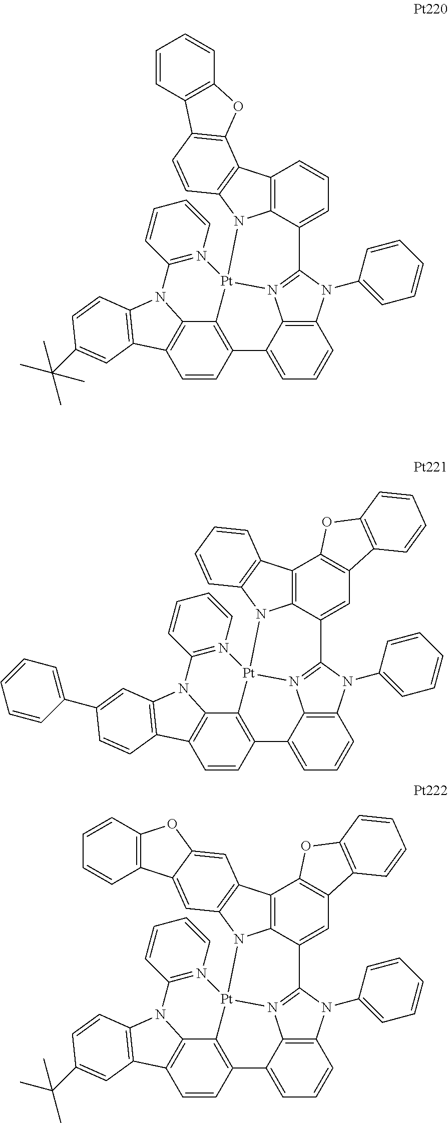

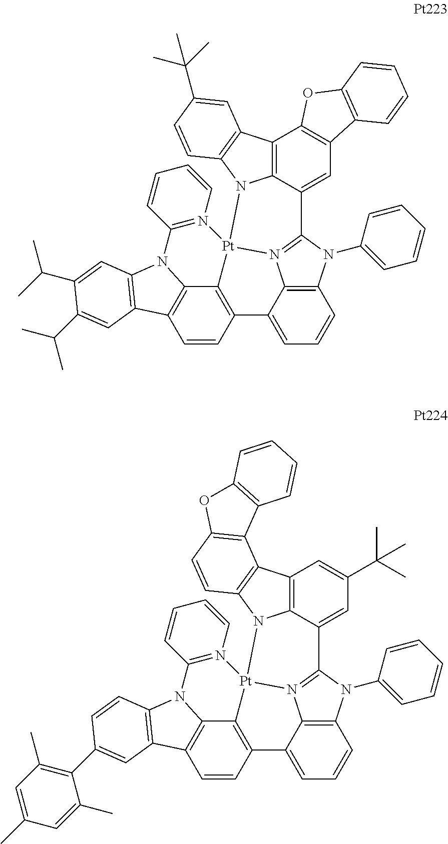

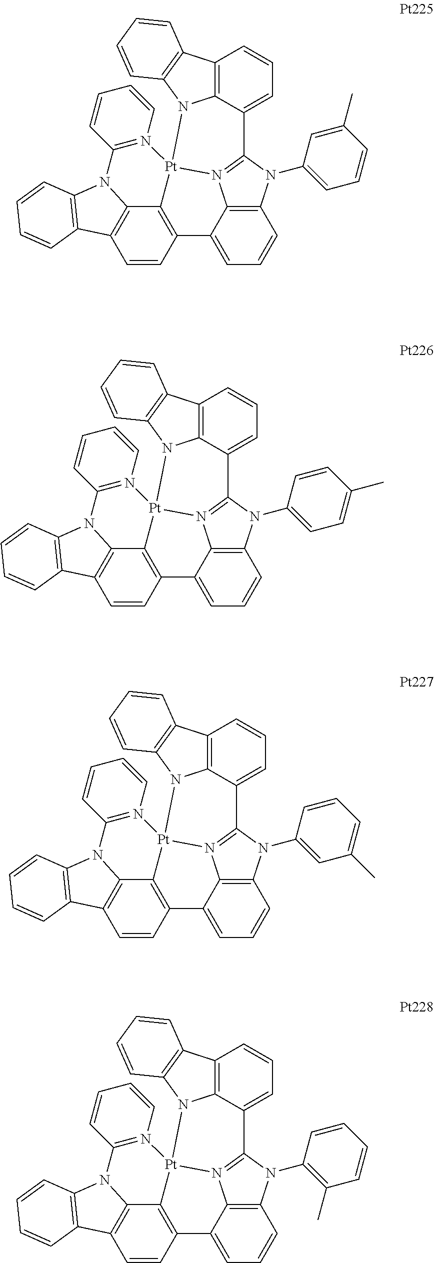

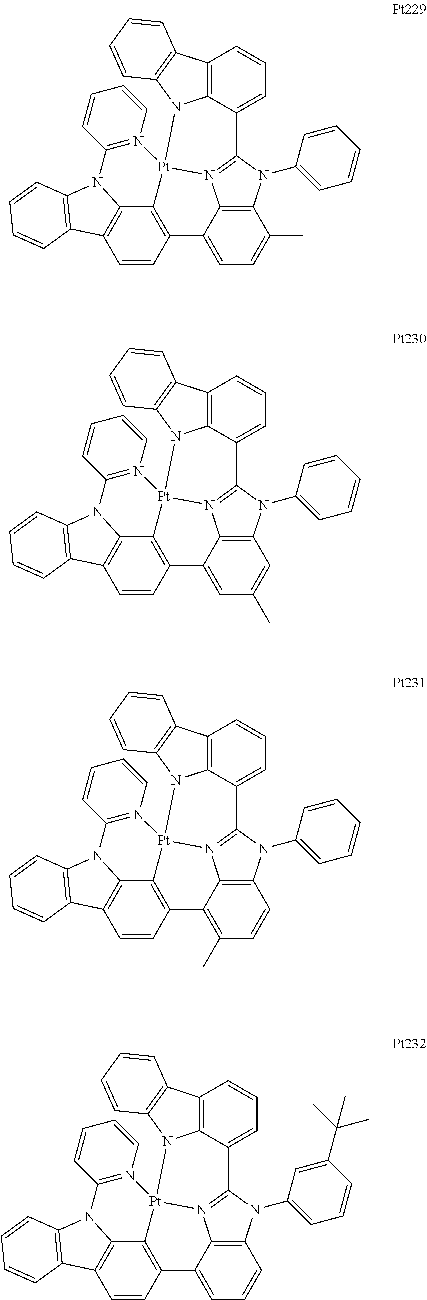

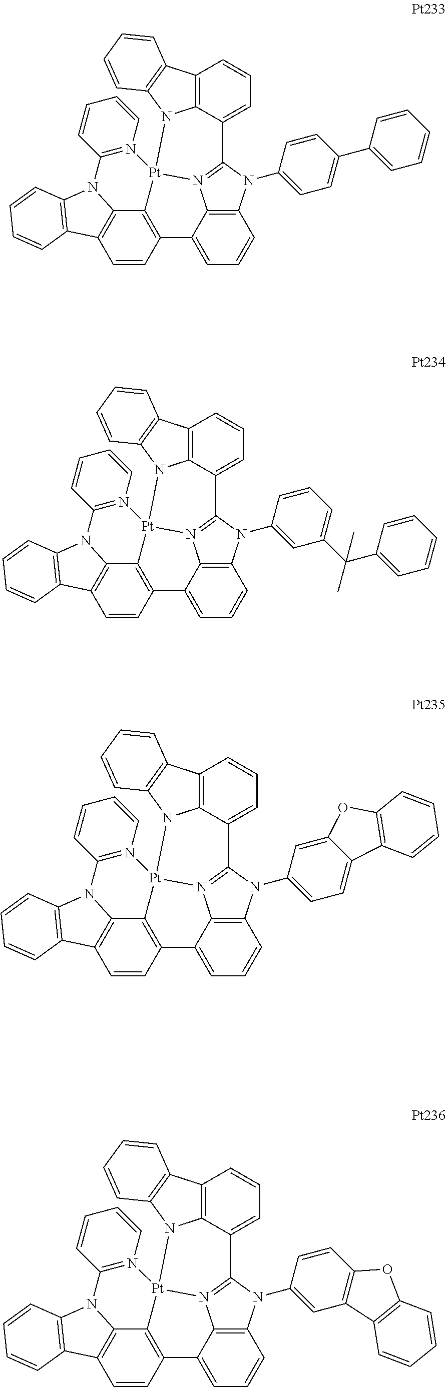

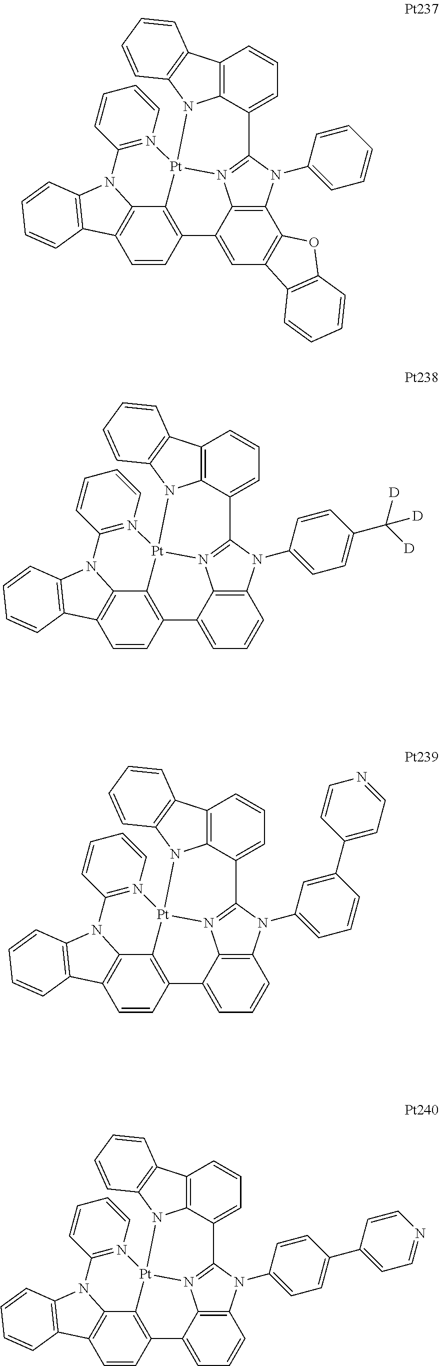

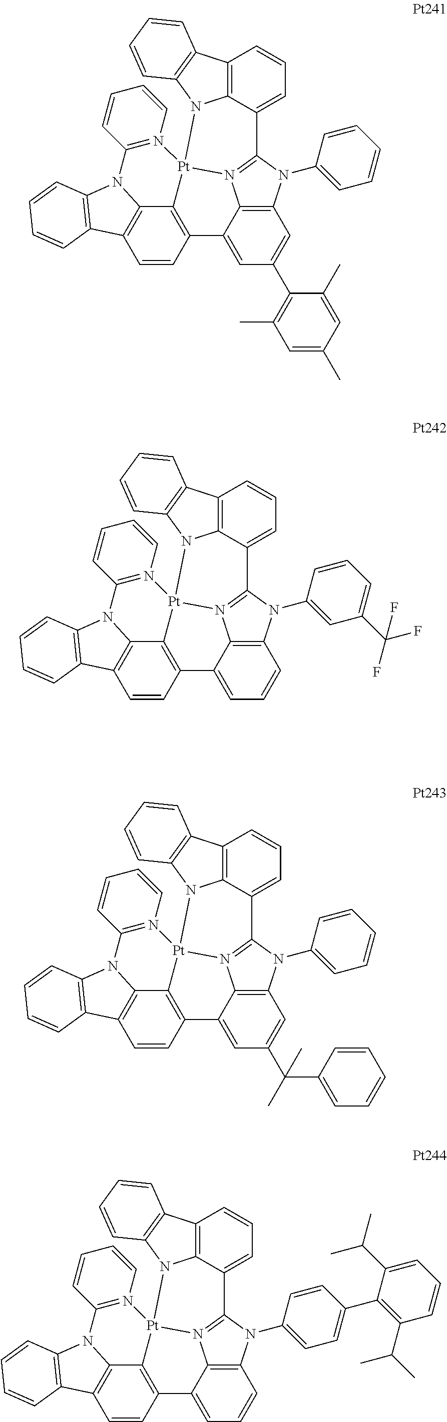

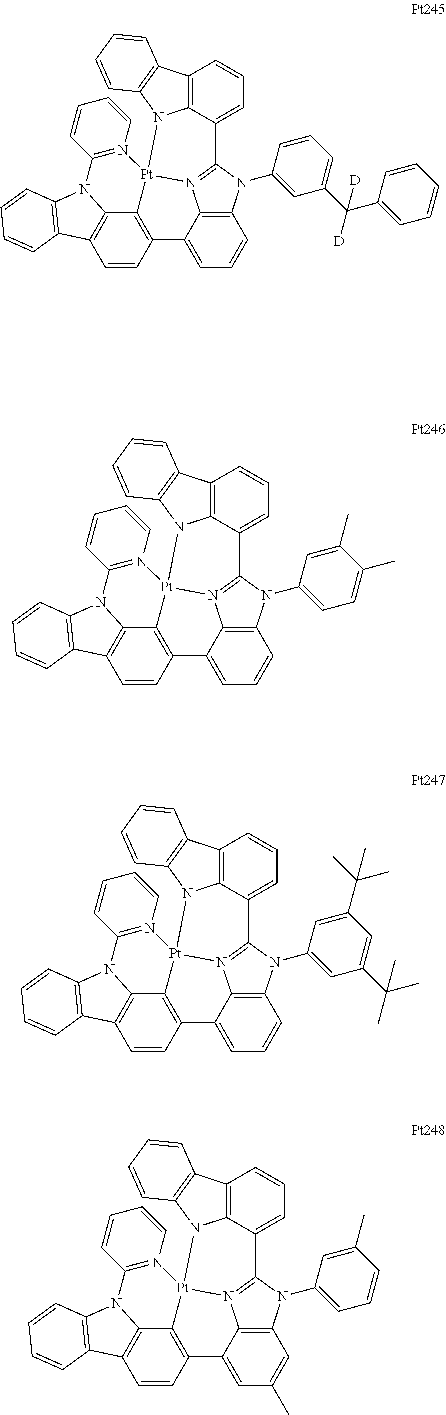

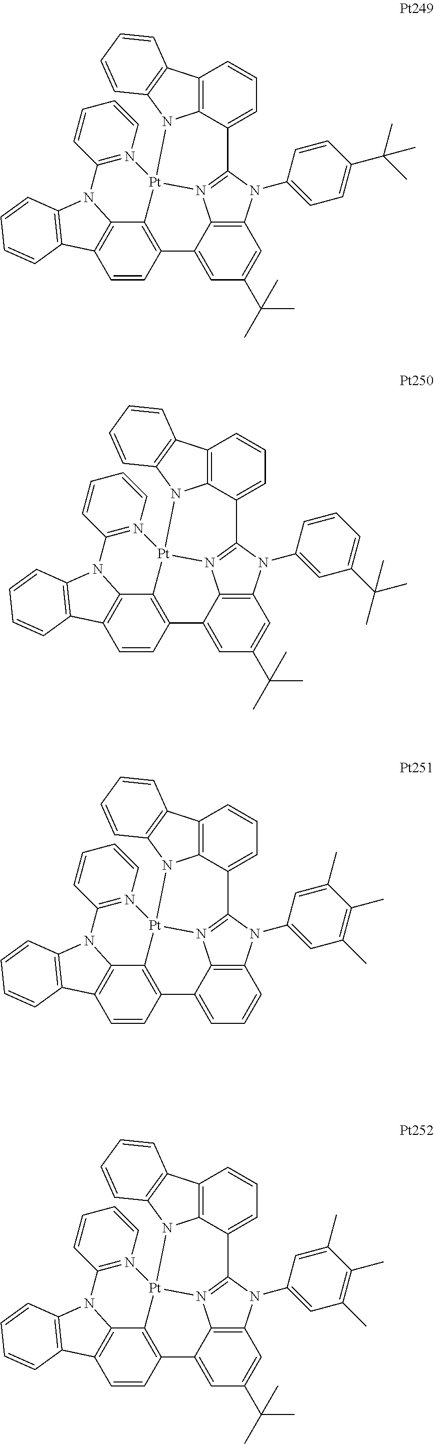

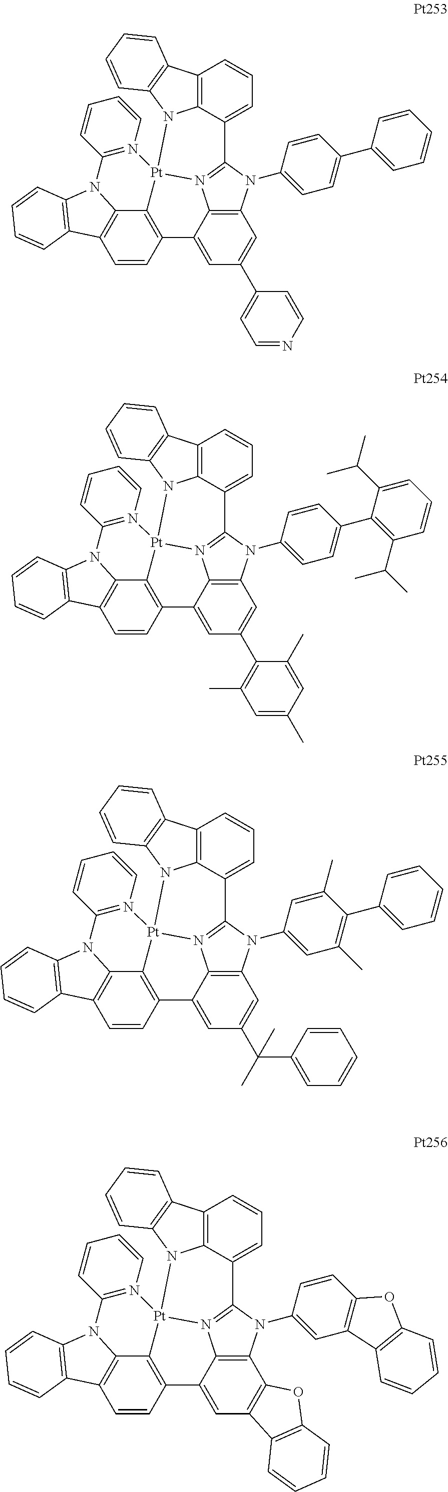

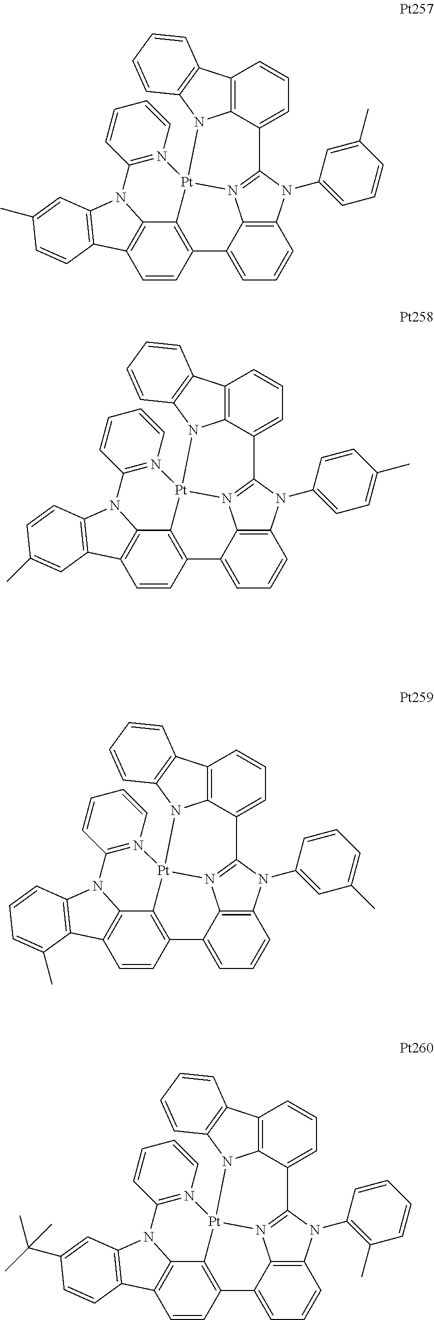

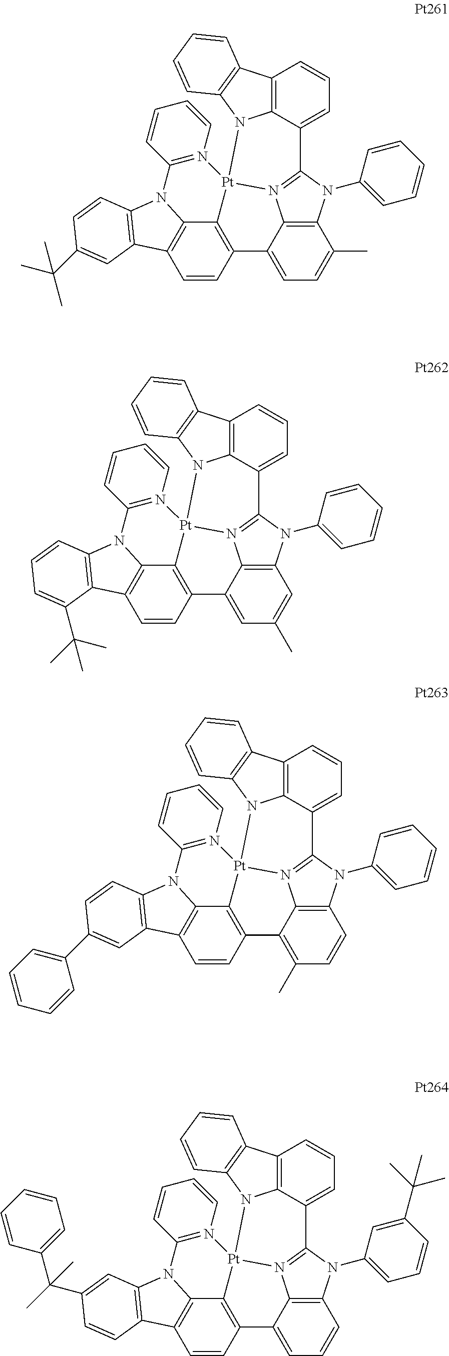

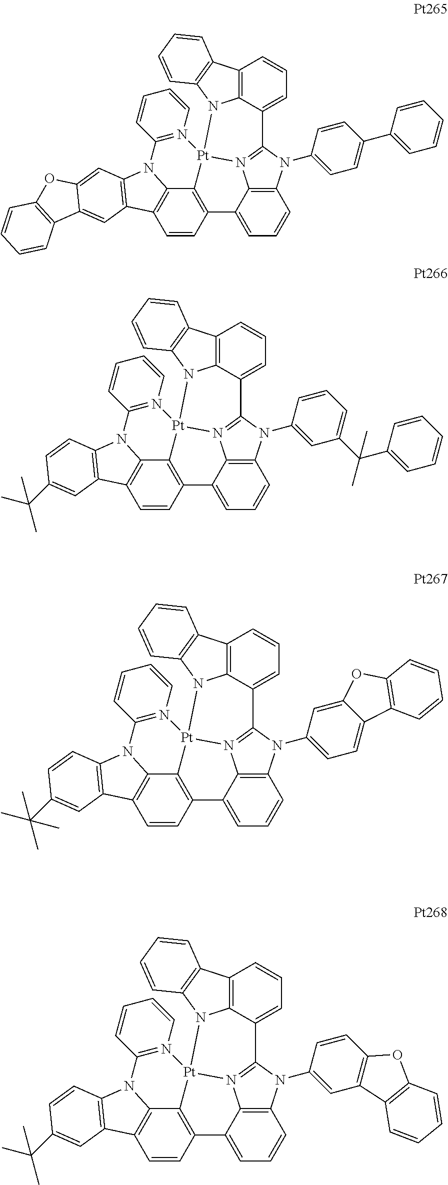

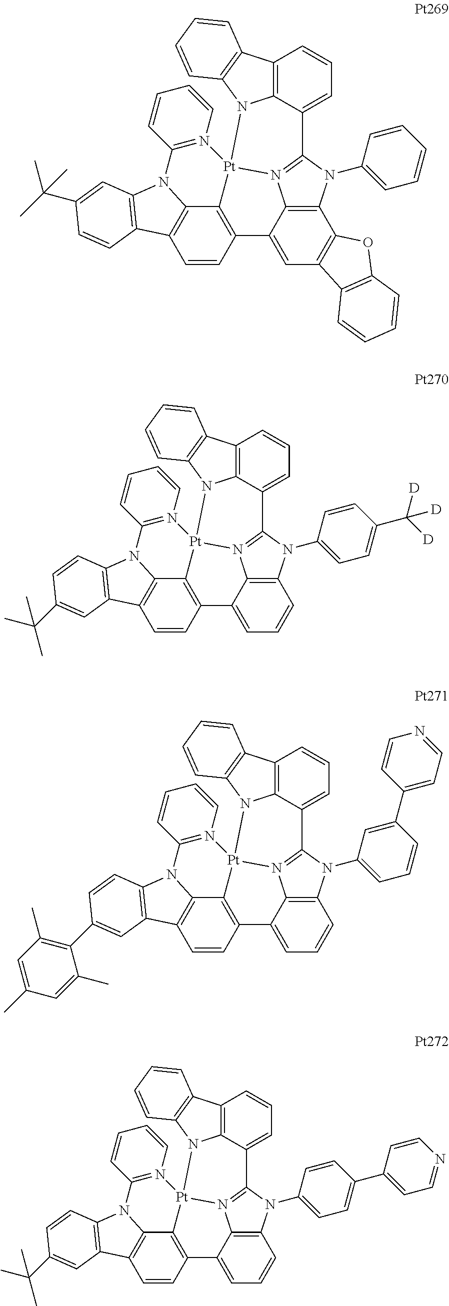

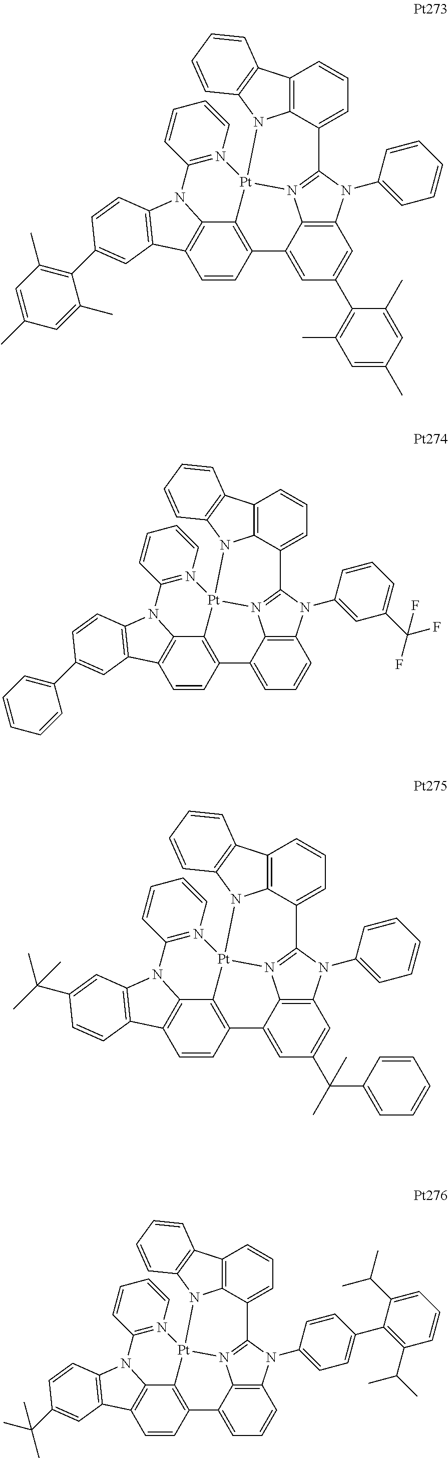

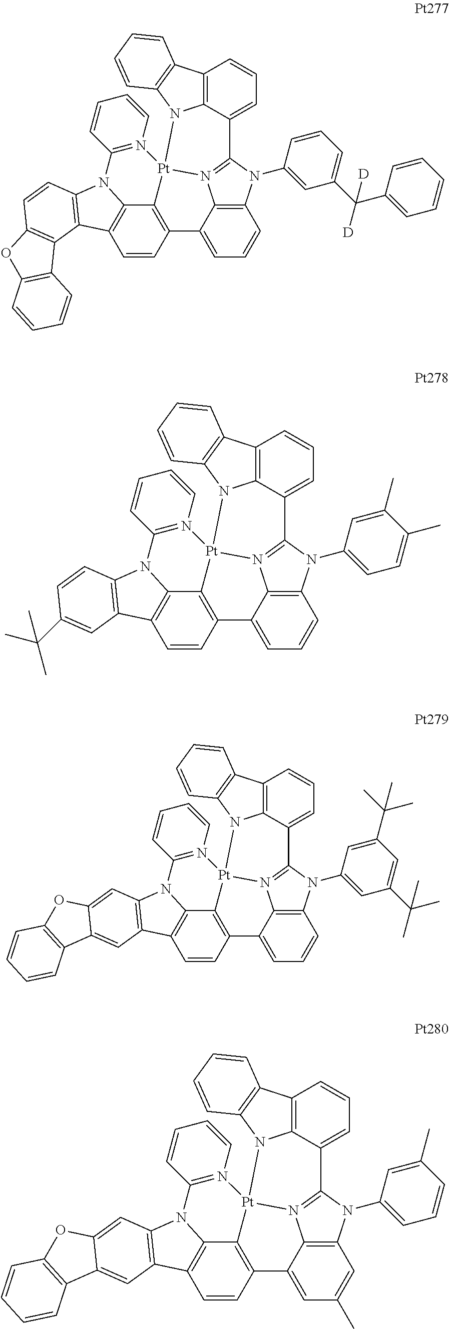

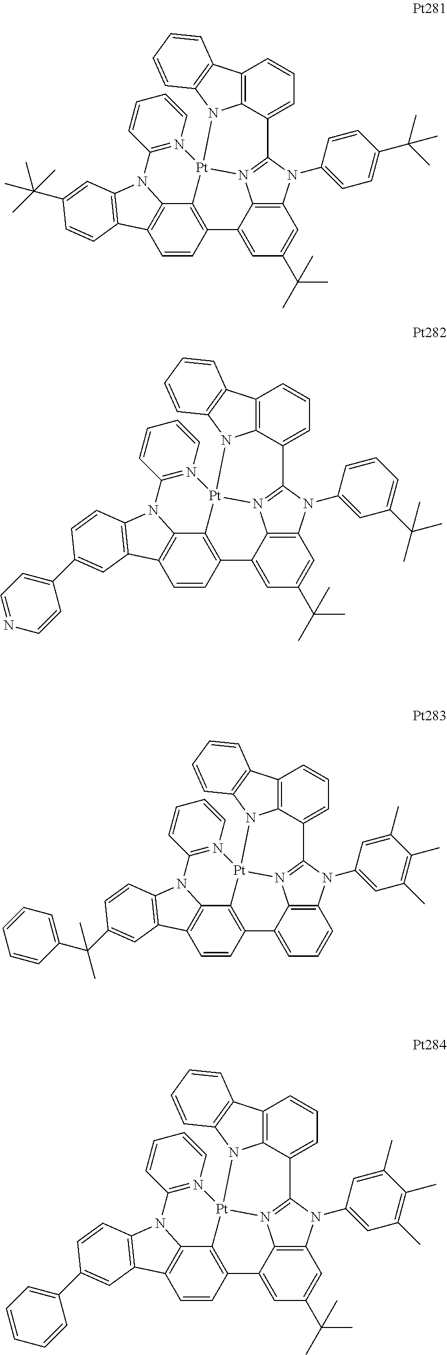

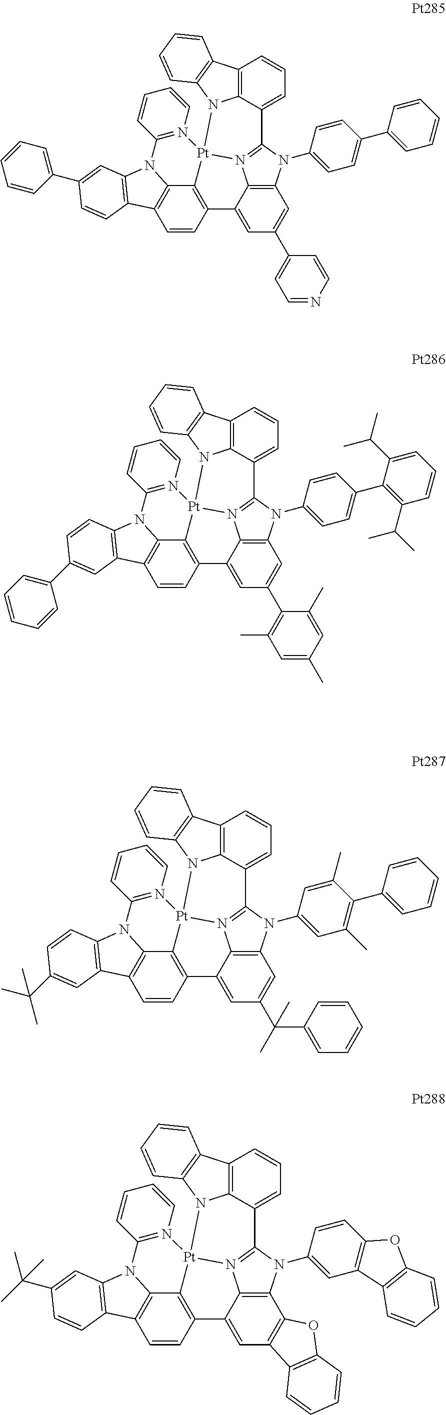

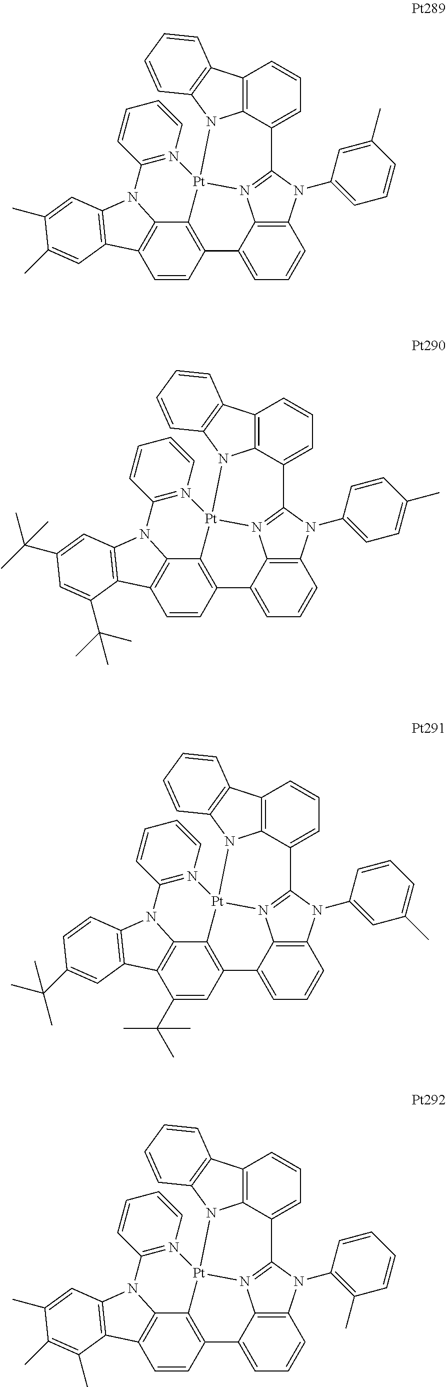

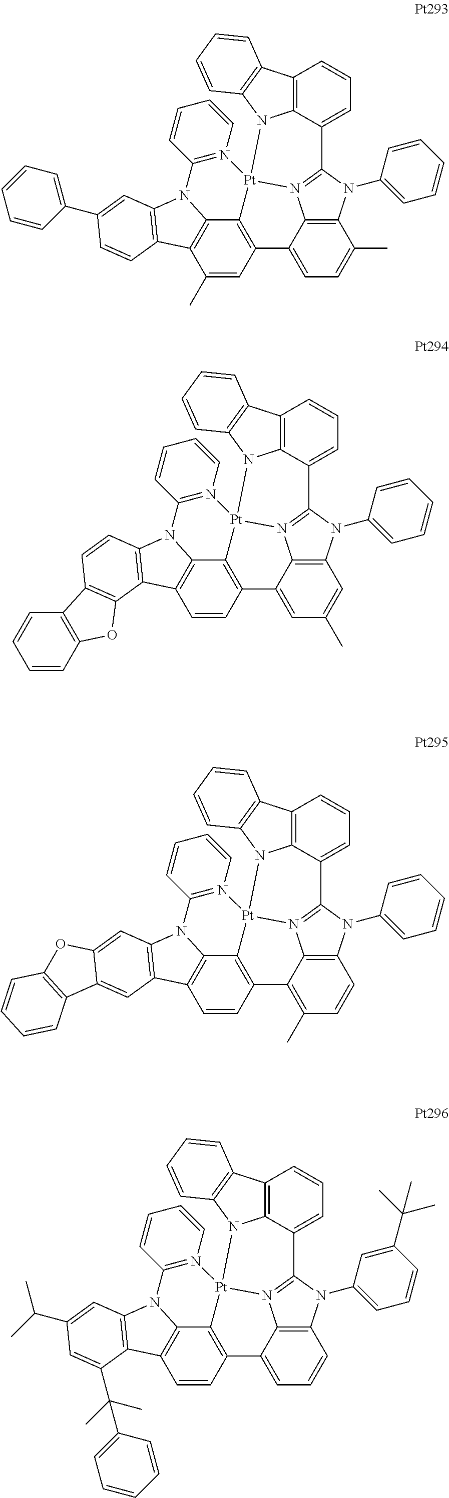

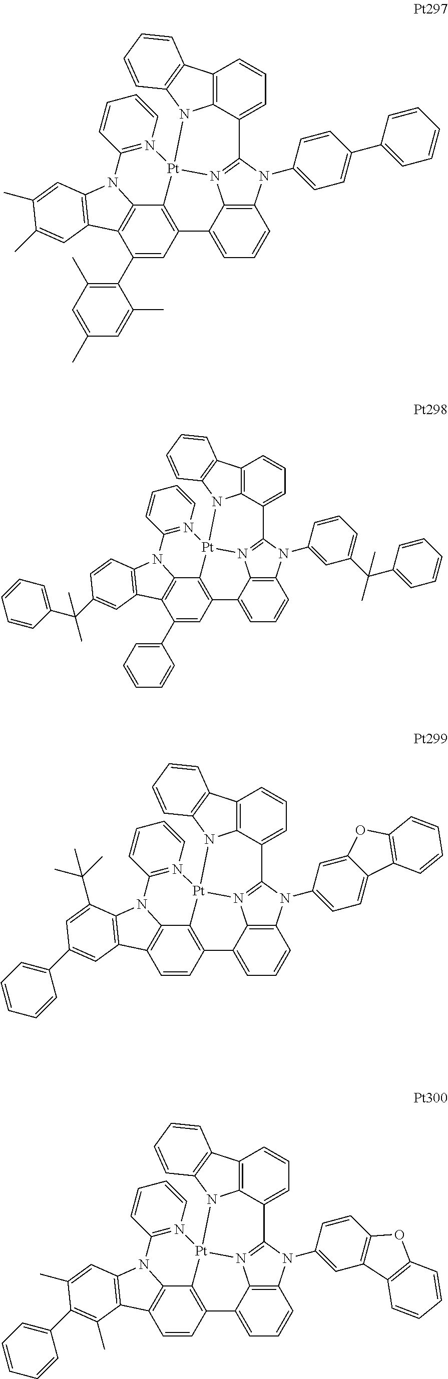

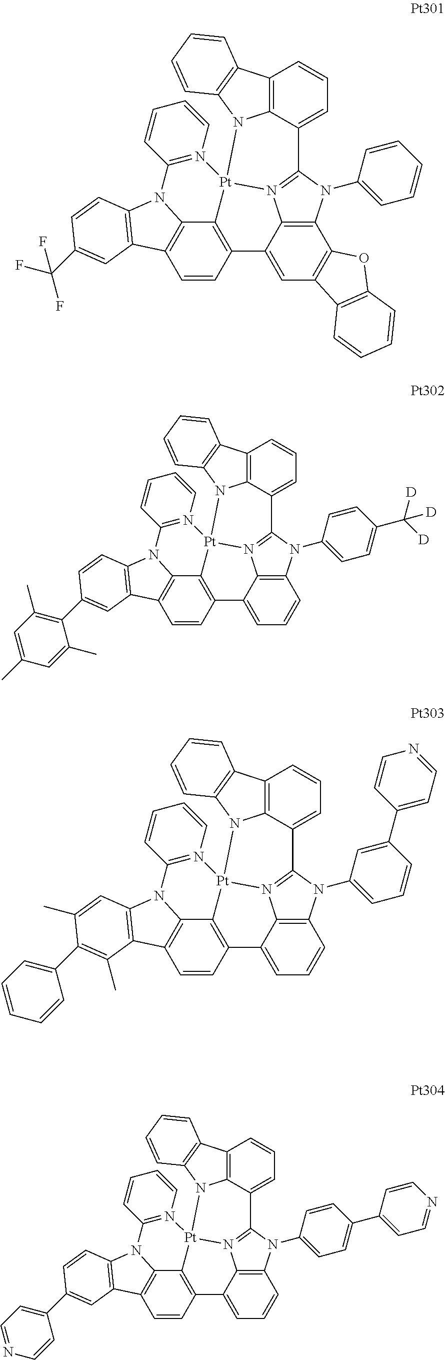

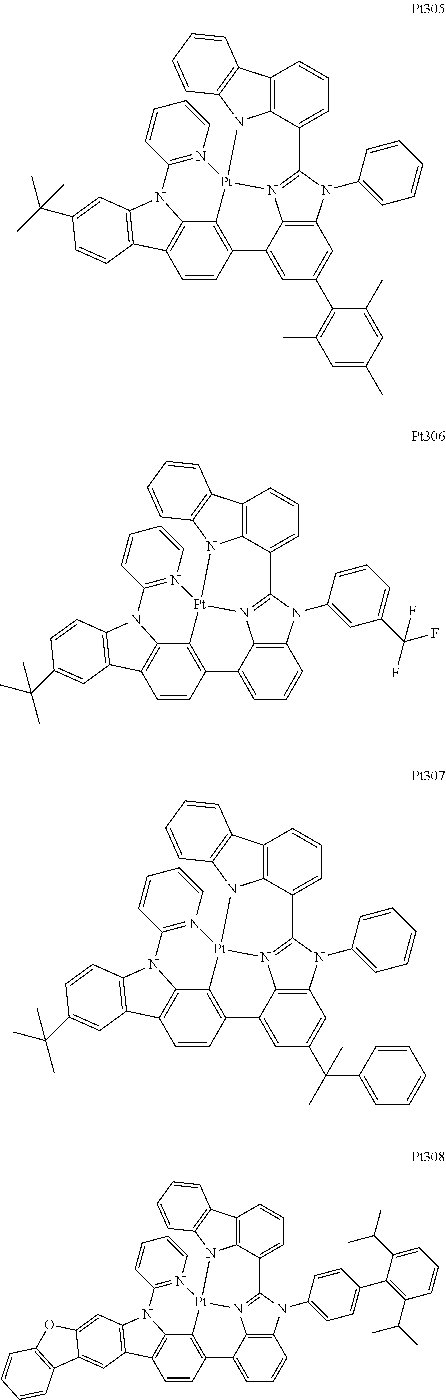

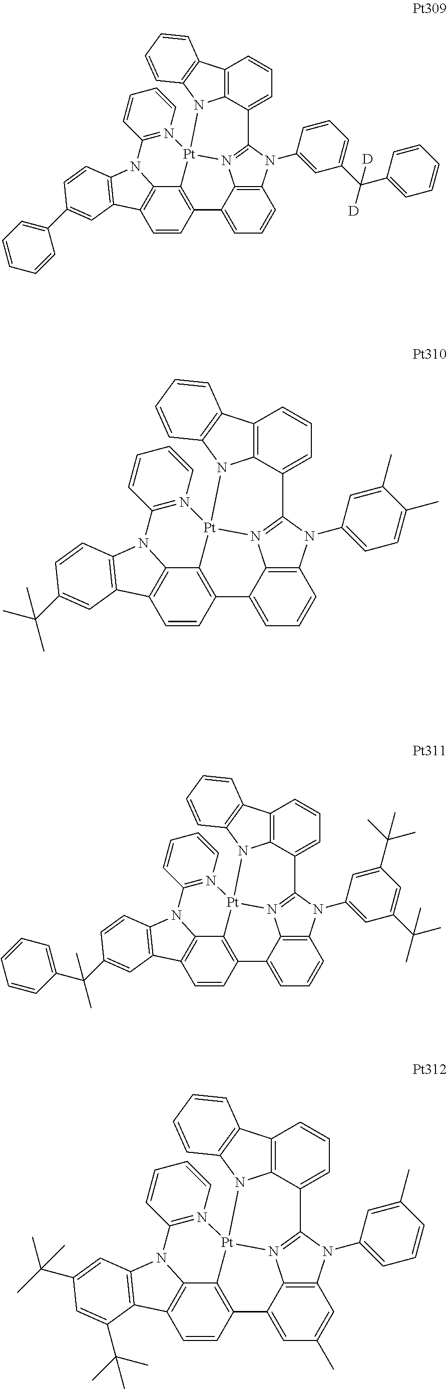

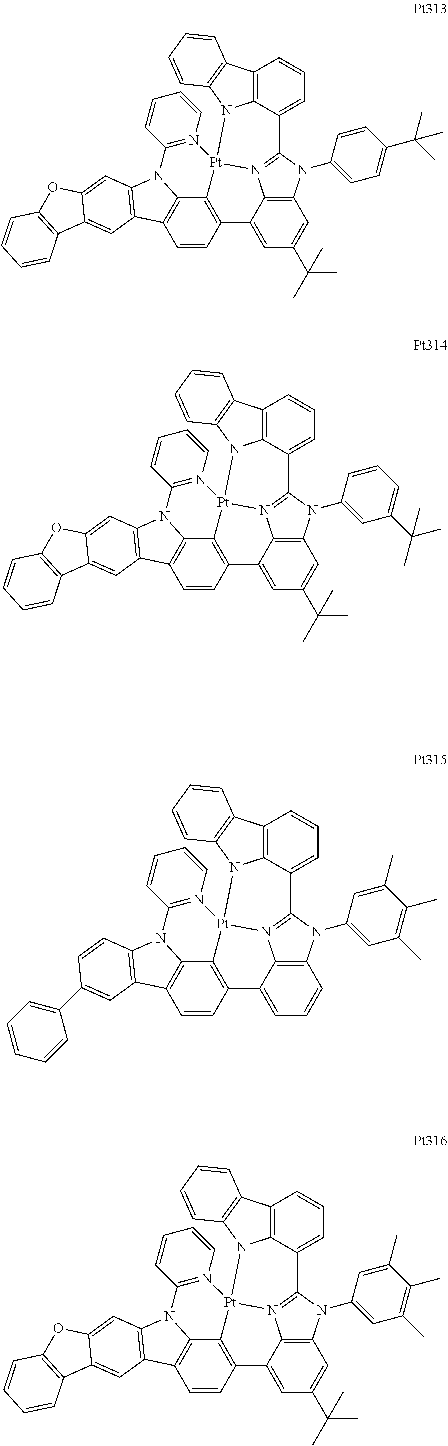

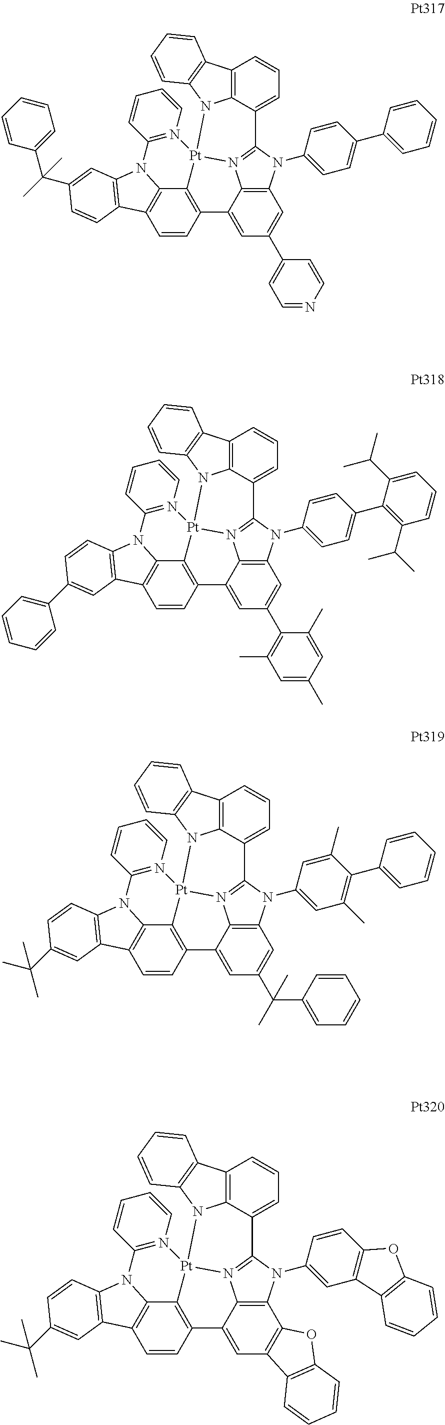

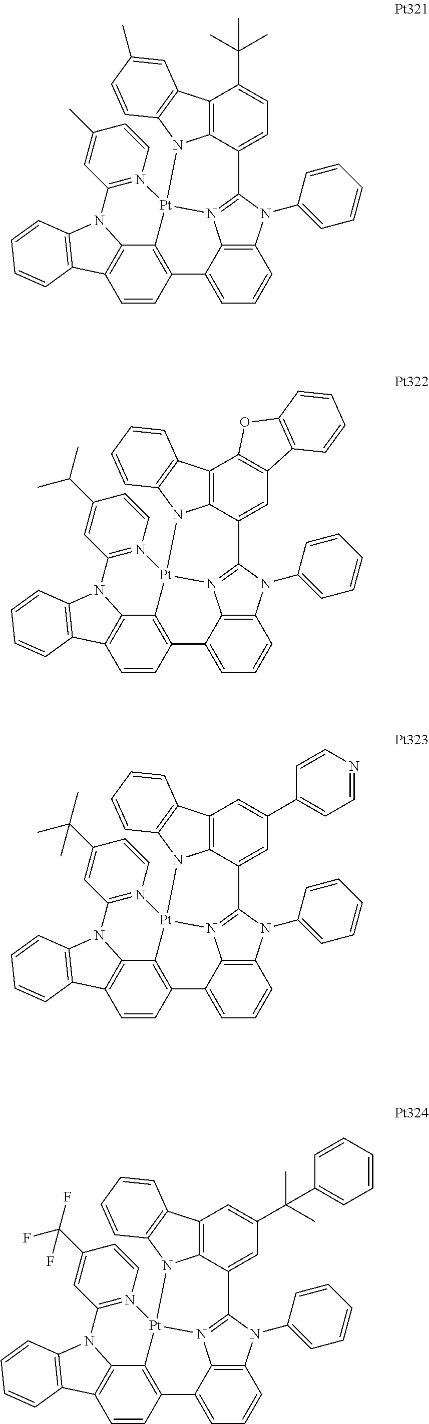

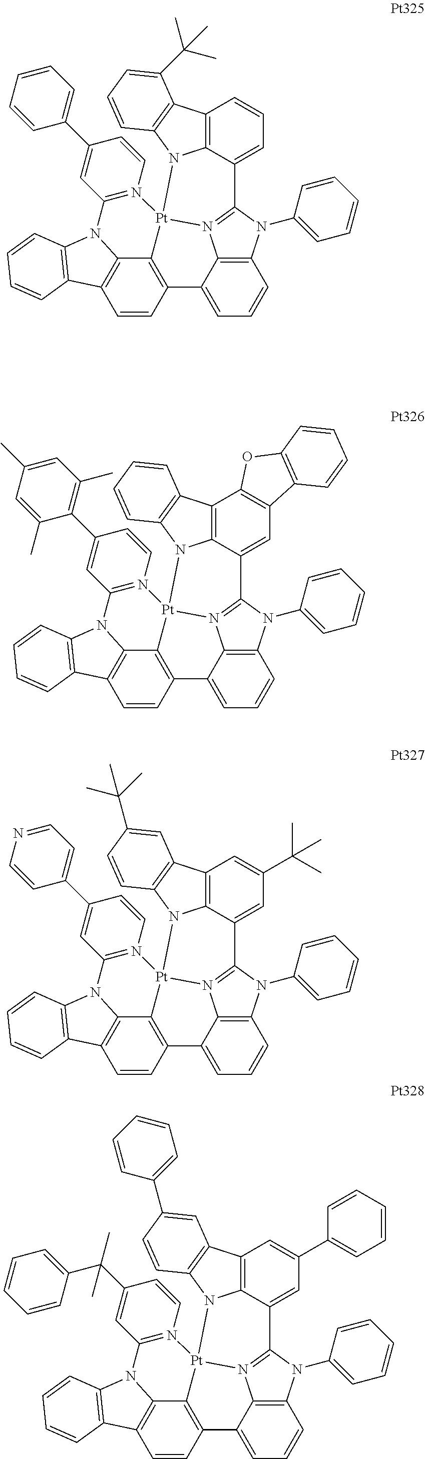

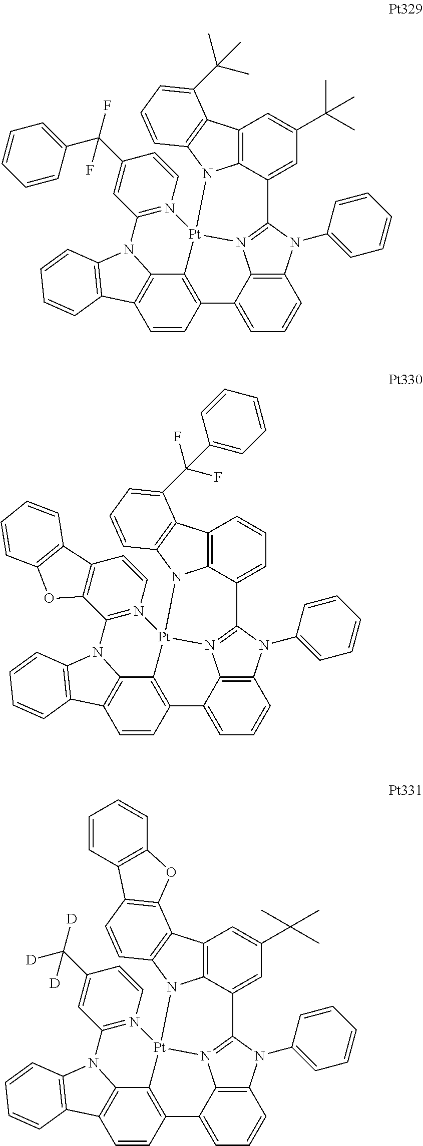

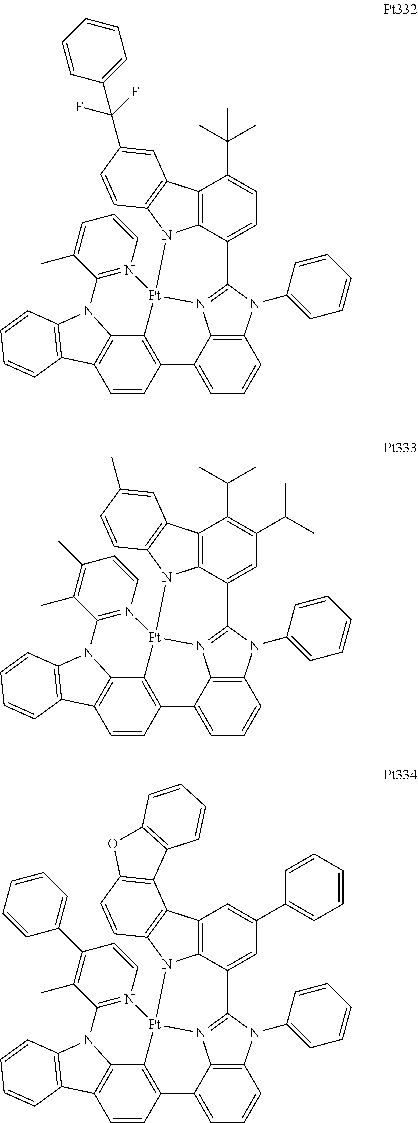

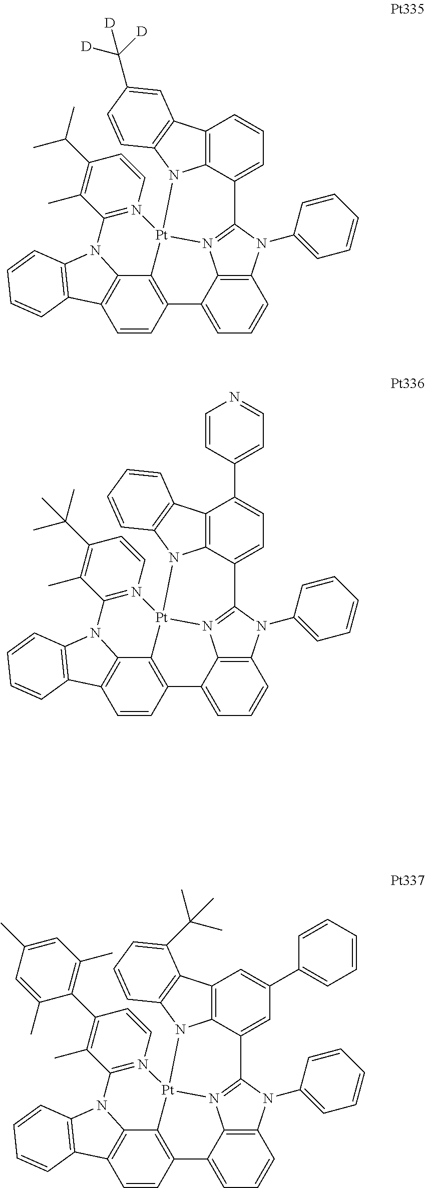

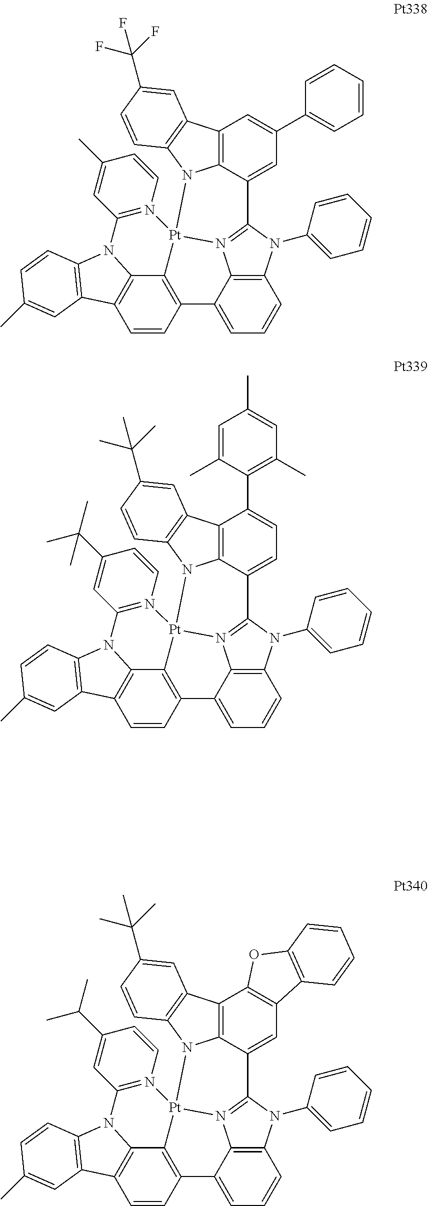

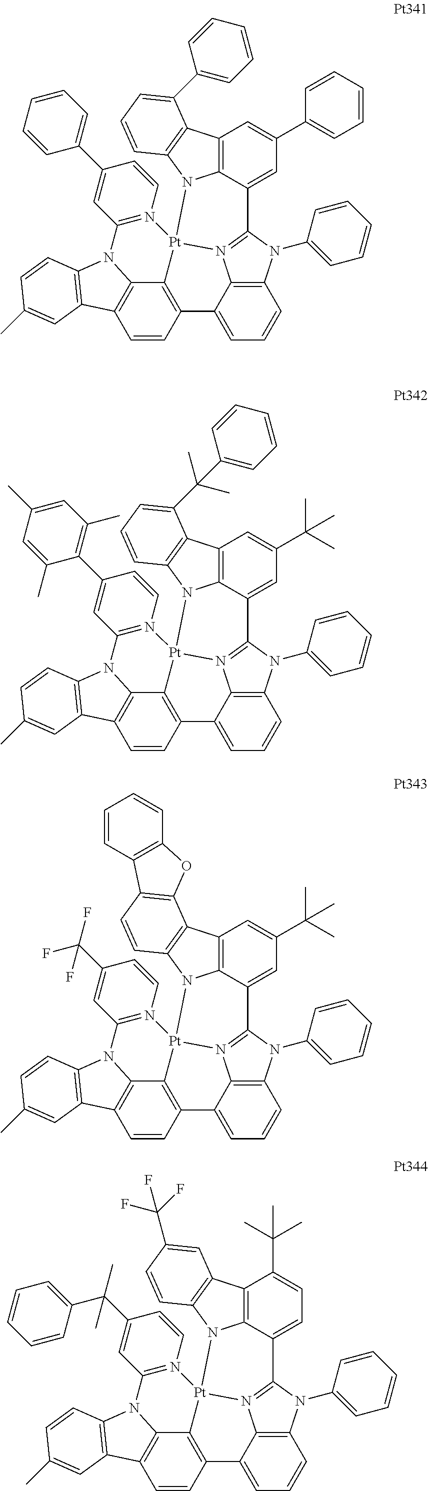

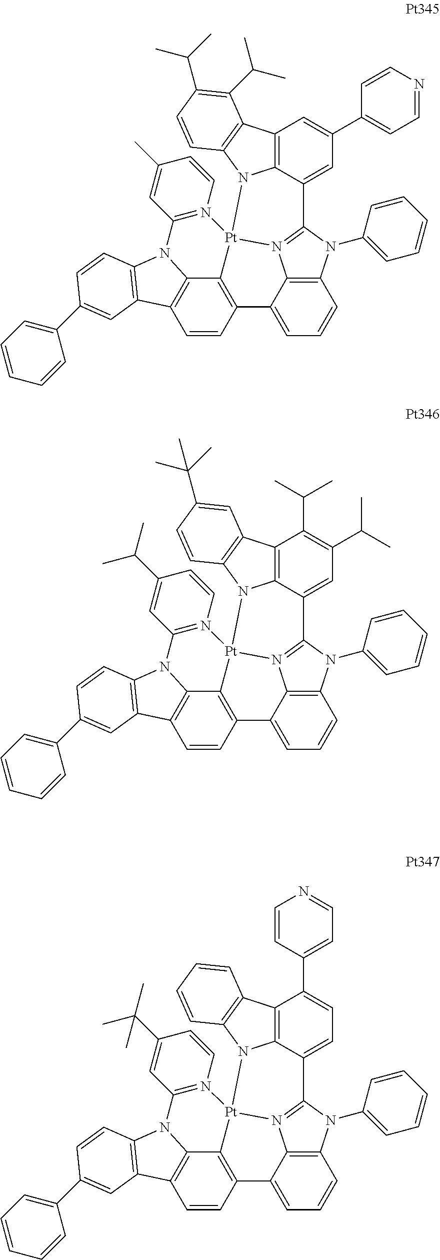

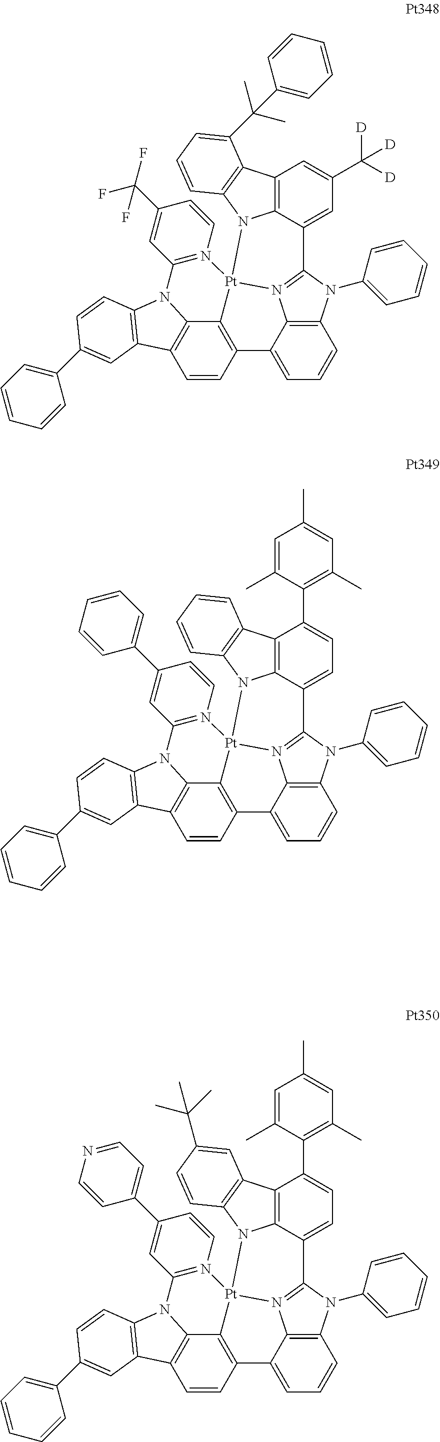

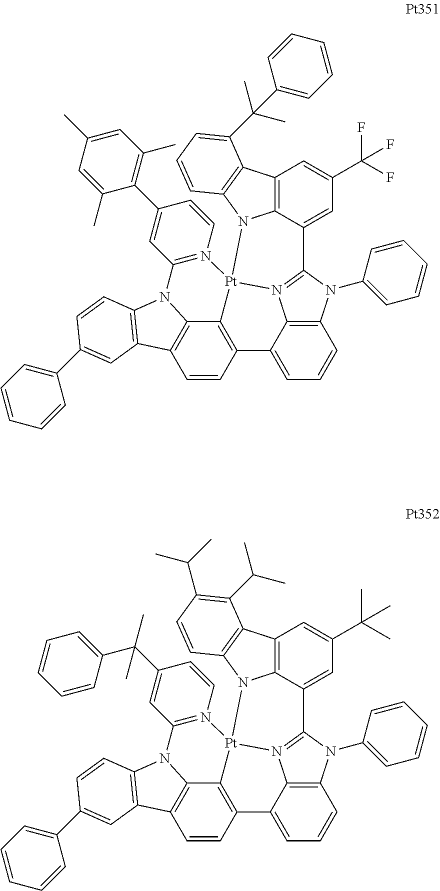

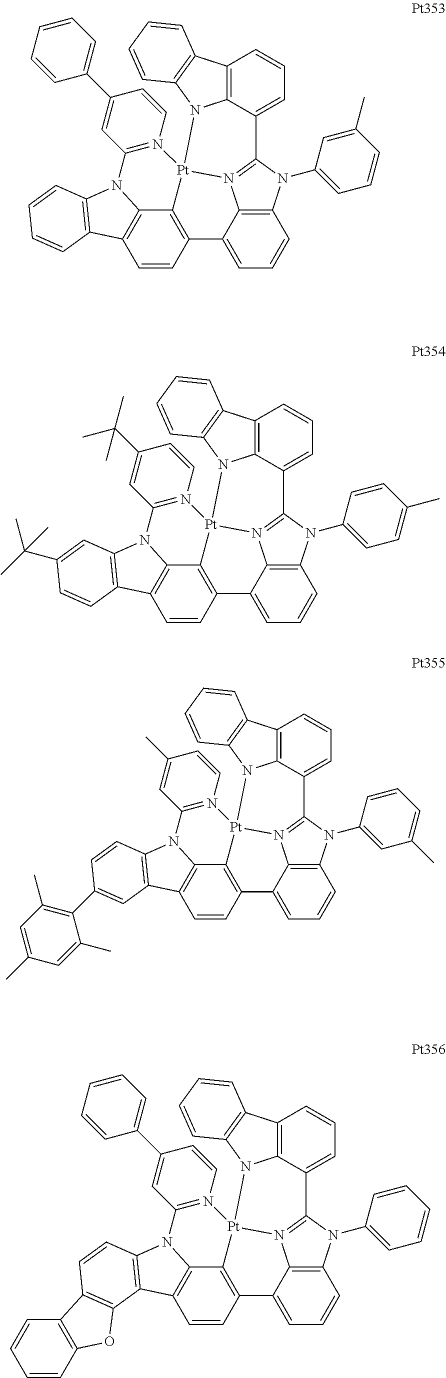

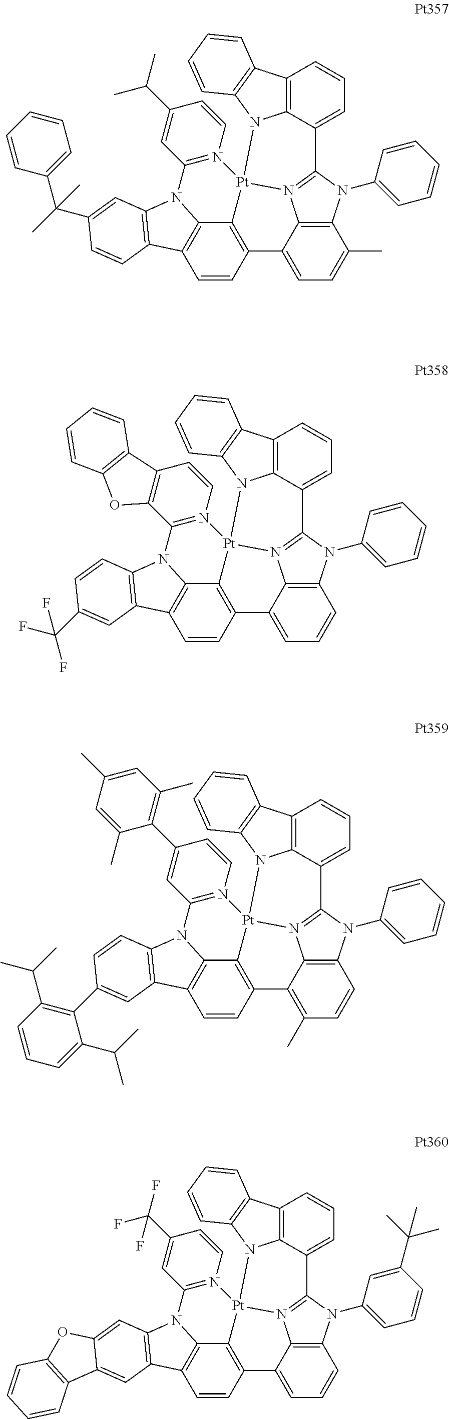

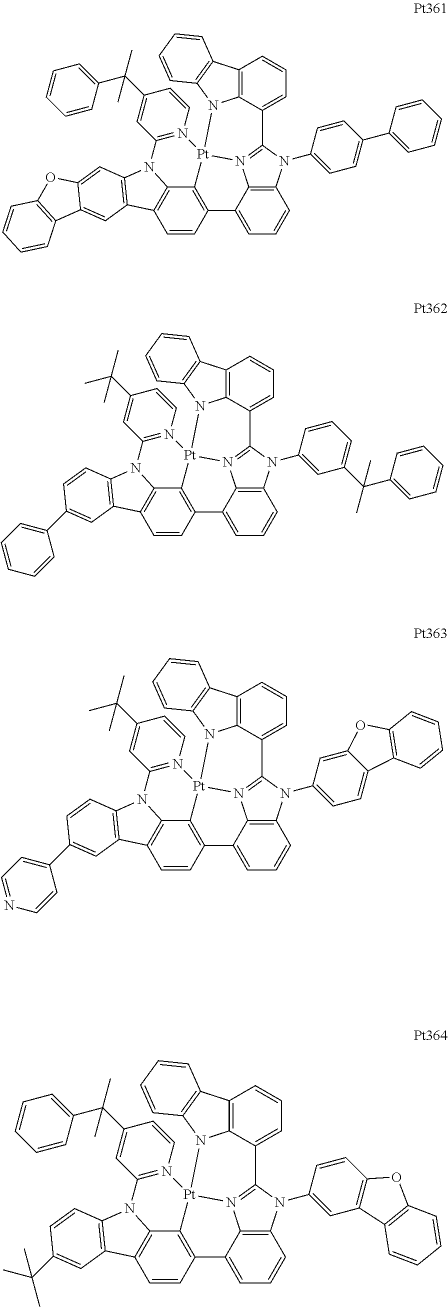

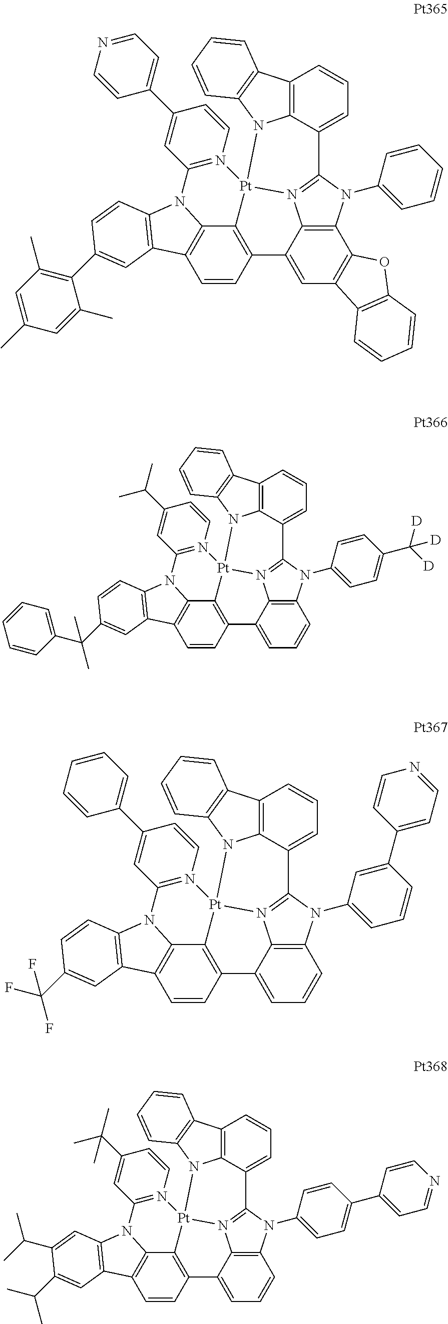

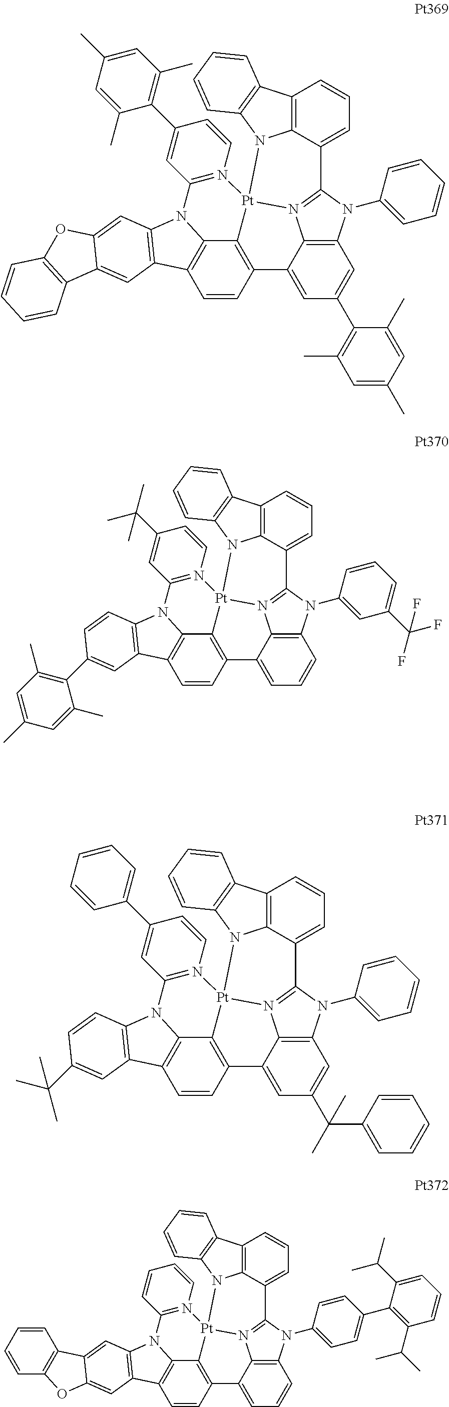

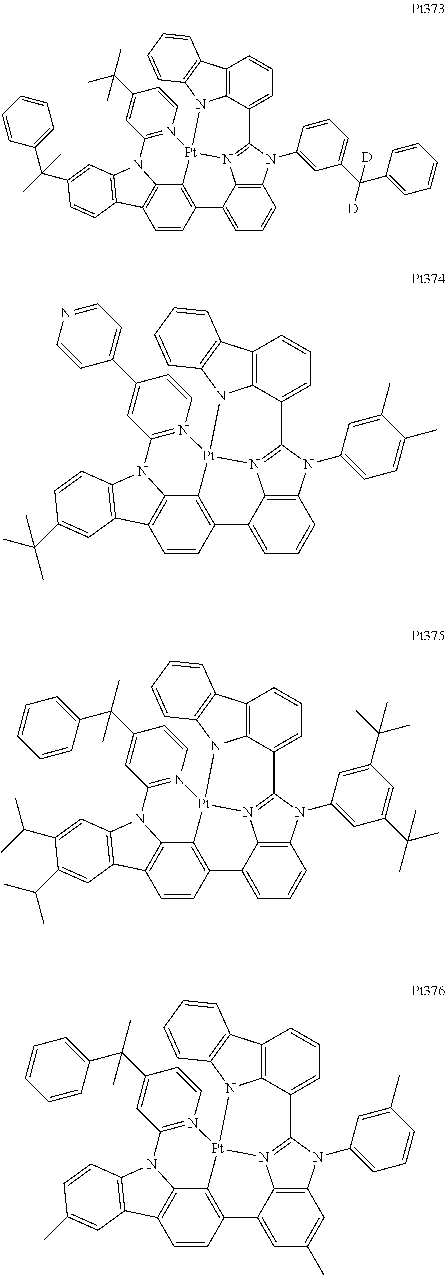

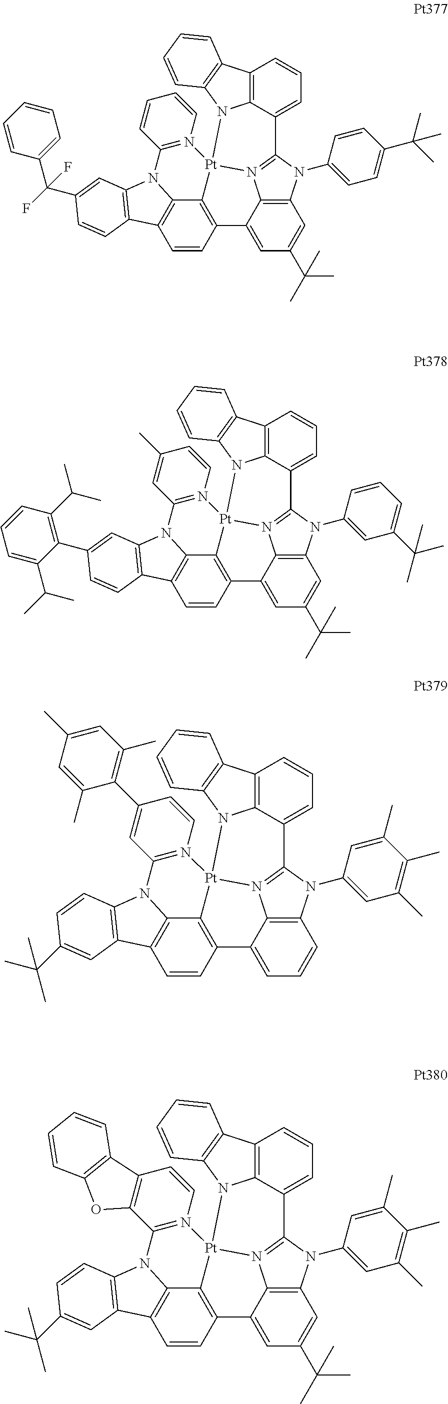

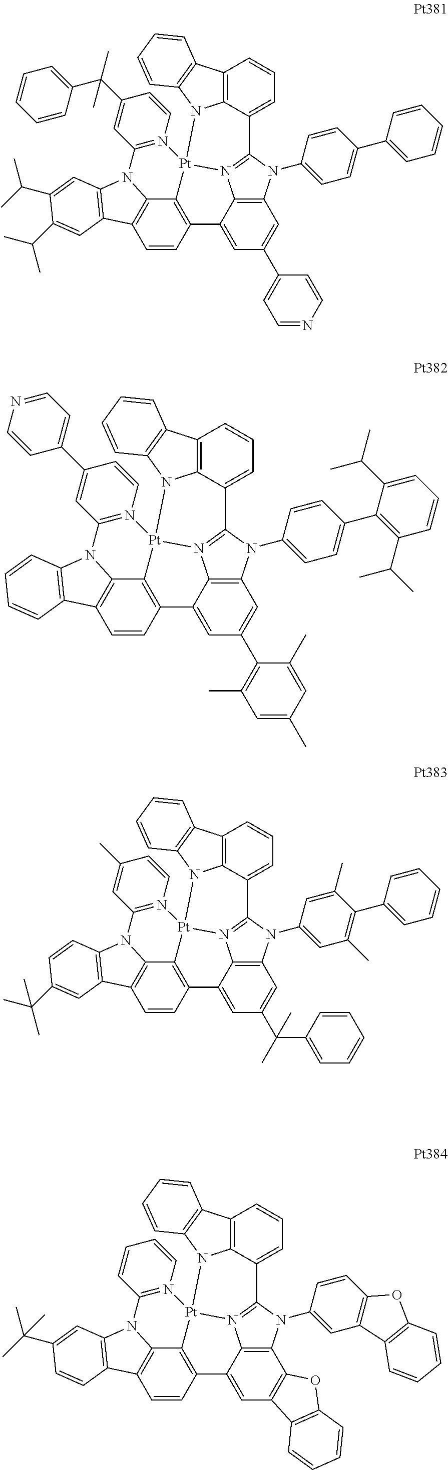

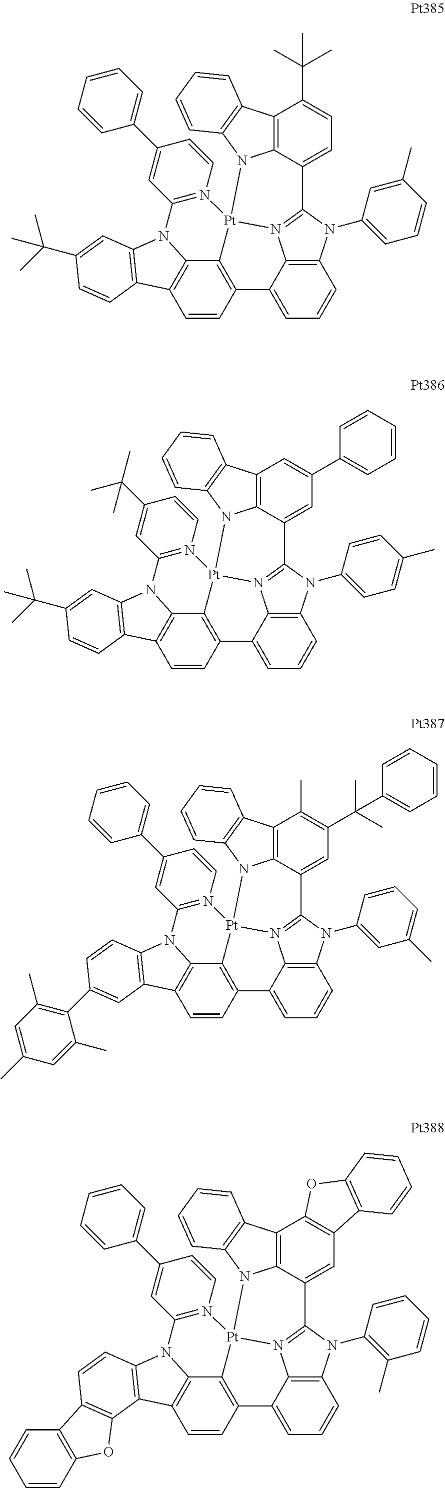

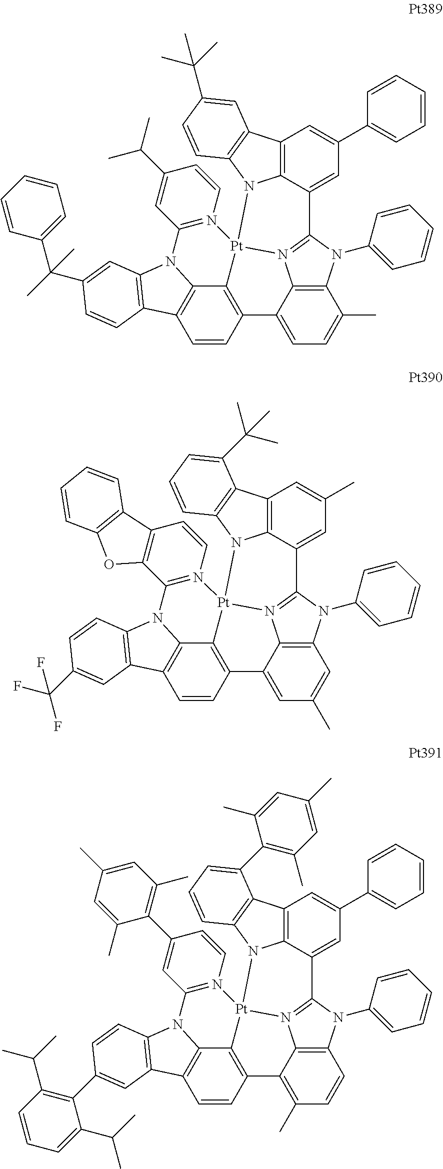

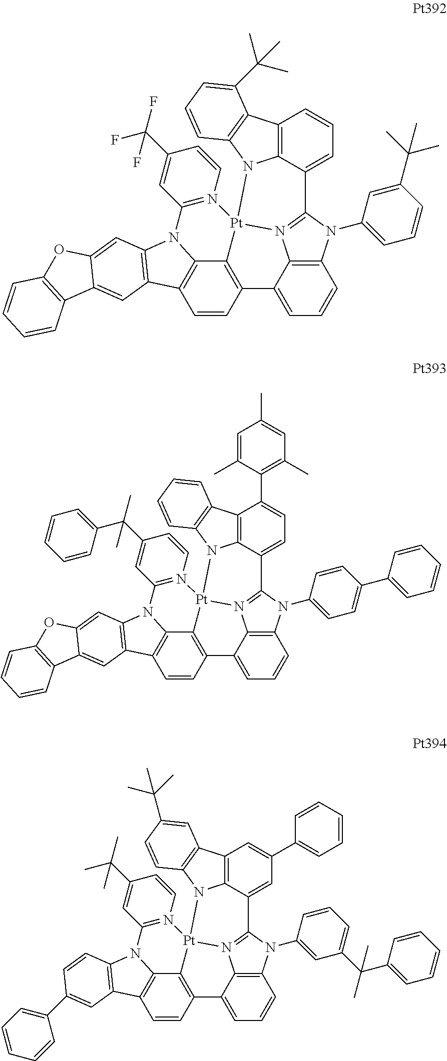

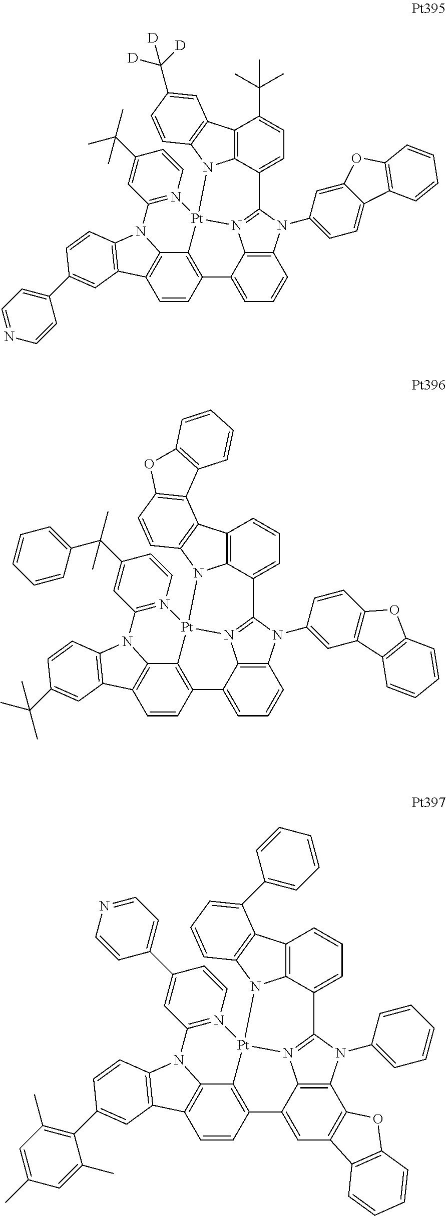

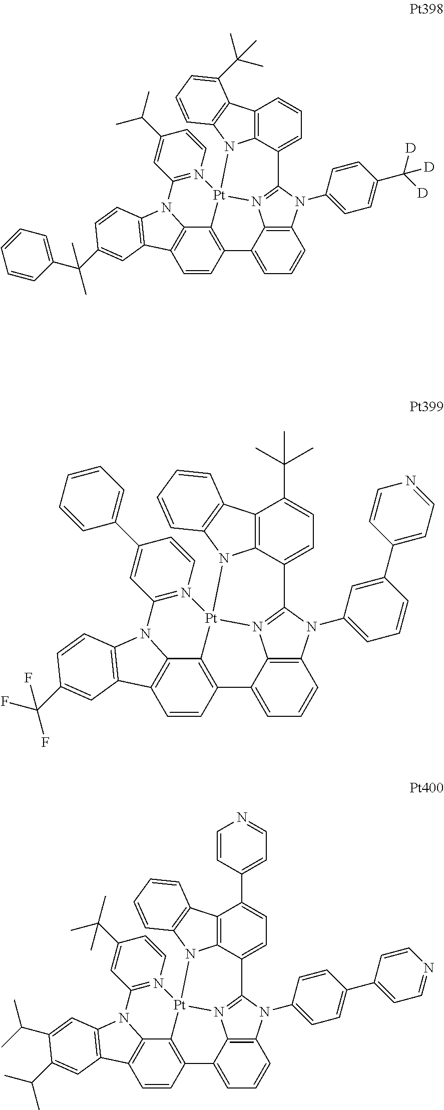

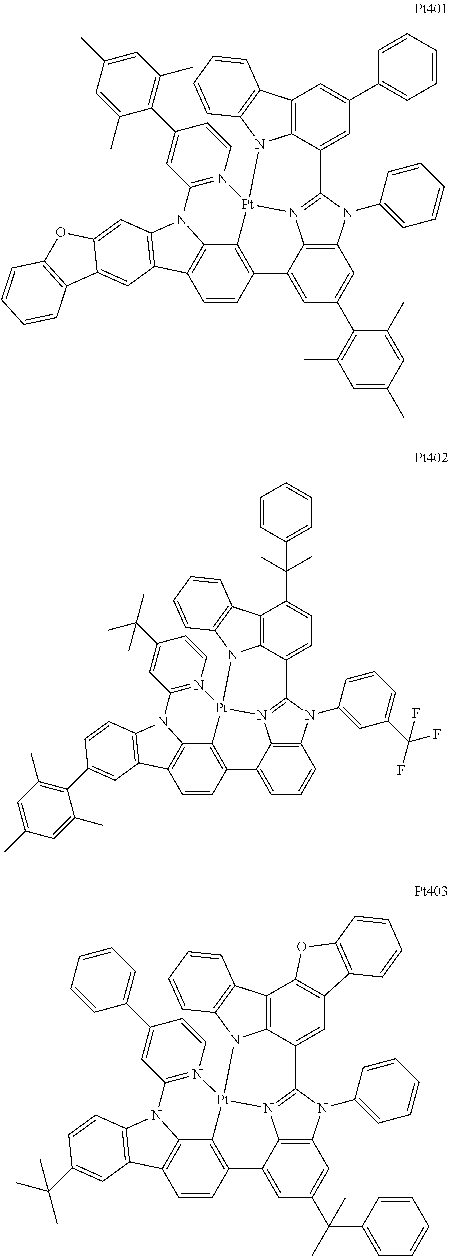

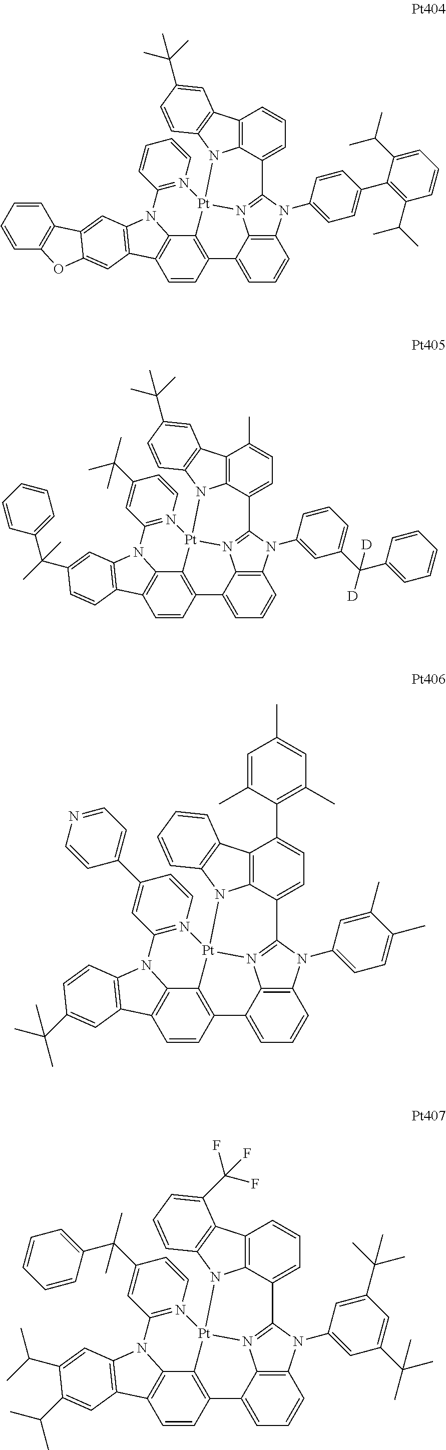

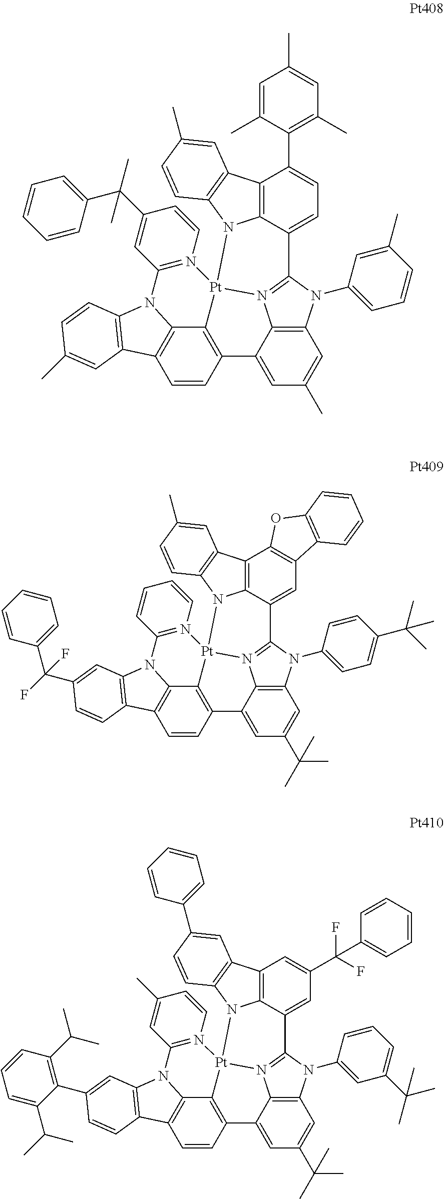

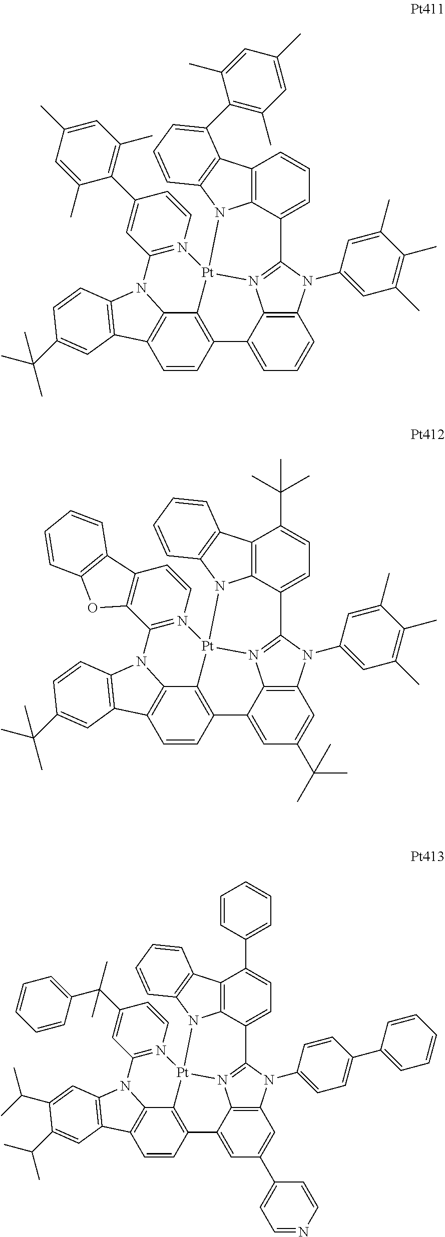

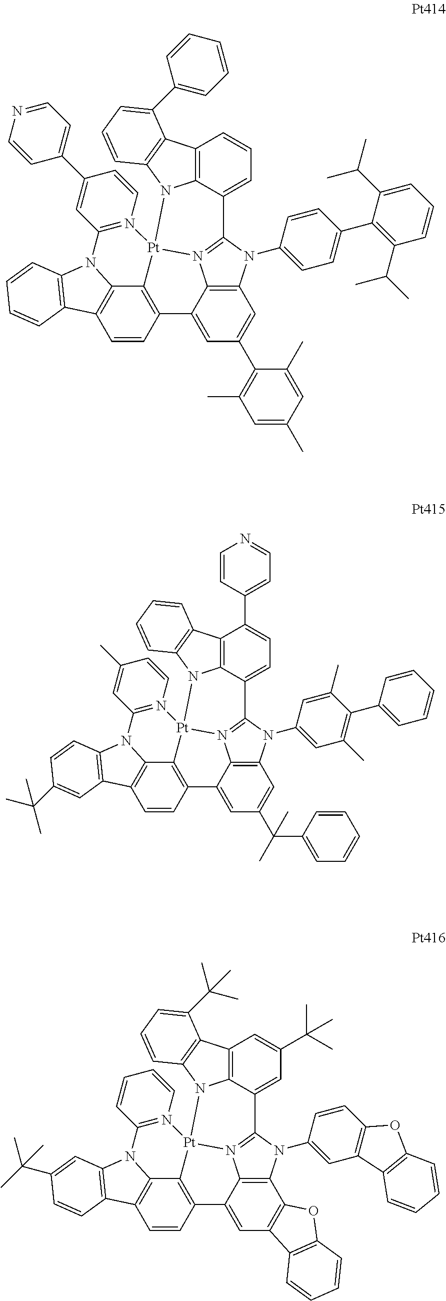

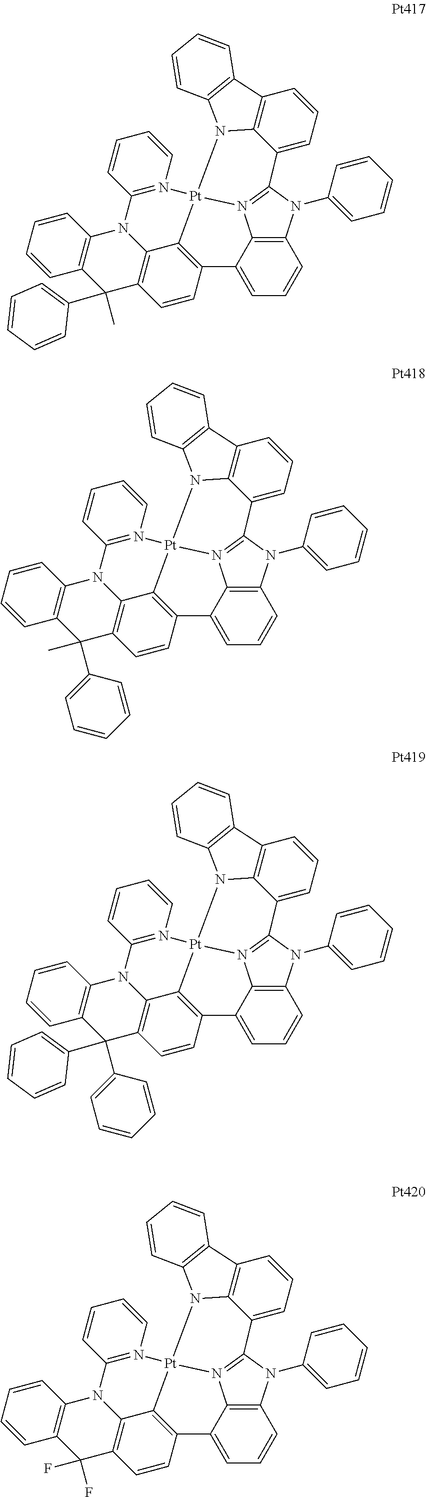

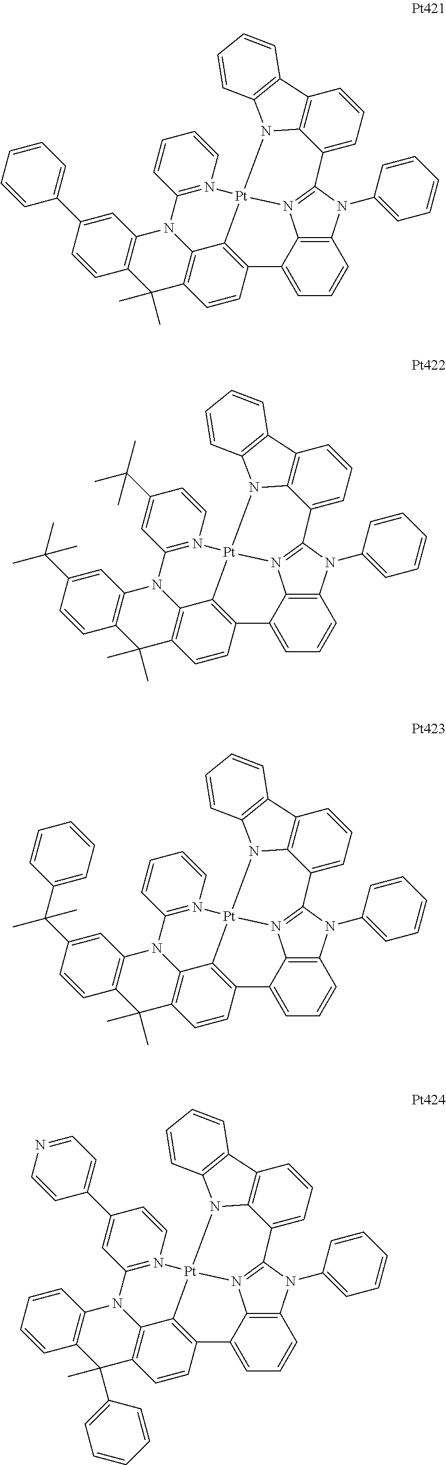

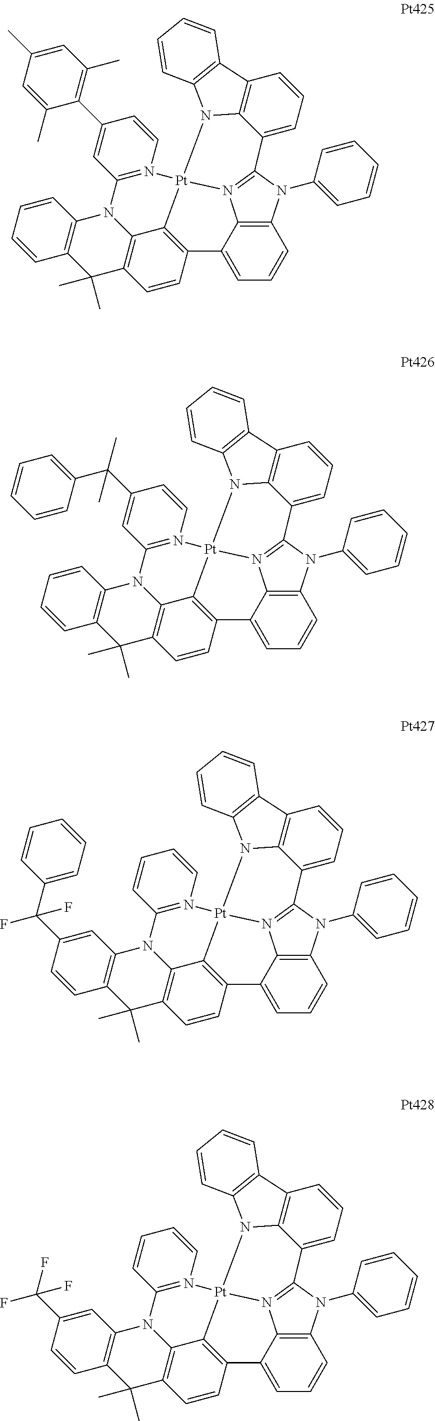

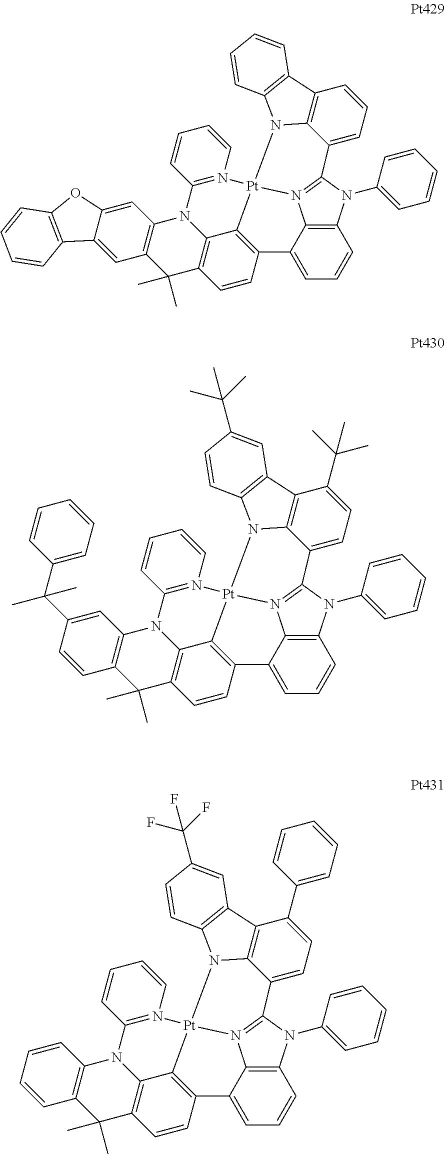

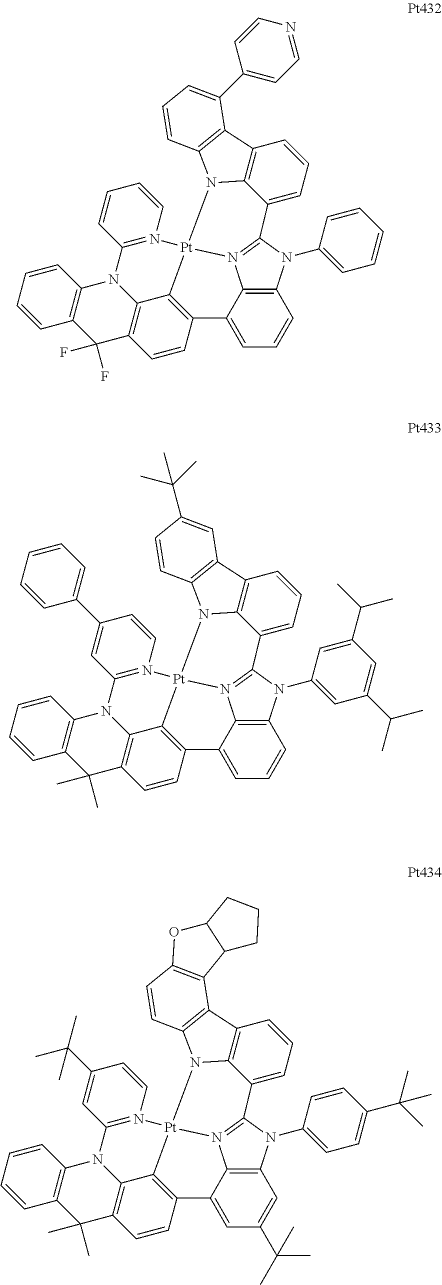

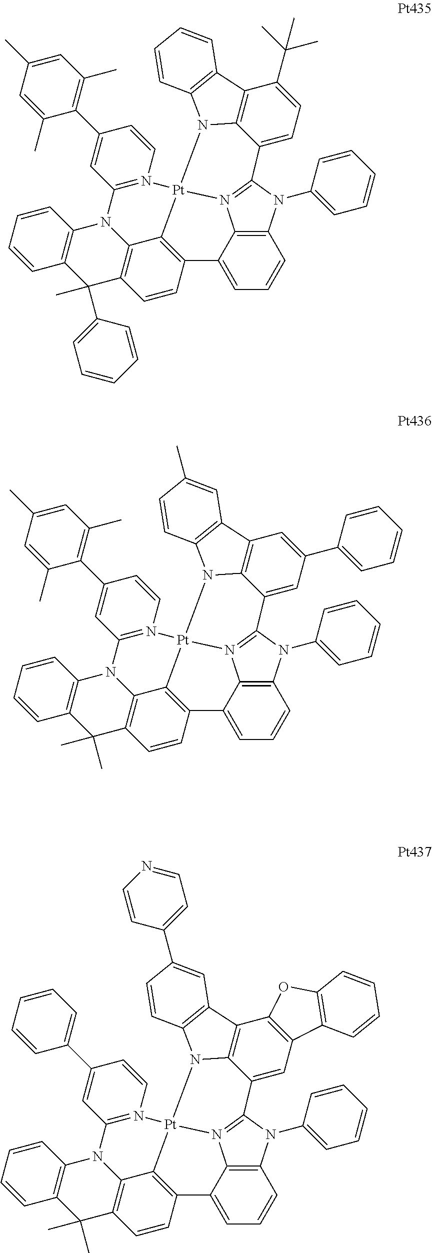

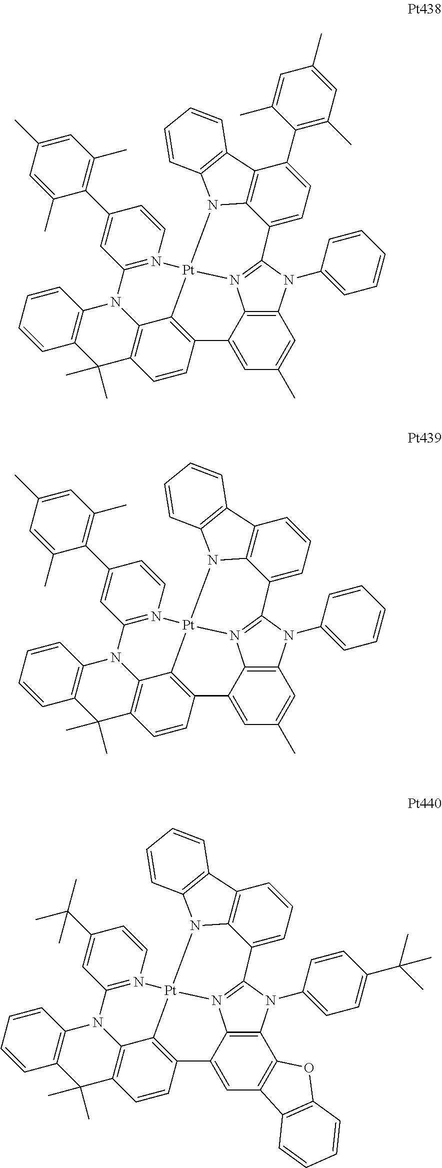

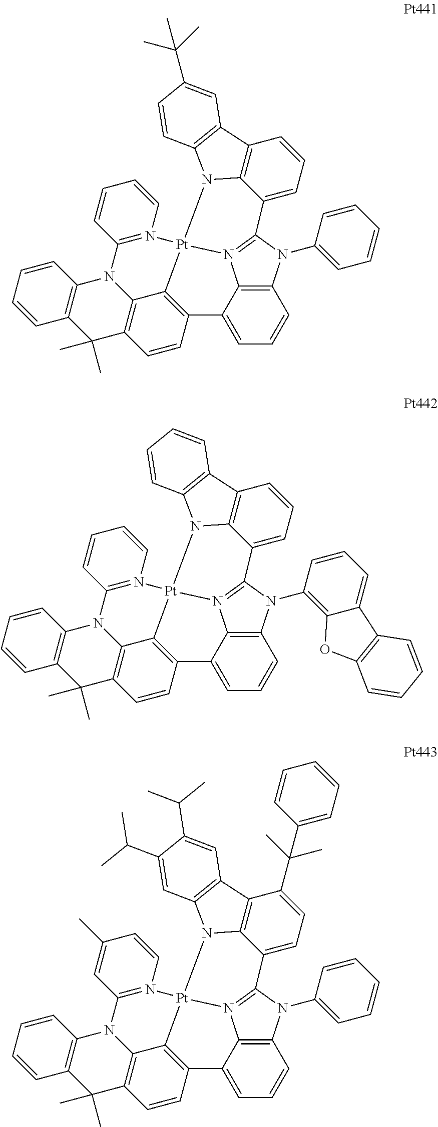

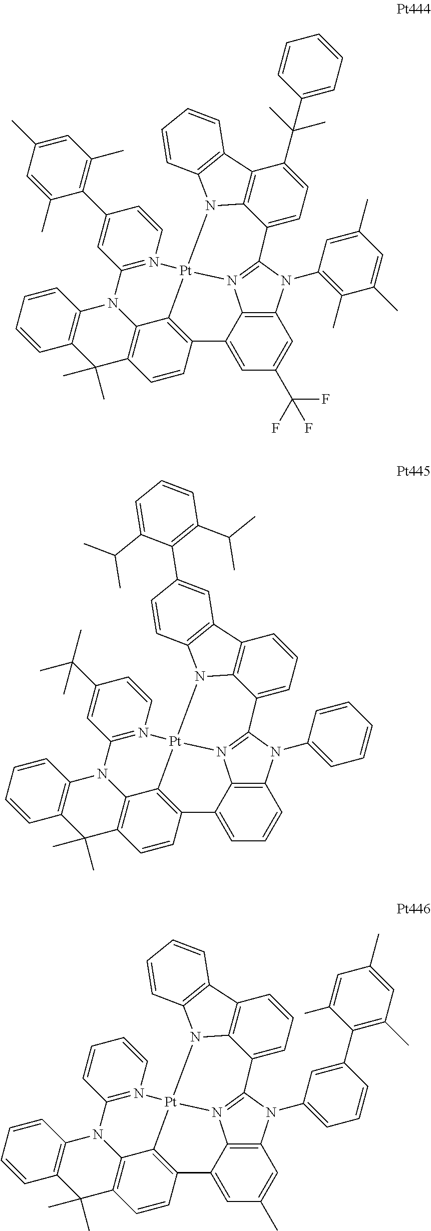

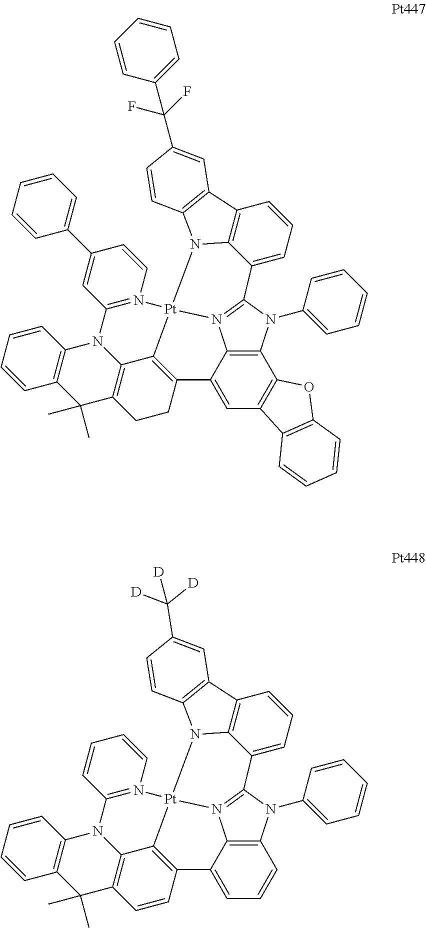

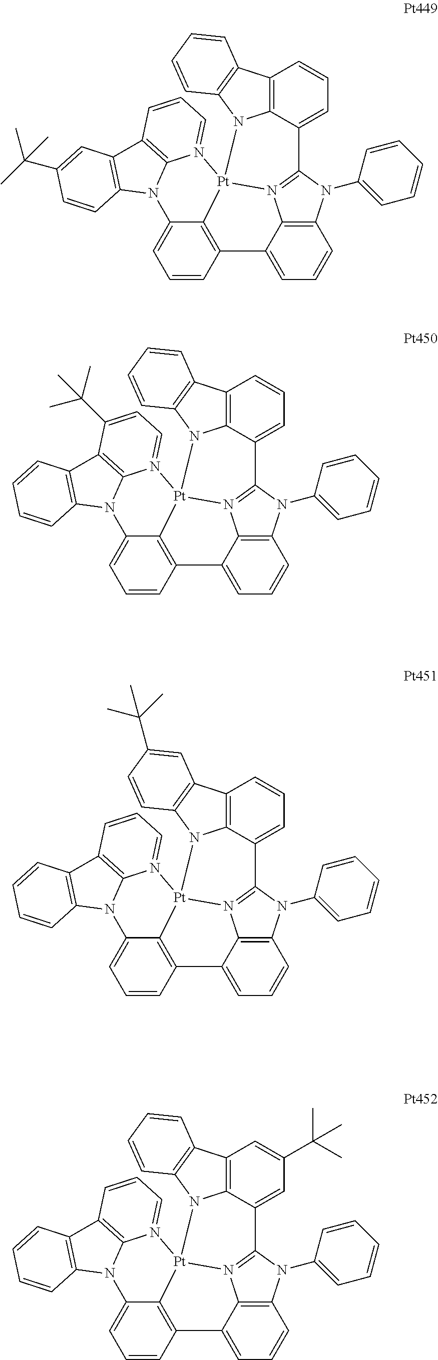

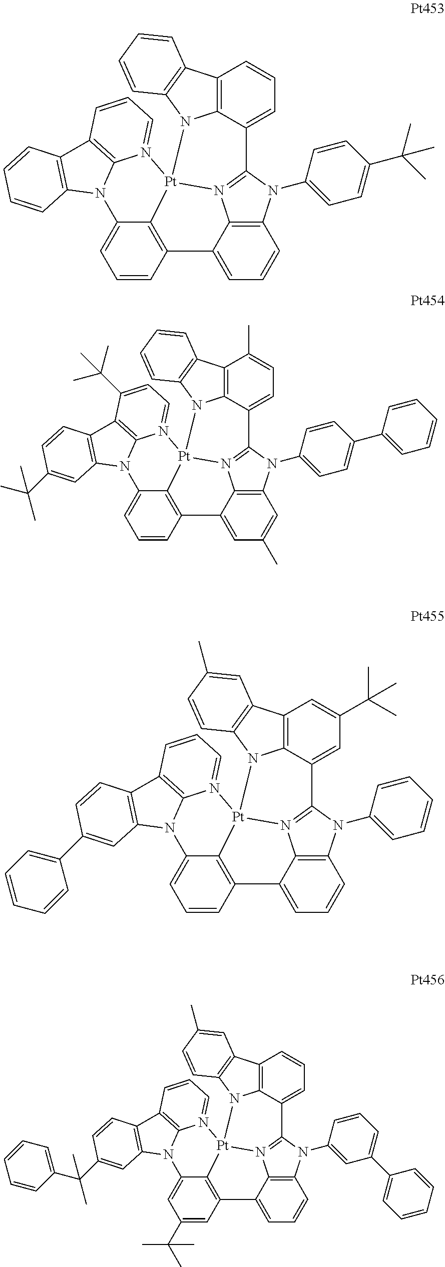

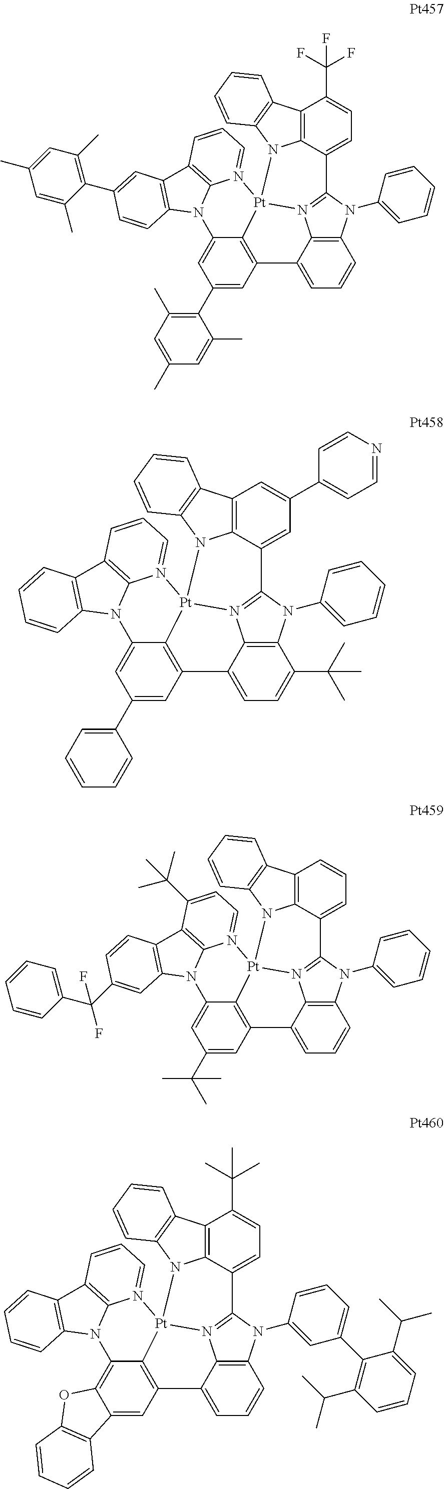

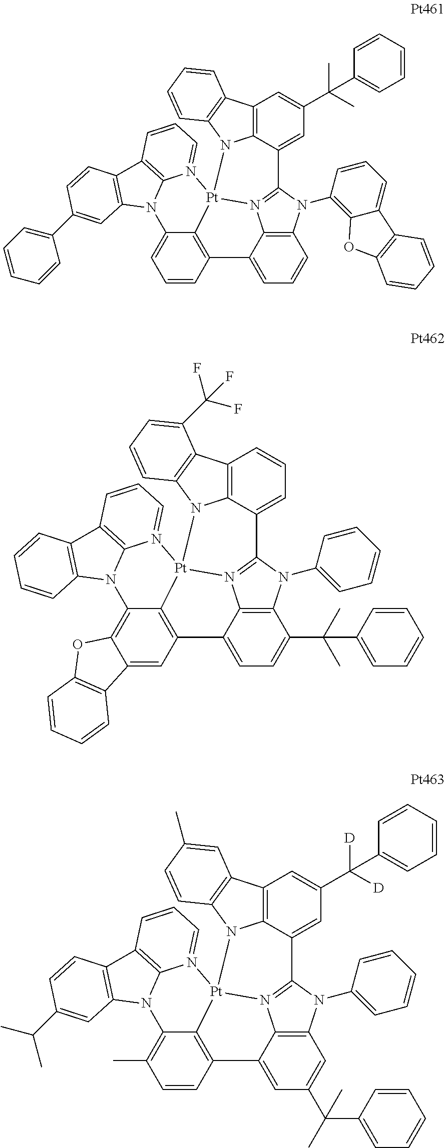

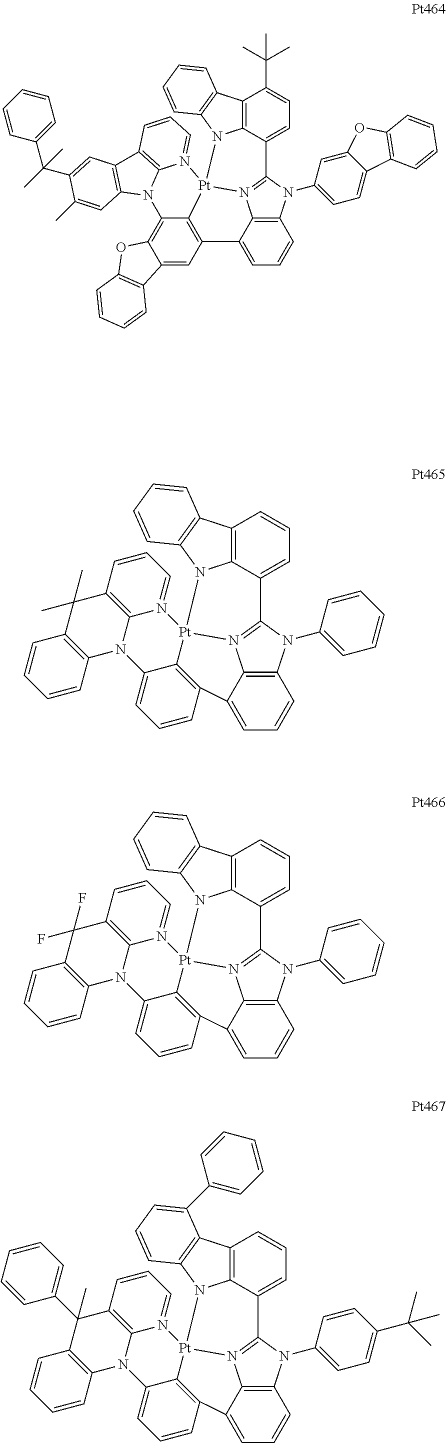

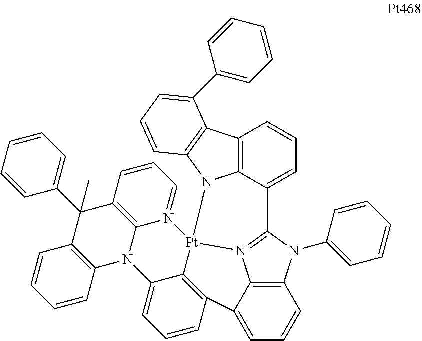

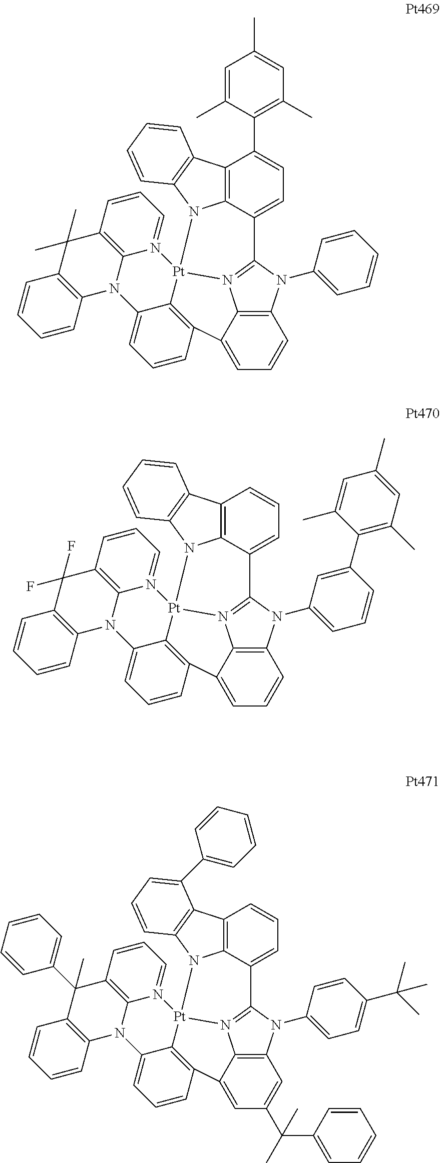

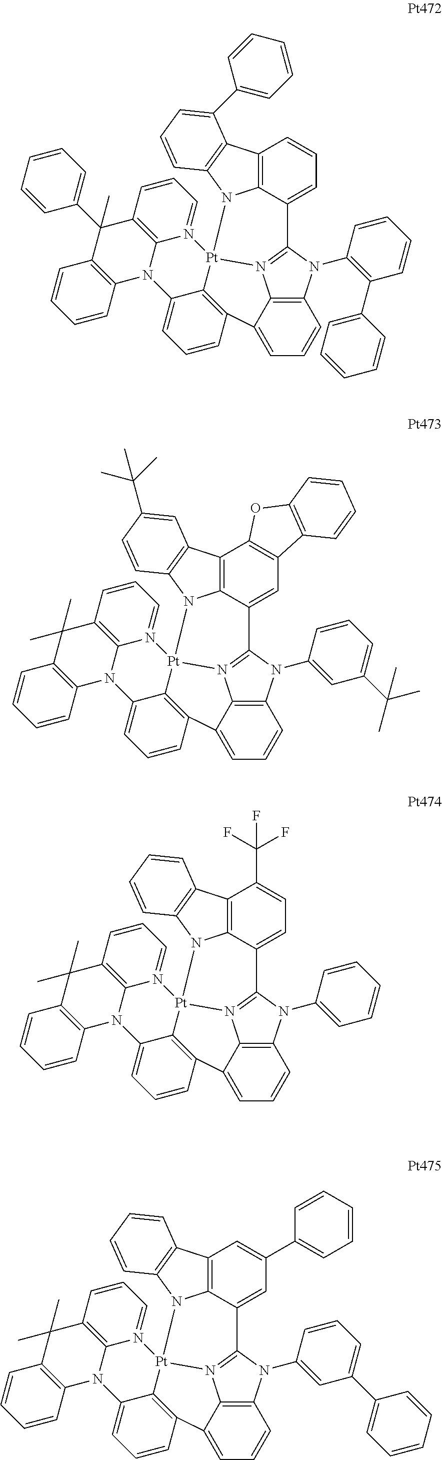

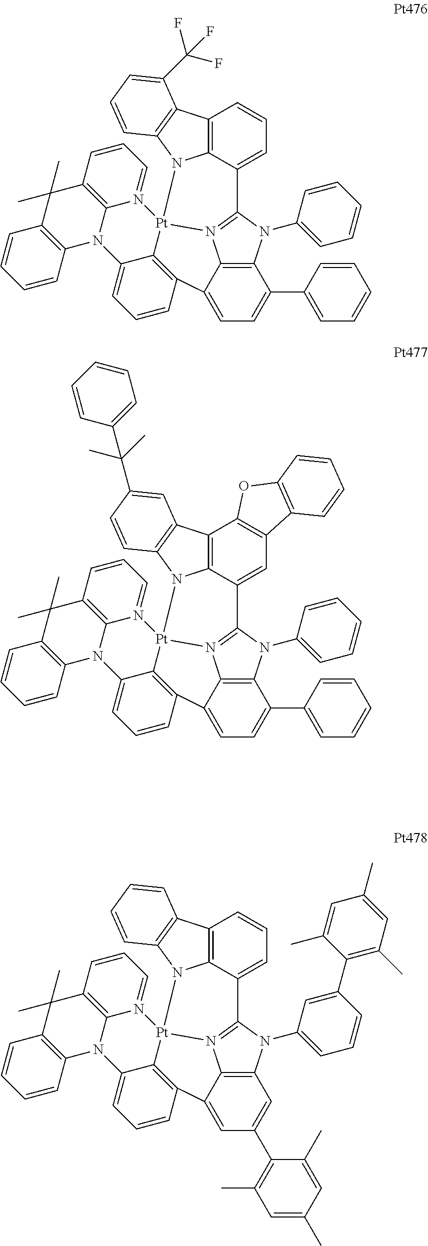

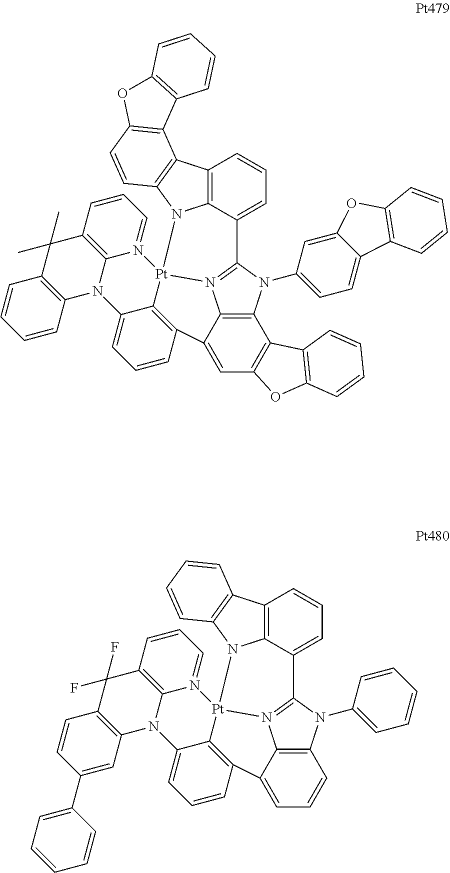

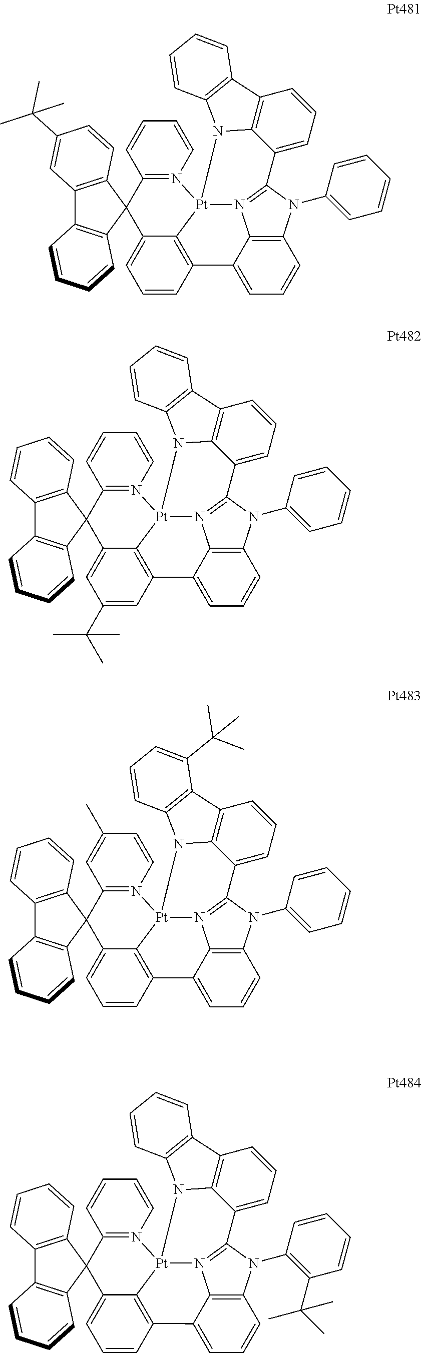

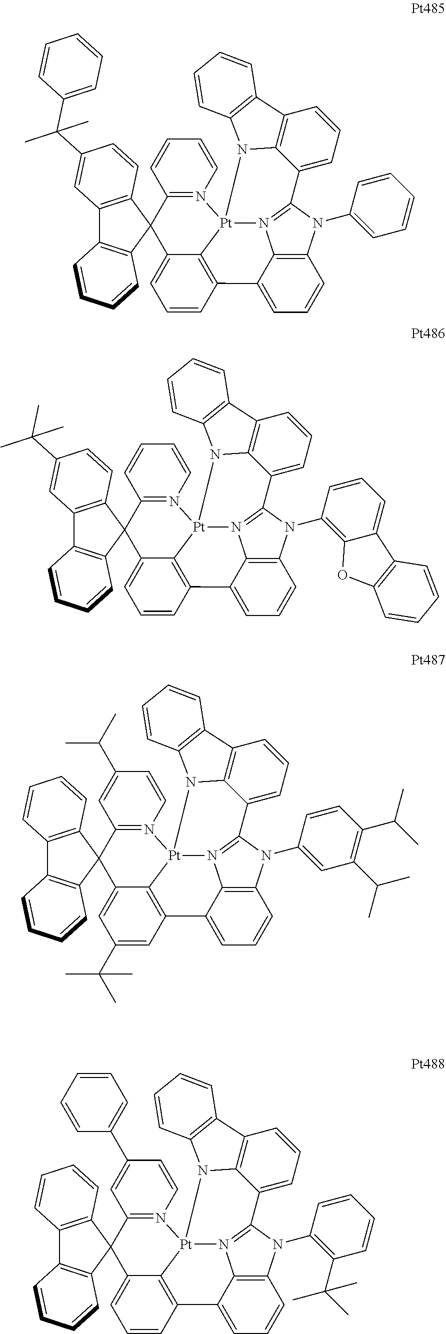

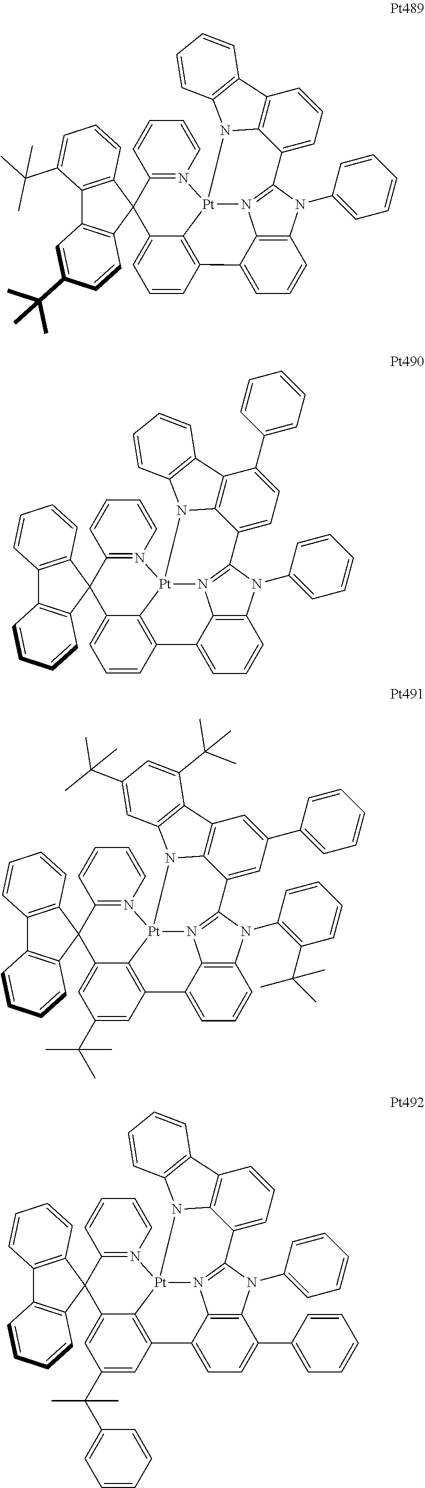

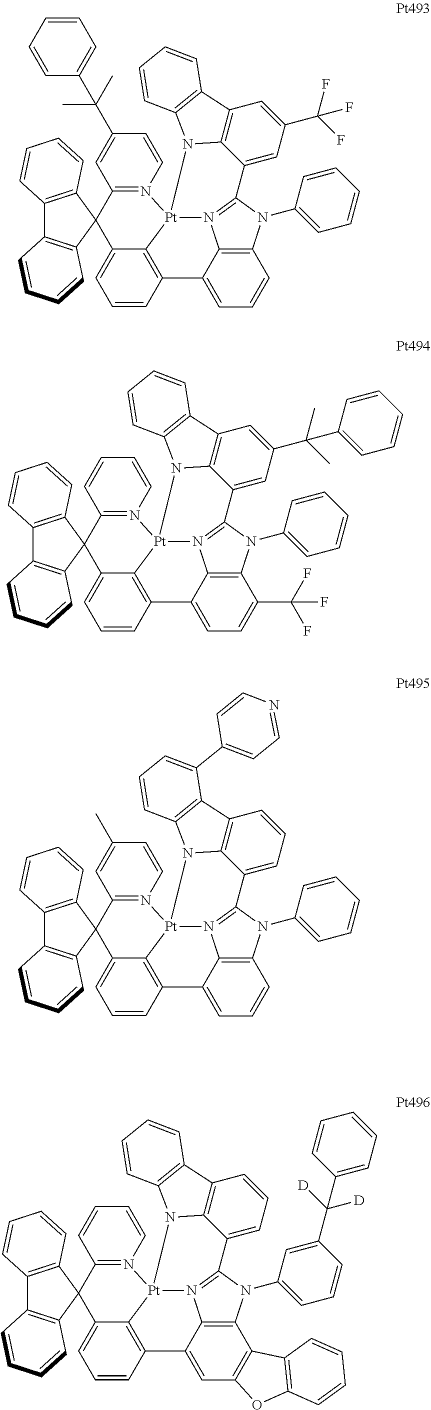

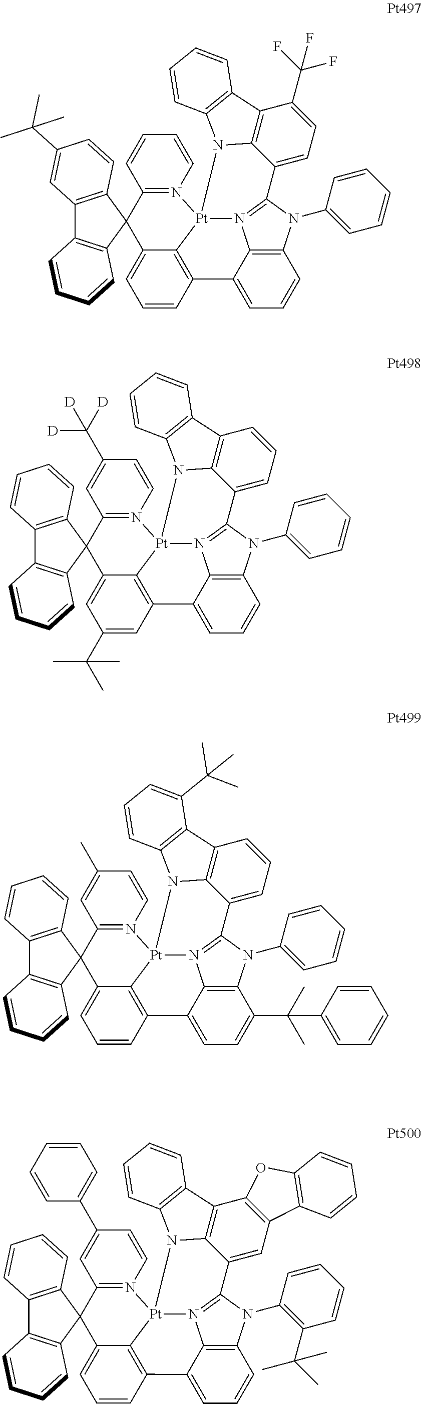

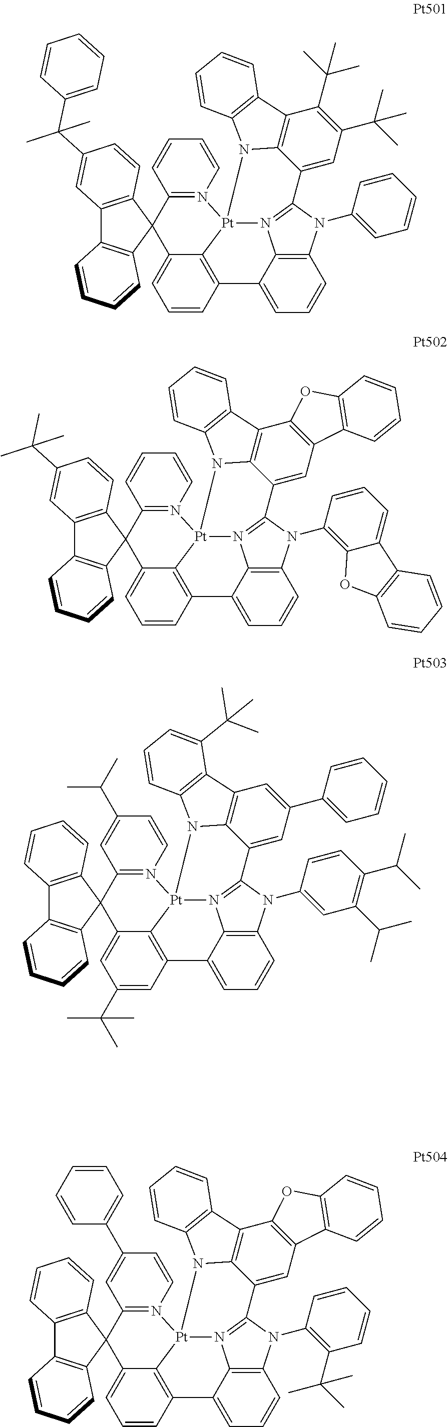

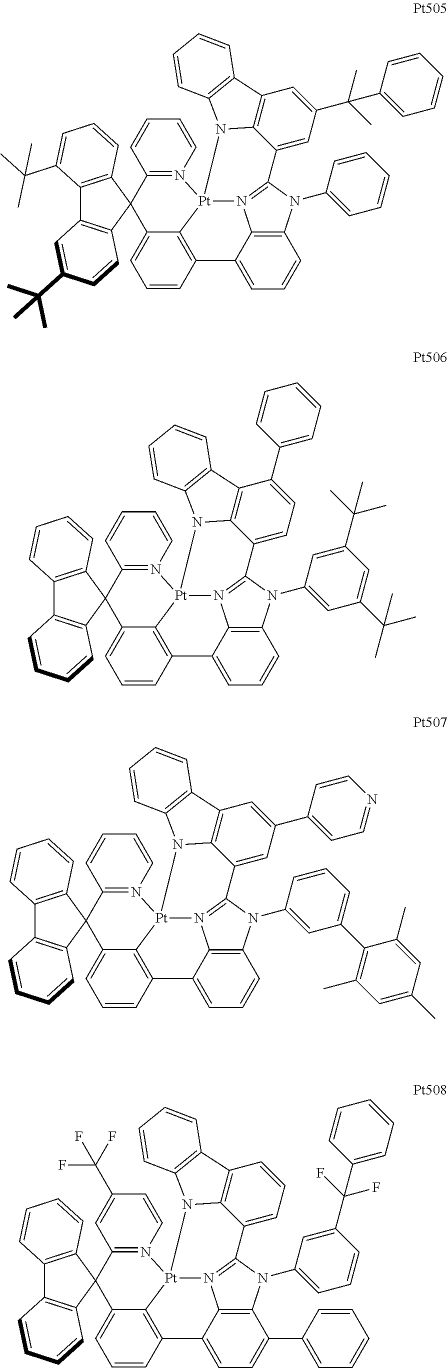

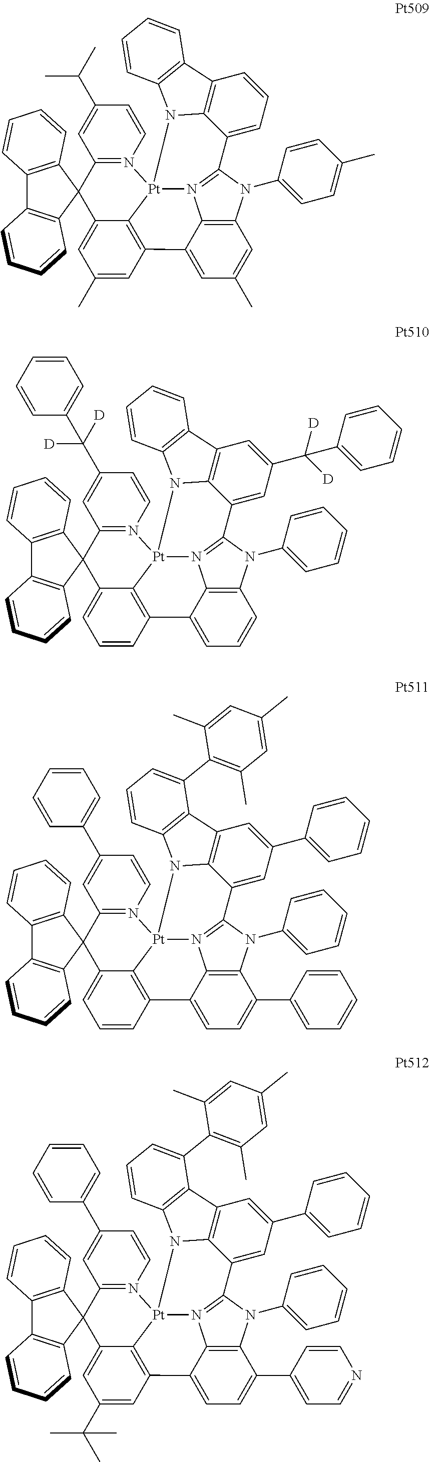

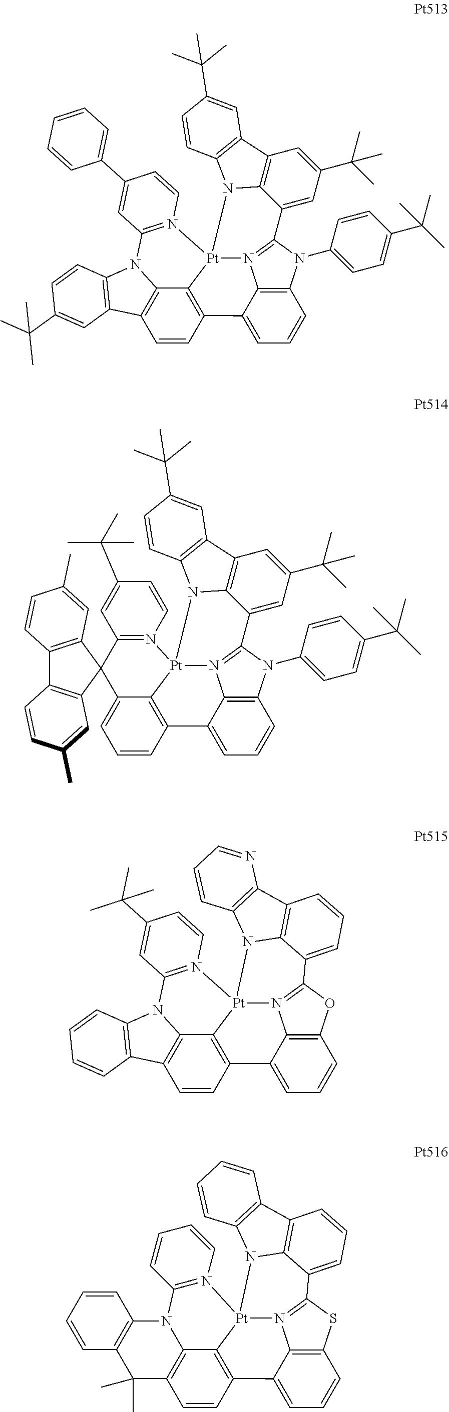

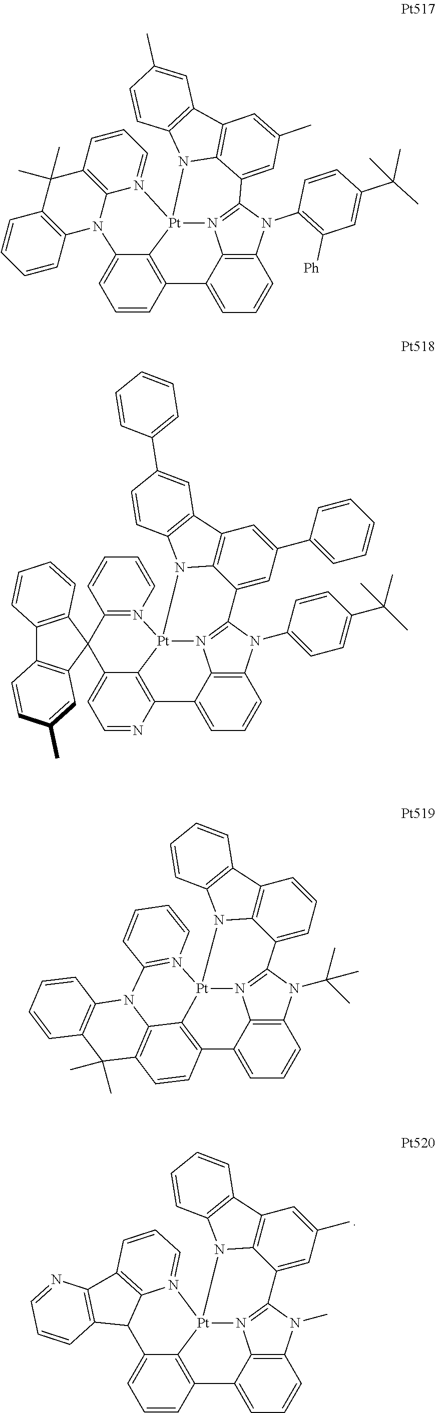

Further, the present invention also provides the use of the cyclic tetradentate metal platinum complex phosphorescent material having the structure shown in formula (I) to (V) above in an electronic device.

Further, the electronic device includes an organic electroluminescent device (OLED), an organic integrated circuit (0-IC), an organic field effect transistor (0-FET), an organic thin film transistor (0-TFT), an organic light-emitting transistor (0-LET), an organic solar cell (0-SC), an organic optical detector, an organic photoreceptor, an organic field quenching device (0-FQD), a light-emitting electrochemical cell (LEC), and an organic laser diode (0-laser).

In another aspect, the present invention also provides an organic electroluminescent device including the cyclic tetradentate metal platinum complex phosphorescent material having the structure shown in formula (I), (I-1), or (I-2) as described above.

Further, the organic electroluminescent device includes a cathode, an anode, and an organic functional layer therebetween; the organic functional layer includes the cyclic tetradentate metal platinum complex phosphorescent material having the structure shown in formula (I), (I-1), or (I-2) as described above.

Preferably, the organic functional layer includes a light-emitting layer including the cyclic tetradentate metal platinum complex phosphorescent material having the structure shown in formula (I), (I-1), or (I-2) as described above.

Further, the light-emitting layer also includes a host material, and the mass percentage of the cyclic tetradentate metal platinum complex phosphorescent material is between 1% and 50%. The host material is not limited.

In another aspect, the present invention also provides an organic photovoltaic device including a substrate layer; a first electrode on the substrate; an organic light-emitting functional layer on the first electrode; a second electrode on the organic light-emitting functional layer; wherein the organic light-emitting functional layer includes the cyclic tetradentate metal platinum complex phosphorescent material having the structure shown in formula (I), (I-1), or (I-2) as described above. For example, the cyclic tetradentate platinum complex may be included as a light-emitting material in the organic light-emitting functional layer.

Further, the organic light-emitting functional layer includes a host material, and the mass percentage of the cyclic tetradentate metal platinum complex phosphorescent material is between 1% and 50%. The host material is not limited.

In the present invention, the organic optoelectronic device can be prepared by utilizing methods such as sputter coating, electron beam evaporation, vacuum evaporation, etc. to evaporate metal or oxides having electrical conductivity and alloys thereof on a substrate to form an anode; evaporating a hole-injection layer, a hole-transporting layer, a light-emitting layer, an air-blocking layer, and an electron transporting layer on the surface of the anode obtained by the preparation in sequential order, and then evaporating a cathode at a later time. In addition to the above method, an organic electroluminescent device is fabricated on a substrate by evaporation in the order of a cathode, an organic layer, and an anode. The organic layer may also include a multilayer structure such as a hole injection layer, a hole transport layer, a light-emitting layer, a hole blocking layer, and an electron transport layer. In the present invention, the organic layer is prepared by solvent engineering (spin-coating, tape-casting, doctor-blading, screen-printing, ink-jet printing, or Thermal-Imaging) using a high molecular material instead of the evaporation method, reducing the number of device layers.

The present invention also provides a composition including the cyclic tetradentate metal platinum complex phosphorescent material having the structure shown in formula (I), (I-1), or (I-2). Preferably, the composition further includes a fluorescent doping material, and the fluorescent doping materials are preferably boron-containing organic molecular light-emitting materials, and preferably phosphorescent sensitizable boron-containing compounds.

The present invention also provides a formulation including the cyclic tetradentate metal platinum complex phosphorescent material having the structure shown in formula (I), (I-1), or (I-2) or a composition as described above and at least one solvent.

The solvent is not particularly limited, and an unsaturated hydrocarbon solvent such as toluene, xylene, mesitylene, tetrahydronaphthalene, decahydronaphthalene, dicyclohexane, n-butylbenzene, sec-butylbenzene, t-butylbenzene and other unsaturated hydrocarbon solvents, halogenated saturated hydrocarbon solvents such as carbon tetrachloride, chloroform, methylene chloride, ethylene chloride, butyl chloride, butyl bromide, pentyl chloride, pentyl bromide, hexyl chloride, hexyl bromide, cyclohexyl chloride, cyclohexyl bromide, halogenated unsaturated hydrocarbon solvents such as chlorobenzene, dichlorobenzene, trichlorobenzene, ether solvents such as tetrahydrofuran and tetrahydropyran, and other halogenated solvents known to those skilled in the art, can be used.

The present invention also provides a display or lighting device including one or more of the organic photoelectric devices described above.

Compared with the prior art, the present invention has the following beneficial effects:

The present invention provides a cyclic tetradentate metal platinum complex phosphorescent material based on pyridine heterocycle, benzoxazole, and carbazole derivatives.

It is a novel tetradentate platinum (II) complex with a 6/6/6 metal fused ring phenoxy coordination structure. The phosphorescent material of the N—C—N—N tetradentate fused ring structure system of the present invention has the characteristics of easy modulation of HOMO and LUMO orbital energy levels and strong luminescence. It has good chemical stability and thermal stability and is easy to fabricate evaporation-type OLED devices. The organic electroluminescent device fabricated using the compound of the present invention as a light-emitting layer can reduce the start-up voltage and remarkably improve the external quantum efficiency.

### BRIEF DESCRIPTION OF DRAWINGS

FIG. 1 show emission spectrums of compounds Pt1, Pt2, Pt3 and Pt4 in the deoxygenated state in dichloromethane solution at room temperature;

FIG. 2 shows the HOMO, LUMO orbital distributions of compounds Pt513-Pt516; and

FIG. 3 shows the HOMO, LUMO orbital distributions of compounds Pt517-Pt520.

### DETAILED DESCRIPTION OF THE EMBODIMENTS

Hereinafter, the present invention will be described in detail. The description of the constituent elements recorded below is sometimes based on representative embodiments or specific examples of the present invention, but the present invention is not limited to such embodiments or specific examples.

As used herein, the term “substituted” is intended to encompass all permissible substituents of organic compounds. In broad aspects, permissible substituents include acyclic and cyclic, branched and unbranched, carbocyclic and heterocyclic, and aromatic and non-aromatic substituents of the organic compounds. Illustrative substituents include, for example, those described below. The permissible substituents may be one or more and the same or different for appropriate organic compounds. For the purposes of the present invention, the present invention is not intended to be limited in any manner by the permissible substituents of organic compounds. Likewise, the term “substituted” or “substituted with” includes the implicit proviso that such substitution is in accordance with a permitted valence of the substituted atom and the substituent and that the substitution results in a stable compound (e.g. a compound that does not spontaneously undergo transformation such as by rearrangement, cyclization, elimination, etc.). It is also contemplated that, in certain aspects, unless expressly stated to the contrary, individual substituents can be further optionally substituted (i.e. further substituted or unsubstituted).

In defining various terms, R₁-R₄, R^{a}, R^{b}, R^{c}, R^{d} and R^{e} are used herein as a general symbol to represent various specific substituents. These symbols can be any substituents, not limited to those disclosed herein, and when they are limited in one instance to certain substituents, they can be limited in other instances to some other substituents. R₁-R₄, R^{a}, R^{b}, R^{c}, R^{d} and R^{e} used in the present invention may independently have one or more of the groups listed above. For example, if R¹ is a straight chain alkyl group, one hydrogen atom of the alkyl group may be optionally substituted with hydroxyl, alkoxy, alkyl, halogen, and the like. Depending on the group selected, the first group may be incorporated within the second group, or alternatively, the first group may be pendant, i.e. attached, to the second group.

The term “alkyl” as used herein is a branched or unbranched saturated hydrocarbon group of 1 to 60 carbon atoms such as methyl, ethyl, n-propyl, isopropyl, n-butyl, isobutyl, sec-butyl, t-butyl, n-pentyl, isopentyl, sec-pentyl, neopentyl, hexyl, heptyl, hemi-, nonyl, decyl, dodecyl, tetradecyl, hexadecyl, eicosyl, tetracosyl and the like. The alkyl group may be cyclic or acyclic. The alkyl group may be branched or unbranched. The alkyl group is substitutable or unsubstituted. For example, the alkyl group is substitutable with one or more groups including, but not limited to, an optionally substituted alkyl, cycloalkyl, alkoxy, amino, halo, hydroxy, nitro, silyl, sulfo-oxo, or mercapto group as described herein.

The term “aryl” as used herein is a radical of any carbon-based aromatic group containing from 5 to 60 carbon atoms including, but not limited to, phenyl, naphthyl, phenyl, biphenyl, phenoxyphenyl, anthracenyl, phenanthrenyl, and the like. The term “aryl” also includes “heteroaryl”, which is defined as a group containing an aromatic group having at least one heteroatom incorporated within the ring of the aromatic group. Examples of heteroatoms include but are not limited to, nitrogen, oxygen, sulfur, and phosphorus. Likewise, the term “non-heteroaryl” (which is also encompassed by the term “aryl”) defines groups that contain aromatic groups that are free of a heteroatom. The aryl group is substitutable or unsubstituted. The aryl group is substitutable with one or more groups including, but not limited to, alkyl, cycloalkyl, alkoxy, alkenyl, cycloalkenyl, alkynyl, cycloalkynyl, aryl, heteroaryl, aldehyde, amino, carboxyl, ester, halogen, hydroxyl, carbonyl, azido, nitro, silyl, sulfo-oxo, or thiol as described herein.

The compounds of the invention may contain “optionally substituted” moieties. In general, the term “substituted” (whether preceded by the term “optionally” or not) means that one or more hydrogens of the designated moiety are replaced with a suitable substituent. Unless otherwise indicated, an “optionally substituted” group may have a suitable substituent at each substitutable position of the group, and when more than one position in any given structure is substitutable with more than one substituent selected from a specified group, the substituent may be either the same or different at every position. Combinations of substituents envisioned by this invention are preferably those that result in the formation of stable or chemically feasible compounds. In certain aspects, unless expressly stated to the contrary, it is encompassed that individual substituents can be further optionally substituted (i.e. further substituted or unsubstituted).

The compound disclosed herein can exhibit desirable properties and have emission and/or absorption spectra that can be modulated by the selection of appropriate ligands. In another aspect, the invention may exclude any one or more compounds, structures, or portions thereof specifically recited herein.

The compounds of the present invention can be prepared using a variety of methods, including but not limited to those described in the examples provided herein.

It is to be understood that both the foregoing general description and the following detailed description are exemplary and explanatory only and are not restrictive. The present application can be understood more readily by reference to the following detailed description and examples contained therein.

Before the present compounds, devices, and/or methods are disclosed and described, it is to be understood that they are not limited to specific synthetic methods (as otherwise indicated), or to specific reagents (as otherwise indicated), as such can, of course, vary. It is also to be understood that the terminology used in the invention is for the purpose of describing only the particular aspect and is not intended to be limiting. Although any methods and materials similar or equivalent to those described herein can be used in the practice or testing, exemplary methods and materials are described below. All starting materials and solvents of synthesis examples were purchased commercially unless otherwise specified, and the solvents were used as they were without further treatment.

The substrate of the present invention may be any substrate typically used in organic optoelectronic devices. It may be a glass or transparent plastic substrate, it may be a substrate of an opaque material such as silicon or stainless steel, and it may be a flexible PI film. Different substrates have different mechanical strength, thermal stability, transparency, surface smoothness, and water resistance. The application direction is different according to the properties of the substrates. As the materials for the hole-injecting layer, the hole-transporting layer, and the electron injecting layer, any material can be selected and used from known related materials for OLED devices, and the present invention is not particularly limited thereto.

### SYNTHESIS EXAMPLES

The following examples of compound syntheses, compositions, devices, or methods are provided merely to provide a general approach to the industry and are not intended to limit the scope of the patent. The data (quantity, temperature, etc.) mentioned in the patent are as accurate as possible, but some errors may exist. Unless otherwise noted, the weighing is done separately, the temperature is ° C., or room temperature, and the pressure is near atmospheric.

Methods for the preparation of novel compounds are provided in the following examples, but the preparation of such compounds is not limited to this method. In this technical field, since the claimed compound of the present invention can be easily prepared by modification, the methods listed below or other methods can be used. The following examples are given by way of example only and are not intended to limit the scope of this patent. The temperature, catalyst, concentration, reactants, and course of reaction may be varied to select different conditions for different reactants to produce the compound.

¹H NMR (500 MHz), ¹H NMR (400 MHz), and ¹³C NMR (126 MHz) spectra were measured on an ANANCE III (500M) NMR spectrometer. Unless otherwise specified, DMSO-d₆ or CDCl₃ containing 0.1% TMS was used as the solvent for NMR. TMS (δ=0.00 ppm) was used as the internal standard when CDCl₃ was used as the solvent for ¹H NMR spectrum. TMS (δ=0.00 ppm), residual DMSO peak (δ=2.50 ppm) or residual water peak (δ=3.33 ppm) was used as an internal standard when DMSO-d₆ was used as a solvent. In ¹³C NMR spectra, CDCl₃ (δ=77.00 ppm) or DMSO-d₆ (δ=39.52 ppm) was used as the internal standard. Determination was done on the HPLC-MS Agilent 6210 TOF LC/MS. HRMS spectra were determined on the Agilent 6210 TOF LC/MS type liquid chromatography-time-of-flight mass spectrometer. ¹H NMR spectral data: s=singlet, d=doublet, t=triplet, q=quartet, p=quintet, m=multiplet, br=broad.

### Example 1: Synthesis of Cyclic Tetradentate Metal Platinum Complex Pt1

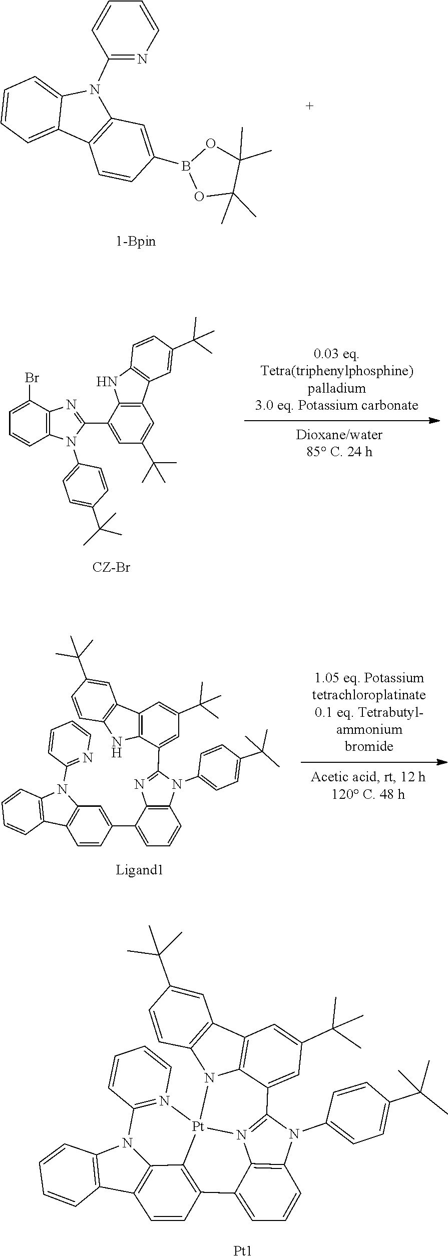

(1) Synthesis of ligand Ligand1: to a reaction tube added were 1-Bpin (174 mg, 0.47 mmol, 1.0 eq.), CZ—Br (300 mg, 0.49 mmol, 1.05 eq.), tetratriphenylphosphine palladium (16 mg, 0.014 mol, 3 mol %), and potassium carbonate (195 mg, 1.41 mmol, 3.0 eq.) sequentially. Nitrogen was pumped three times before adding 1,4-dioxane (5 mL) and water (1 mL). The reaction lasted 12 hours at 85° C. in an oil bath. The reaction mixture was cooled to room temperature, washed with water, and extracted with ethyl acetate. The aqueous layer was extracted three times with ethyl acetate, dried over anhydrous sodium sulfate, filtered, and distilled under reduced pressure to remove the solvent. The crude product obtained was purified by chromatography on a silica gel column with eluent: petroleum ether/ethyl acetate=20: 1-10:1 to give a white solid, 70 mg, 19% yield. ¹H NMR (500 MHz, CDCl₃): δ (ppm) 1.10 (s, 10H), 1.38 (s, 9H), 1.40 (s, 9H), 7.14-7.19 (m, 3H), 7.34 (d, J=8.5 Hz, 1H), 7.40-7.44 (m, 3H), 7.50-7.54 (m, 4H), 7.70 (d, J=8.5 Hz, 3H), 7.91 (d, J=8.5 Hz, 1H), 7.97 (d, J=8.0 Hz, 1H), 8.14 (dd, J=8.0, 1.5 Hz, 1H), 8.23 (d, J=1.5 Hz, 1H), 8.26 (d, J=1.5 Hz, 1H), 8.36 (d, J=7.5 Hz, 1H), 8.39-8.42 (m, 1H), 8.47 (d, J=8.0 Hz, 1H), 8.94 (d, J=1.0 Hz, 1H), 11.24 (s, 1H).

(2) Synthesis of Pt1: to a 50 mL dried three-necked flask equipped with a magnetic rotor and a condenser tube added were Ligand1 (70 mg, 0.091 mmol, 1.0 eq.), potassium chloroplatinite (40 mg, 0.095 mmol, 1.05 eq.), tetra-n-butylammonium bromide (3 mg, 0.009 mmol, 0.1 eq.) successively. Nitrogen was pumped three times before adding acetic acid (6 mL). The reaction solution was bubbled with nitrogen for 30 minutes, stirred at room temperature for 12 hours, and then reacted at 120° C. for 48 hours. The reaction mixture was cooled to room temperature, and distilled under reduced pressure to remove the solvent. The crude product obtained was purified by chromatography on a silica gel column with eluent: petroleum ether/dichloromethane=3: 1-1:1 to give a yellow solid, 52 mg, 59% yield. ¹H NMR (500 MHz, CDCl₃): δ (ppm) 1.11 (s, 9H), 1.41 (s, 9H), 1.48 (s, 9H), 6.66-6.73 (m, 2H), 7.05 (dd, J=7.5, 0.5 Hz, 1H), 7.10 (dd, J=9.0, 2.0 Hz, 1H), 7.42-7.49 (m, 2H), 7.52 (dd, J=8.5, 2.0 Hz, 1H), 7.54-7.59 (m, 1H), 7.66 (d, J=2.0 Hz, 1H), 7.69 (dd, J=8.0, 2.0 Hz, 1H), 7.73 (dd, J=8.5, 2.0 Hz, 1H), 7.81 (dd, J=8.0, 2.0 Hz, 1H), 7.84 (ddd, J=8.5, 7.0, 1.5 Hz, 1H), 7.97 (d, J=8.0 Hz, 1H), 8.09-8.21 (m, 6H), 8.28 (d, J=2.0 Hz, 1H), 9.22 (dd, J=6.0, 1.5 Hz, 1H).

### Example 2: Synthesis of Cyclic Tetradentate Metal Platinum Complex Pt2

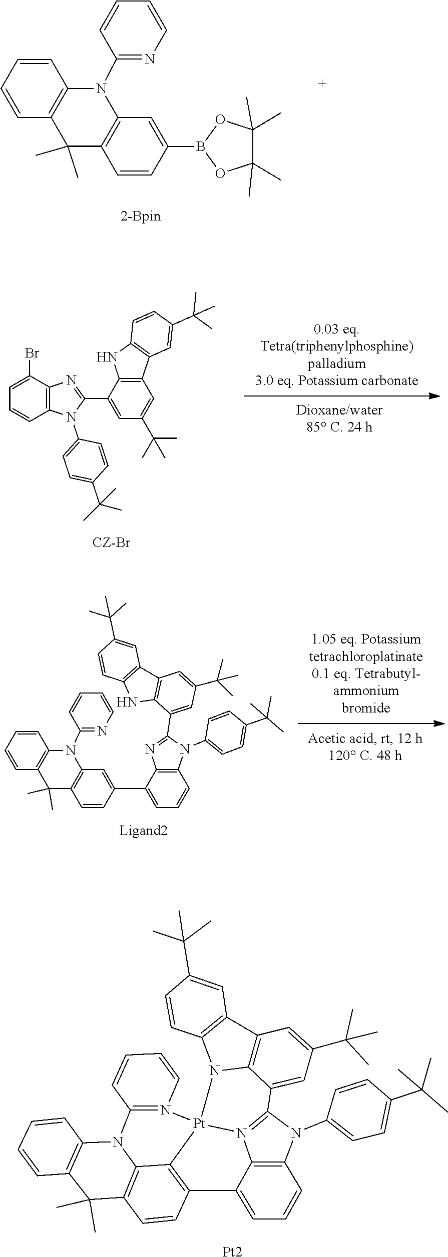

(1)Synthesis of ligand Ligand2: to a reaction tube added were 2-Bpin (247 mg, 0.60 mmol, 1.0 eq.), CZ—Br (400 mg, 0.66 mmol, 1.1 eq.), tetratriphenylphosphine palladium (21 mg, 0.018 mol, 3 mol %), and potassium carbonate (249 mg, 1.80 mmol, 3.0 eq.) sequentially. Nitrogen was pumped three times before adding 1,4-dioxane (5 mL) and water (1 mL). The reaction lasted 12 hours at 85° C. in an oil bath. The reaction mixture was cooled to room temperature, washed with water, and extracted with ethyl acetate. The aqueous layer was extracted three times with ethyl acetate, dried over anhydrous sodium sulfate, filtered, and distilled under reduced pressure to remove the solvent. The crude product obtained was purified by chromatography on a silica gel column with eluent: petroleum ether/ethyl acetate=20: 1-10:1 to give a white solid, 141 mg, 23% yield.

(2)Synthesis of Pt2: to a 50 mL dried three-necked flask equipped with a magnetic rotor and a condenser tube added were Ligand2 (120 mg, 0.15 mmol, 1.0 eq.), potassium chloroplatinite (64 mg, 0.16 mmol, 1.05 eq.), tetra-n-butylammonium bromide (5 mg, 0.015 mmol, 0.1 eq.) successively. Nitrogen was pumped three times before adding acetic acid (9 mL). The reaction solution was bubbled with nitrogen for 30 minutes, stirred at room temperature for 12 hours, and then reacted at 120° C. for 48 hours. The reaction mixture was cooled to room temperature, and distilled under reduced pressure to remove the solvent. The crude product obtained was purified by chromatography on a silica gel column with eluent: petroleum ether/dichloromethane=3: 1-1:1 to give a product, yellow solid, 50 mg, 34% yield. ¹H NMR (400 MHz, DMSO-d₆): δ (ppm) 1.06 (s, 9H), 1.34 (s, 3H), 1.39 (s, 9H), 1.43 (s, 9H), 1.97 (s, 3H), 6.00 (d, J=8.8 Hz, 1H), 6.98-7.11 (m, 3H), 7.33 (t, J=7.2 Hz, 2H), 7.39-7.57 (m, 6H), 7.68 (d, J=8.0 Hz, 1H), 7.74 (d, J=8.4 Hz, 1H), 7.92 (d, J=8.8 Hz, 1H), 7.96-8.08 (m, 3H), 8.10 (d, J=7.6 Hz, 1H), 8.18 (s, 1H), 8.37 (s, 1H), 8.83 (d, J=6.0 Hz, 1H).

### Example 3: Synthesis of Cyclic Tetradentate Metal Platinum Complex Pt3

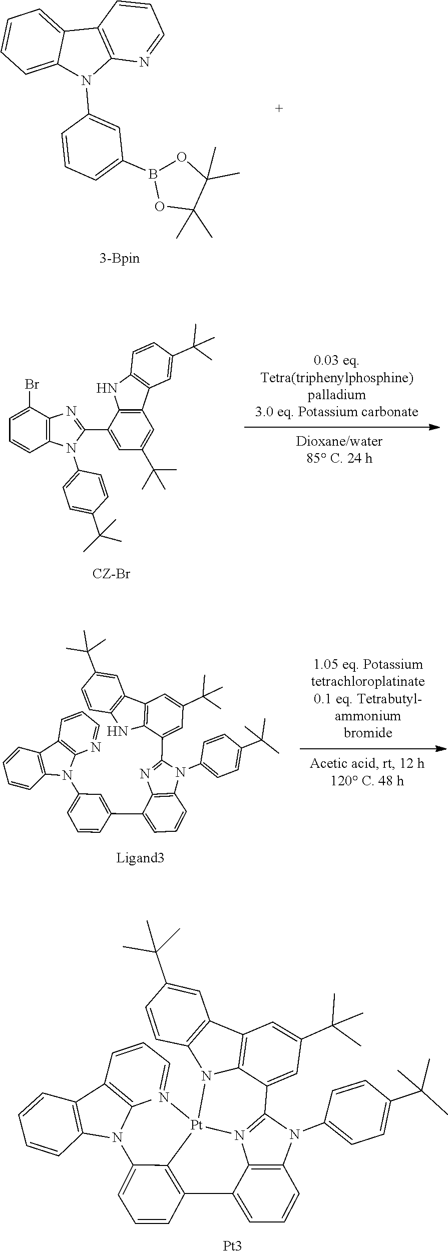

(1) Synthesis of ligand Ligand3: to a reaction tube added were 3-Bpin (148 mg, 0.40 mmol, 1.0 eq.), CZ—Br (255 mg, 0.42 mmol, 1.05 eq.), tetratriphenylphosphine palladium (14 mg, 0.012 mol, 3 mol %), and potassium carbonate (166 mg, 1.20 mmol, 3.0 eq.) sequentially. Nitrogen was pumped three times before adding 1,4-dioxane (4 mL) and water (1 mL). The reaction lasted 12 hours at 85° C. in an oil bath. The reaction mixture was cooled to room temperature, washed with water, and extracted with ethyl acetate. The aqueous layer was extracted three times with ethyl acetate, dried over anhydrous sodium sulfate, filtered, and distilled under reduced pressure to remove the solvent. The crude product obtained was purified by chromatography on a silica gel column with eluent: petroleum ether/ethyl acetate=20: 1-10:1 to give a white solid, 292 mg, 95% yield. ¹H NMR (400 MHz, DMSO-d₆): δ (ppm) 1.06 (s, 9H), 1.35 (s, 9H), 1.38 (s, 9H), 6.70 (d, J=8.4 Hz, 1H), 7.08 (d, J=1.6 Hz, 1H), 7.14-7.27 (m, 4H), 7.36 (dd, J=7.6, 4.8 Hz, 1H), 7.44 (t, J=7.2 Hz, 1H), 7.48-7.49 (m, 2H), 7.64-7.69 (m, 2H), 7.71 (d, J=7.2 Hz, 1H), 7.80-7.82 (m, 2H), 7.89 (t, J=7.6 Hz, 1H), 8.16 (d, J=1.6 Hz, 1H), 8.20 (d, J=1.6 Hz, 1H), 8.26-8.29 (m, 2H), 8.43 (dd, J=4.8, 1.6 Hz, 1H), 8.61 (t, J=1.6 Hz, 1H), 8.66 (dd, J=7.6, 1.6 Hz, 1H), 11.00 (s, 1H).

(2) Synthesis of Pt3: to a 50 mL dried three-necked flask equipped with a magnetic rotor and a condenser tube added were Pt3 (233 mg, 0.30 mmol, 1.0 eq.), potassium chloroplatinite (132 mg, 0.32 mmol, 1.05 eq.), tetra-n-butylammonium bromide (10 mg, 0.03 mmol, 0.1 eq.) successively. Nitrogen was pumped three times before adding acetic acid (18 mL). The reaction solution was bubbled with nitrogen for 30 minutes, stirred at room temperature for 12 hours, and then reacted at 120° C. for 48 hours. The reaction mixture was cooled to room temperature, and distilled under reduced pressure to remove the solvent. The crude product obtained was purified by chromatography on a silica gel column with eluent: petroleum ether/dichloromethane=3: 1-1:1 to give a product, yellow solid, 140 mg, 48% yield. ¹H NMR (400 MHz, DMSO-d₆): δ (ppm) 1.06 (s, 9H), 1.27 (s, 9H), 1.44 (s, 9H), 4.69 (d, J=8.8 Hz, 1H), 6.63 (dd, J=8.8, 2.0 Hz, 1H), 7.05 (d, J=8.0 Hz, 1H), 7.31 (dd, J=7.6, 6.0 Hz, 1H), 7.38 (t, J=8.0 Hz, 1H), 7.53 (t, J=8.0 Hz, 1H), 7.56 (d, J=1.6 Hz, 1H), 7.63 (t, J=7.6 Hz, 1H), 7.72-7.90 (m, 5H), 7.92 (d, J=8.0 Hz, 1H), 8.06 (d, J=2.0 Hz, 1H), 8.16-8.25 (m, 2H), 8.33 (d, J=1.6 Hz, 1H), 8.35 (d, J=8.4 Hz, 1H), 8.55-8.65 (m, 2H), 9.01 (dd, J=7.6, 1.2 Hz, 1H).

### Example 4: Synthesis of Cyclic Tetradentate Metal Platinum Complex Pt4

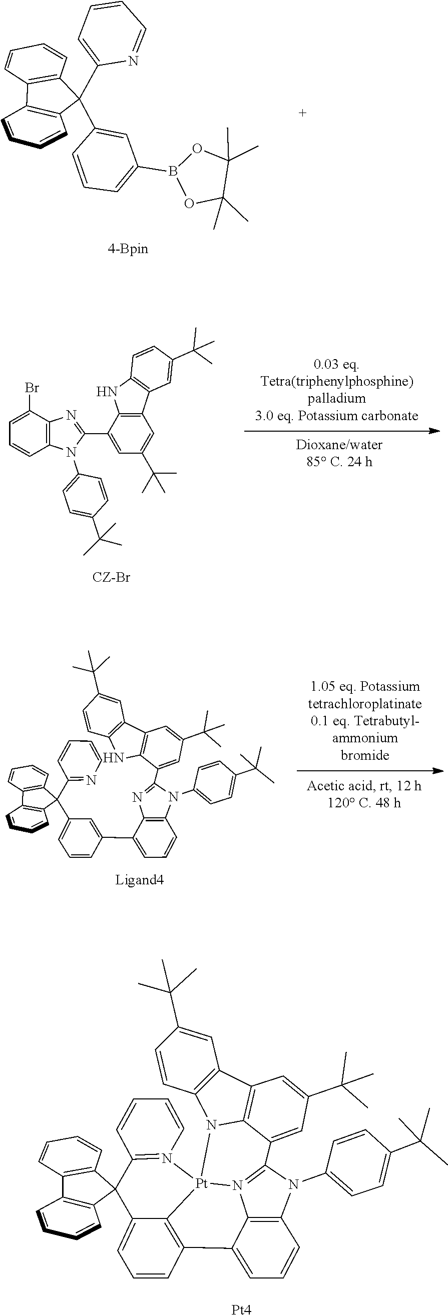

(1)Synthesis of ligand Ligand4: to a reaction tube added were 4-Bpin (181 mg, 0.41 mmol, 1.0 eq.), CZ—Br (300 mg, 0.41 mmol, 1.0 eq.), tetratriphenylphosphine palladium (14 mg, 0.012 mol, 3 mol %), and potassium carbonate (169 mg, 1.22 mmol, 3.0 eq.) sequentially. Nitrogen was pumped three times before adding 1,4-dioxane (4 mL) and water (1 mL). The reaction lasted 12 hours at 85° C. in an oil bath. The reaction mixture was cooled to room temperature, washed with water, and extracted with ethyl acetate. The aqueous layer was extracted three times with ethyl acetate, dried over anhydrous sodium sulfate, filtered, and distilled under reduced pressure to remove the solvent. The crude product obtained was purified by chromatography on a silica gel column with eluent: petroleum ether/ethyl acetate=20: 1-10:1 to give a white solid, 318 mg, 92% yield. ¹H NMR (400 MHz, CDCl₃): δ (ppm) 1.10 (s, 9H), 1.41 (s, 9H), 1.45 (s, 9H), 7.08-7.13 (m, 3H), 7.14 (d, J=1.6 Hz, 1H), 7.15-7.20 (m, 3H), 7.21-7.25 (m, 2H), 7.33 (td, J=7.6, 0.8 Hz, 2H), 7.35-7.39 (m, 2H), 7.42-7.51 (m, 4H), 7.59-7.64 (m, 2H), 7.66 (t, J=1.6 Hz, 1H), 7.75 (t, J=7.2 Hz, 4H), 8.05 (d, J=1.6 Hz, 1H), 8.08 (s, 1H), 8.25 (d, J=7.6 Hz, 1H), 8.63-8.68 (m, 1H), 11.03 (s, 1H).

(2) Synthesis of Pt4: to a 50 mL dried three-necked flask equipped with a magnetic rotor and a condenser tube added were Pt3 (231 mg, 0.27 mmol, 1.0 eq.), potassium chloroplatinite (119 mg, 0.29 mmol, 1.05 eq.), tetra-n-butylammonium bromide (9 mg, 0.027 mmol, 0.1 eq.) successively. Nitrogen was pumped three times before adding acetic acid (17 mL). The reaction solution was bubbled with nitrogen for 30 minutes, stirred at room temperature for 12 hours, and then reacted at 120° C. for 48 hours. The reaction mixture was cooled to room temperature, and distilled under reduced pressure to remove the solvent. The crude product obtained was purified by chromatography on a silica gel column with eluent: petroleum ether/dichloromethane=3: 1-1:1 to give a product, yellow solid, 200 mg, 71% yield. ¹H NMR (400 MHz, CDCl₃): δ (ppm) 1.09 (s, 9H), 1.22 (s, 9H), 1.45 (s, 9H), 4.84 (d, J=8.8 Hz, 1H), 6.39 (dd, J=8.8, 2.0 Hz, 1H), 6.51-6.62 (m, 2H), 6.91 (t, J=7.6 Hz, 1H), 7.04 (d, J=8.0 Hz, 1H), 7.09 (d, J=8.4 Hz, 1H), 7.17-7.22 (m, 2H), 7.35 (d, J=7.6 Hz, 1H), 7.45-7.52 (m, 2H), 7.55 (d, J=1.6 Hz, 1H), 7.59 (t, J=7.6 Hz, 1H), 7.66-7.79 (m, 2H), 7.86-8.04 (m, 6H), 8.07 (d, J=2.0 Hz, 1H), 8.19 (d, J=7.6 Hz, 1H), 8.36 (d, J=1.6 Hz, 1H), 9.23-9.36 (m, 1H), 10.42 (d, J=8.0 Hz, 1H).

### Example 5: Synthesis of Pt16

Pt16 was synthesized by referring to the synthesis procedure and reaction condition of compound Pt1. The desired product was obtained as 562 mg of yellow solid with a yield of 60%. Molecular weight [M+H]⁺: 885.2.

### Example 6: Synthesis of Pt21

Pt-21 was synthesized by referring to the synthesis procedure and reaction condition of compound Pt1. The desired product was obtained as 624 mg of yellow solid with a yield of 59%. Molecular weight [M+H]⁺: 885.2.

### Example 7: Synthesis of Pt62

Pt-62 was synthesized by referring to the synthesis procedure and reaction condition of compound Pt1. The desired product was obtained as 661 mg of yellow solid with a yield of 72%. Molecular weight [M+H]⁺: 939.2.

### Example 8: Synthesis of Pt74

Pt-74 was synthesized by referring to the synthesis procedure and reaction condition of compound Pt1. The desired product was obtained as 484 mg of yellow solid with a yield of 61%. Molecular weight [M+H]⁺: 885.2.

### Example 9: Synthesis of Pt03

Pt-103 was synthesized by referring to the synthesis procedure and reaction condition of compound Pt1. The desired product was obtained as 455 mg of yellow solid with a yield of 65%. Molecular weight [M+H]⁺: 928.3.

### Example 10: Synthesis of Pt18

Pt118 was synthesized by referring to the synthesis procedure and reaction condition of compound Pt1. The desired product was obtained as 410 mg of yellow solid with a yield of 60%. Molecular weight [M+H]⁺: 1003.3.

### Example 11: Synthesis of Pt128

Pt128 was synthesized by referring to the synthesis procedure and reaction condition of compound Pt1. The desired product was obtained as 492 mg of yellow solid with a yield of 62%. Molecular weight [M+H]⁺: 989.2.

### Example 12: Synthesis of Pt40

Pt140 was synthesized by referring to the synthesis procedure and reaction condition of compound Pt1. The desired product was obtained as 467 mg of yellow solid with a yield of 61%. Molecular weight [M+H]⁺: 1017.3.

### Example 13: Synthesis of Pt157

Pt157 was synthesized by referring to the synthesis procedure and reaction condition of compound Pt1. The desired product was obtained as 528 mg of yellow solid with a yield of 68%. Molecular weight [M+H]⁺: 1011.3.

### Example 14: Synthesis of Pt171

Pt171 was synthesized by referring to the synthesis procedure and reaction condition of compound Pt1. The desired product was obtained as 436 mg of yellow solid with a yield of 48%. Molecular weight [M+H]⁺: 812.2.

### Example 15: Synthesis of Pt190

Pt190 was synthesized by referring to the synthesis procedure and reaction condition of compound Pt1. The desired product was obtained as 410 mg of yellow solid with a yield of 66%. Molecular weight [M+H]⁺: 975.2.

### Example 16: Synthesis of Pt224

Pt224 was synthesized by referring to the synthesis procedure and reaction condition of compound Pt1. The desired product was obtained as 492 mg of yellow solid with a yield of 82%. Molecular weight [M+H]⁺: 1059.3.

### Example 17: Synthesis of Pt263

Pt263 was synthesized by referring to the synthesis procedure and reaction condition of compound Pt1. The desired product was obtained as 467 mg of yellow solid with a yield of 72%. Molecular weight [M+H]⁺: 885.2.

### Example 18: Synthesis of Pt276

Pt276 was synthesized by referring to the synthesis procedure and reaction condition of compound Pt1. The desired product was obtained as 528 mg of yellow solid with a yield of 68%. Molecular weight [M+H]⁺: 1011.4.

### Example 19: Synthesis of Pt319

Pt319 was synthesized by referring to the synthesis procedure and reaction condition of compound Pt1. The desired product was obtained as 436 mg of yellow solid with a yield of 49%. Molecular weight [M+H]⁺: 1073.4.

### Example 20: Synthesis of Pt345

Pt345 was synthesized by referring to the synthesis procedure and reaction condition of compound Pt1. The desired product was obtained as 410 mg of yellow solid with a yield of 66%. Molecular weight [M+H]⁺: 1046.4.

### Example 21: Synthesis of Pt395

Pt395 was synthesized by referring to the synthesis procedure and reaction condition of compound Pt1. The desired product was obtained as 492 mg of yellow solid with a yield of 82%. Molecular weight [M+H]⁺: 1091.4.

### Example 22: Synthesis of Pt410

Pt410 was synthesized by referring to the synthesis procedure and reaction condition of compound Pt1. The desired product was obtained as 467 mg of yellow solid with a yield of 72%. Molecular weight [M+H]⁺: 1283.5.

### Example 23: Synthesis of Pt442

Pt442 was synthesized by referring to the synthesis procedure and reaction condition of compound Pt1. The desired product was obtained as 528 mg of yellow solid with a yield of 63%. Molecular weight [M+H]⁺: 927.2.

### Example 24: Synthesis of Pt486

Pt486 was synthesized by referring to the synthesis procedure and reaction condition of compound Pt1. The desired product was obtained as 436 mg of yellow solid with a yield of 54%. Molecular weight [M+H]⁺: 1016.3.

### Example 25: Synthesis of Pt508

Pt508 was synthesized by referring to the synthesis procedure and reaction condition of compound Pt1. The desired product was obtained as 410 mg of yellow solid with a yield of 60%. Molecular weight [M+H]⁺: 1140.3.

### Example 26: Synthesis of Pt513

Pt513 was synthesized by referring to the synthesis procedure and reaction condition of compound Pt1. The desired product was obtained as 492 mg of yellow solid with a yield of 59%. Molecular weight [M+H]⁺: 1095.5.

### Example 27: Synthesis of Pt514

Pt514 was synthesized by referring to the synthesis procedure and reaction condition of compound Pt1. The desired product was obtained as 467 mg of yellow solid with a yield of 62%. Molecular weight [M+H]⁺: 1122.5.

### Example 28: Synthesis of Pt515

Pt515 was synthesized by referring to the synthesis procedure and reaction condition of compound Pt1. The desired product was obtained as 528 mg of yellow solid with a yield of 58%. Molecular weight [M+H]⁺: 777.2.

### Example 29: Synthesis of Pt516

Pt516 was synthesized by referring to the synthesis procedure and reaction condition of compound Pt1. The desired product was obtained as 436 mg of yellow solid with a yield of 52%. Molecular weight [M+H]⁺: 778.2.

### Example 30: Synthesis of Pt517

Pt517 was synthesized by referring to the synthesis procedure and reaction condition of compound Pt1. The desired product was obtained as 410 mg of yellow solid with a yield of 56%. Molecular weight [M+H]⁺: 997.4.

### Example 31: Synthesis of Pt518

Pt518 was synthesized by referring to the synthesis procedure and reaction condition of compound Pt1. The desired product was obtained as 492 mg of yellow solid with a yield of 62%. Molecular weight [M+H]⁺: 1093.4.

### Example 32: Synthesis of Pt519

Pt519 was synthesized by referring to the synthesis procedure and reaction condition of compound Pt1. The desired product was obtained as 467 mg of yellow solid with a yield of 66%. Molecular weight [M+H]⁺: 817.3.

### Example 33: Synthesis of Pt520

Pt520 was synthesized by referring to the synthesis procedure and reaction condition of compound Pt1. The desired product was obtained as 528 mg of yellow solid with a yield of 63%. Molecular weight [M+H]⁺: 748.2.

### Photophysical Testing and Theoretical Calculation Description:

Steady state emission experiments and lifetime measurements were performed on a Horiba Jobin Yvon FluoroLog-3 spectrometer. Pt(II) complexes were theoretically calculated using the Titan software package, and the geometry of the ground state (S₀) molecule was optimized using density-functional theory (DFT). DFT calculations were performed using B3LYP functional where the 6-31G(d) basis set was used for C, H, O and S atoms and the LANL2DZ basis set was used for Pt atoms.

### Experimental Data and Analysis

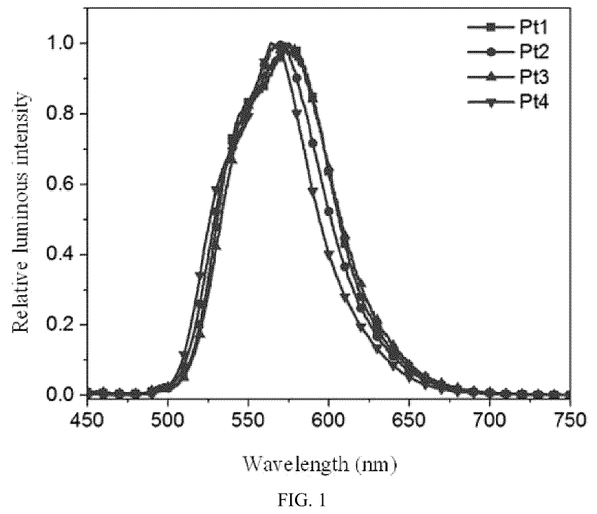

FIG. 1 shows emission spectrums of compounds Pt1, Pt2, Pt3, and Pt4 in the deoxygenated state in dichloromethane solution at room temperature. It can be seen from FIG. 1 that some compounds Pt1, Pt2, Pt3, and Pt4 of the present invention can all emit intense orange-red light and can be applied to the OLED light-emitting layer material.

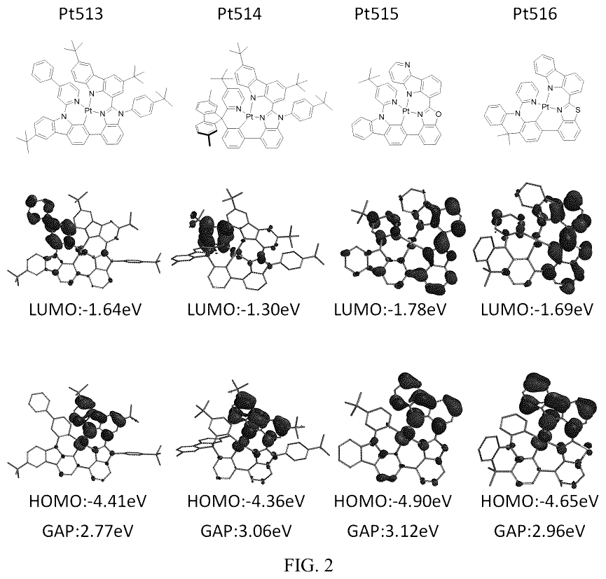

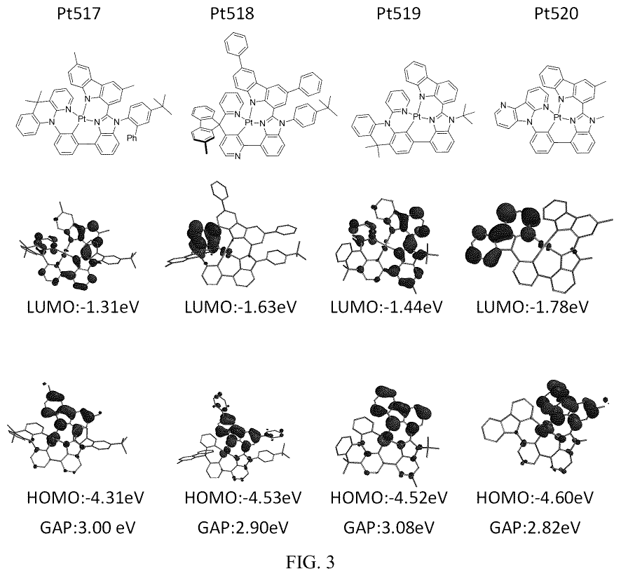

Compounds Pt513-Pt520 were calculated using density functional theory (DFT) and Table 1 shows the DFT theoretical calculation data. FIG. 2 shows the HOMO, LUMO orbital distributions of compounds Pt513-Pt516. FIG. 3 shows the HOMO, LUMO orbital distributions of compounds Pt517-Pt520.

TABLE 1
DFT theoretical calculation data

| | | | Band | | | | Band |
|---|---|---|---|---|---|---|---|
| Name | LUMO/eV | HOMO/eV | gap/eV | Name | LUMO/eV | HOMO/eV | gap/eV |
| Pt513 | −1.64 | −4.41 | 2.77 | Pt514 | −1.30 | −4.36 | 3.06 |
| Pt515 | −1.78 | −4.90 | 3.12 | Pt516 | −1.69 | −4.65 | 2.96 |
| Pt517 | −1.31 | −4.31 | 3.00 | Pt518 | −1.63 | −4.53 | 2.90 |
| Pt519 | −1.44 | −4.52 | 3.08 | Pt520 | −1.78 | −4.60 | 2.82 |

As can be seen from Table 1, FIGS. 2 and 3, Pt513, Pt514, Pt515, and Pt516 have similar HOMO orbital distribution. The HOMO orbital distribution concentrates on the carbazole group and the Pt atom in the metal center. The alkyl substitution and aryl substitution can significantly affect the HOMO energy level. The t-butyl group can effectively improve its electron donating ability, so that the HOMO energy level of Pt513 is increased from −4.90 ev to −4.41 ev compared with that of Pt515. The LUMO orbital distributions of Pt517, Pt518, Pt519, and Pt520 are all different, which is due to the large structural variation of the ligand unit containing pyridine heterocycle. The LUMO energy level of Pt518 is concentrated on the pyridine unit, while that of Pt520 is concentrated on the azacarbazole unit, which indicates that the ligand unit containing different heterocycle can effectively regulate the LUMO energy level distribution and energy level size, which is beneficial to further regulate and control the photophysical properties of the complex. The above experimental data and theoretical calculation results fully indicate that the cyclic tetradentate metal platinum complex phosphorescent materials based on pyridine heterocycle, benzoxazole and carbazole derivatives developed in the present application have the characteristics of easy modulation of HOMO and LUMO orbital energy levels and high efficiency of phosphorescence quantum, indicating its great application prospect in the field of OLED.

### Fabrication of OLED Devices

In a preferred embodiment of the present invention, the OLED device of the present invention includes a hole transport layer. The hole transport material may preferably be selected from known or unknown materials, and the present invention may be selected from one or more of the following hole transport material structures, but this does not mean that the present invention is limited to the following structures:

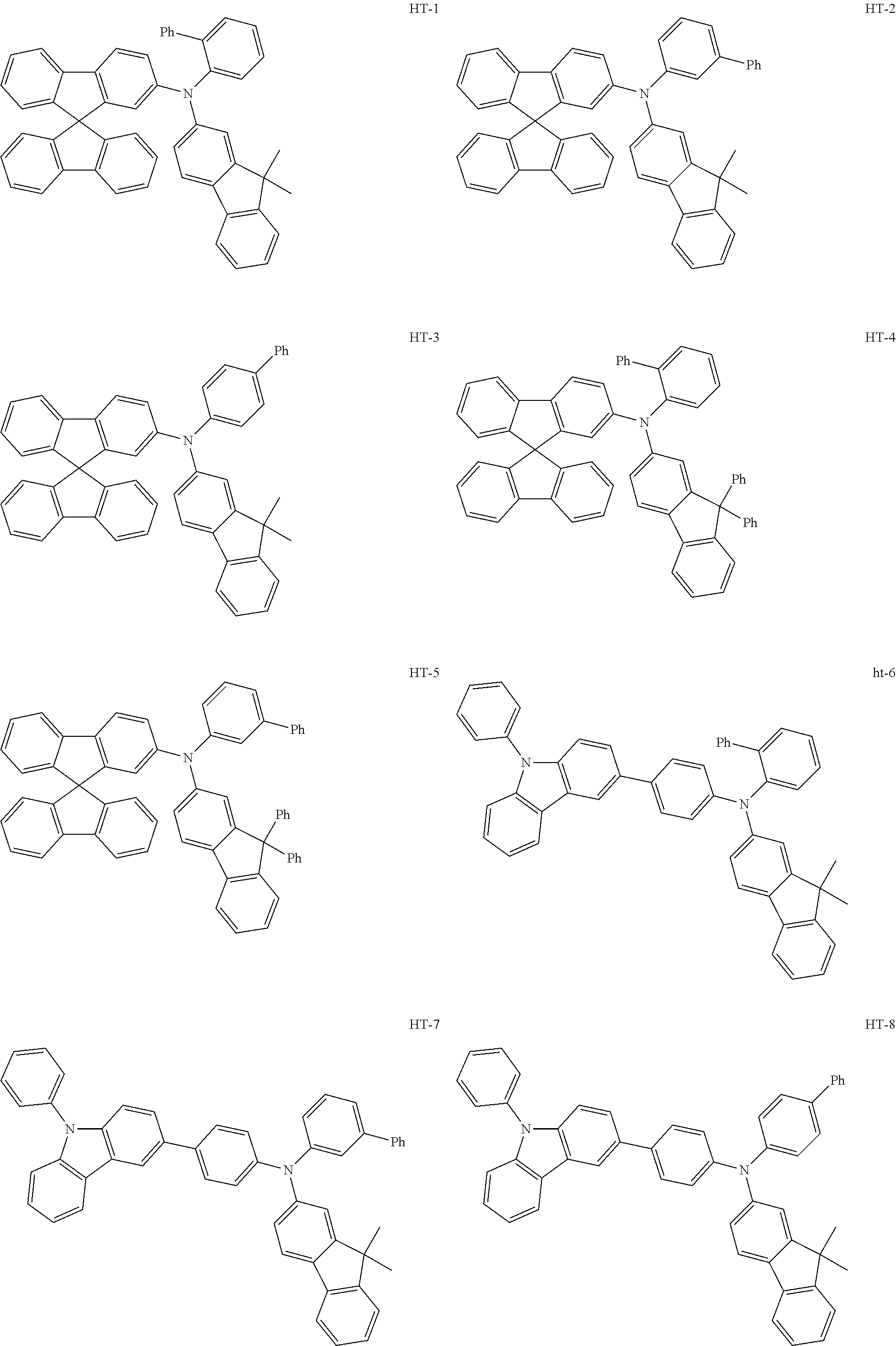

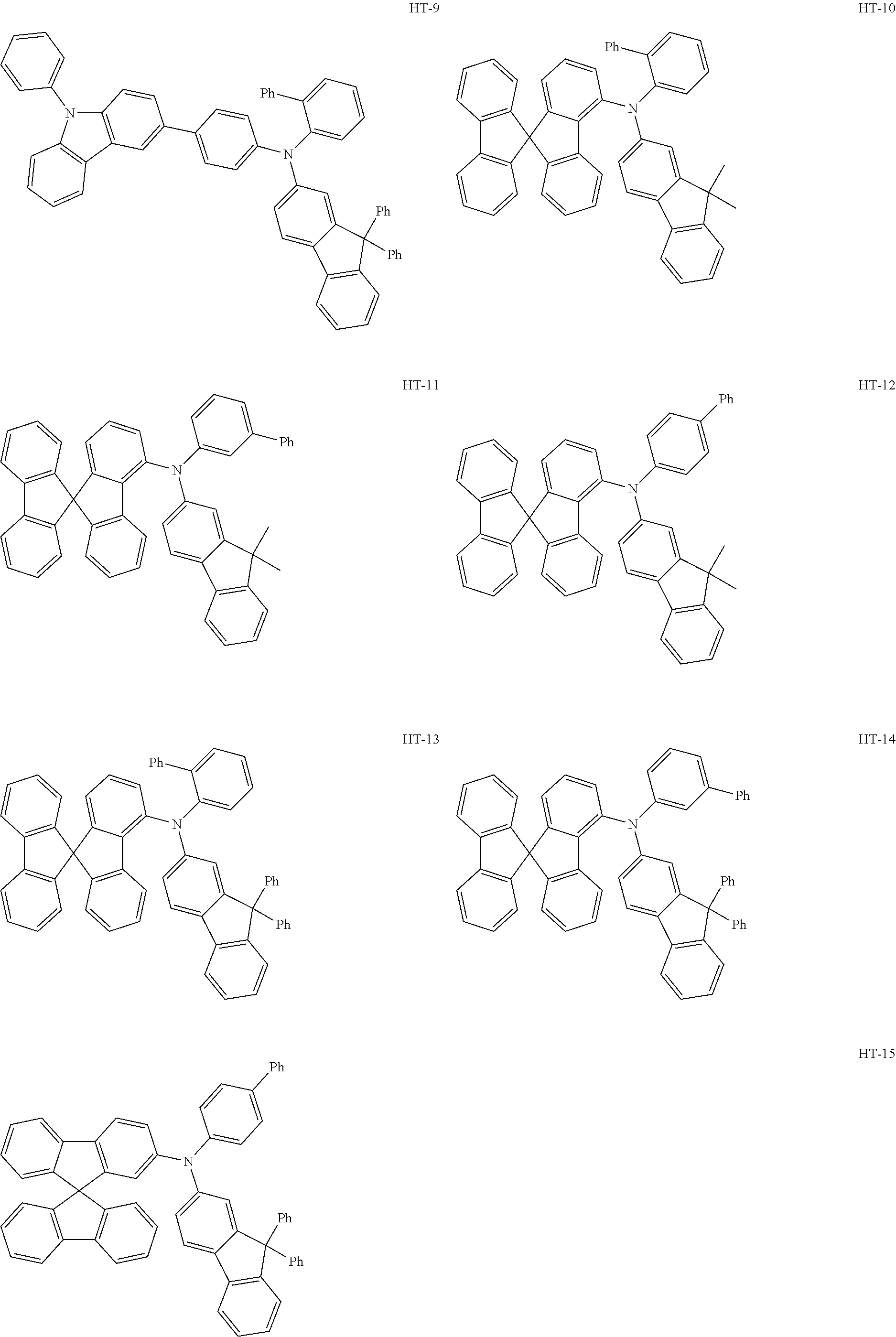

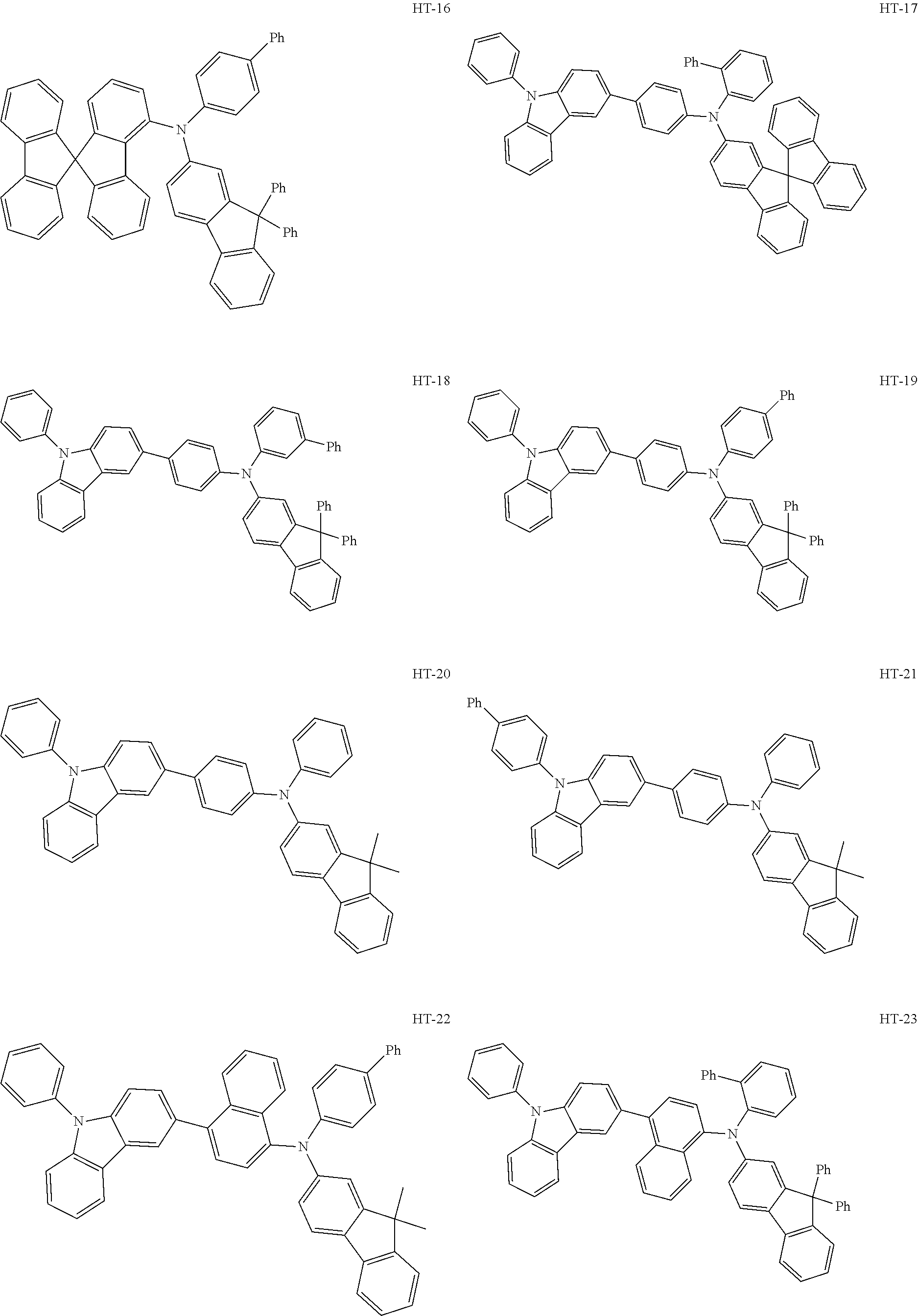

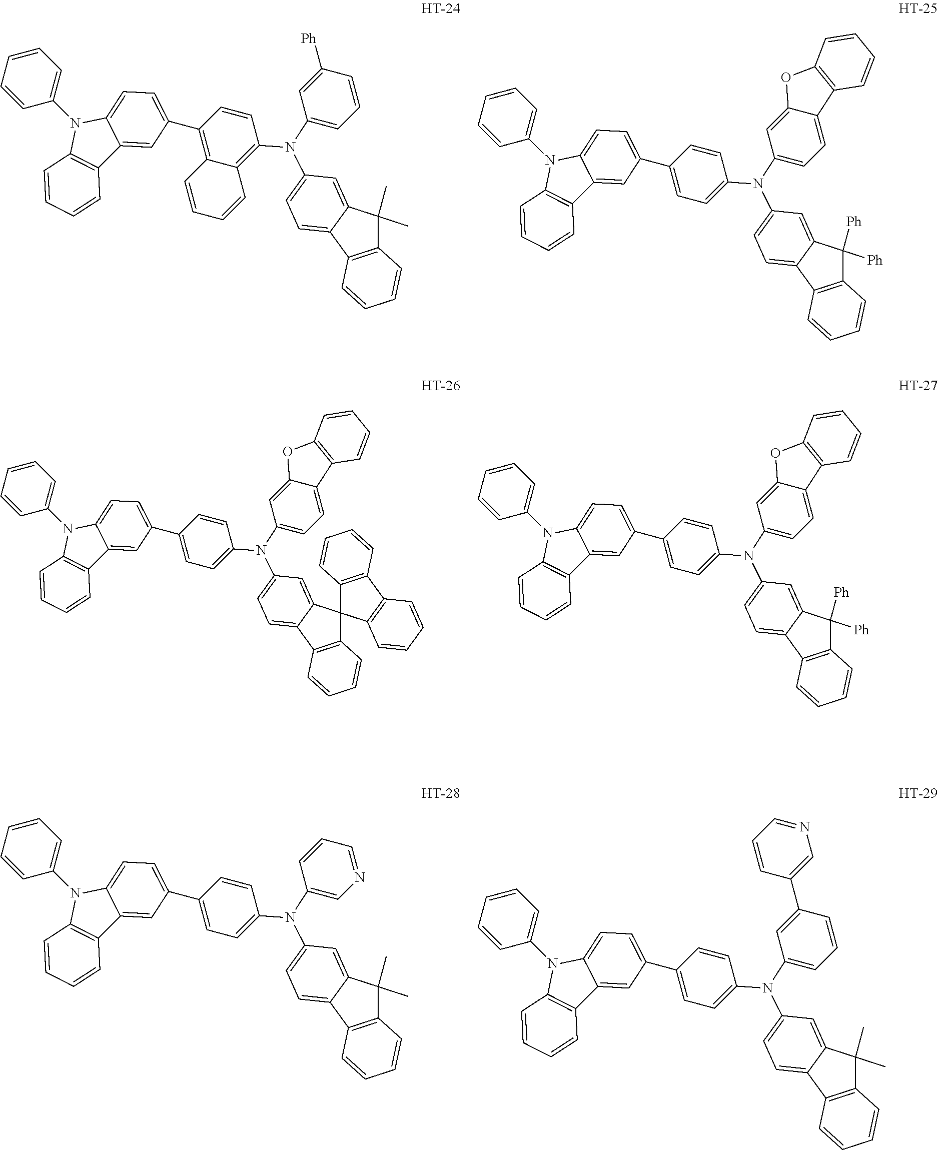

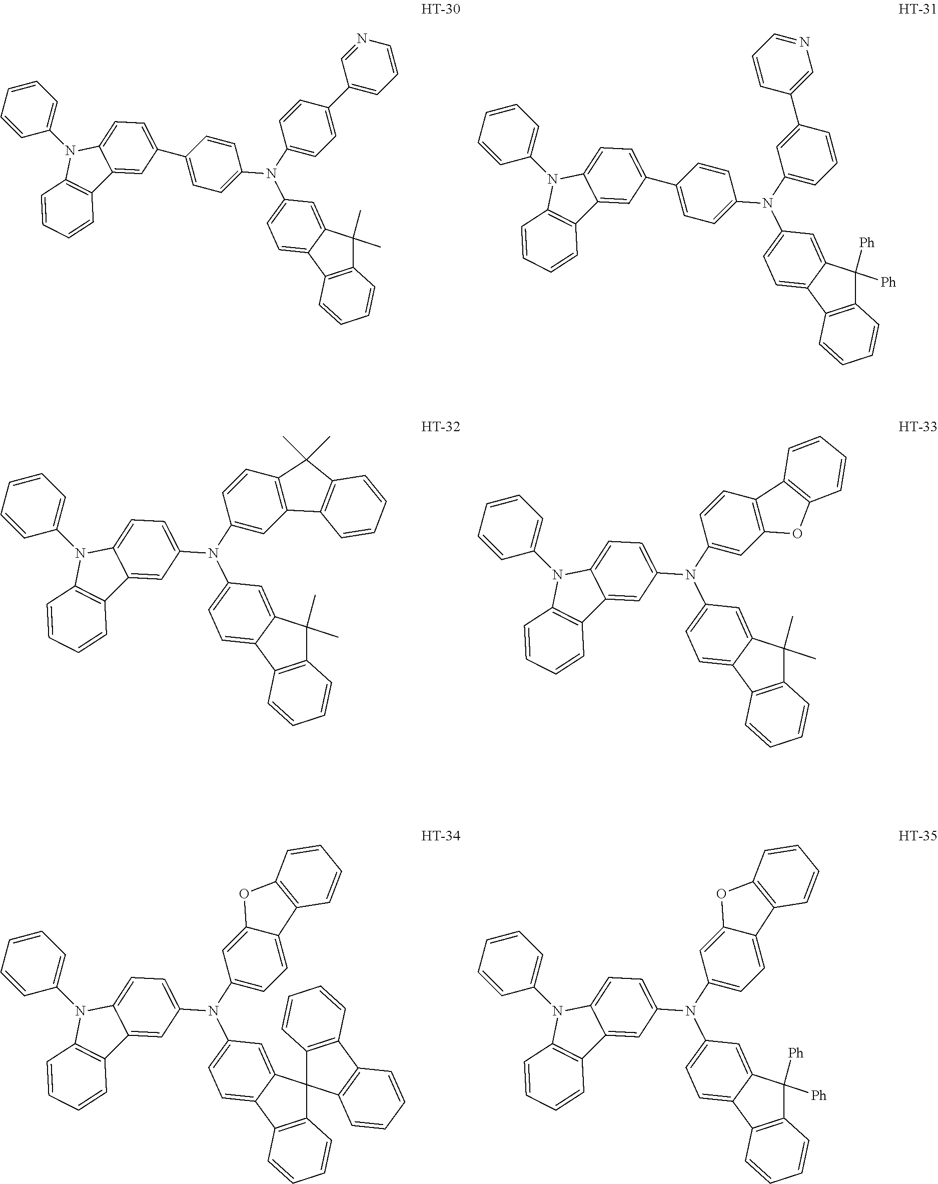

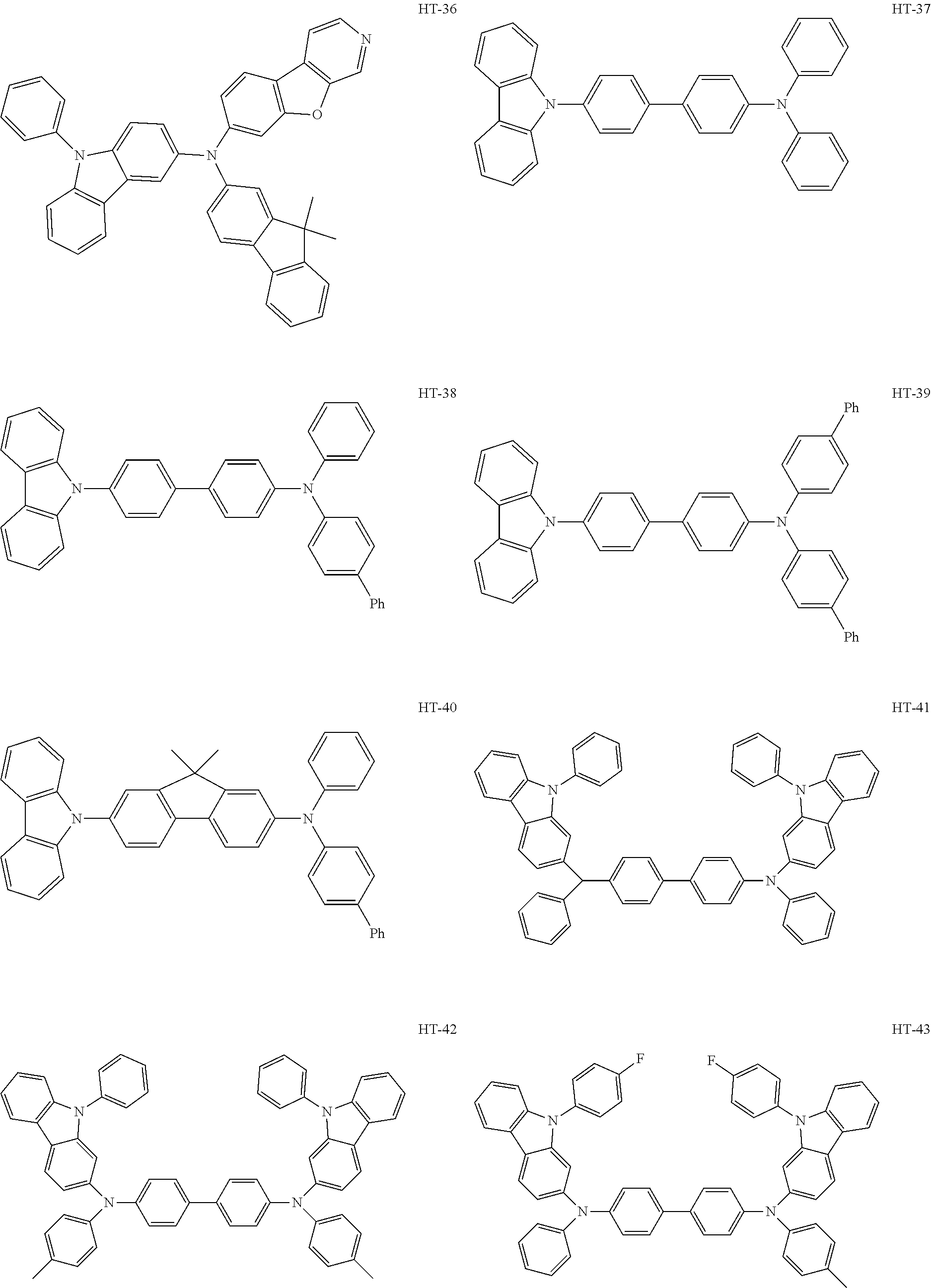

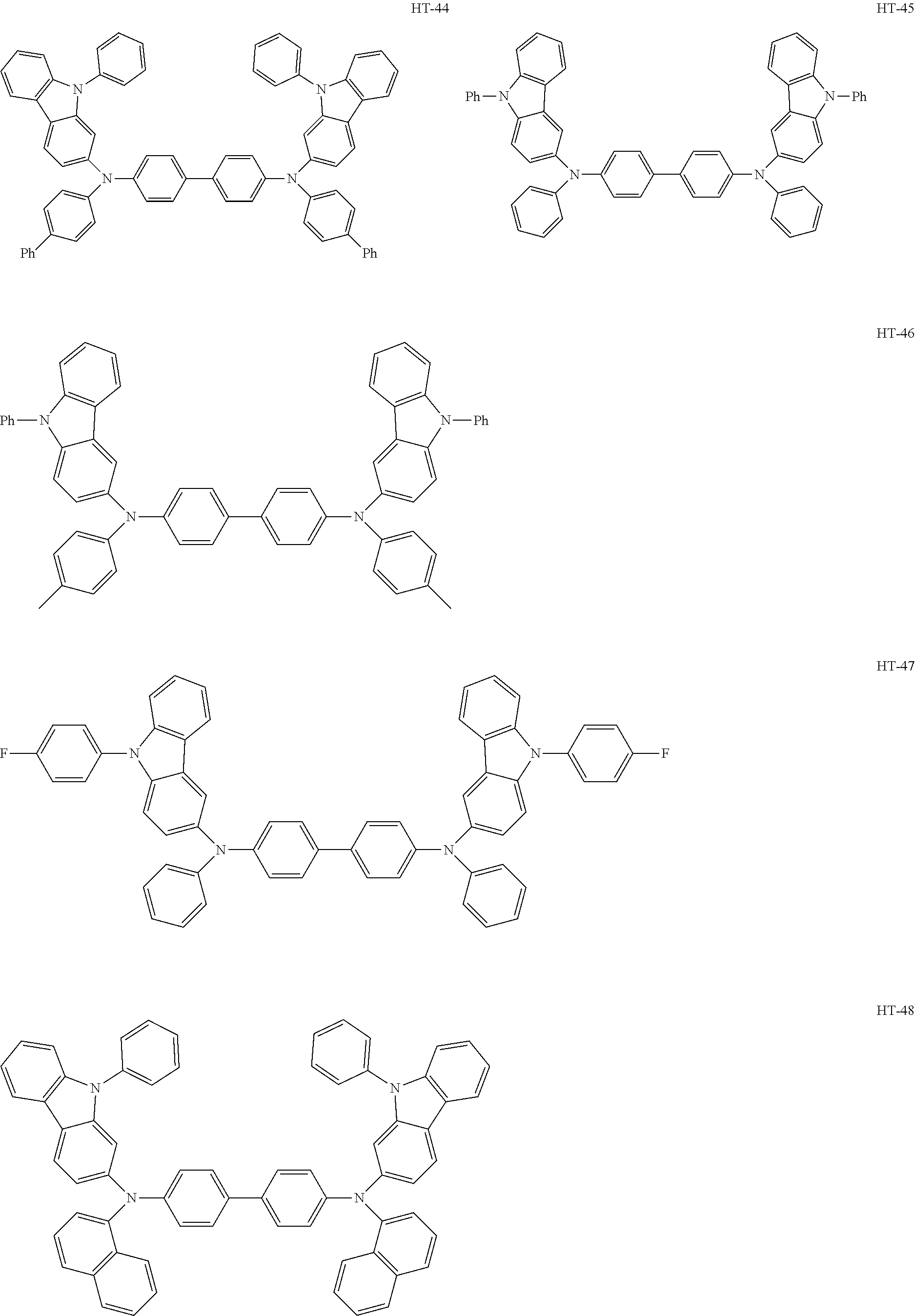

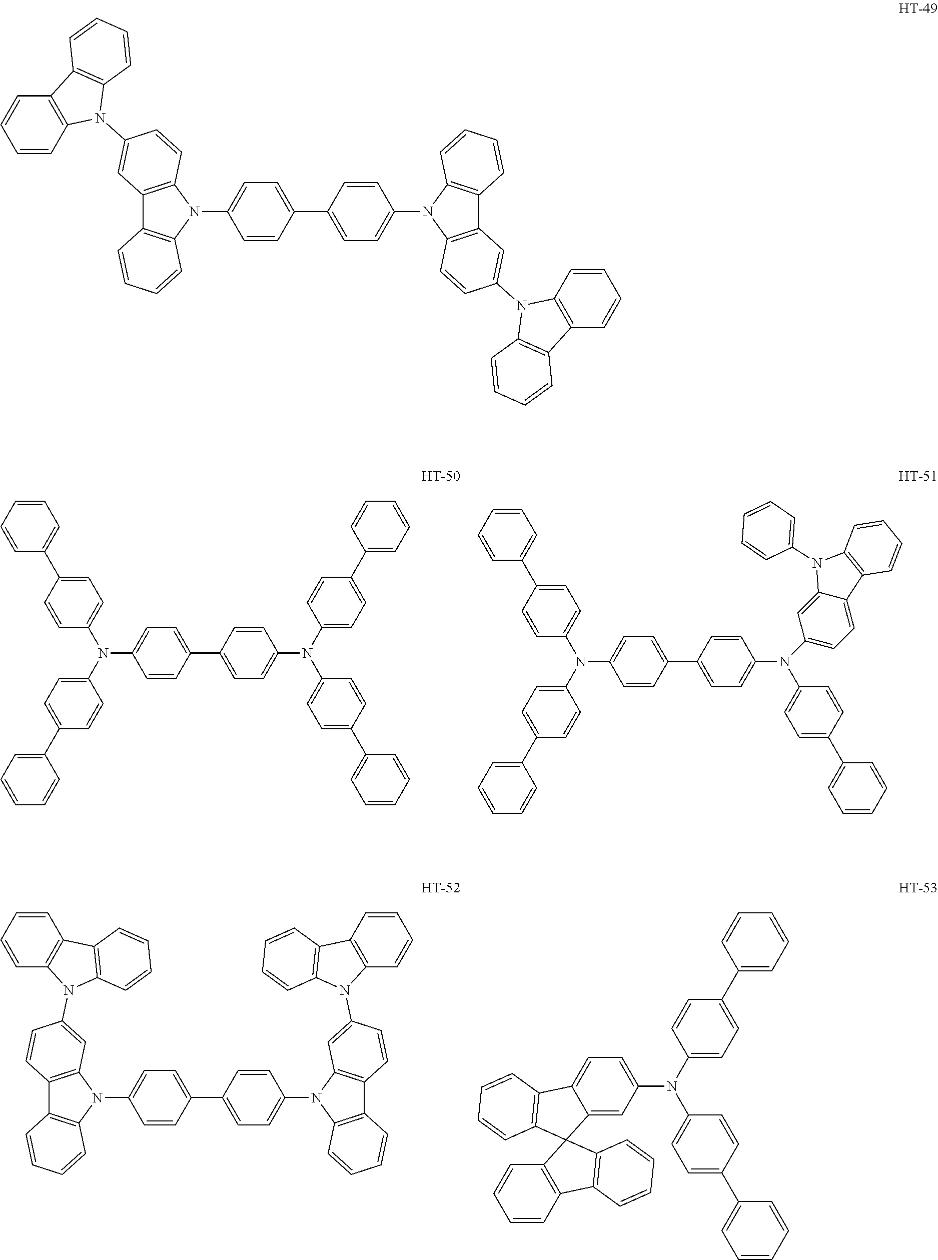

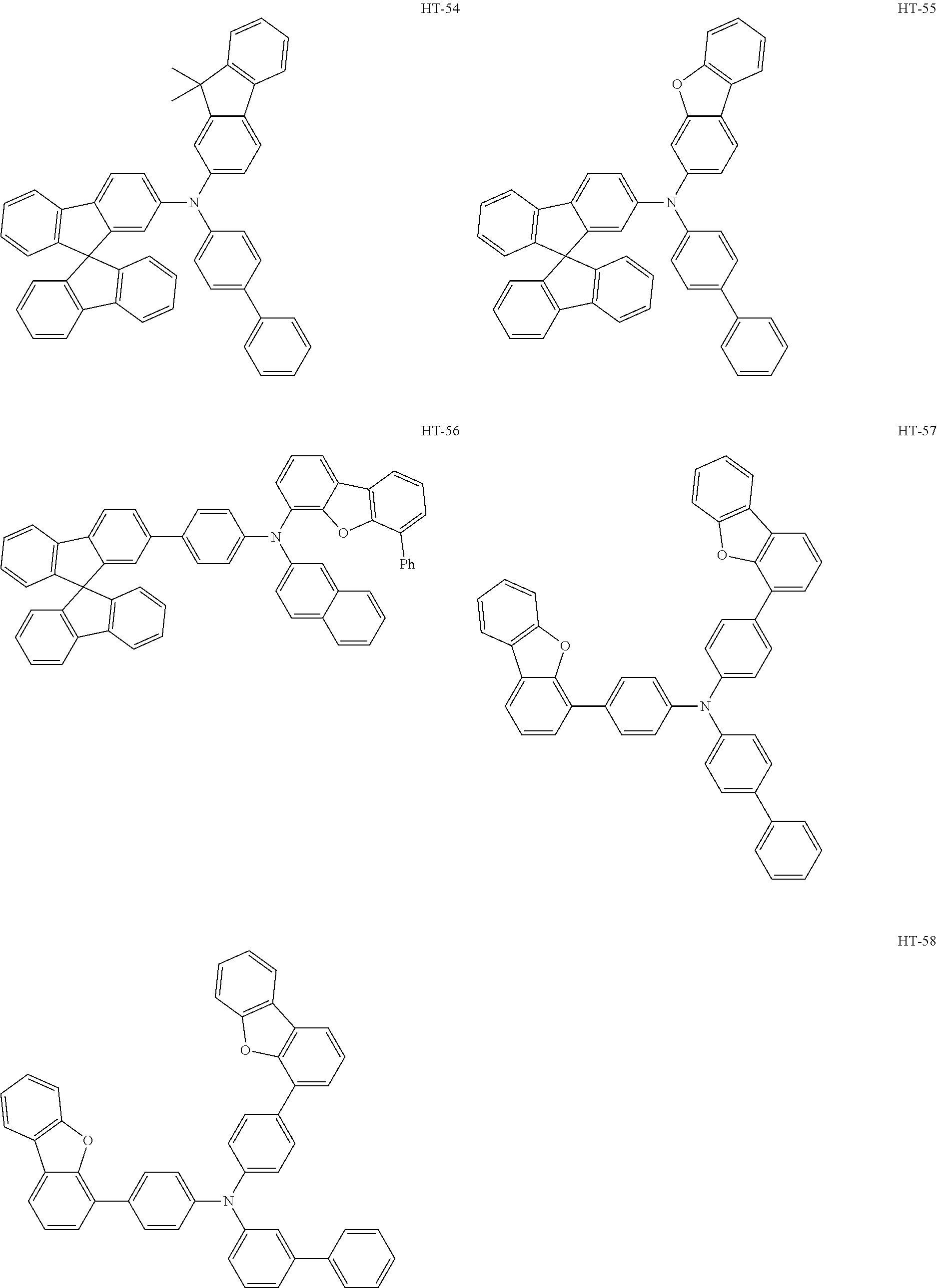 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3ccc4c(c3)C3(c5ccccc5-c5ccccc53)c3ccccc3-4)c3ccc4c(c3)oc3ccccc34)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1]

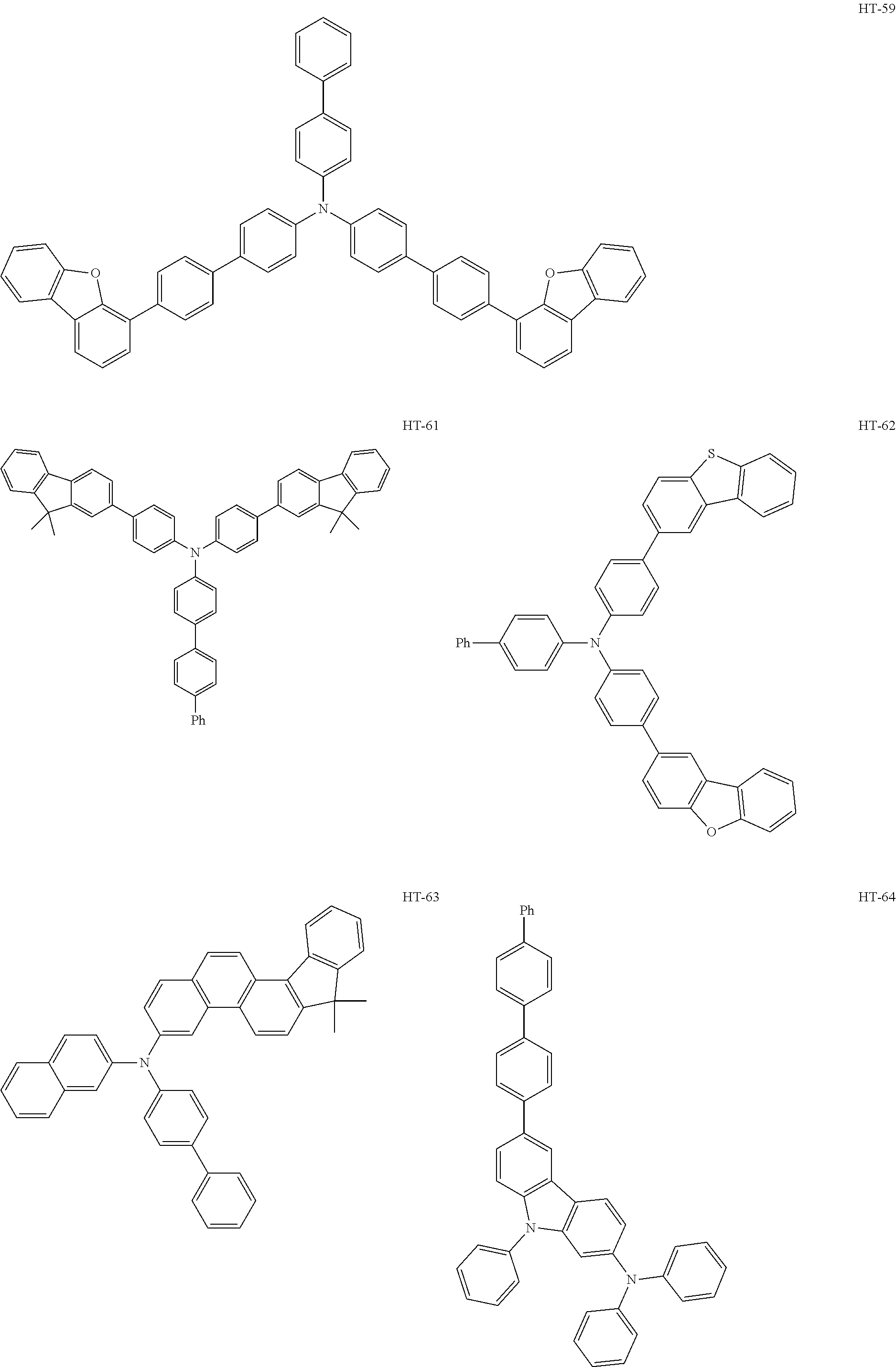 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; CC1(C)c2ccccc2-c2c1ccc1c2ccc2ccc(N(c3ccc(-c4ccccc4)cc3)c3ccc4ccccc4c3)cc21 ; c1ccc(-c2ccc(-c3ccc(-c4ccc5c(c4)c4ccc(N(c6ccccc6)c6ccccc6)cc4n5-c4ccccc4)cc3)cc2)cc1]

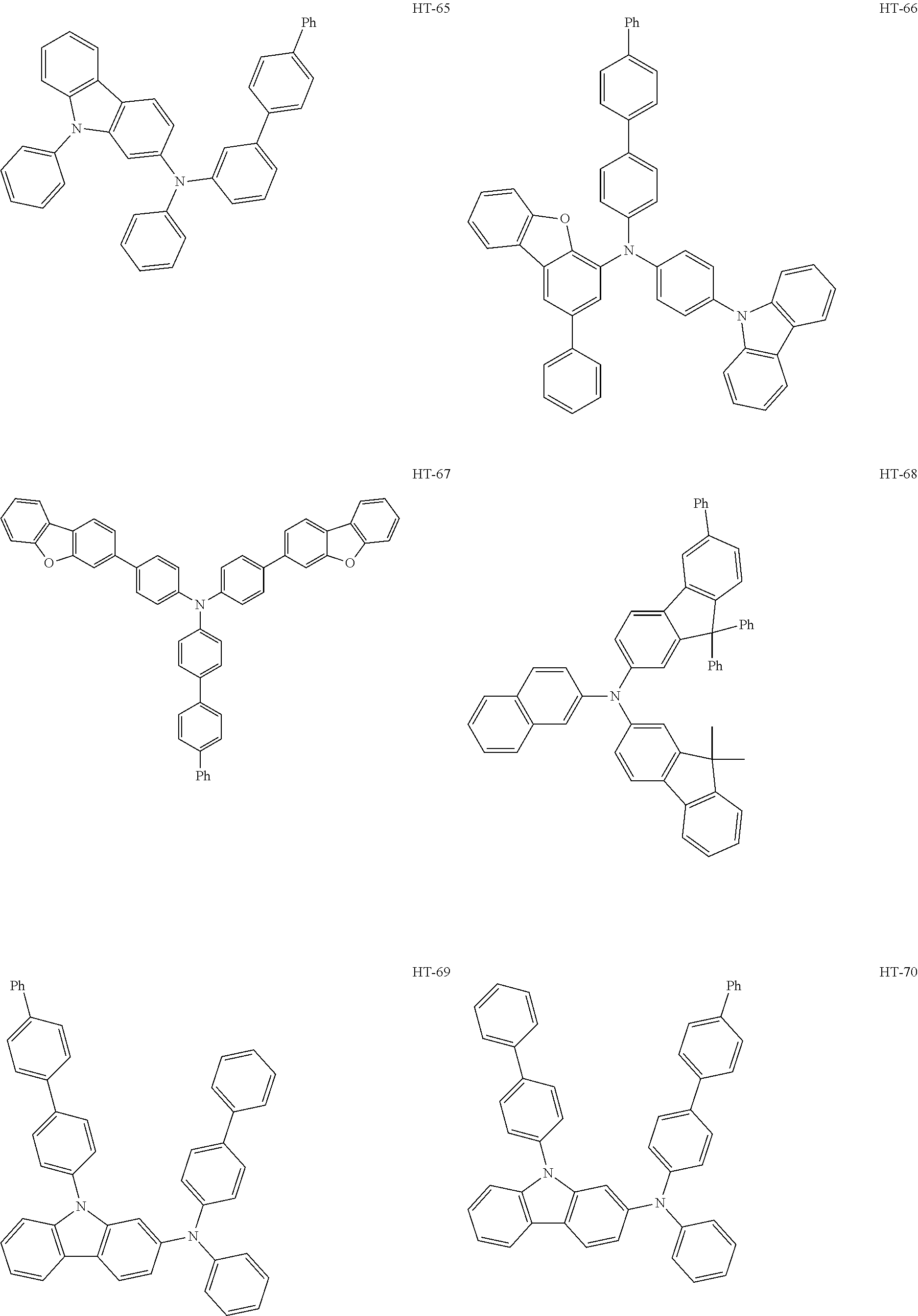

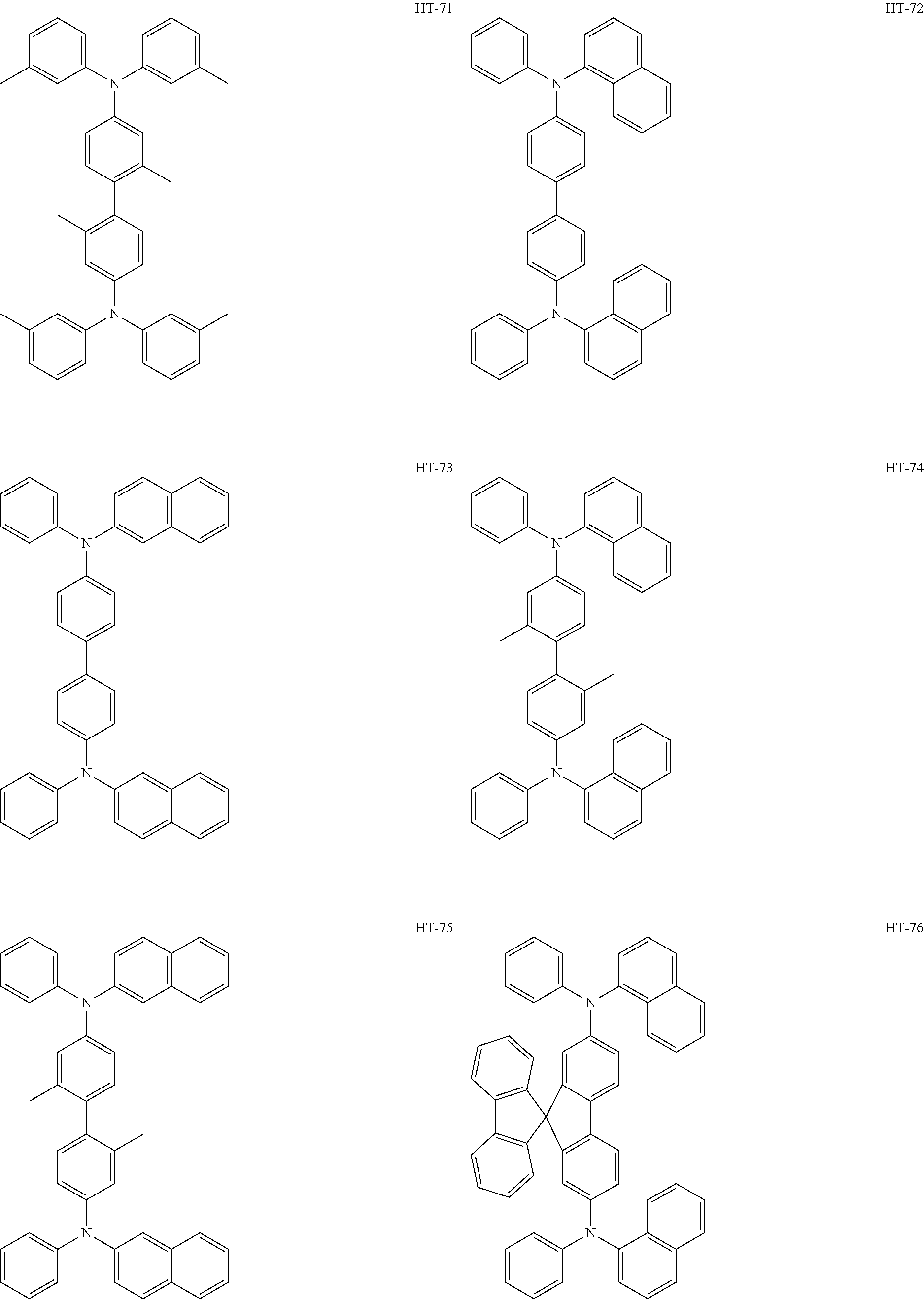

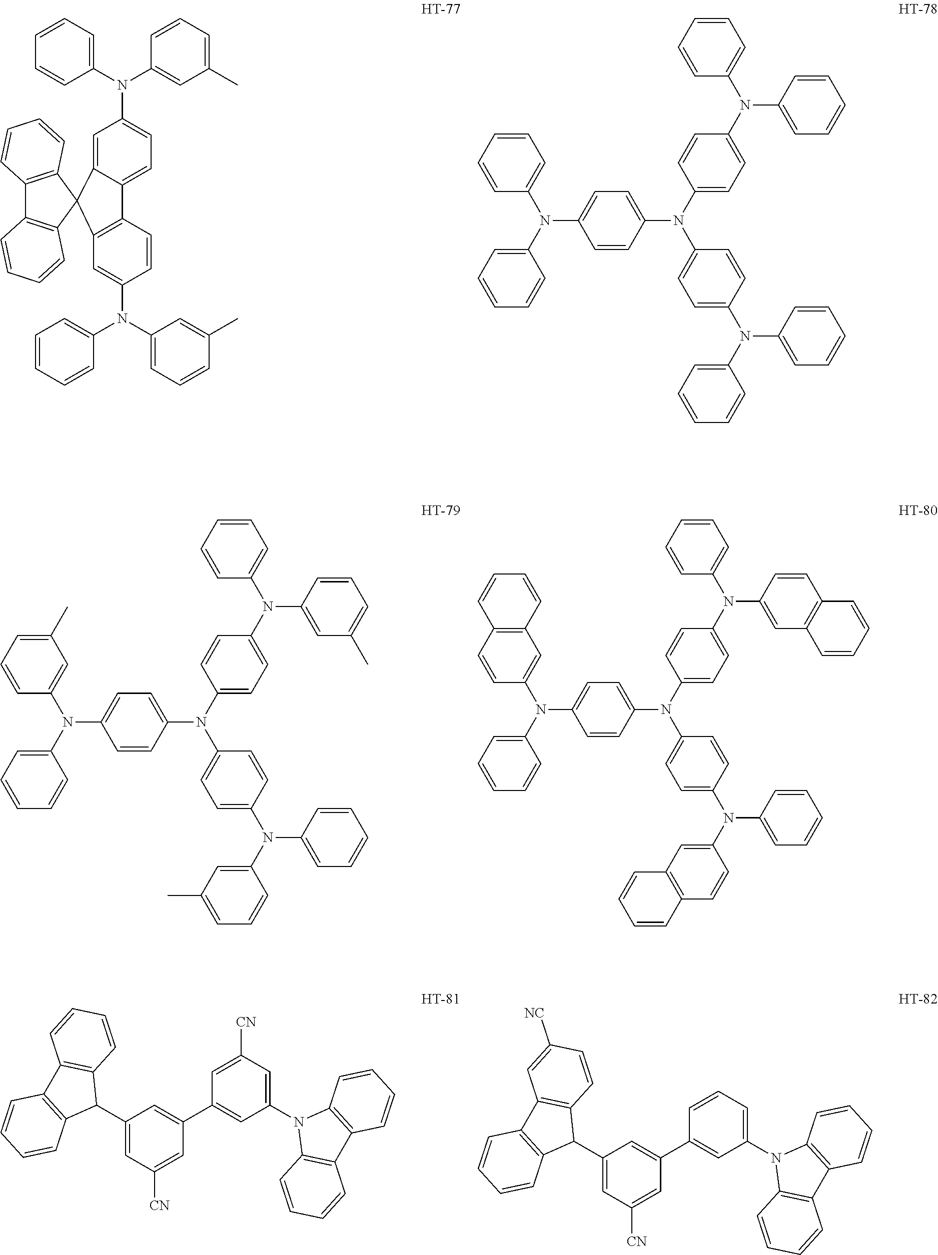

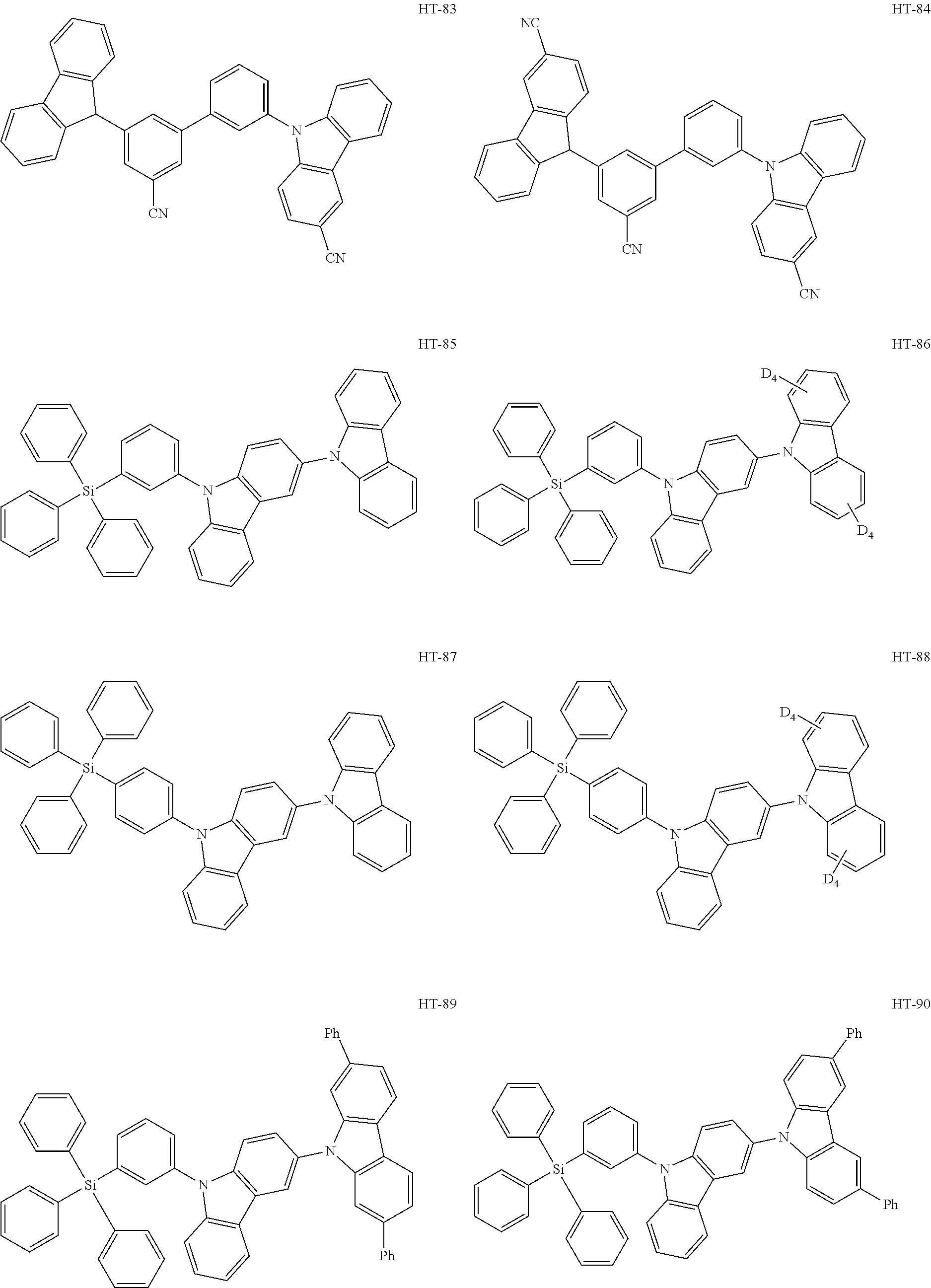

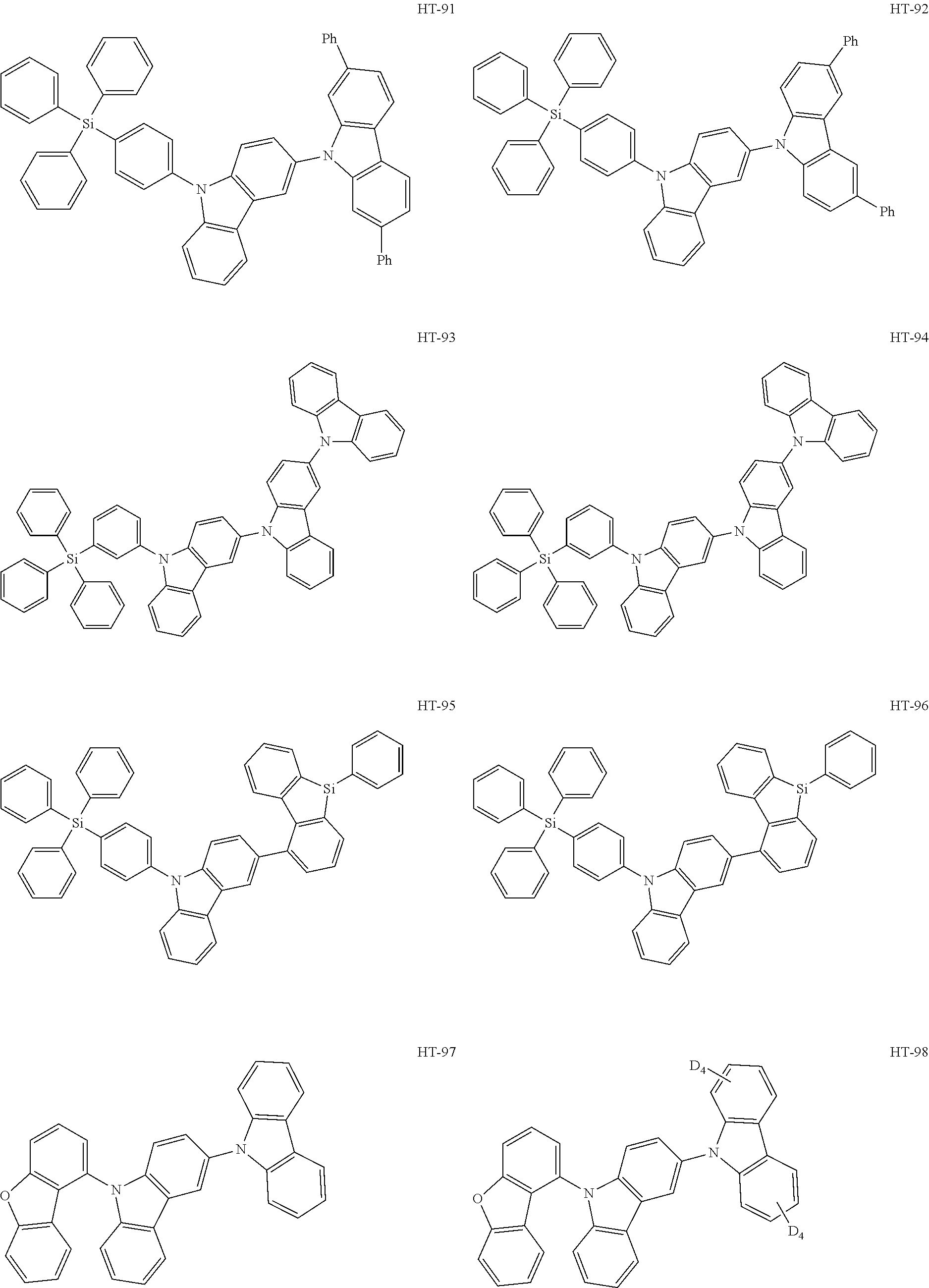

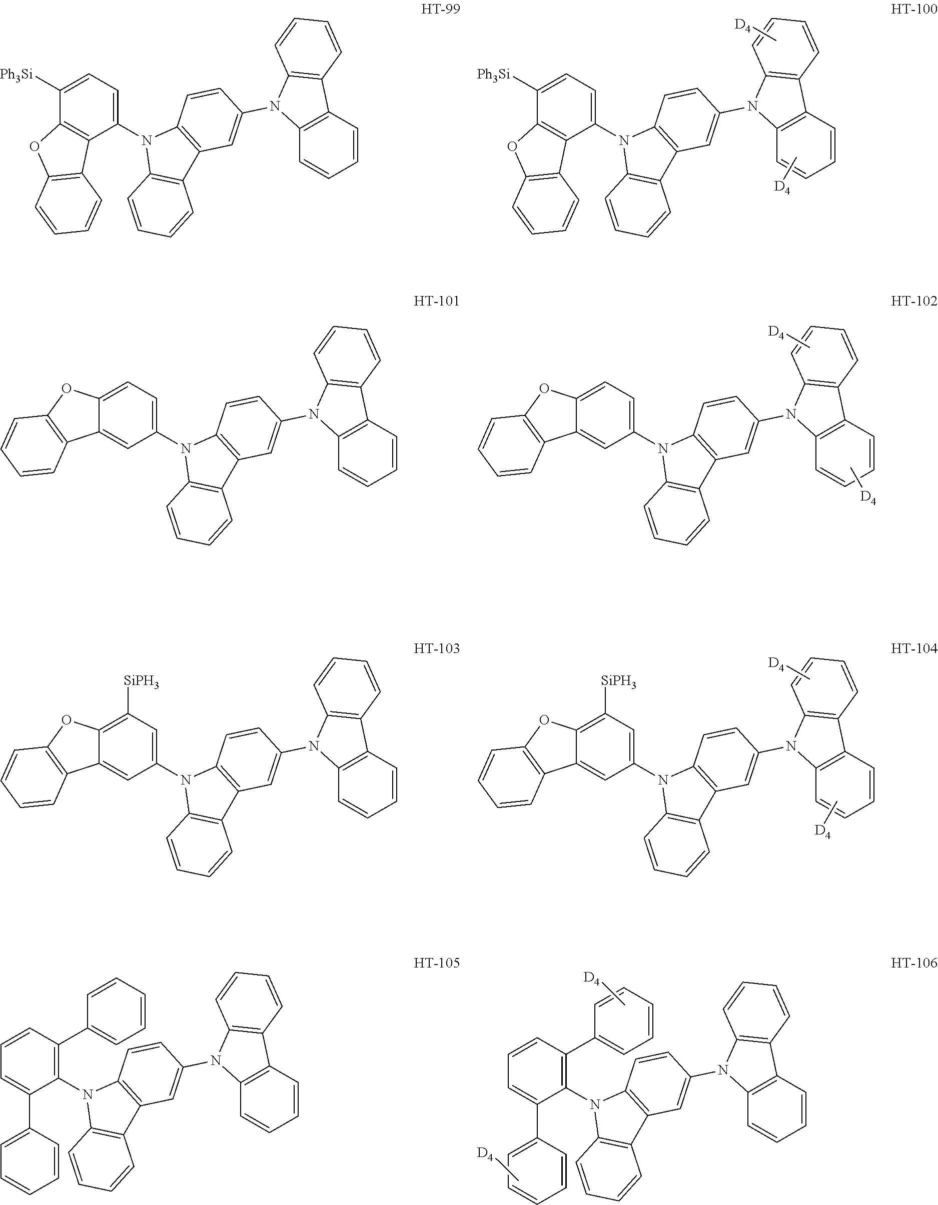

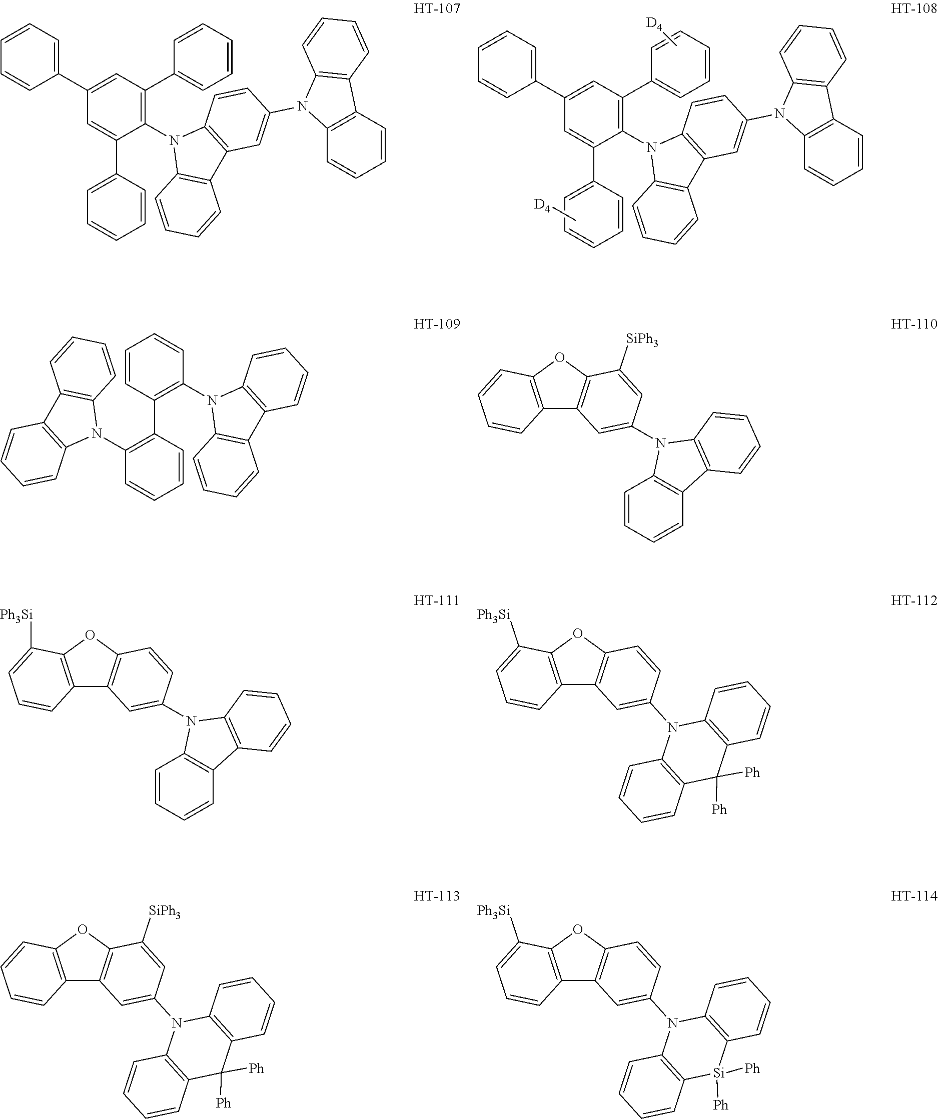

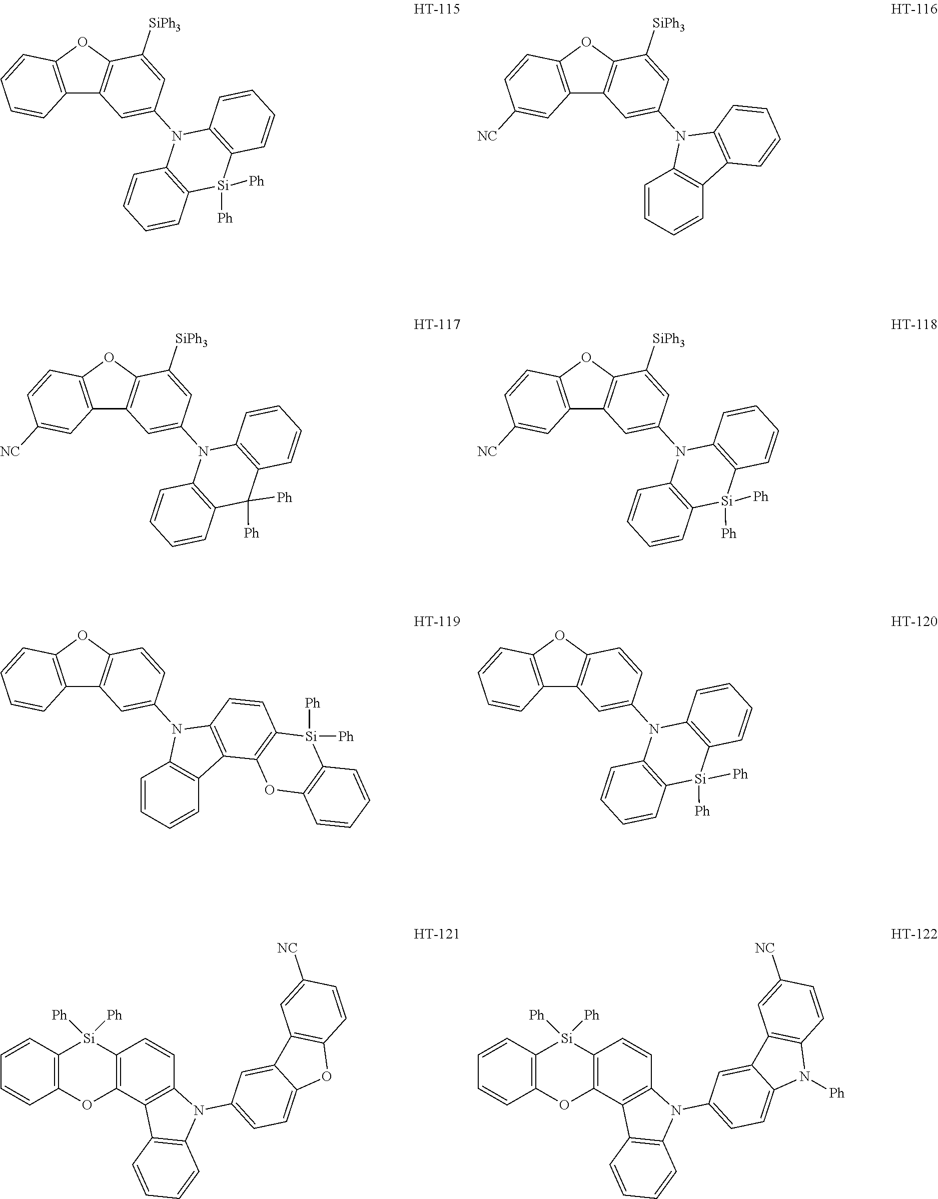

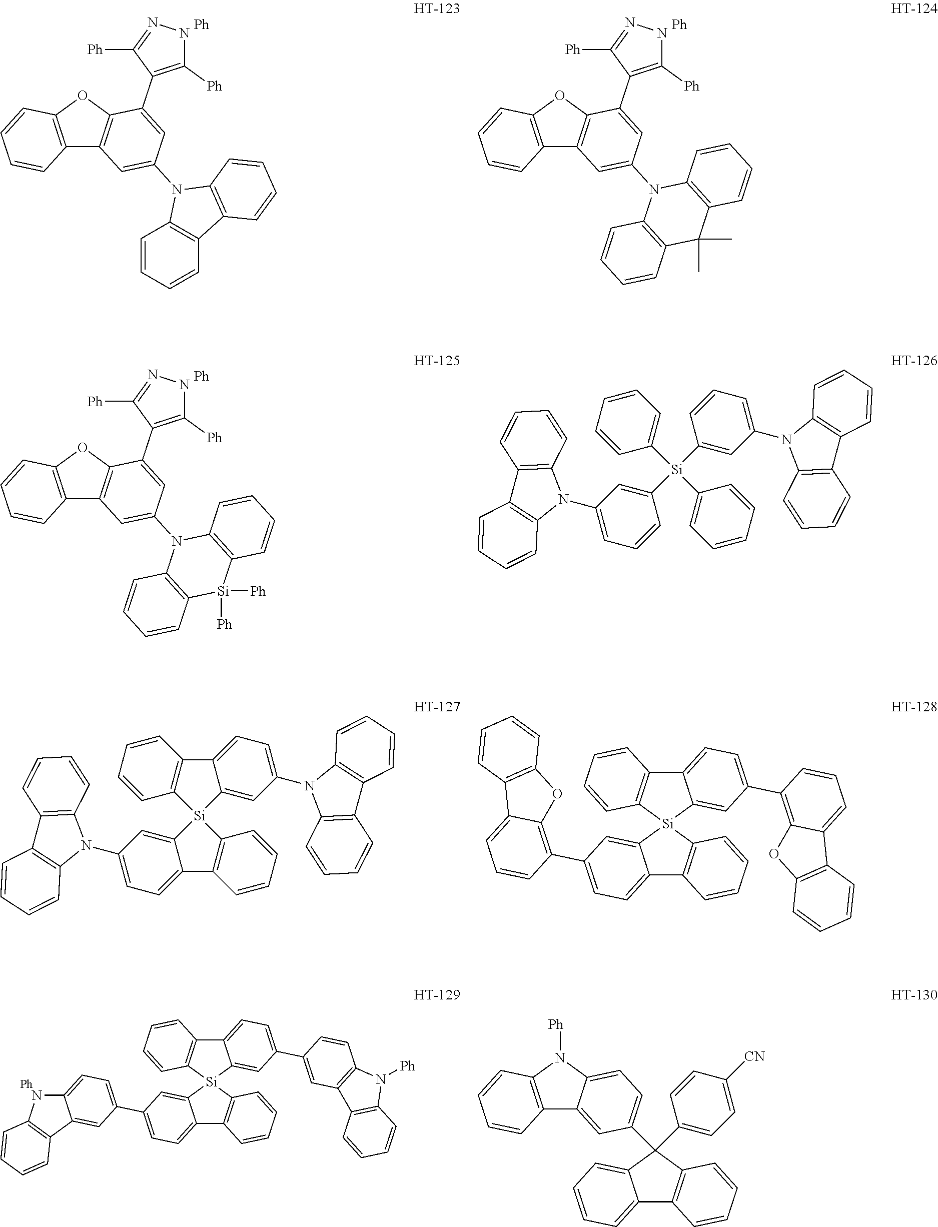

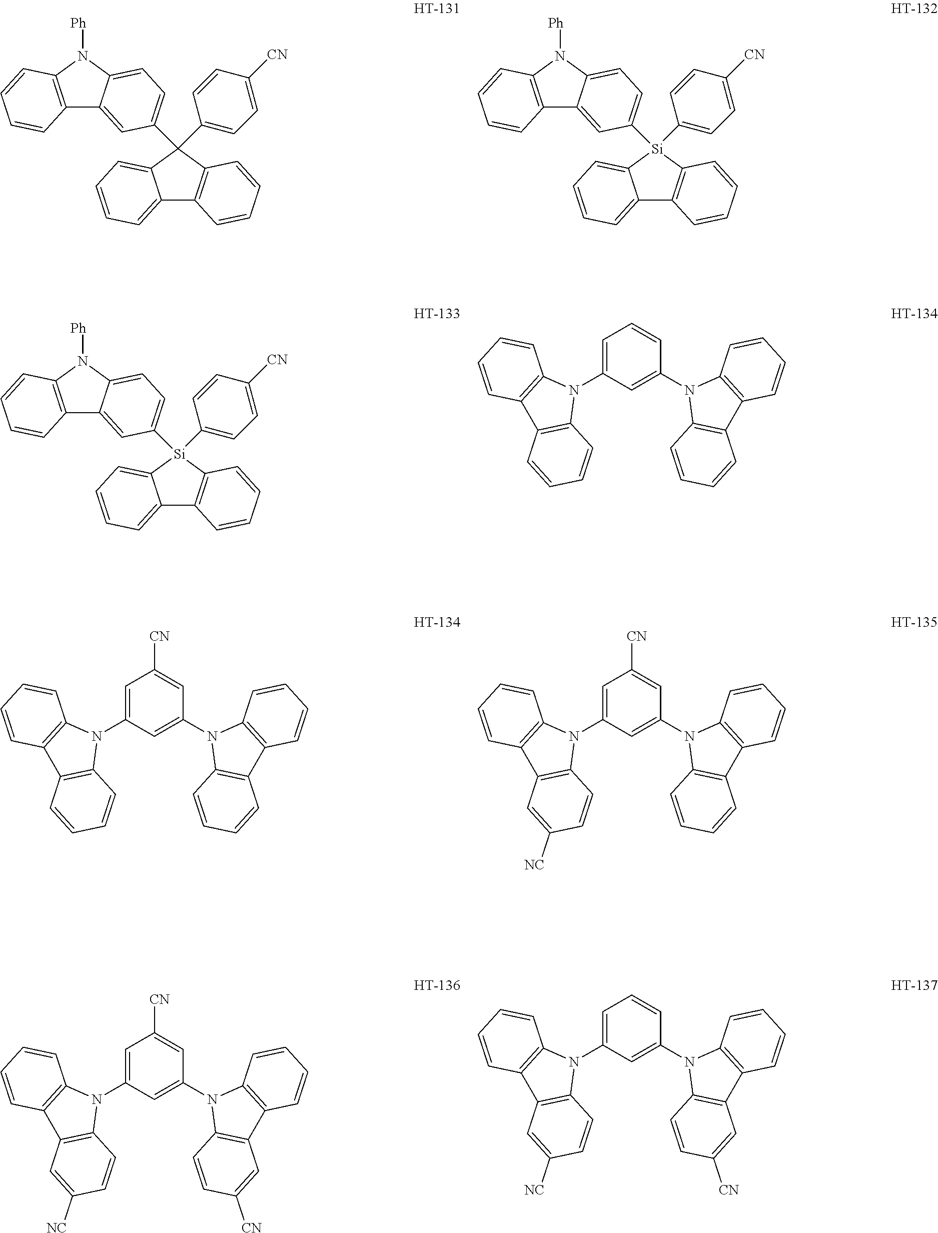

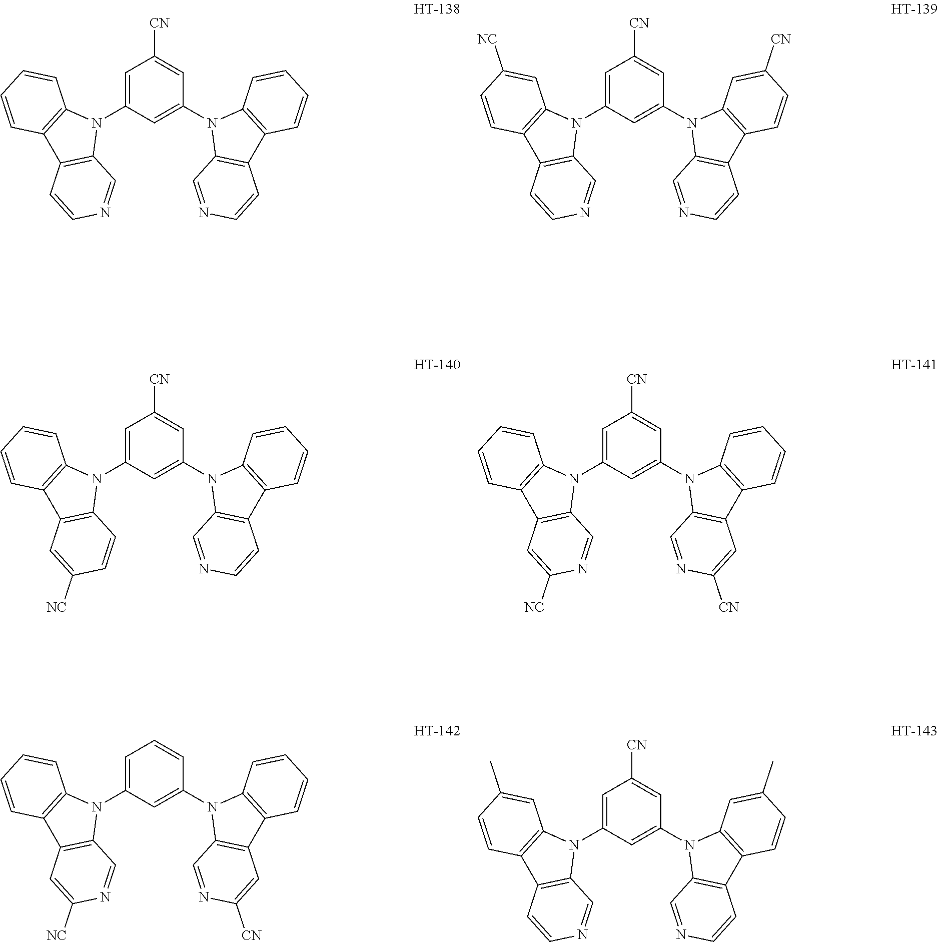 [SMILES: N#Cc1cc(-n2c3ccccc3c3ccncc32)cc(-n2c3ccccc3c3ccncc32)c1 ; N#Cc1cc(-n2c3cnccc3c3ccc(C#N)cc32)cc(-n2c3cnccc3c3ccc(C#N)cc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)c3)c2cn1 ; Cc1ccc2c3ccncc3n(-c3cc(C#N)cc(-n4c5cnccc5c5ccc(C)cc54)c3)c2c1]

In a preferred embodiment of the invention, the hole transport layer contained in the OLED device of the invention includes one or more p-type dopants. One or more of the following p-type dopant structures may be selected, but this does not mean that the present invention is limited to the following structures:

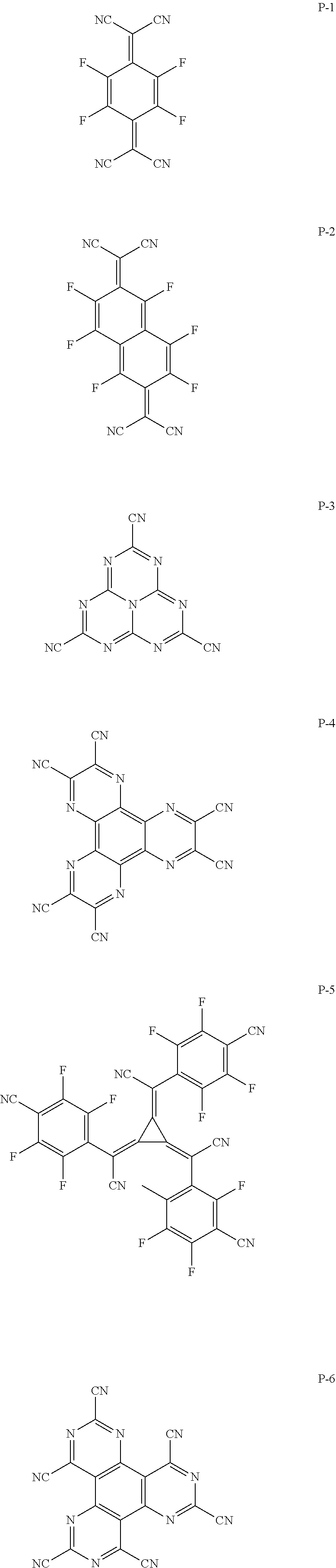 [SMILES: N#CC(C#N)=c1c(F)c(F)c(=C(C#N)C#N)c(F)c1F ; N#CC(C#N)=c1c(F)c(F)c2c(F)c(=C(C#N)C#N)c(F)c(F)c2c1F ; N#CC1=NC2=NC(C#N)=NC3=NC(C#N)=NC(=N1)N23 ; N#Cc1nc2c3nc(C#N)c(C#N)nc3c3nc(C#N)c(C#N)nc3c2nc1C#N ; Cc1c(F)c(F)c(C#N)c(F)c1/C(C#N)=C1/C(=C(/C#N)c2c(F)c(F)c(C#N)c(F)c2F)/C1=C(/C#N)c1c(F)c(F)c(C#N)c(F)c1F ; N#Cc1nc(C#N)c2c(n1)c1c(C#N)nc(C#N)nc1c1c(C#N)nc(C#N)nc21]

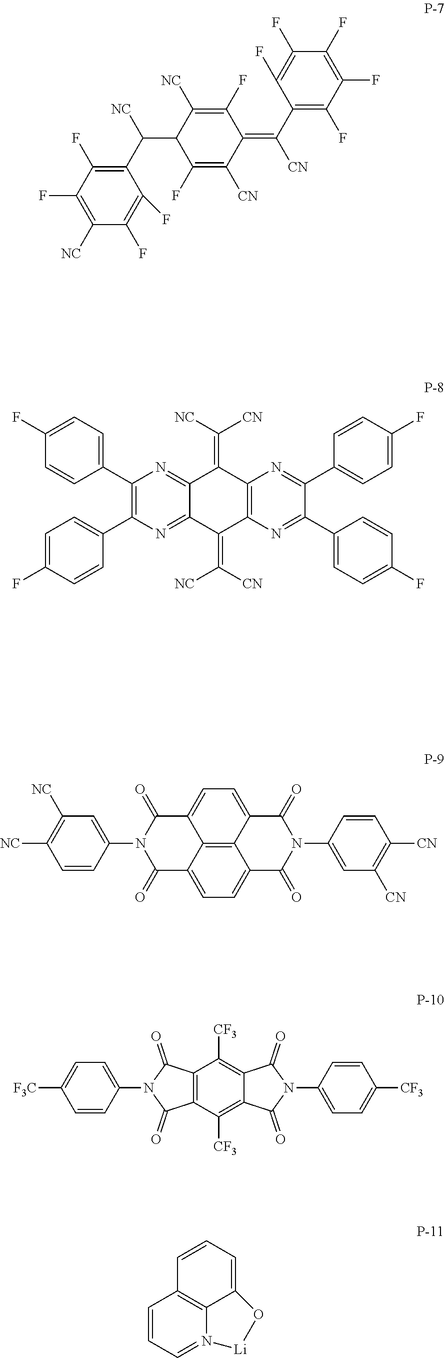

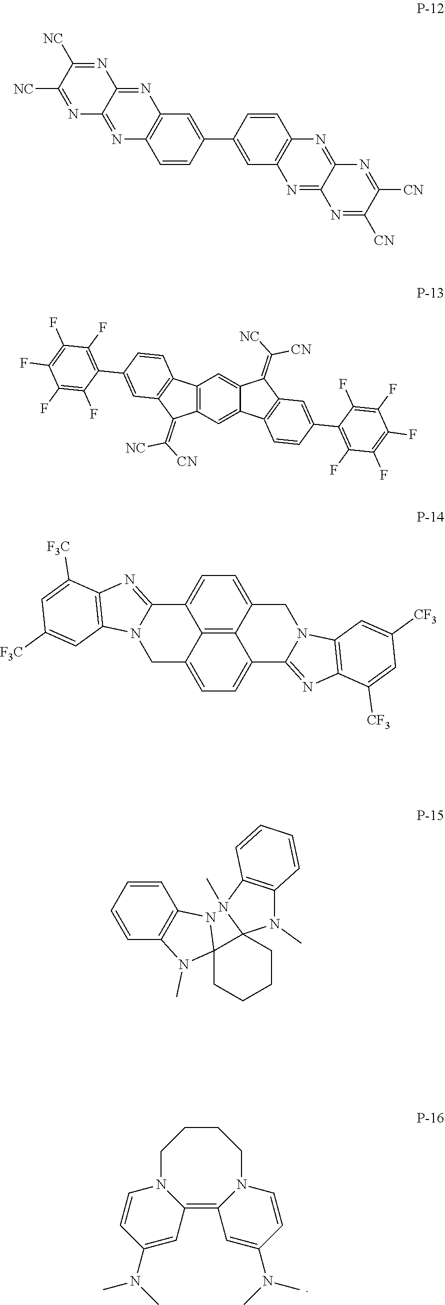

In a preferred embodiment of the invention, the electron transport layer may be selected from at least one of the compounds ET-1 to ET-77, but this does not mean that the present invention is limited to the following structures:

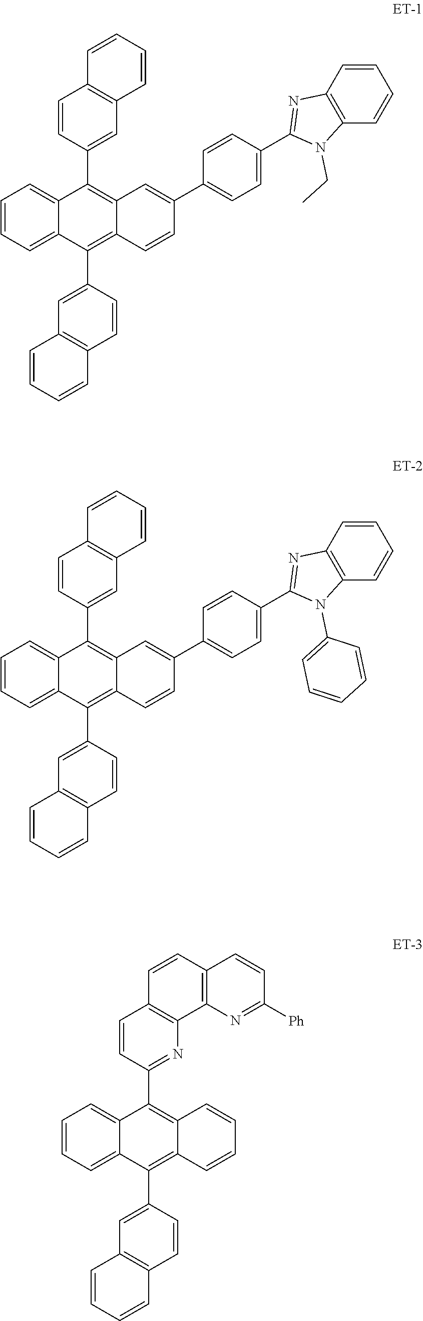 [SMILES: CCn1c(-c2ccc(-c3ccc4c(-c5ccc6ccccc6c5)c5ccccc5c(-c5ccc6ccccc6c5)c4c3)cc2)nc2ccccc21 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3ccc4ccc(-c5c6ccccc6c(-c6ccc7ccccc7c6)c6ccccc56)nc4c3n2)cc1]

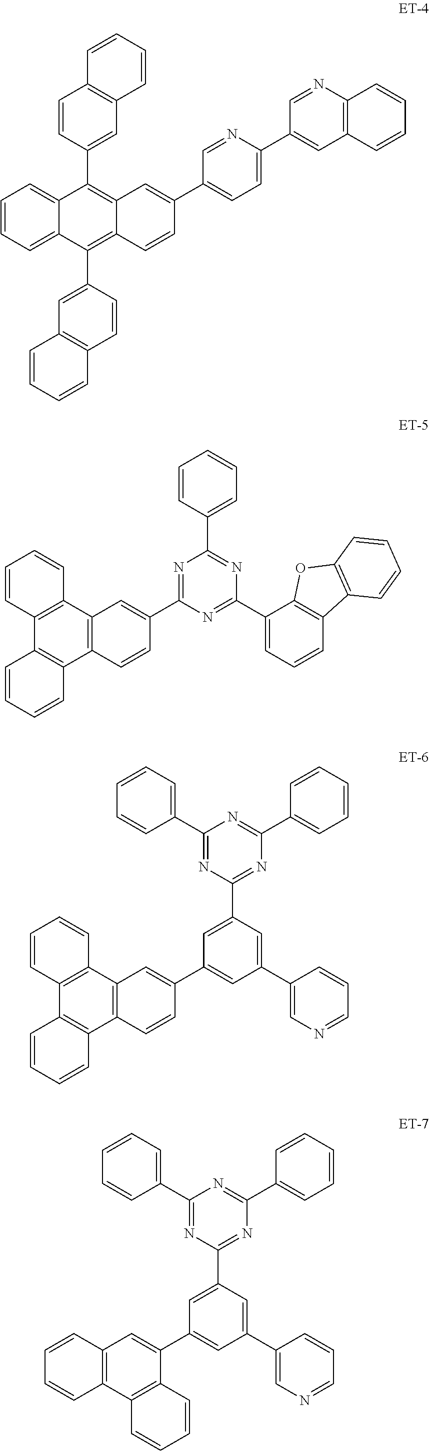 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2nc(-c3ccc4c5ccccc5c5ccccc5c4c3)nc(-c3cccc4c3oc3ccccc34)n2)cc1 ; c1ccc(-c2nc(-c3ccccc3)nc(-c3cc(-c4cccnc4)cc(-c4ccc5c6ccccc6c6ccccc6c5c4)c3)n2)cc1 ; c1ccc(-c2nc(-c3ccccc3)nc(-c3cc(-c4cccnc4)cc(-c4cc5ccccc5c5ccccc45)c3)n2)cc1]

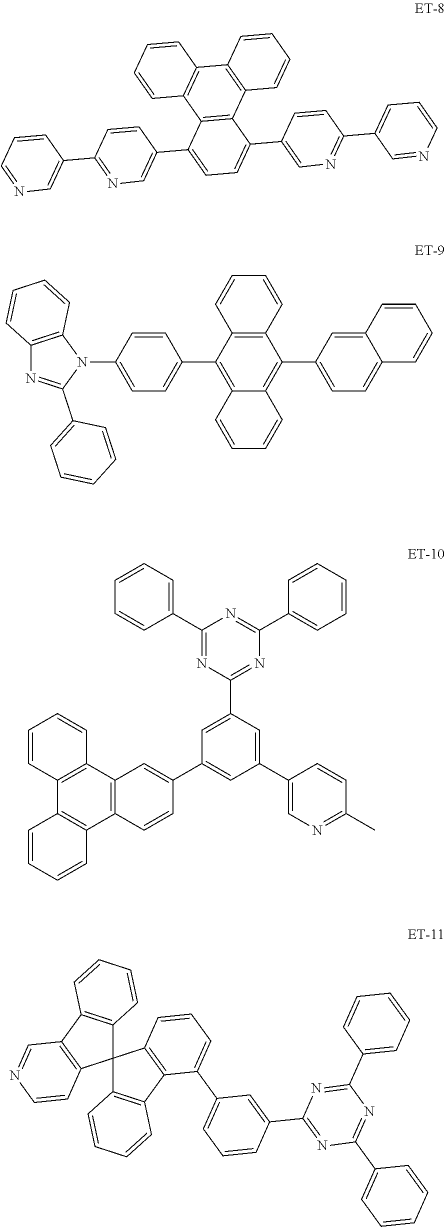 [SMILES: c1cncc(-c2ccc(-c3ccc(-c4ccc(-c5cccnc5)nc4)c4c5ccccc5c5ccccc5c34)cn2)c1 ; c1ccc(-c2nc3ccccc3n2-c2ccc(-c3c4ccccc4c(-c4ccc5ccccc5c4)c4ccccc34)cc2)cc1 ; Cc1ccc(-c2cc(-c3ccc4c5ccccc5c5ccccc5c4c3)cc(-c3nc(-c4ccccc4)nc(-c4ccccc4)n3)c2)cn1 ; c1ccc(-c2nc(-c3ccccc3)nc(-c3cccc(-c4cccc5c4-c4ccccc4C54c5ccccc5-c5cnccc54)c3)n2)cc1]

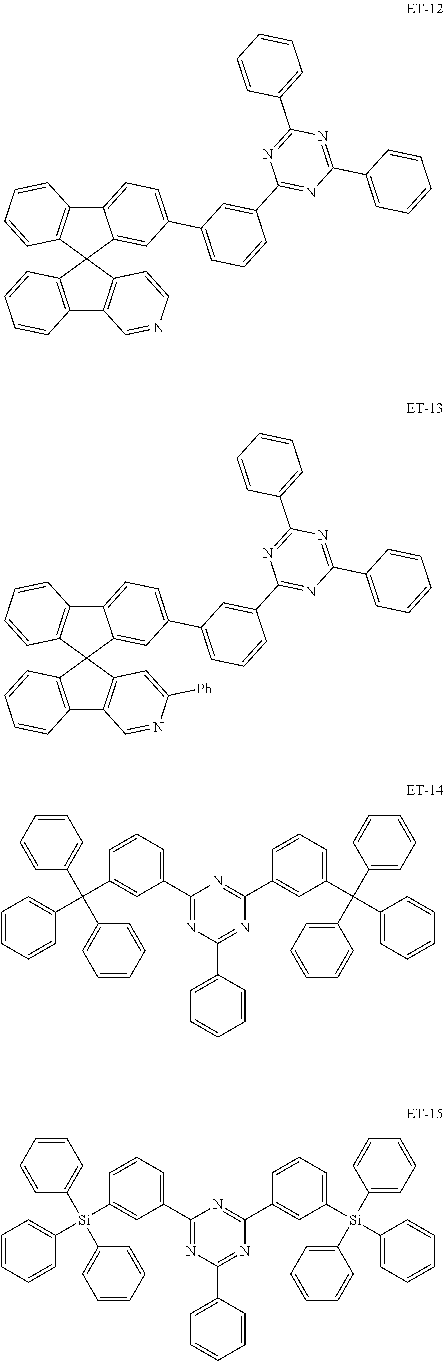 [SMILES: c1ccc(-c2nc(-c3ccccc3)nc(-c3cccc(-c4ccc5c(c4)C4(c6ccccc6-c6cnccc64)c4ccccc4-5)c3)n2)cc1 ; c1ccc(-c2cc3c(cn2)-c2ccccc2C32c3ccccc3-c3ccc(-c4cccc(-c5nc(-c6ccccc6)nc(-c6ccccc6)n5)c4)cc32)cc1 ; c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

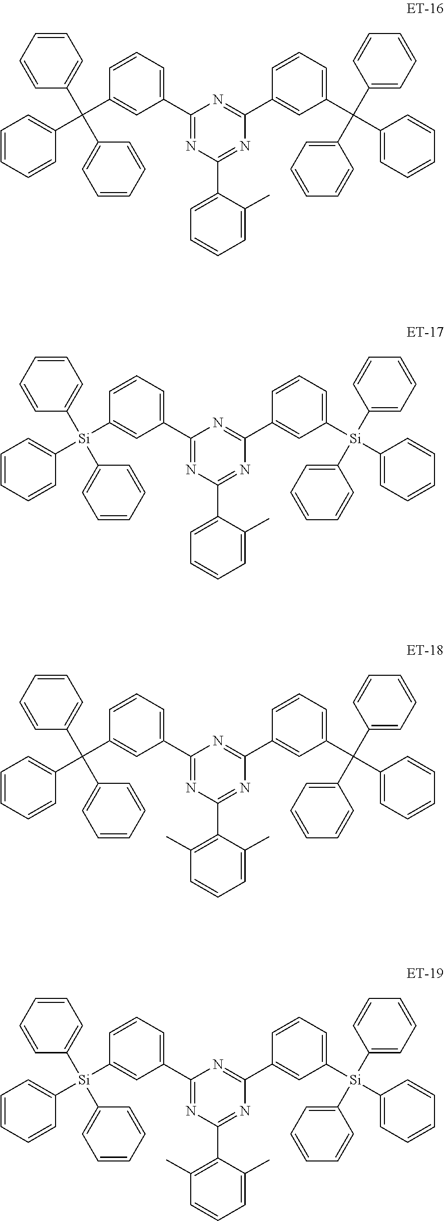 [SMILES: Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

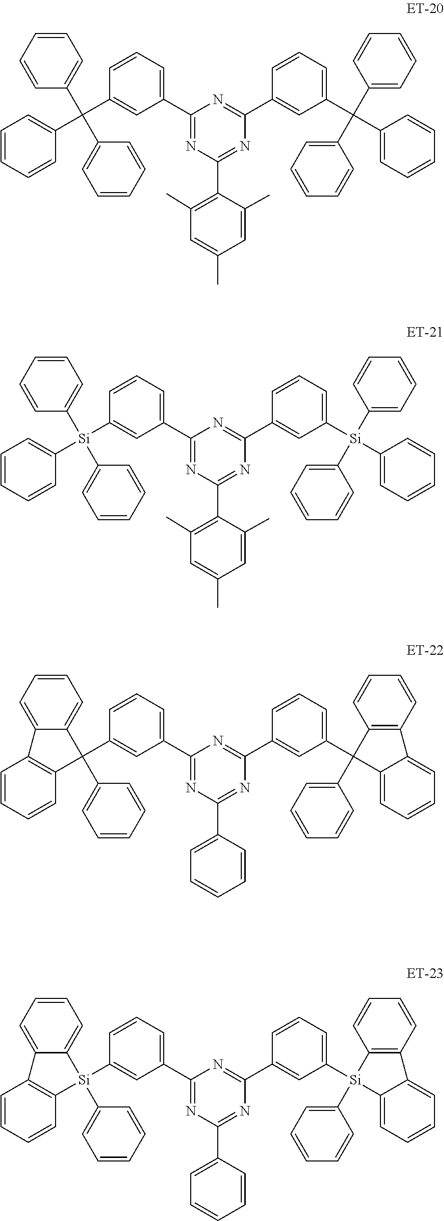 [SMILES: Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc(C4(c5ccccc5)c5ccccc5-c5ccccc54)c3)nc(-c3cccc(C4(c5ccccc5)c5ccccc5-c5ccccc54)c3)n2)cc1 ; c1ccc(-c2nc(-c3cccc([Si]4(c5ccccc5)c5ccccc5-c5ccccc54)c3)nc(-c3cccc([Si]4(c5ccccc5)c5ccccc5-c5ccccc54)c3)n2)cc1]

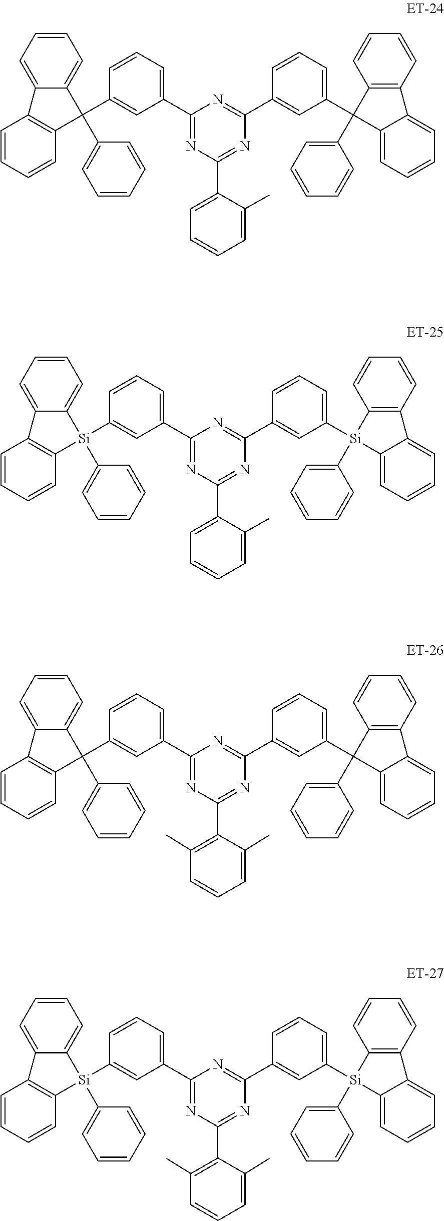 [SMILES: Cc1ccccc1-c1nc(-c2cccc(C3(c4ccccc4)c4ccccc4-c4ccccc43)c2)nc(-c2cccc(C3(c4ccccc4)c4ccccc4-c4ccccc43)c2)n1 ; Cc1ccccc1-c1nc(-c2cccc([Si]3(c4ccccc4)c4ccccc4-c4ccccc43)c2)nc(-c2cccc([Si]3(c4ccccc4)c4ccccc4-c4ccccc43)c2)n1 ; Cc1cccc(C)c1-c1nc(-c2cccc(C3(c4ccccc4)c4ccccc4-c4ccccc43)c2)nc(-c2cccc(C3(c4ccccc4)c4ccccc4-c4ccccc43)c2)n1 ; Cc1cccc(C)c1-c1nc(-c2cccc([Si]3(c4ccccc4)c4ccccc4-c4ccccc43)c2)nc(-c2cccc([Si]3(c4ccccc4)c4ccccc4-c4ccccc43)c2)n1]

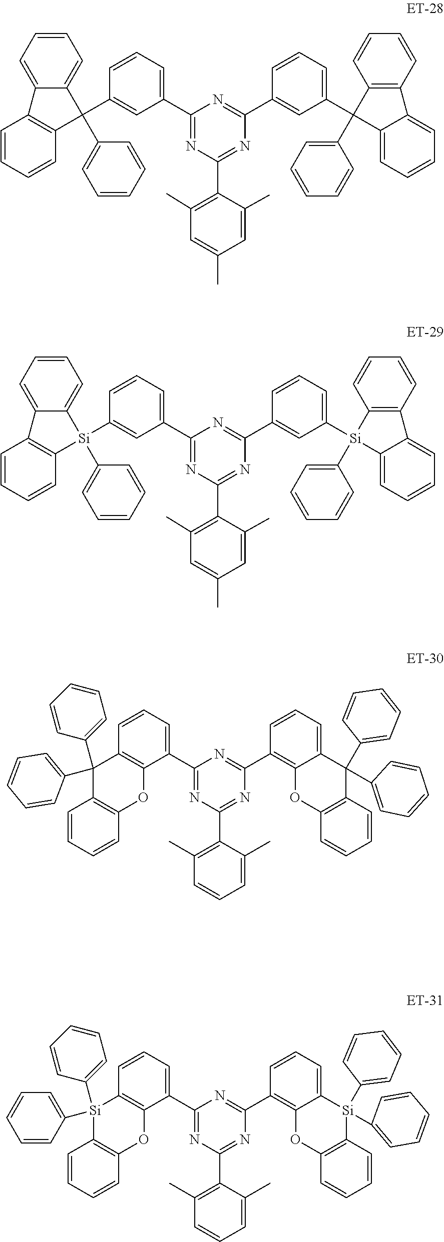 [SMILES: Cc1cc(C)c(-c2nc(-c3cccc(C4(c5ccccc5)c5ccccc5-c5ccccc54)c3)nc(-c3cccc(C4(c5ccccc5)c5ccccc5-c5ccccc54)c3)n2)c(C)c1 ; Cc1cc(C)c(-c2nc(-c3cccc([Si]4(c5ccccc5)c5ccccc5-c5ccccc54)c3)nc(-c3cccc([Si]4(c5ccccc5)c5ccccc5-c5ccccc54)c3)n2)c(C)c1 ; Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

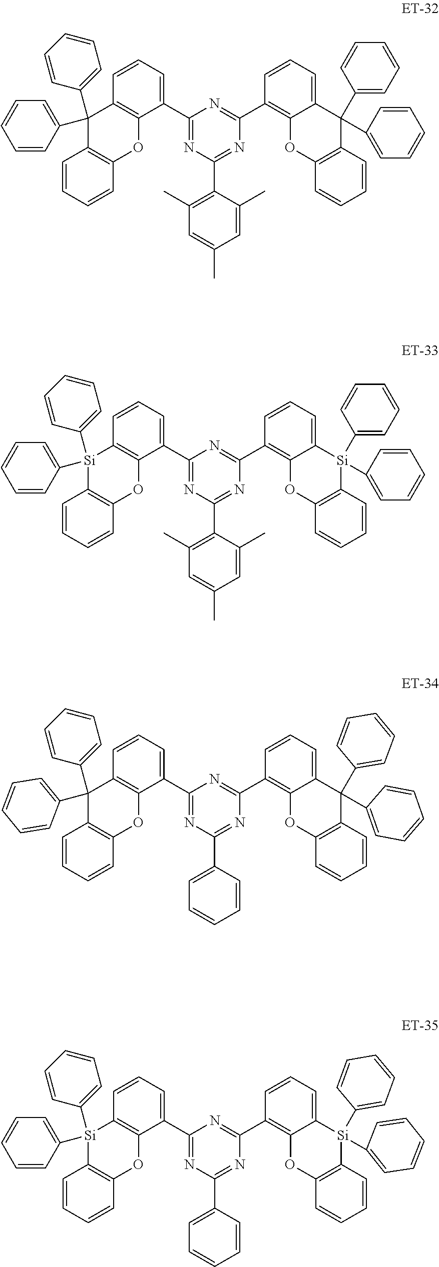 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1]

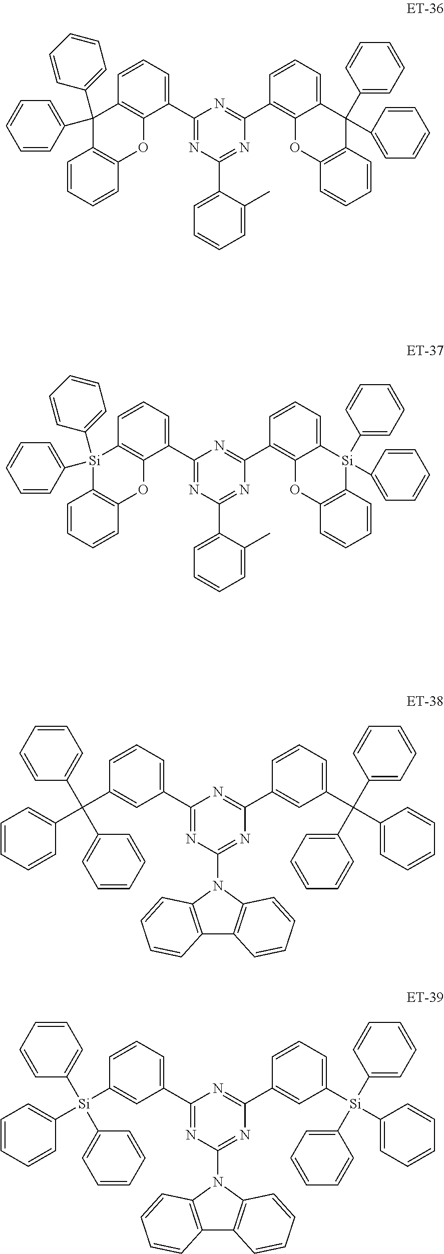 [SMILES: Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; c1ccc(C(c2ccccc2)(c2ccccc2)c2cccc(-c3nc(-c4cccc(C(c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1]

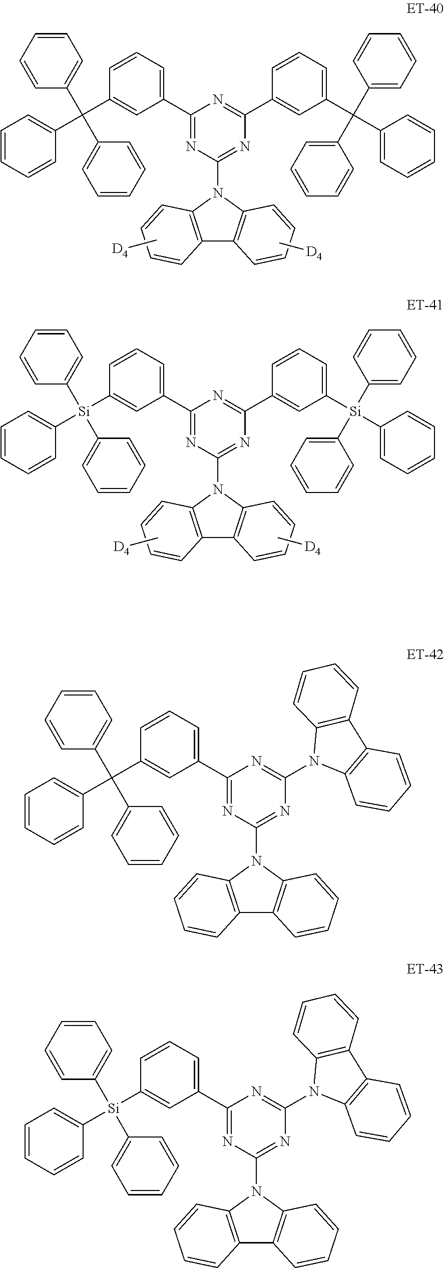

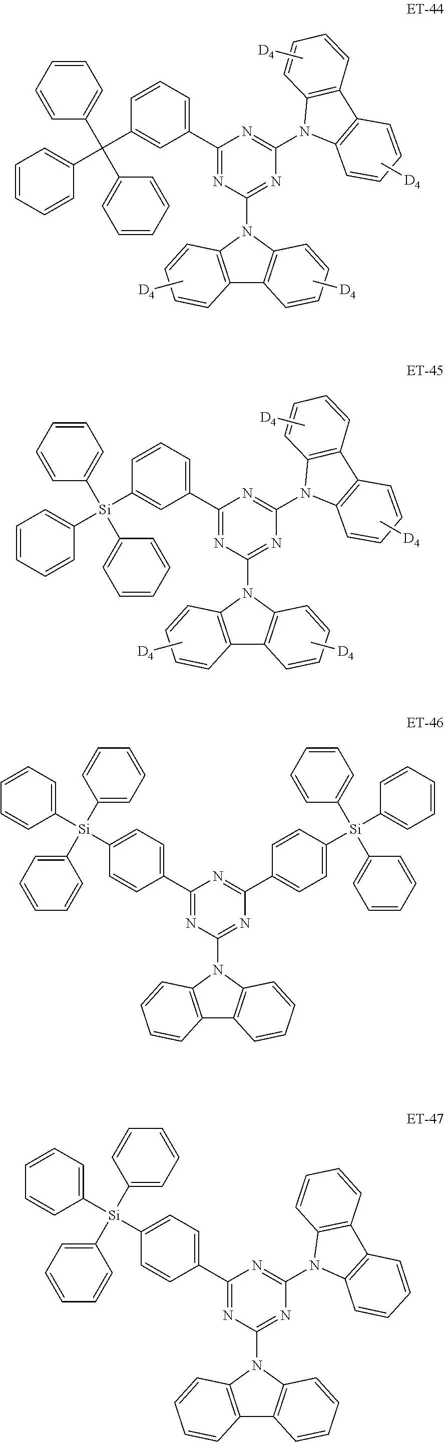

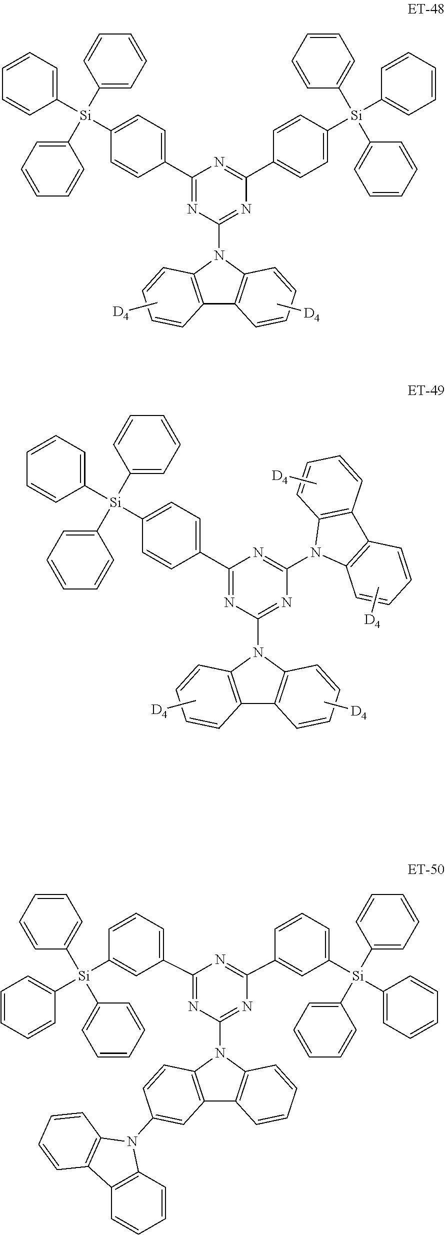

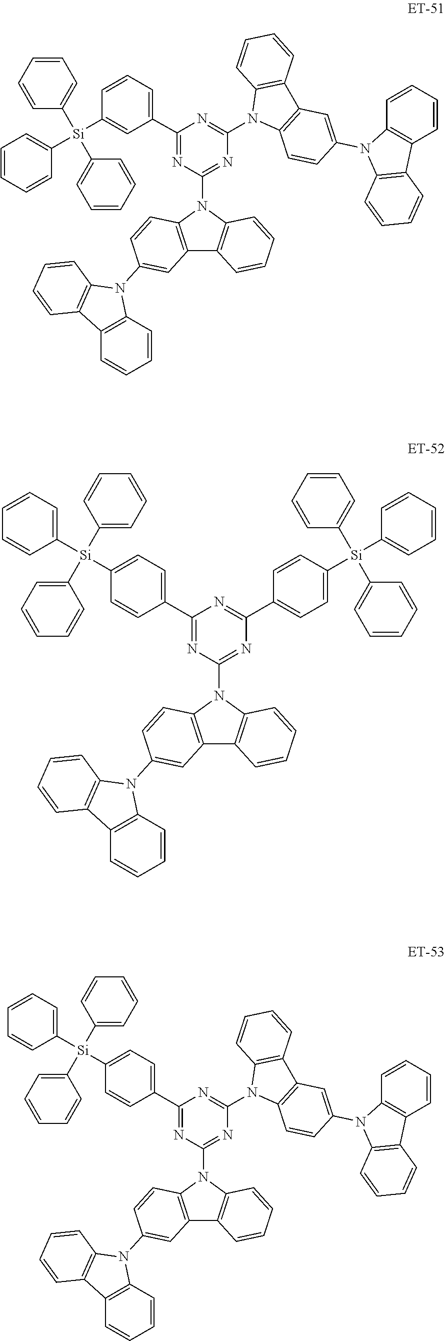 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

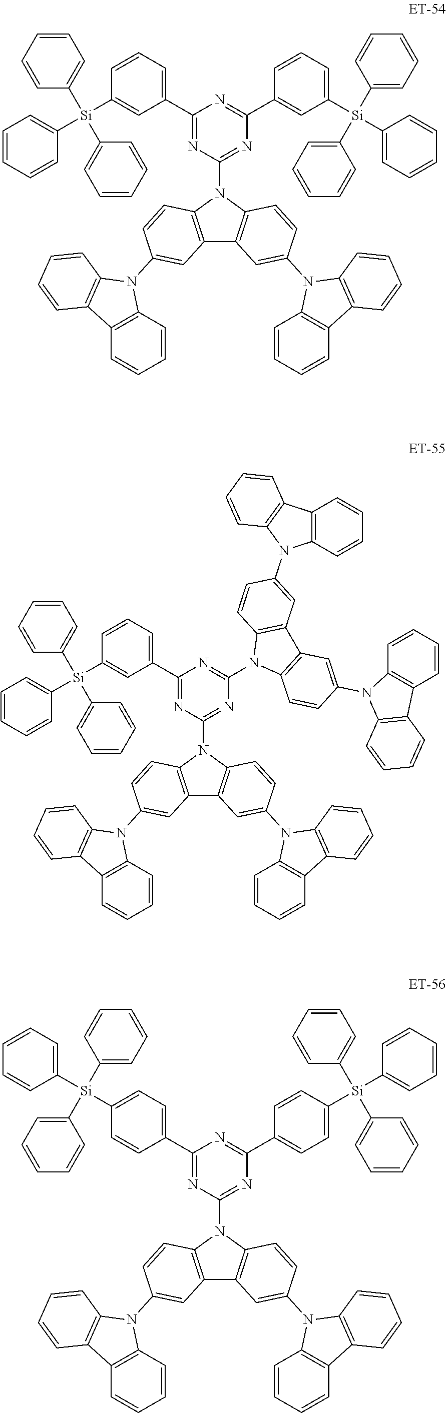

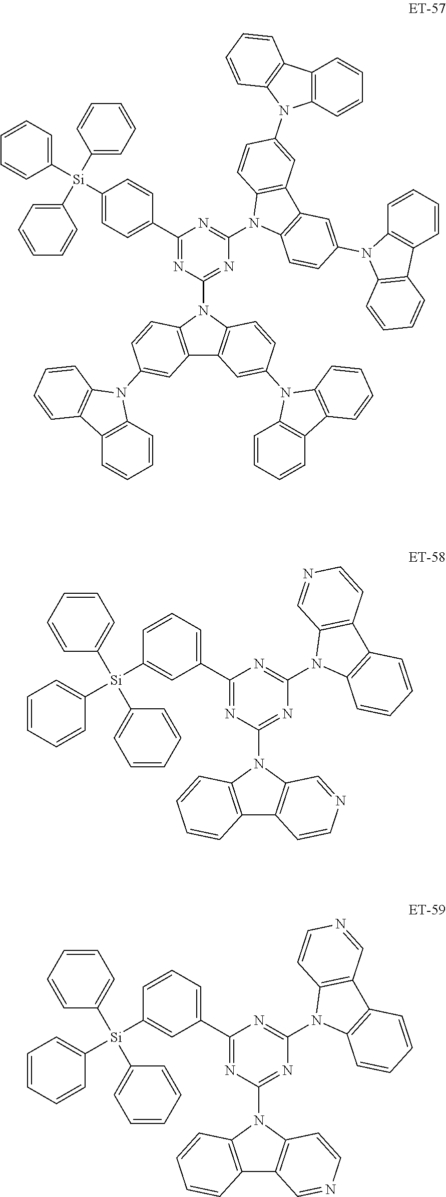 [SMILES: c1ccc([Si](c2ccccc2)(c2ccccc2)c2ccc(-c3nc(-n4c5ccc(-n6c7ccccc7c7ccccc76)cc5c5cc(-n6c7ccccc7c7ccccc76)ccc54)nc(-n4c5ccc(-n6c7ccccc7c7ccccc76)cc5c5cc(-n6c7ccccc7c7ccccc76)ccc54)n3)cc2)cc1 ; c1ccc([Si](c2ccccc2)(c2ccccc2)c2cccc(-c3nc(-n4c5ccccc5c5ccncc54)nc(-n4c5ccccc5c5ccncc54)n3)c2)cc1 ; c1ccc([Si](c2ccccc2)(c2ccccc2)c2cccc(-c3nc(-n4c5ccccc5c5cnccc54)nc(-n4c5ccccc5c5cnccc54)n3)c2)cc1]

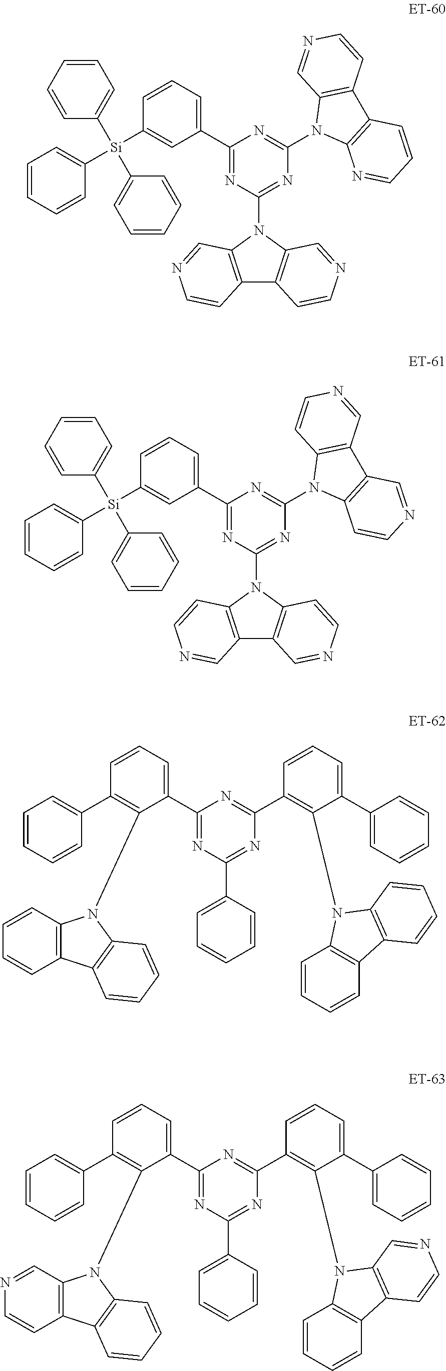 [SMILES: c1ccc([Si](c2ccccc2)(c2ccccc2)c2cccc(-c3nc(-n4c5cnccc5c5ccncc54)nc(-n4c5cnccc5c5cccnc54)n3)c2)cc1 ; c1ccc([Si](c2ccccc2)(c2ccccc2)c2cccc(-c3nc(-n4c5ccncc5c5cnccc54)nc(-n4c5ccncc5c5cnccc54)n3)c2)cc1 ; c1ccc(-c2nc(-c3cccc(-c4ccccc4)c3-n3c4ccccc4c4ccccc43)nc(-c3cccc(-c4ccccc4)c3-n3c4ccccc4c4ccccc43)n2)cc1 ; c1ccc(-c2nc(-c3cccc(-c4ccccc4)c3-n3c4ccccc4c4ccncc43)nc(-c3cccc(-c4ccccc4)c3-n3c4ccccc4c4ccncc43)n2)cc1]

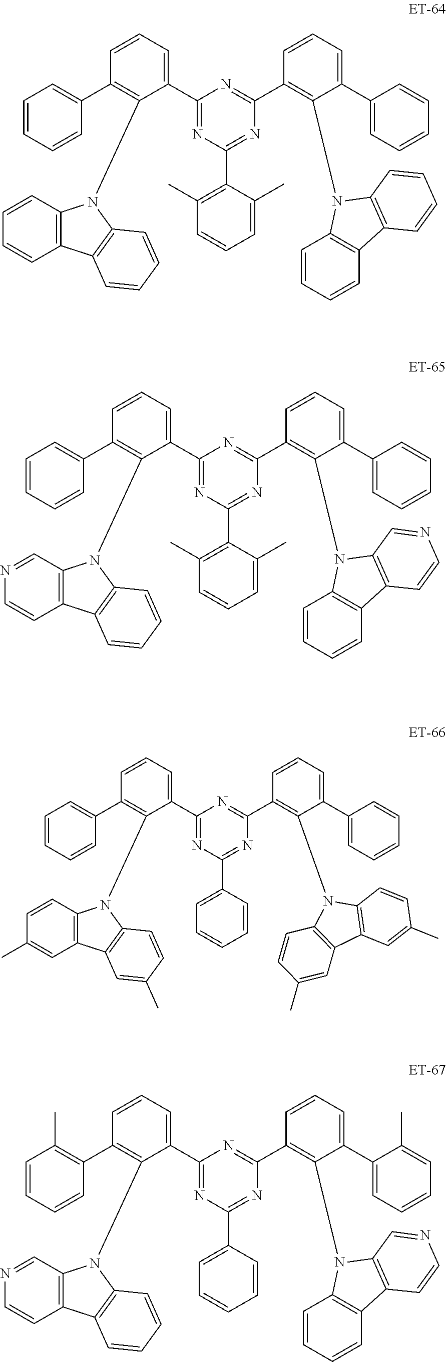

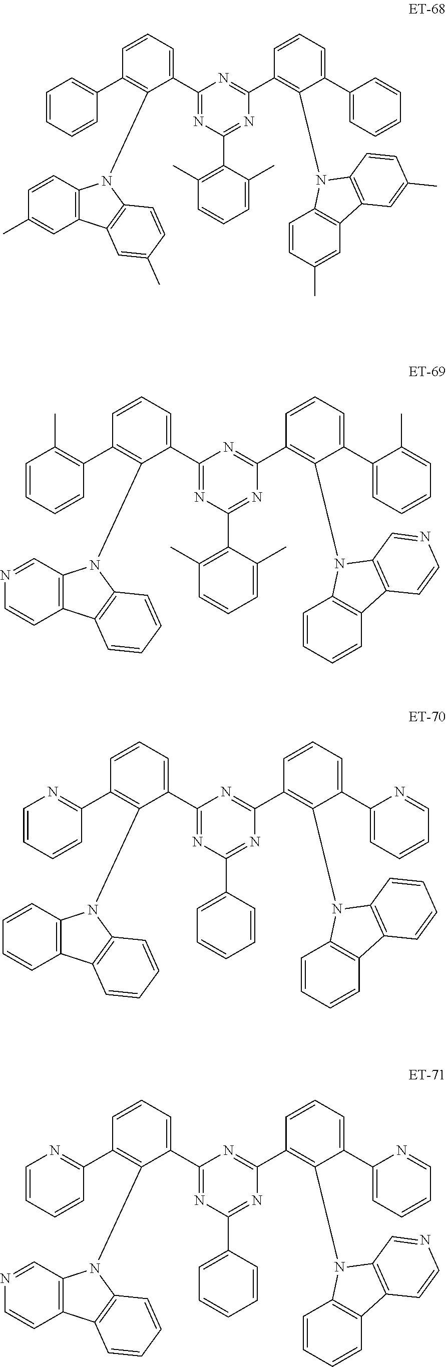

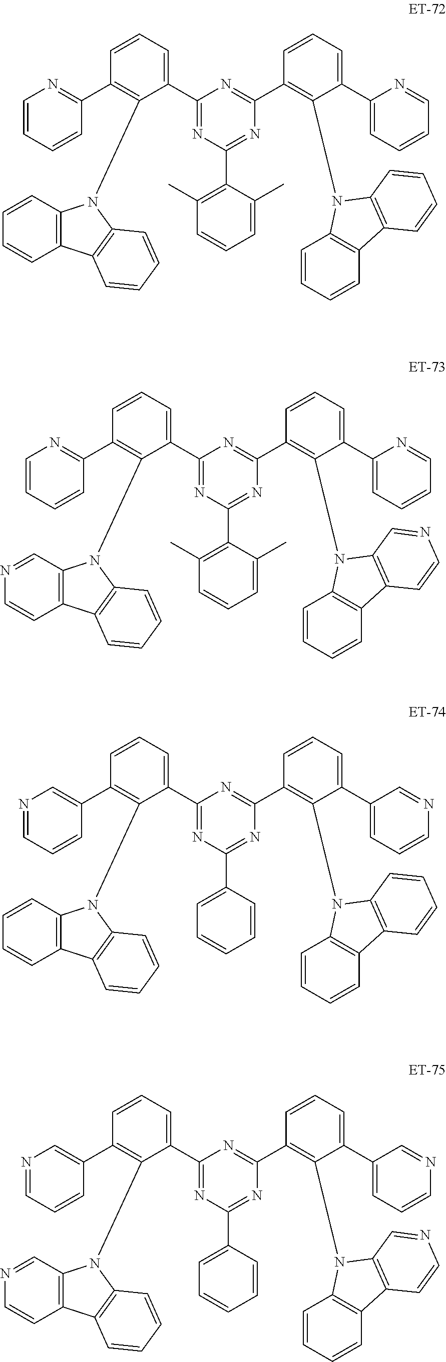 [SMILES: Cc1cccc(C)c1-c1nc(-c2cccc(-c3ccccn3)c2-n2c3ccccc3c3ccccc32)nc(-c2cccc(-c3ccccn3)c2-n2c3ccccc3c3ccccc32)n1 ; Cc1cccc(C)c1-c1nc(-c2cccc(-c3ccccn3)c2-n2c3ccccc3c3ccncc32)nc(-c2cccc(-c3ccccn3)c2-n2c3ccccc3c3ccncc32)n1 ; c1ccc(-c2nc(-c3cccc(-c4cccnc4)c3-n3c4ccccc4c4ccccc43)nc(-c3cccc(-c4cccnc4)c3-n3c4ccccc4c4ccccc43)n2)cc1 ; c1ccc(-c2nc(-c3cccc(-c4cccnc4)c3-n3c4ccccc4c4ccncc43)nc(-c3cccc(-c4cccnc4)c3-n3c4ccccc4c4ccncc43)n2)cc1]

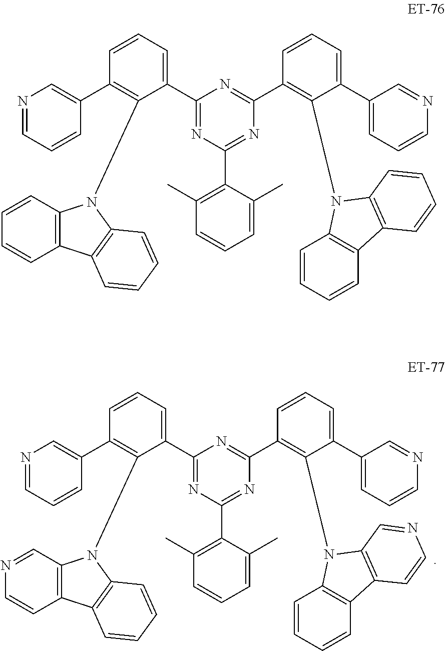 [SMILES: Cc1cccc(C)c1-c1nc(-c2cccc(-c3cccnc3)c2-n2c3ccccc3c3ccccc32)nc(-c2cccc(-c3cccnc3)c2-n2c3ccccc3c3ccccc32)n1 ; Cc1cccc(C)c1-c1nc(-c2cccc(-c3cccnc3)c2-n2c3ccccc3c3ccncc32)nc(-c2cccc(-c3cccnc3)c2-n2c3ccccc3c3ccncc32)n1]

The electron transport layer may be formed from an organic material together with one or more n-type dopants (e.g. LiQ, LiTHPh, etc.).

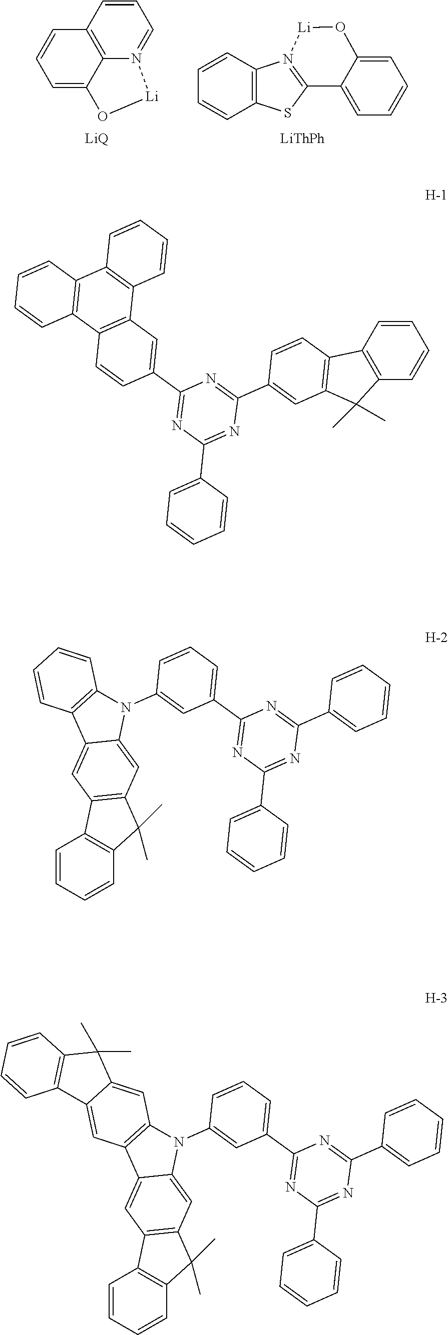

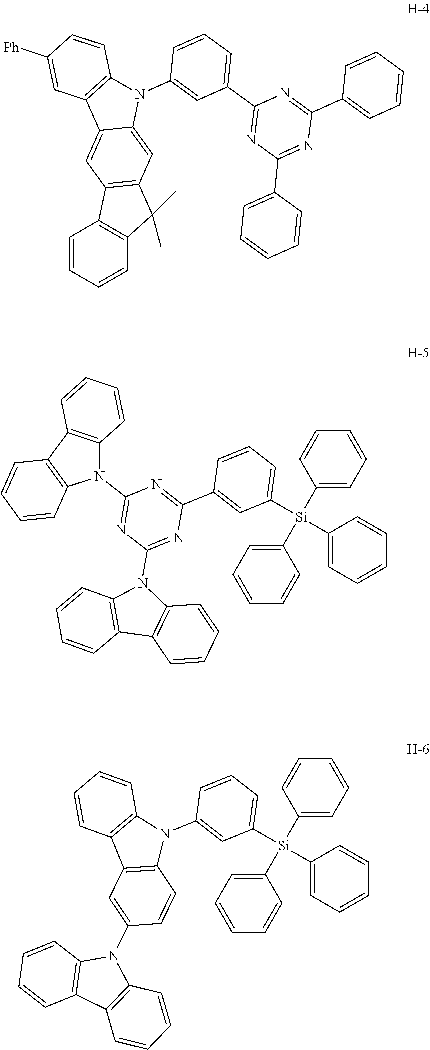 [SMILES: CC1(C)c2ccccc2-c2cc3c4cc(-c5ccccc5)ccc4n(-c4cccc(-c5nc(-c6ccccc6)nc(-c6ccccc6)n5)c4)c3cc21 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-n3c4ccccc4c4cc(-n5c6ccccc6c6ccccc65)ccc43)c2)cc1]

As a reference fabrication method for an OLED device example, the method includes: evaporating a p-doped material on the surface or an anode of an ITO glass with a light-emitting area of 2 mm×2 mm or co-evaporating the p-doped material with a hole injection material at a concentration of 1%-50% to form a hole injection layer (HIL) of 5-100 nm, a hole transport layer (HTL) of 5-200 nm, then forming a light-emitting layer (EML) of 10-100 nm (which may contain the compound described in the present invention) on the hole transport layer, and forming an electron transport layer (ETL) of 20-200 nm and a cathode of 50-200 nm. If necessary, an electron blocking layer (EBL) is added between the HTL and EML layers, and an electron injecting layer (EIL) is added between the ETL and the cathode to fabricate an OLED device. The OLED was tested by standard methods. The device materials referred to in the present invention may be obtained by known synthetic methods unless otherwise specified.

In a preferred embodiment, the structure of Device Example 1 provided by the present invention is ITO/P-4 (10 nm)/NPD (60 nm)/HT-85 (5 nm)/Pt1: H-2 (25 nm)(mass ration of Pt1: H-2 is 10:90)/ET-8 (5 nm)/ET-14 or BPyTP (40 nm)/LiQ (1 nm)/A1 (100 nm).

Device Examples 2-33 and Comparative Example 1 were prepared using a structure similar to Device Example 1, except that Pt1 in Device Example 1 was replaced with Pt2, Pt3, Pt4, Pt16, Pt21, Pt62, Pt74, Pt103, Pt118, Pt128, Pt140, Pt157, Pt171, Pt190, Pt224, Pt263, Pt276, Pt319, Pt345, Pt395, Pt410, Pt442, Pt486, Pt508, Pt513, Pt514, Pt515, Pt516, Pt517, Pt518, Pt519, Pt520, and R1, respectively. The comparative example and each device example prepared above were tested for luminescent characteristics by standard methods, and the data are shown in Table 2. The structural formulas of the devices involved are as follows:

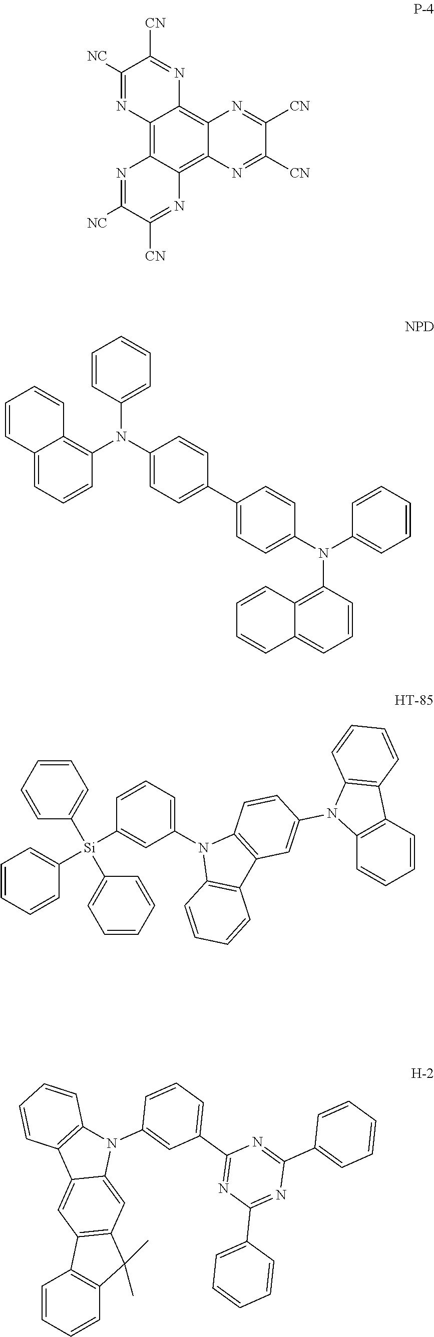

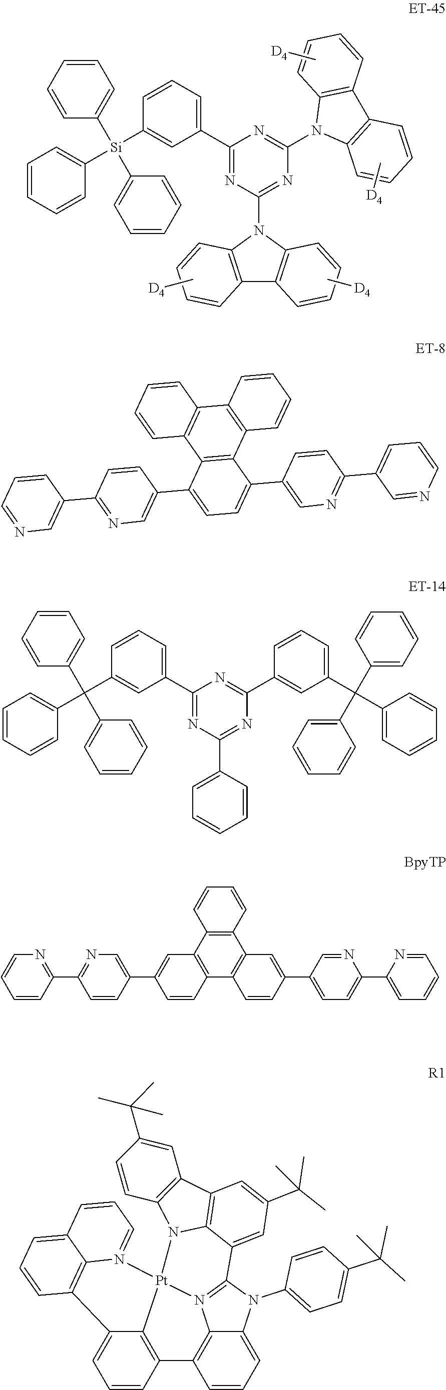

TABLE 2
Device Properties of Some Phosphorescent Materials

| | Metal | Start-up | External quantum |
|---|---|---|---|
| | complex | Voltage (V) | efficiency EQE (%) |
| Device 1 | Pt1 | 3.1 | 20 |
| Device 2 | Pt2 | 3.2 | 18 |
| Device 3 | Pt3 | 3.1 | 20 |
| Device 4 | Pt4 | 3.2 | 21 |
| Device Example 5 | Pt16 | 3.1 | 20 |
| Device Example 6 | Pt21 | 3.1 | 20 |
| Device Example 7 | Pt62 | 3.1 | 20 |
| Device Example 8 | Pt74 | 3.1 | 20 |
| Device Example 9 | Pt103 | 3.1 | 20 |
| Device Example 10 | Pt118 | 3.1 | 21 |
| Device Example 11 | Pt128 | 3.2 | 19 |
| Device Example 12 | Pt140 | 3.2 | 20 |
| Device Example 13 | Pt157 | 3.1 | 20 |
| Device Example 14 | Pt171 | 3.2 | 18 |
| Device Example 15 | Pt190 | 3.1 | 19 |
| Device Example 16 | Pt224 | 3.1 | 20 |
| Device Example 17 | Pt263 | 3.1 | 20 |
| Device Example 18 | Pt276 | 3.1 | 20 |
| Device Example 19 | Pt319 | 3.1 | 22 |
| Device Example 20 | Pt345 | 3.1 | 21 |
| Device Example 21 | Pt395 | 3.1 | 21 |
| Device Example 22 | Pt410 | 3.2 | 20 |
| Device Example 23 | Pt442 | 3.1 | 19 |
| Device Example 24 | Pt486 | 3.2 | 22 |
| Device Example 25 | Pt508 | 3.2 | 22 |
| Device Example 26 | Pt513 | 3.1 | 20 |
| Device Example 27 | Pt514 | 3.1 | 20 |
| Device Example 28 | Pt515 | 3.1 | 20 |
| Device Example 29 | Pt516 | 3.2 | 20 |
| Device Example 30 | Pt517 | 3.1 | 21 |
| Device Example 31 | Pt518 | 3.2 | 21 |
| Device Example 32 | Pt519 | 3.1 | 21 |
| Device Example 33 | Pt520 | 3.1 | 21 |
| Comparative Example 1 | R1 | 3.3 | 4 |

As can be seen from Table 2, Device examples 1 to 33 prepared in the present application all have a lower start-up voltage and a higher external quantum efficiency compared with the comparative example 1, indicating that the cyclic tetradentate metal platinum complex phosphorescent material provided in the present invention has a certain commercial application value.

It will be understood by those skilled in the art that the embodiments described above are specific examples for practicing the invention, and that various changes in form and details may be made therein without departing from the spirit and scope of the invention. For example, many of the substituent structures described herein can be replaced with other structures without departing from the spirit of the invention.

What is claimed is:

1. A cyclic tetradentate metal platinum complex phosphorescent material having a general structure represented by formula (I), 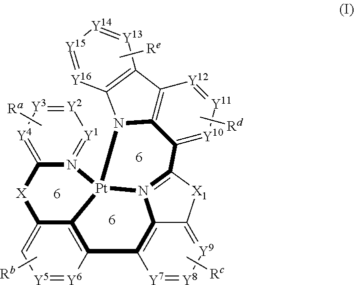
where, X is CR₁R₂ or NR₃; X₁ is selected from NR₄, O or S; each of R₁-R₄ is independently selected from hydrogen, halogen, substituted or unsubstituted C1-C30 alkyl, substituted or unsubstituted C1-C30 cycloalkyl, substituted or unsubstituted C1-C30 heterocycloalkyl, substituted or unsubstituted C1-C30 cycloalkyl, substituted or unsubstituted C6-C60 aryl, substituted or unsubstituted C6-C18 arylamine, substituted or unsubstituted C6-C18 heterocycloamine, and combination thereof;
Y¹-Y¹⁶ are each independently selected from C or N;
R^{a}, R^{b}, R^{c}, R^{d} and R^{e} each independently represent mono-to maximum substitution, or no substitution, and are each independently selected from hydrogen, halogen, substituted or unsubstituted C1-C30 alkyl, substituted or unsubstituted C1-C30 cycloalkyl, substituted or unsubstituted C1-C30 heterocycloalkyl, substituted or unsubstituted C1-C30 cycloalkyl, substituted or unsubstituted C6-C60 aryl, substituted or unsubstituted C6-C60 heteroaryl, and combination thereof;
at least one hydrogen in R₁-R₄, R^{a}, R^{b}, R^{c}, R^{d} and R^{e} is substitutable by deuterium; the substituent in the “substituted or unsubstituted” radical is selected from one or more of deuterium, halogen, methyl, ethyl, propyl, isopropyl, butyl, t-butyl, pentyl, phenyl; in case of substituted by multiple substituents, the multiple substituents are the same or different from each other; when containing a heteroatom, the heteroatom is selected from O or N; the two or more adjacent substituents of R₁-R₄, R^{a}, R^{b}, R^{c}, R^{d} and R^{e} are independently or optionally linkable to form a fused ring.

2. The cyclic tetradentate metal platinum complex phosphorescent material according to claim 1, having a general structure according to Formula (I-1) or Formula (I-2): 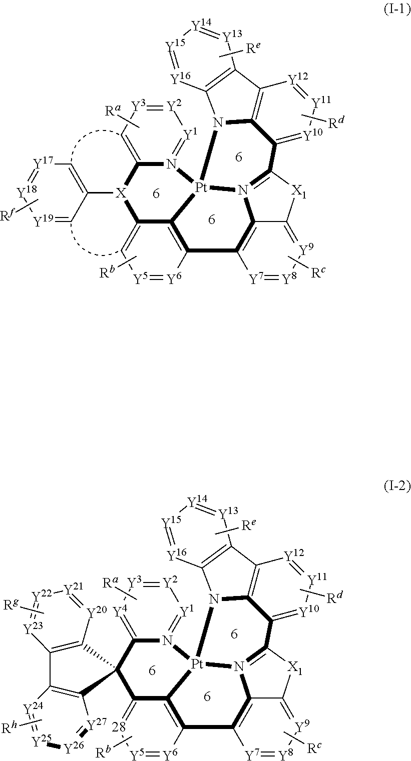
where Y¹⁷-Y²⁷ are each independently selected from C or N;
R^{f}, R^{g} and R^{h} each independently represent mono-to maximum substitution, or no substitution, and are each independently selected from hydrogen, halogen, substituted or unsubstituted C1-C30 alkyl, C1-C30 haloalkyl, substituted or unsubstituted C1-C30 cycloalkyl, substituted or unsubstituted C1-C30 heterocycloalkyl, substituted or unsubstituted C6-C60 aryl, substituted or unsubstituted C6-C60 heteroaryl, and combination thereof.

3. The cyclic tetradentate metal platinum complex phosphorescent material according to claim 1, wherein R₄ is selected from hydrogen, deuterium, F, methyl, ethyl, propyl, t-butyl, phenyl, biphenyl, methylbenzene, t-butylphenyl, benzofuranyl, pyridyl, and combination thereof.

4. The cyclic tetradentate metal platinum complex phosphorescent material according to claim 1, wherein R^{a}, R^{b}, R^{c}, R^{d} and R^{e} are each independently selected from hydrogen, deuterium, F, methyl, ethyl, propyl, isopropyl, n-butyl, isobutyl, sec-butyl, t-butyl, 2-methylbutyl, phenyl, furyl, benzofuranyl, pyridyl, and combination thereof.

5. The cyclic tetradentate metal platinum complex phosphorescent material according to claim 2, wherein R^{f}, R^{g} and R^{h} are each independently selected from hydrogen, deuterium, F, methyl, ethyl, propyl, isopropyl, n-butyl, isobutyl, sec-butyl, t-butyl, 2-methylbutyl, phenyl, furyl, benzofuranyl, pyridyl, and combination thereof.

6. The cyclic tetradentate metal platinum complex phosphorescent material according to claim 2, wherein R^{g} and R^{h} are each independently selected from hydrogen, methyl, t-butyl, t-butylbenzene, and combination thereof.

7. The cyclic tetradentate metal platinum complex phosphorescent material according to claim 1, wherein the cyclic tetradentate metal platinum complex phosphorescent material is selected from any one of the following structural formulae:

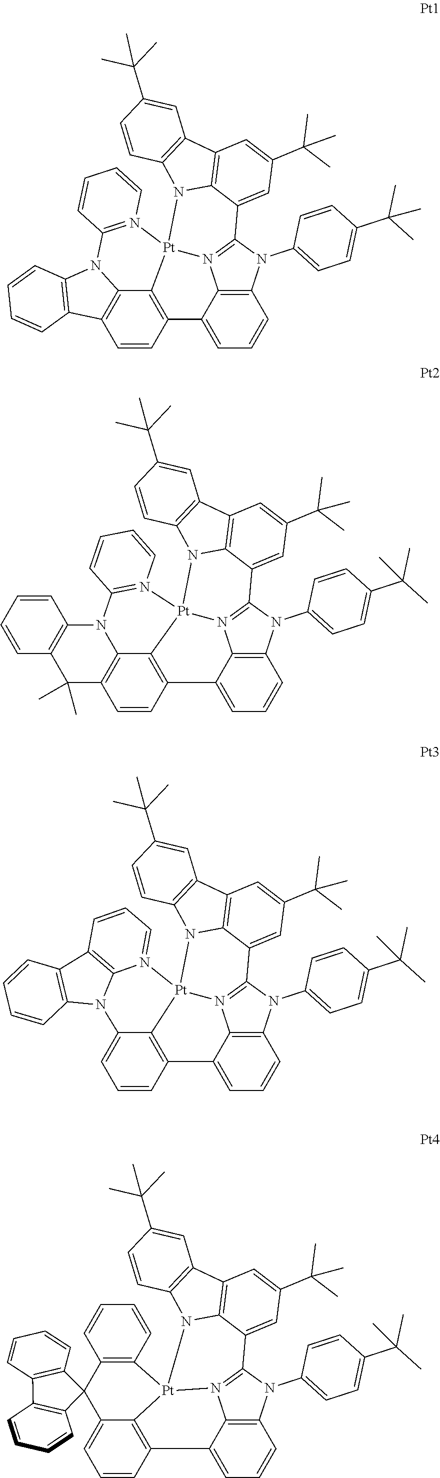

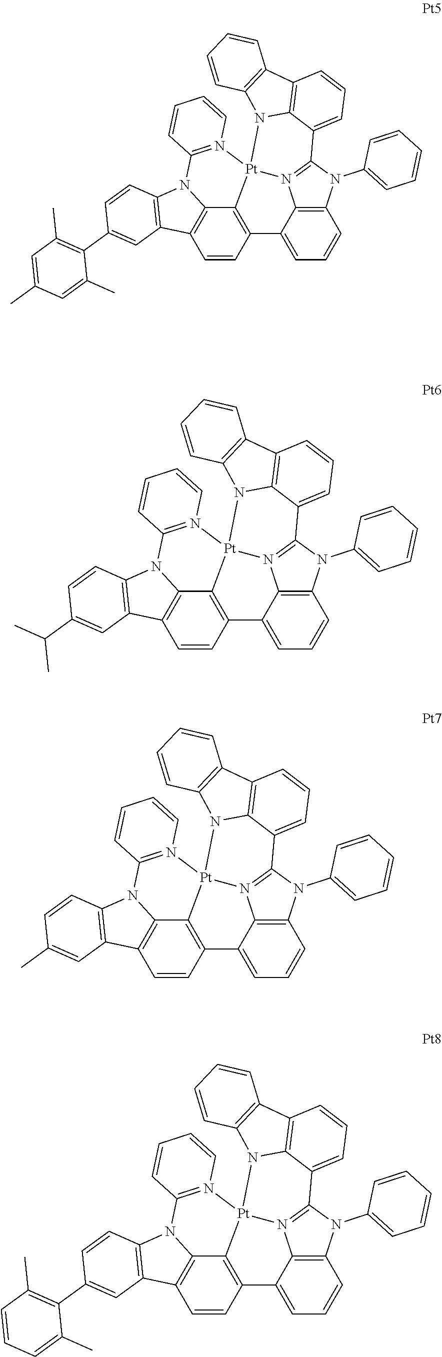

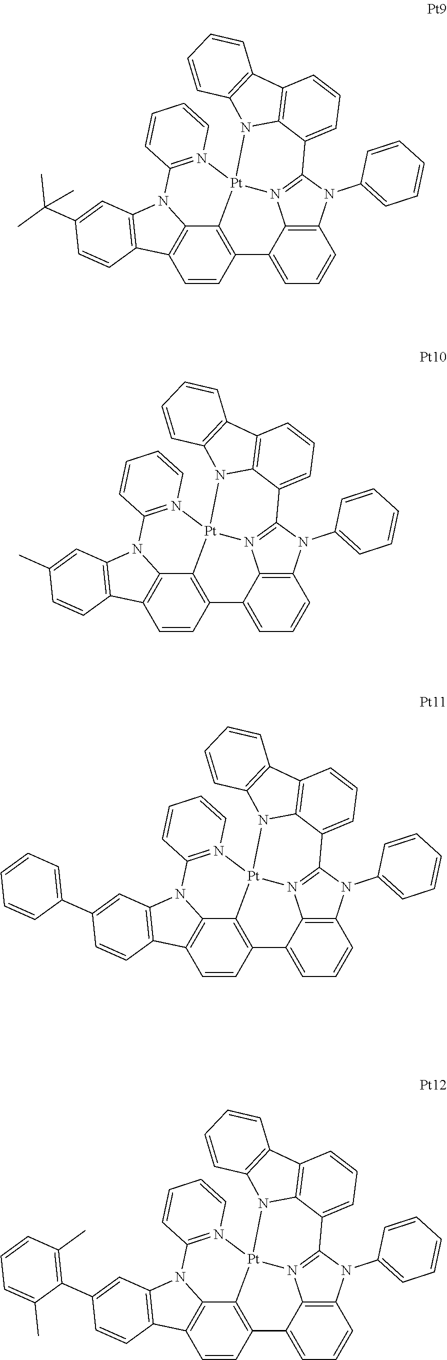

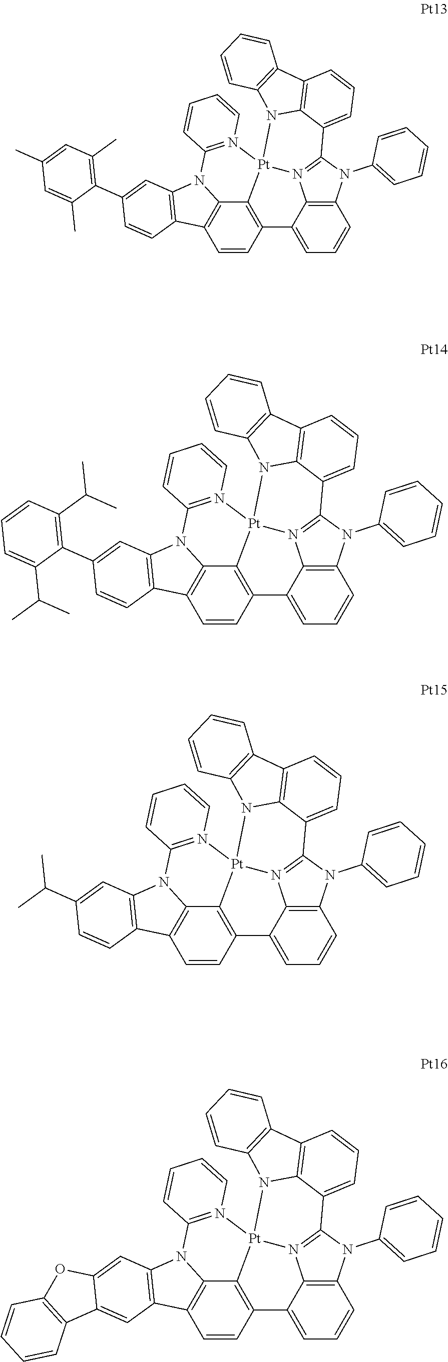

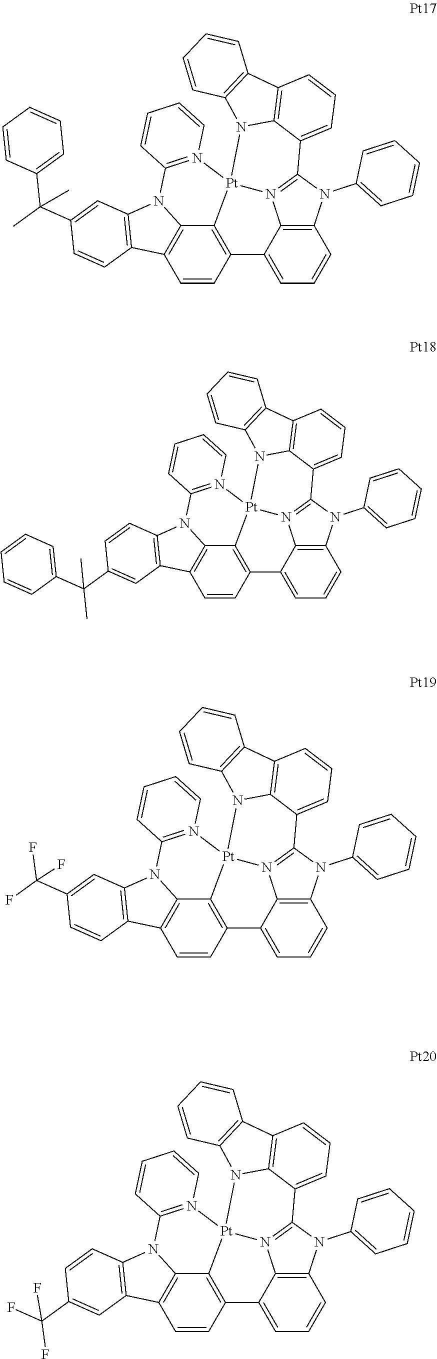

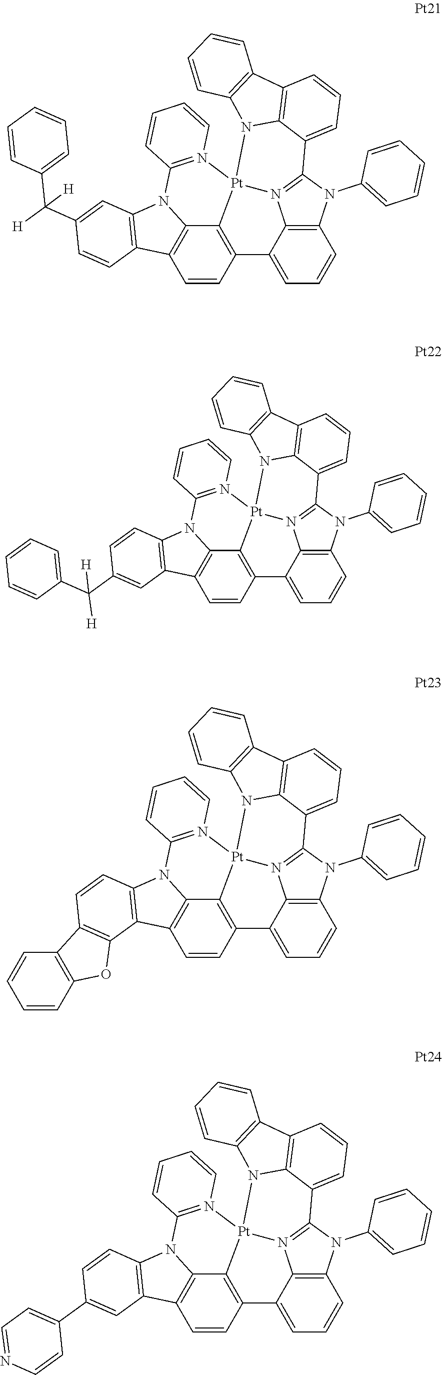

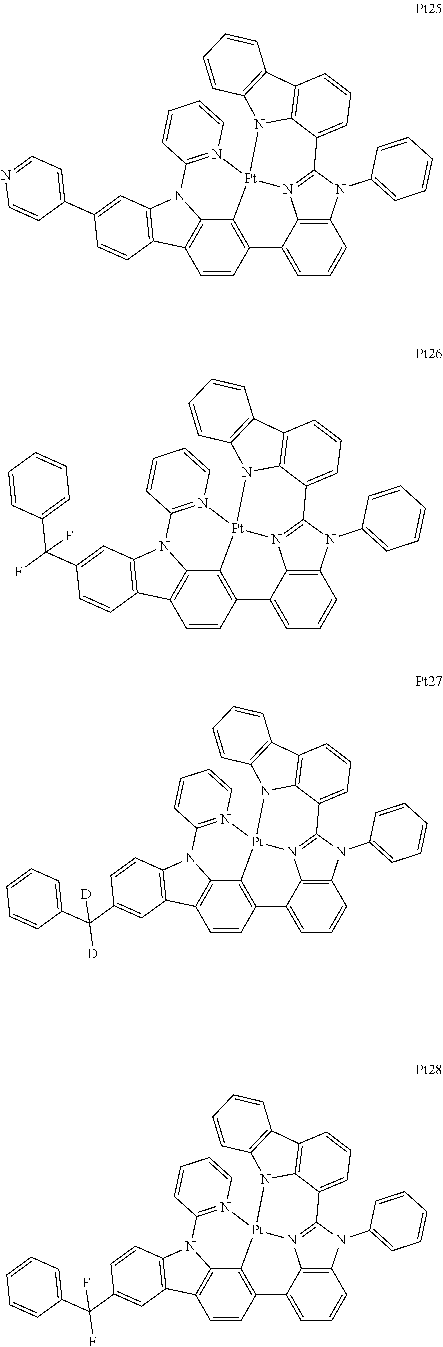

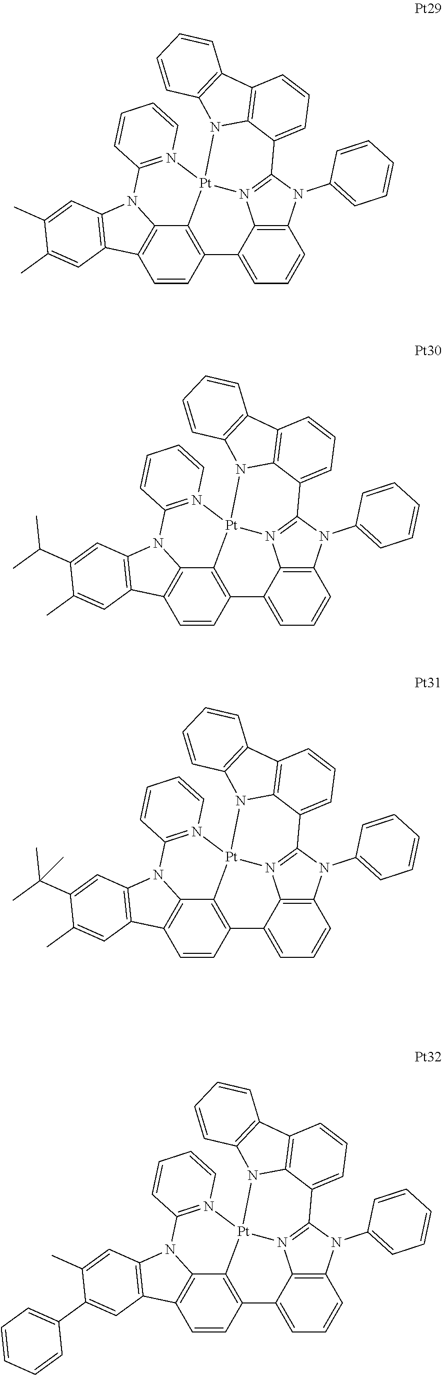

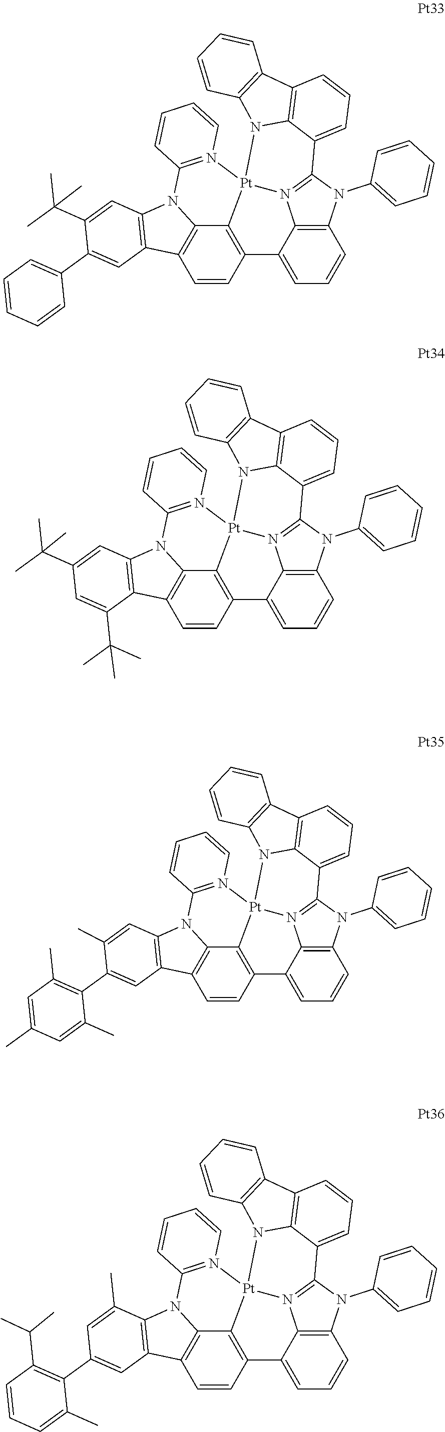

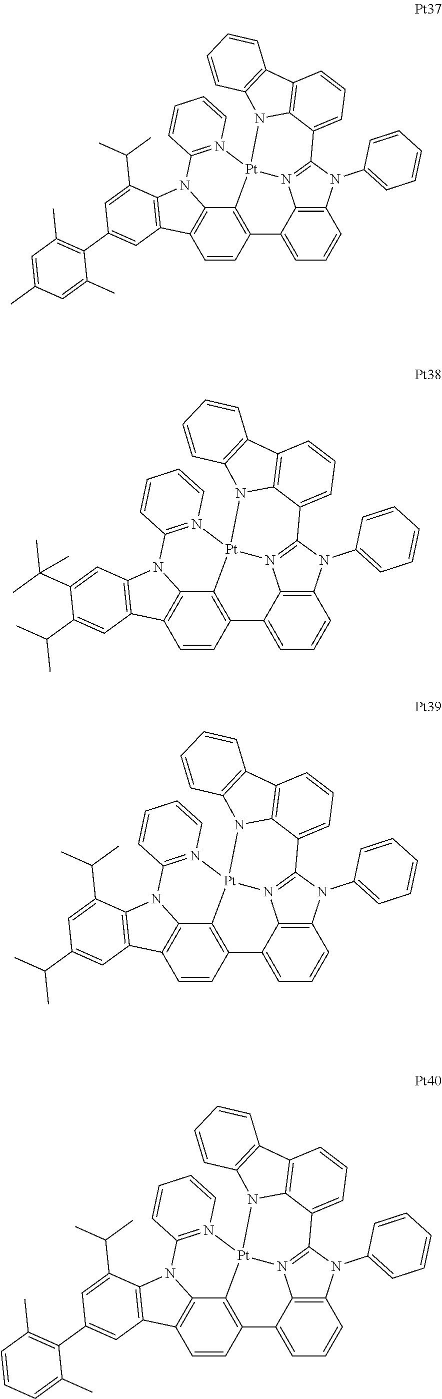

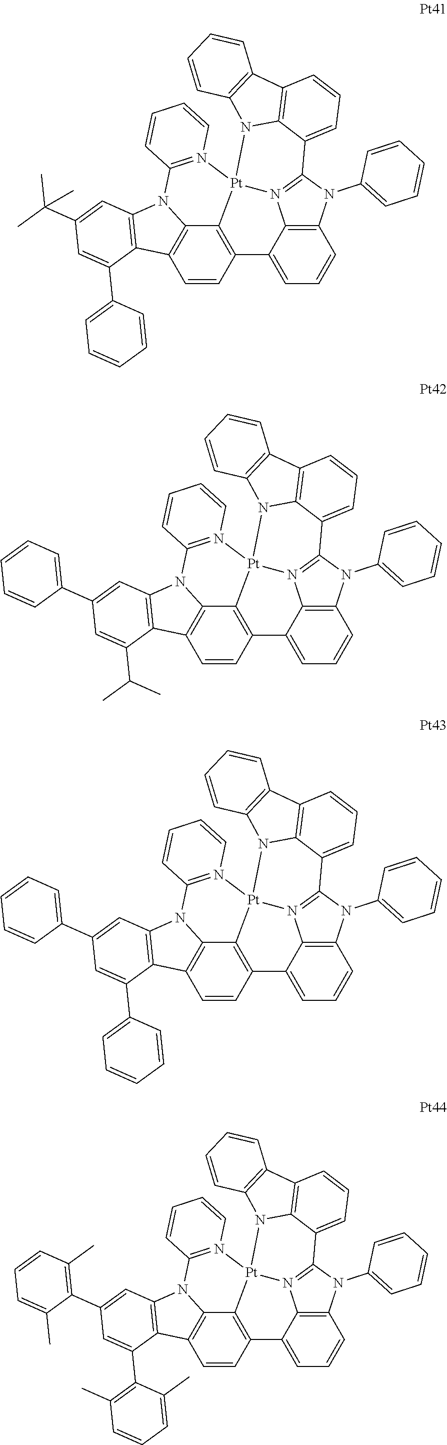

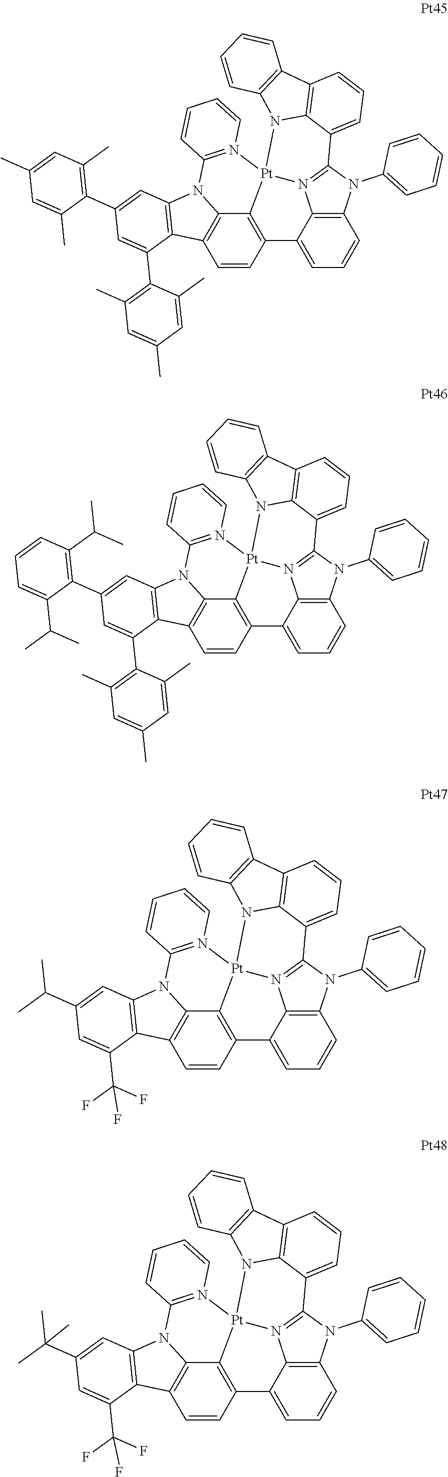

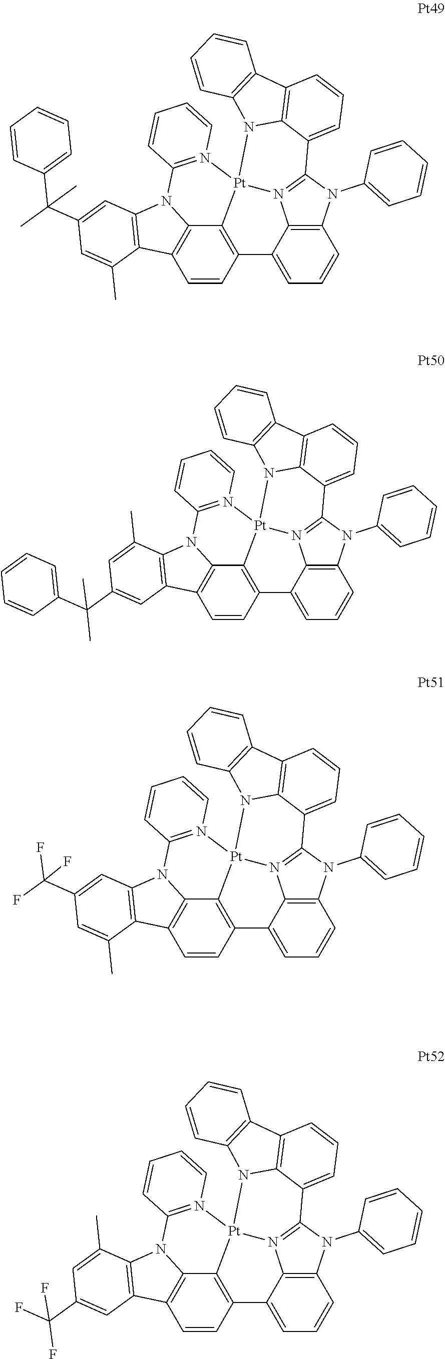

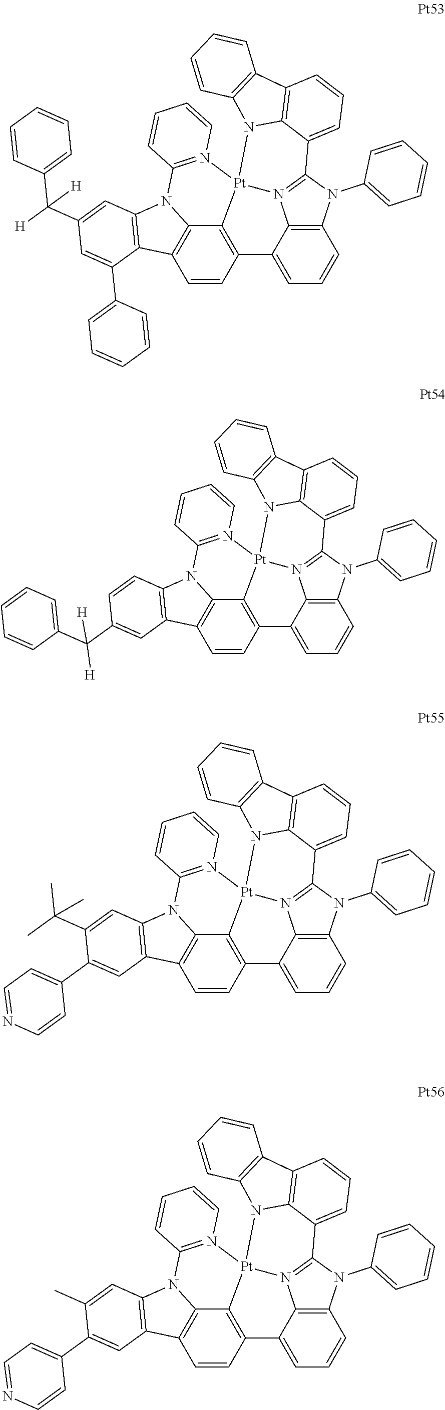

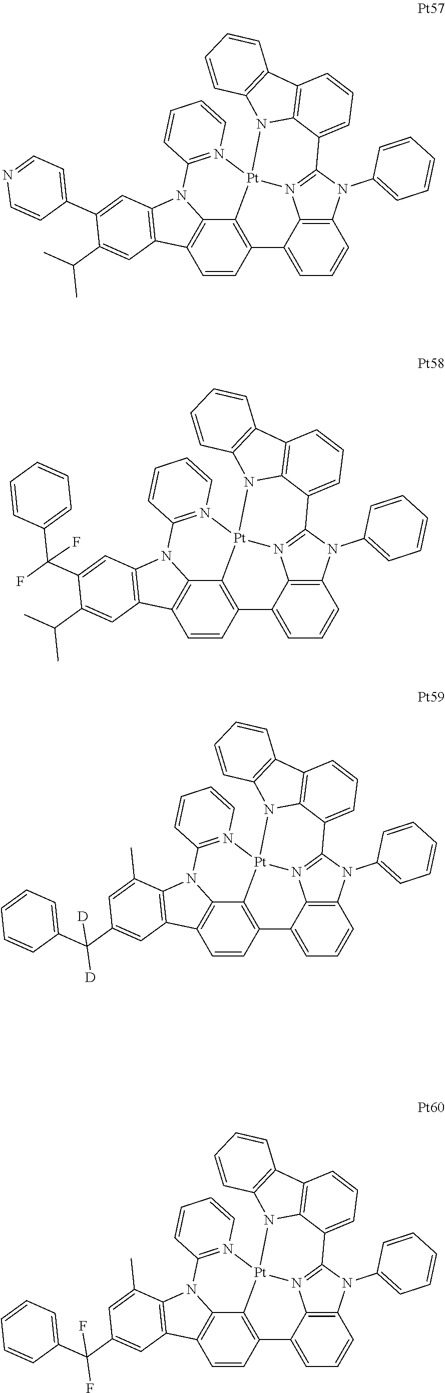

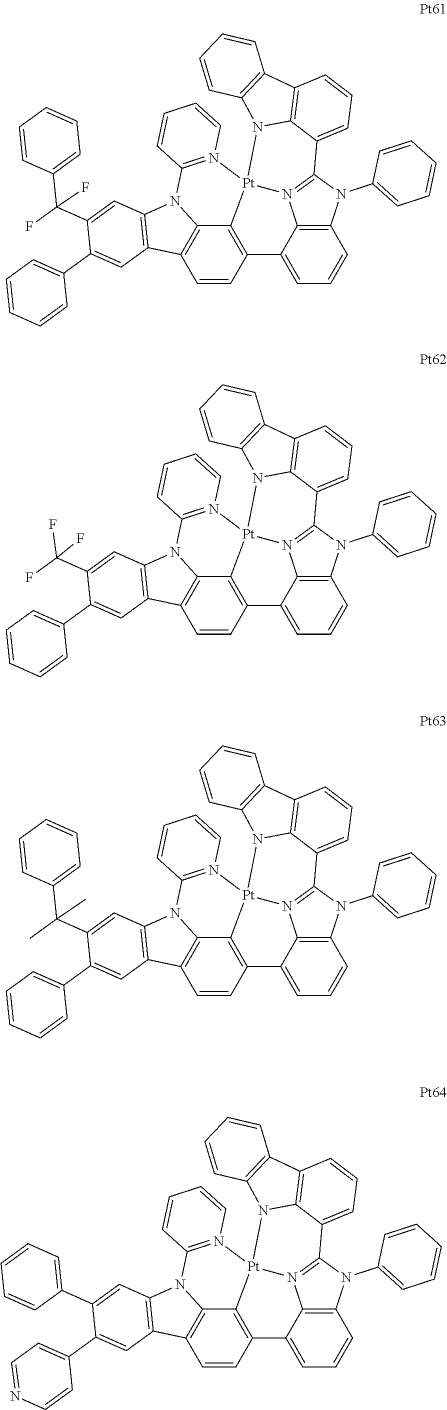

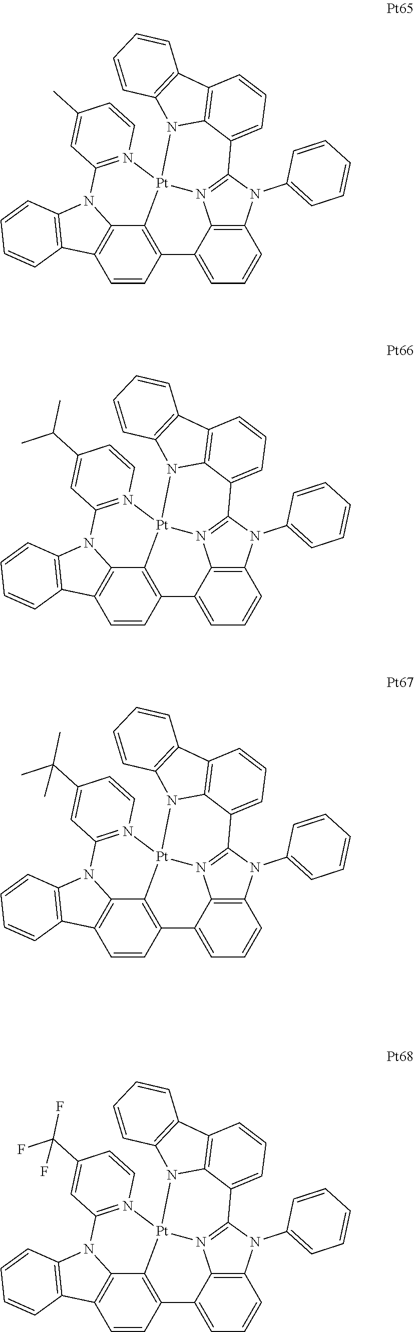

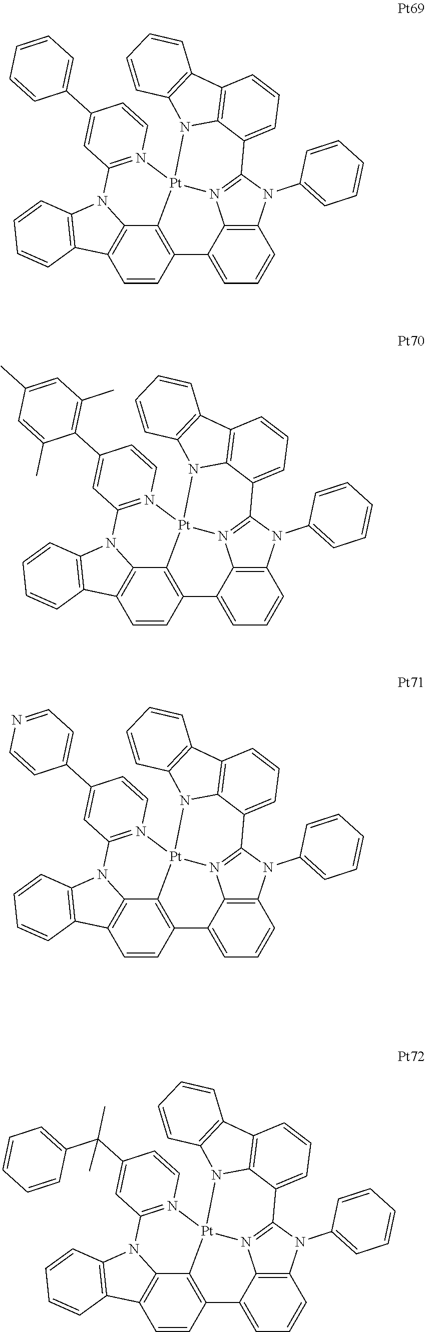

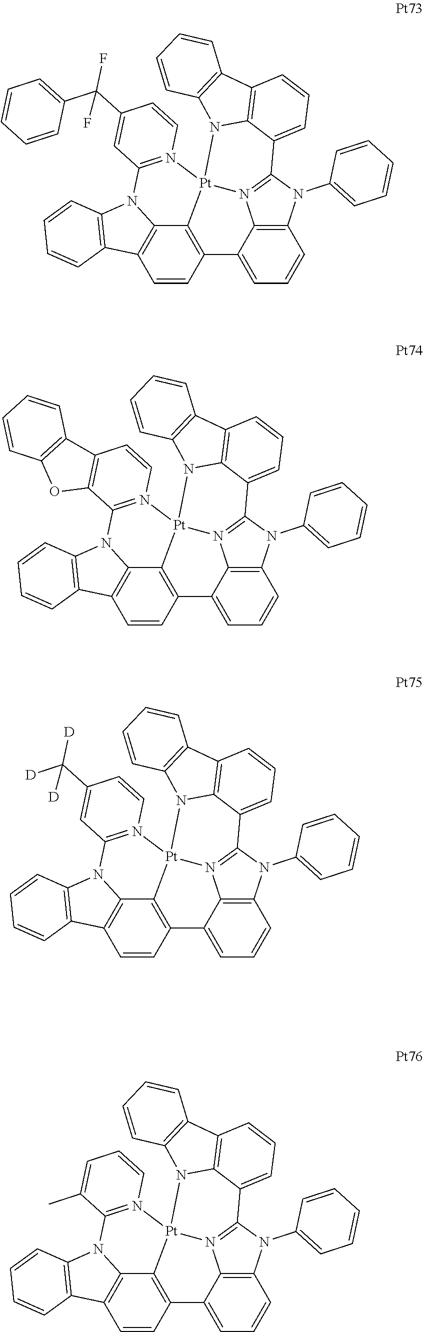

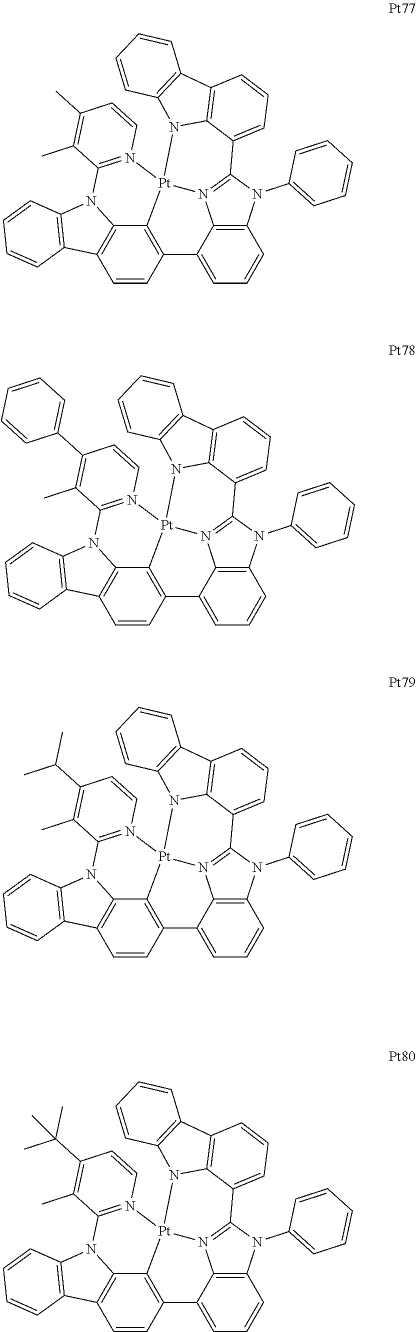

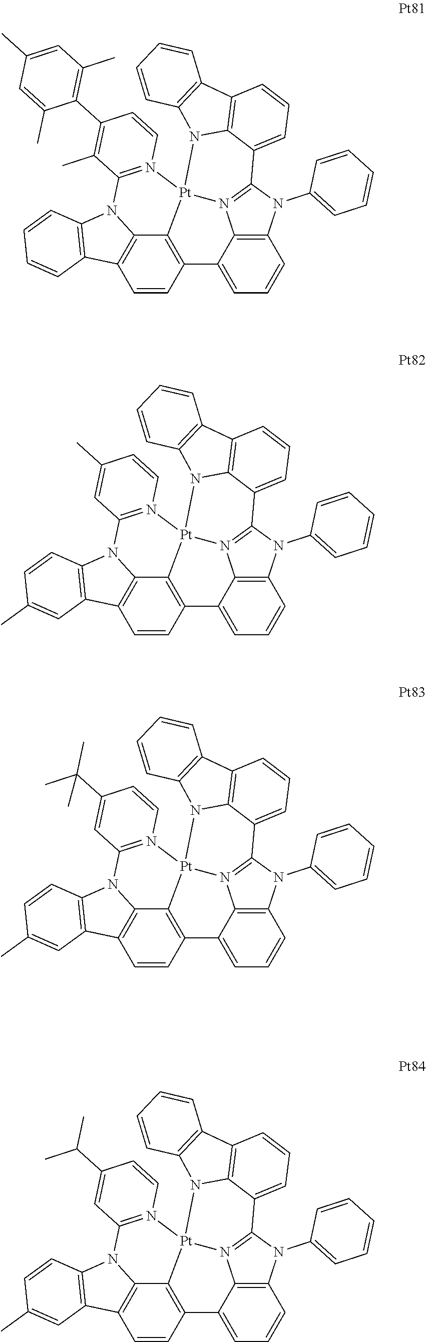

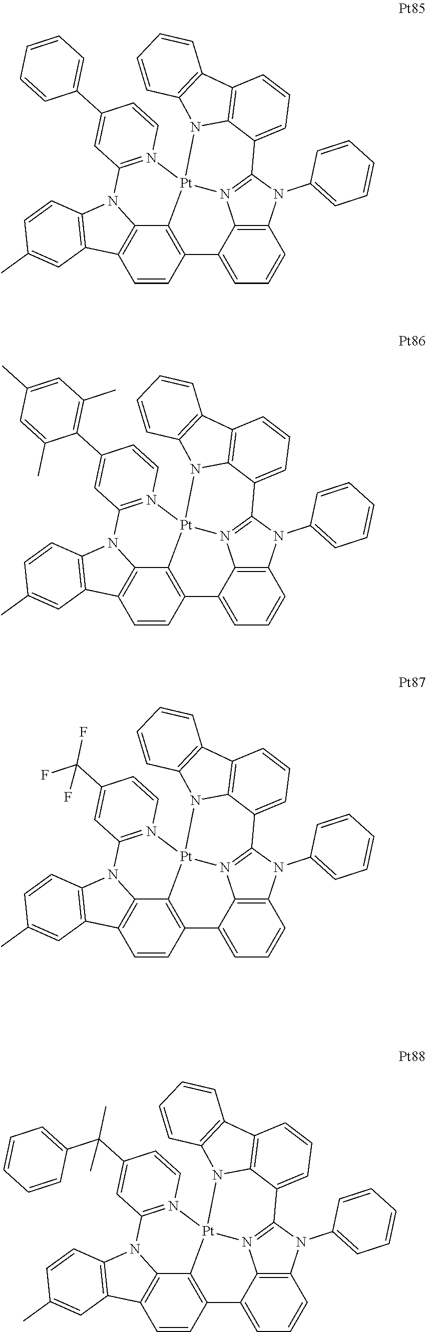

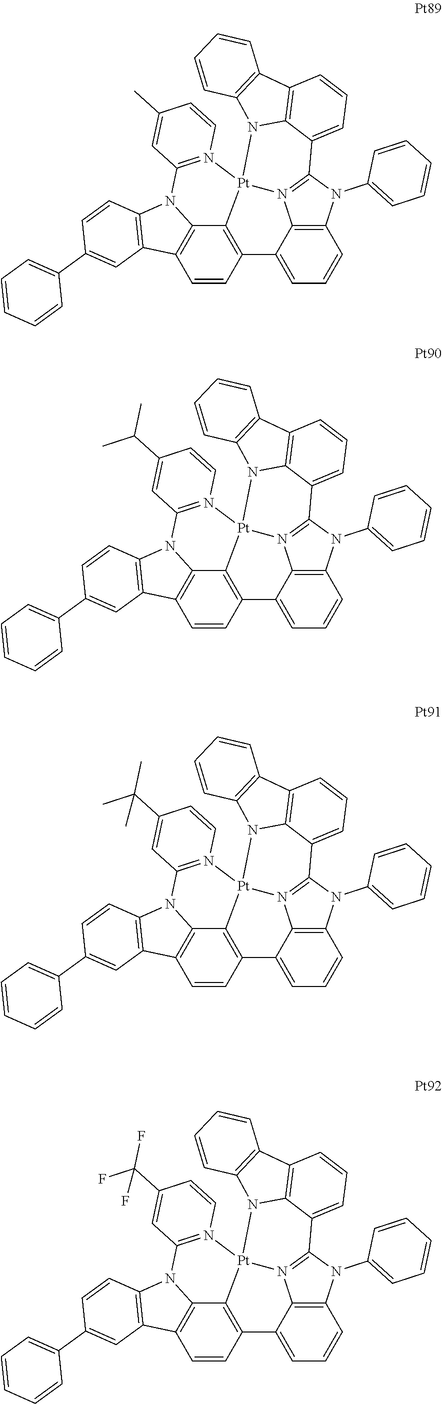

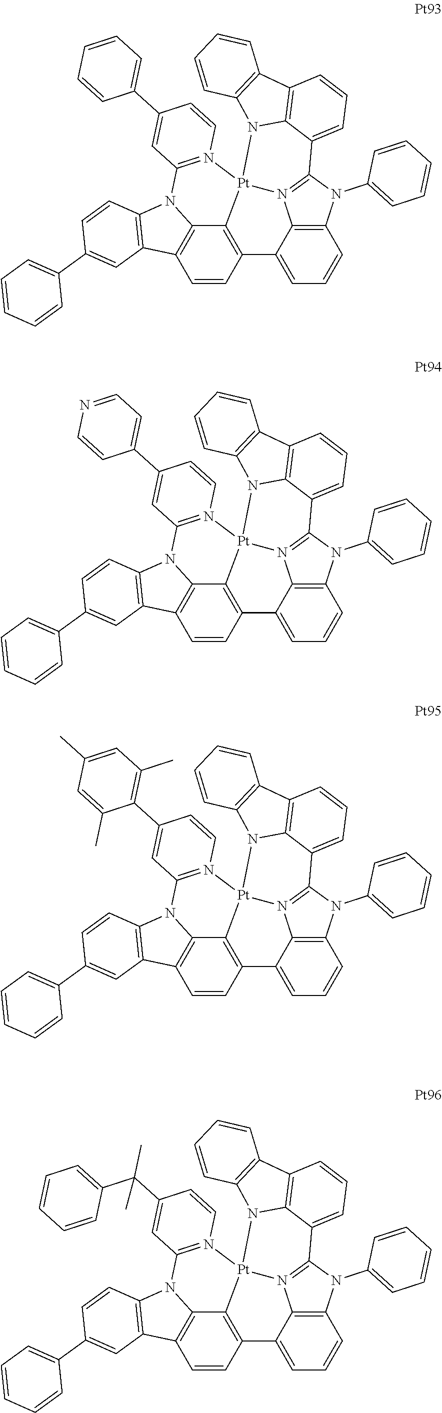

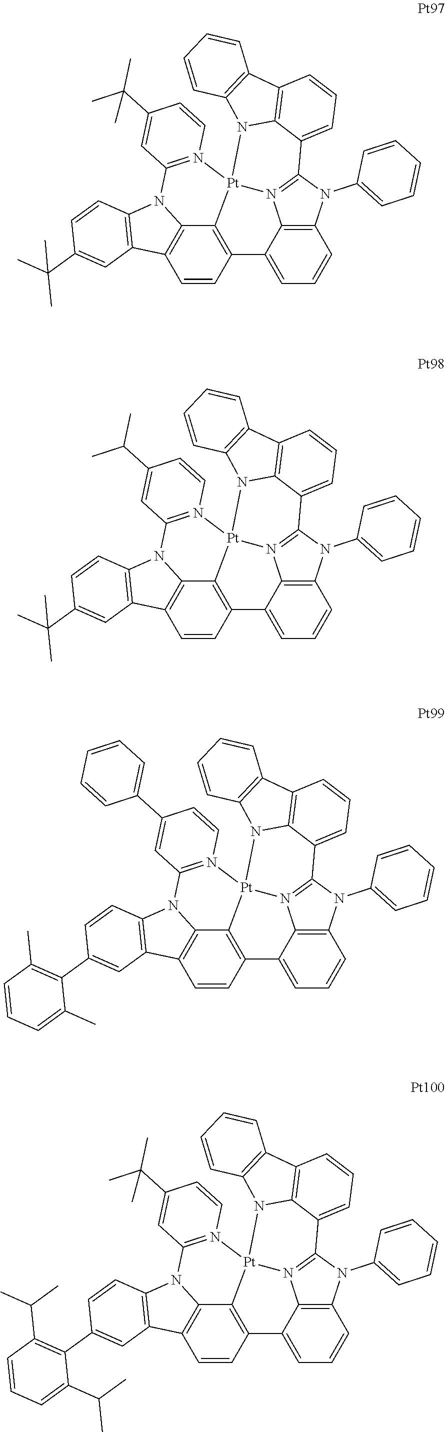

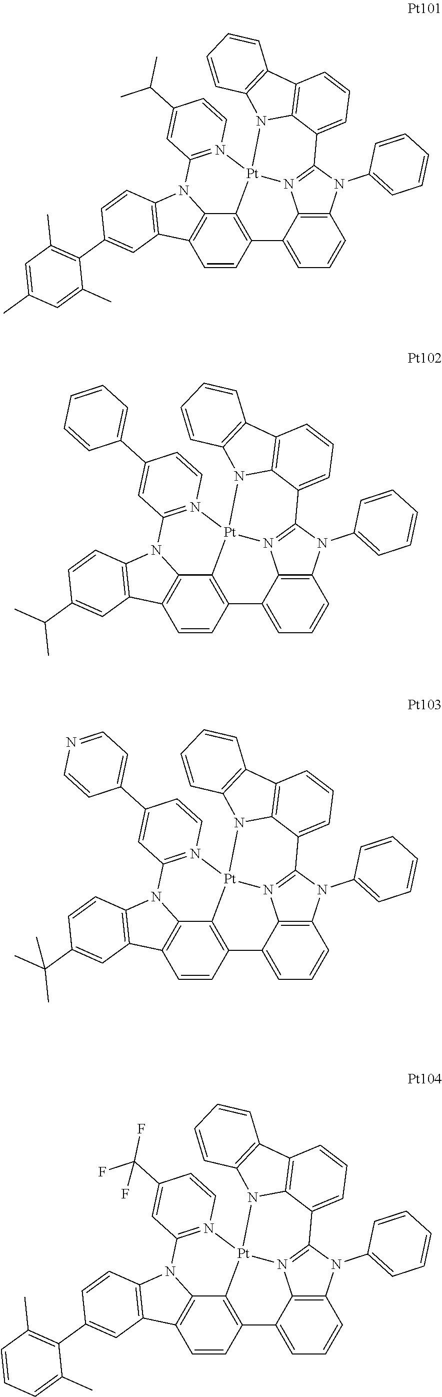

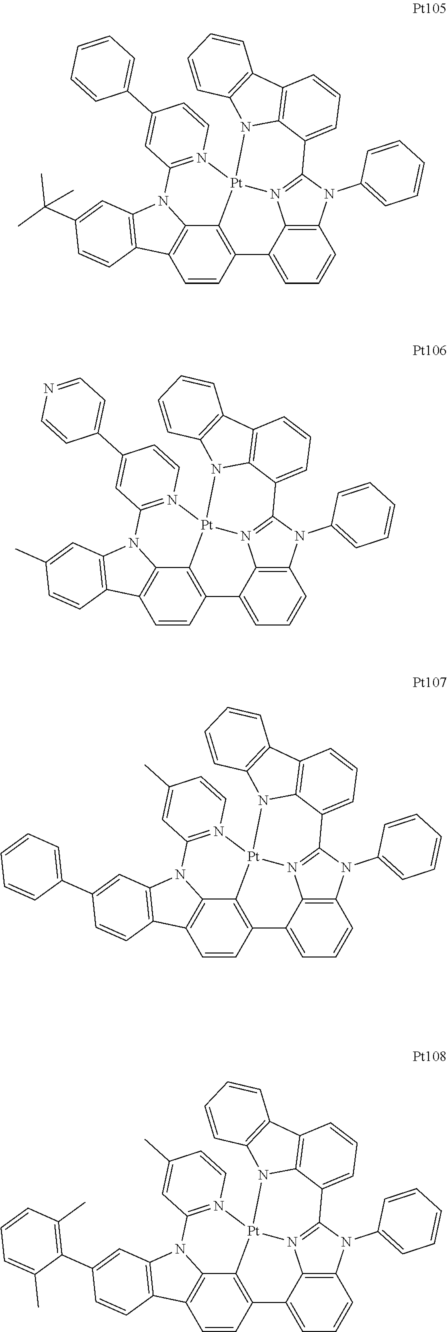

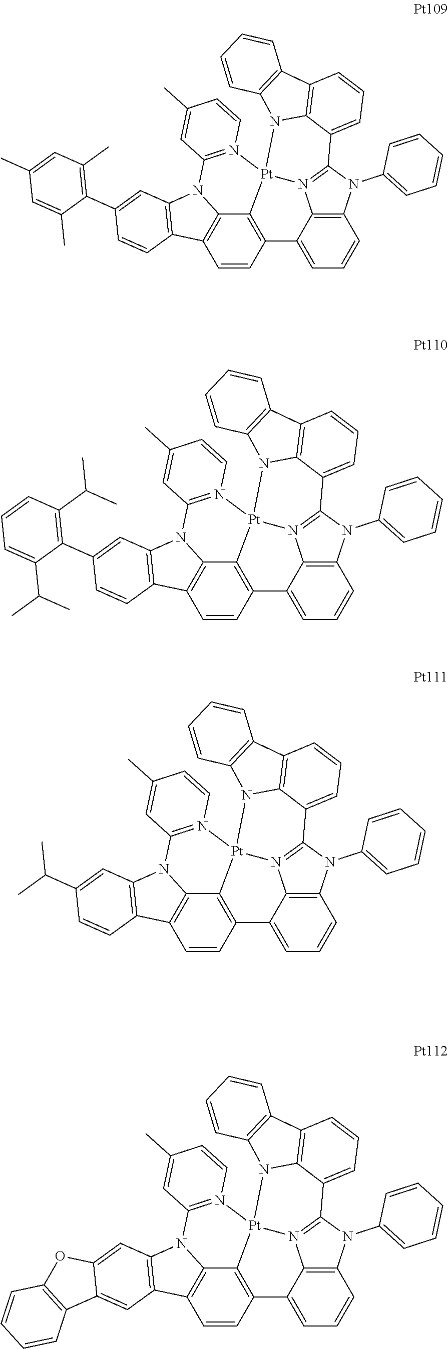

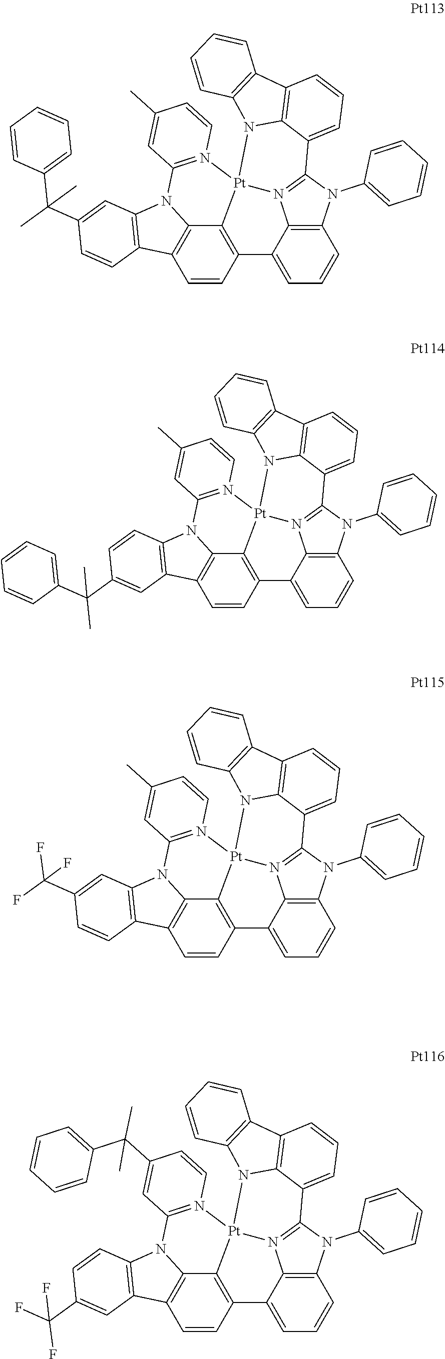

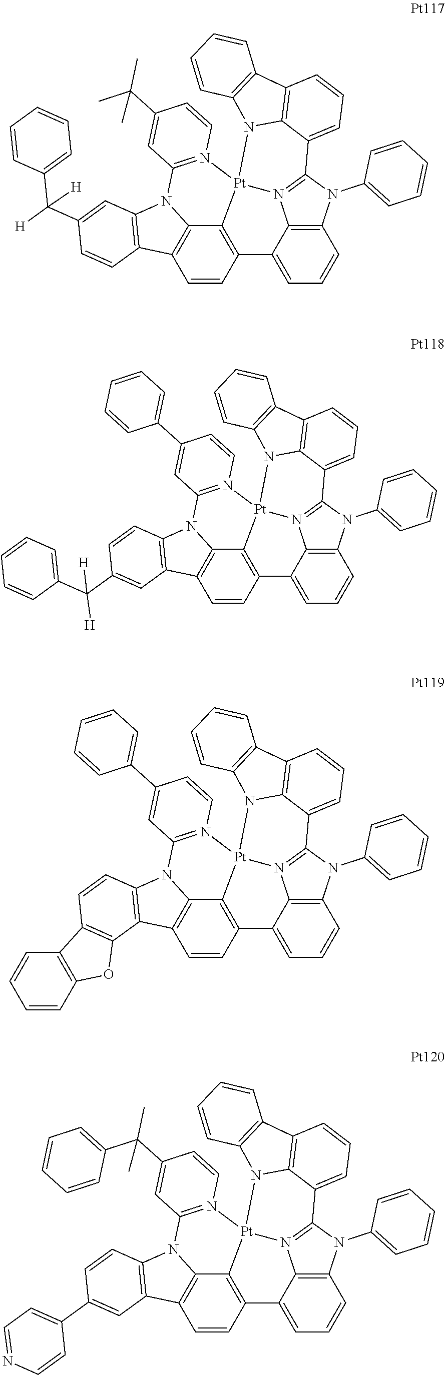

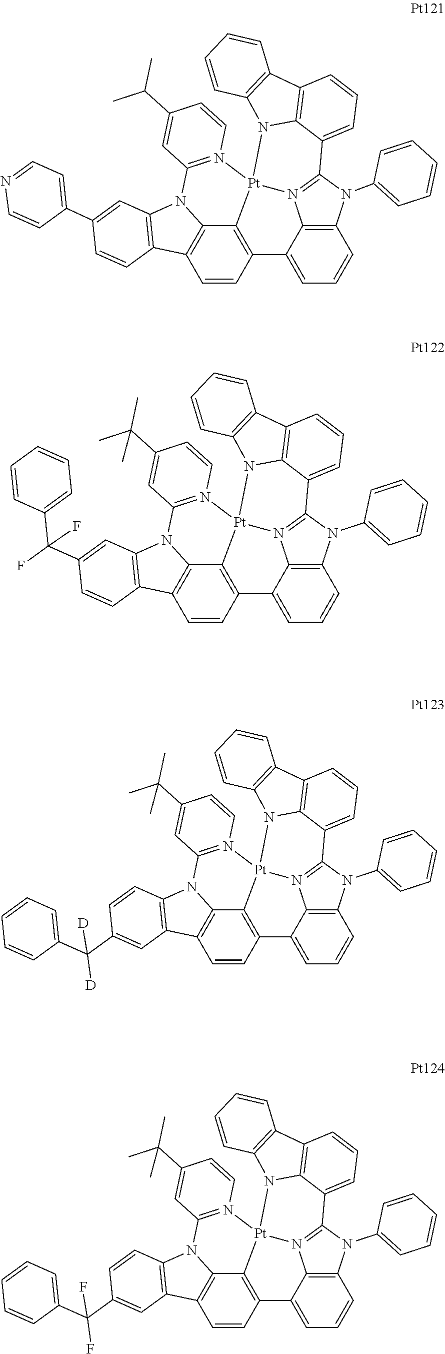

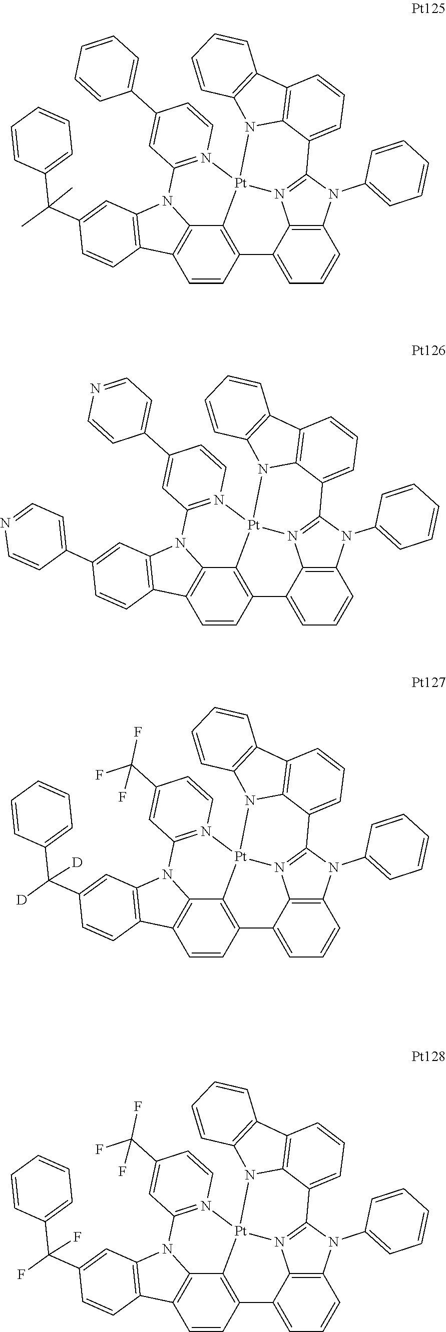

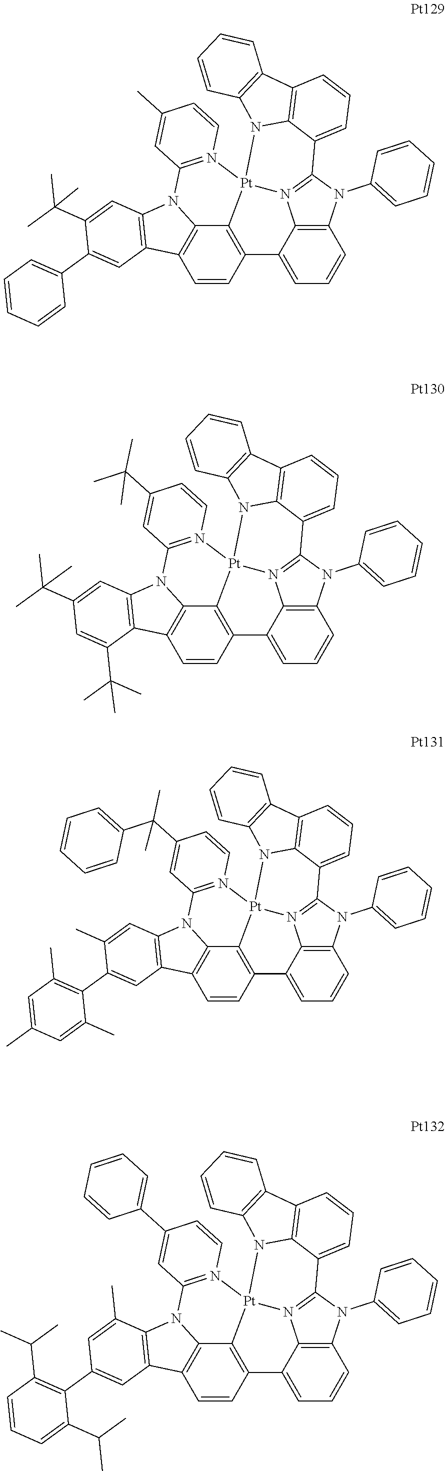

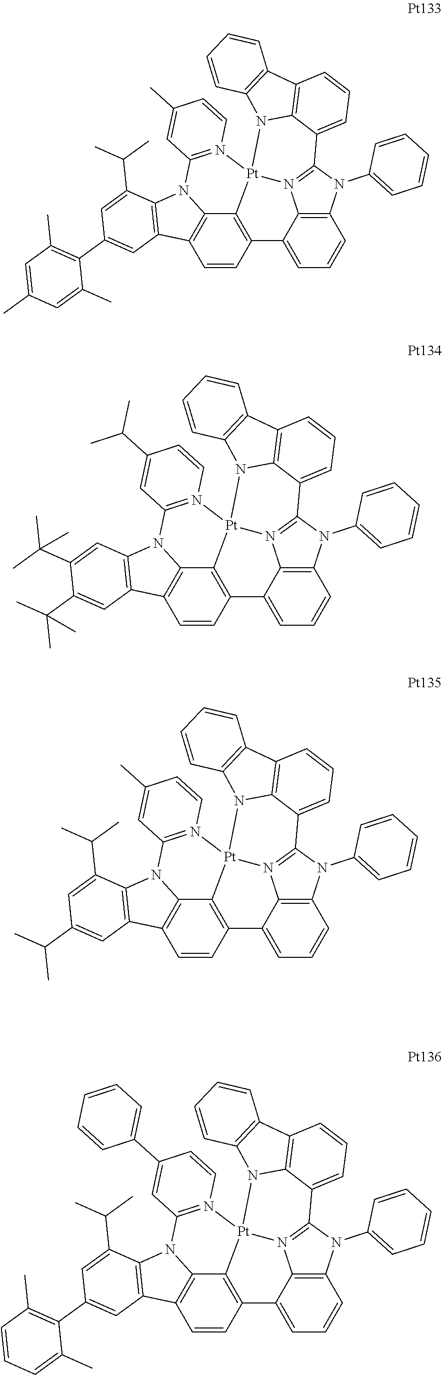

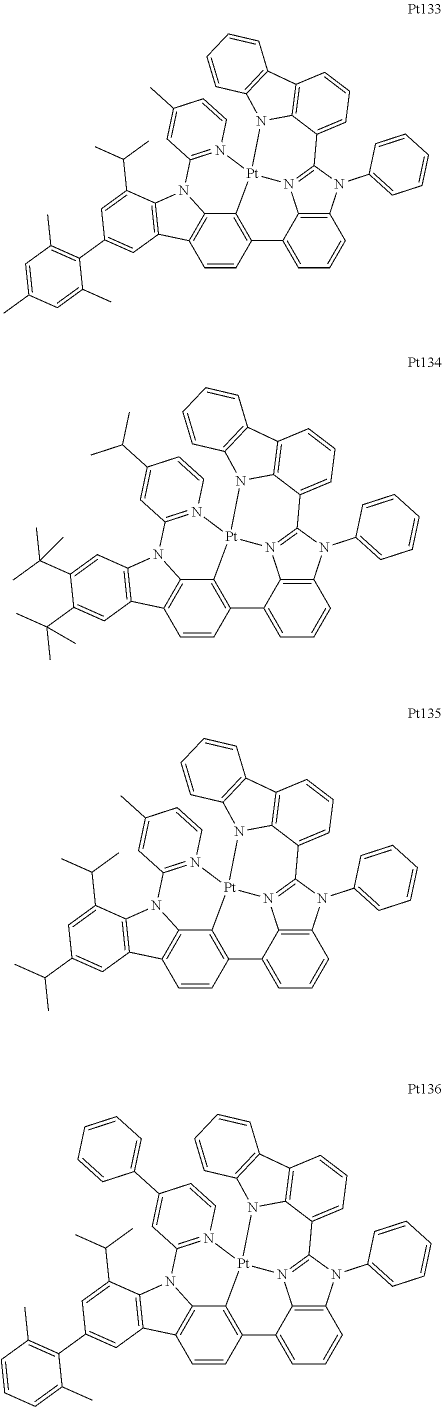

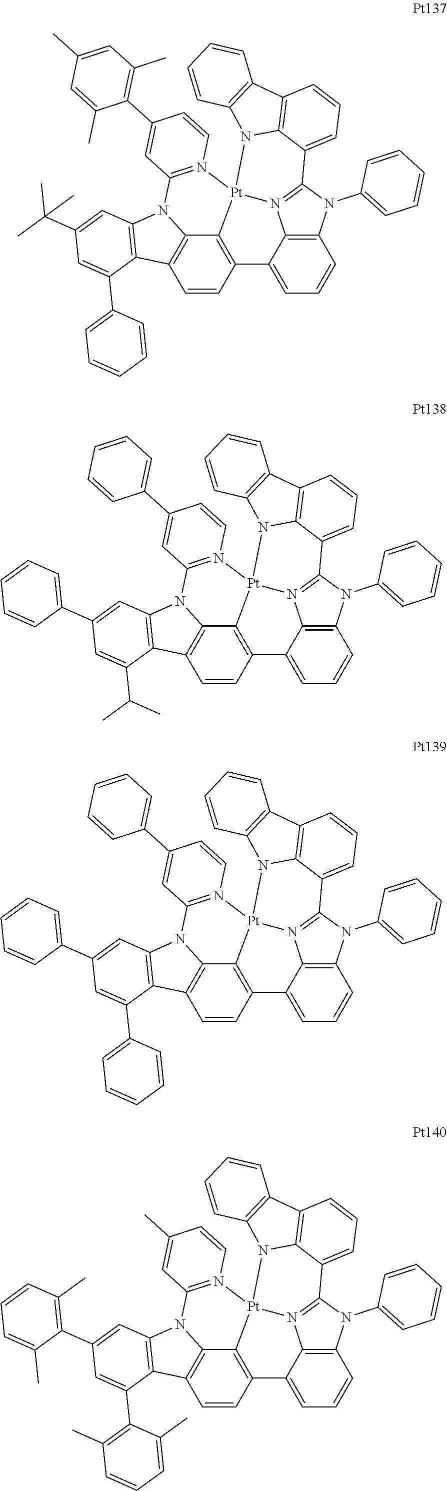

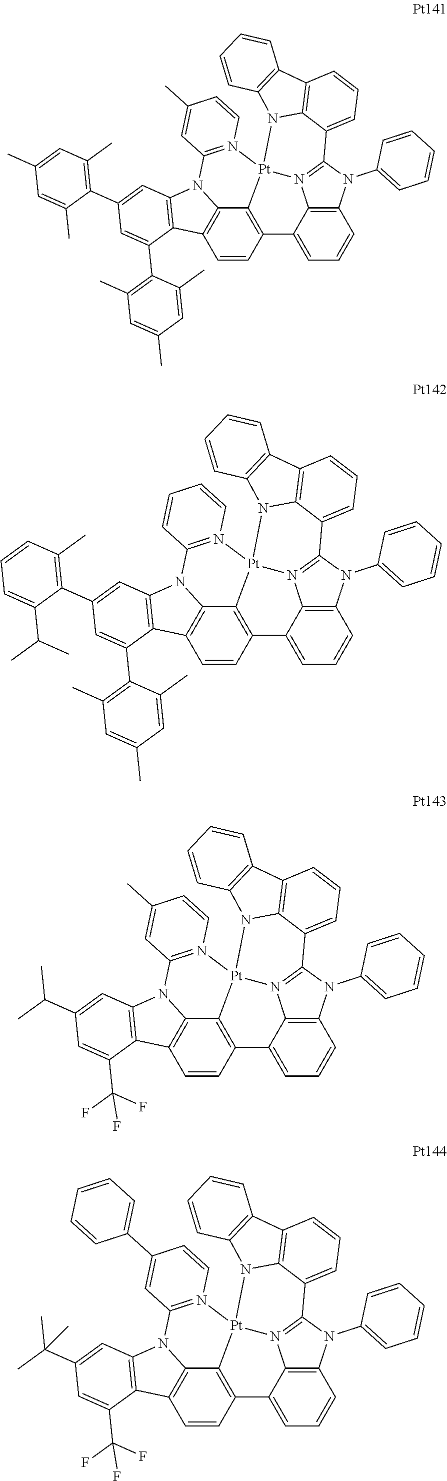

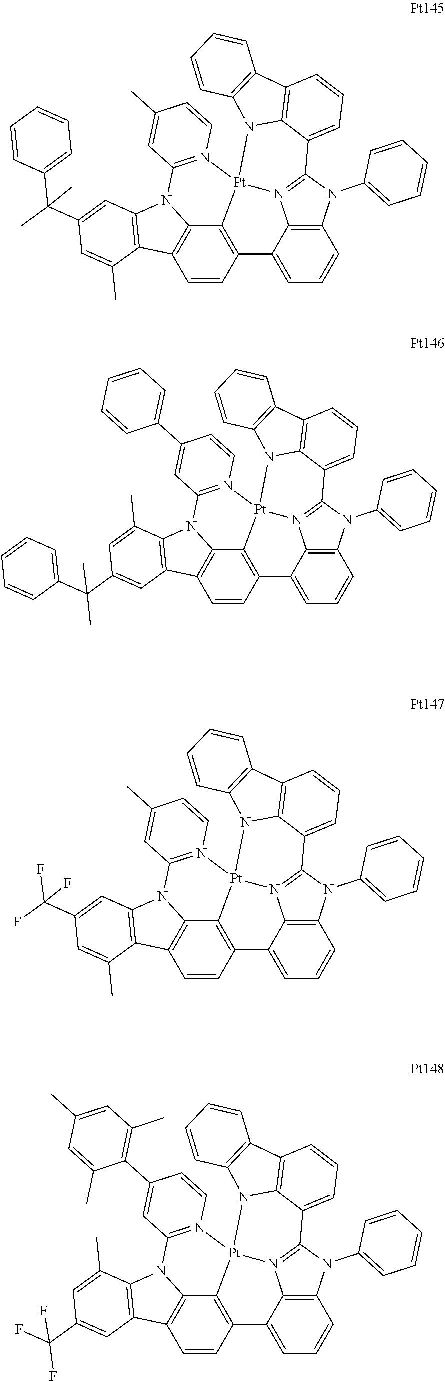

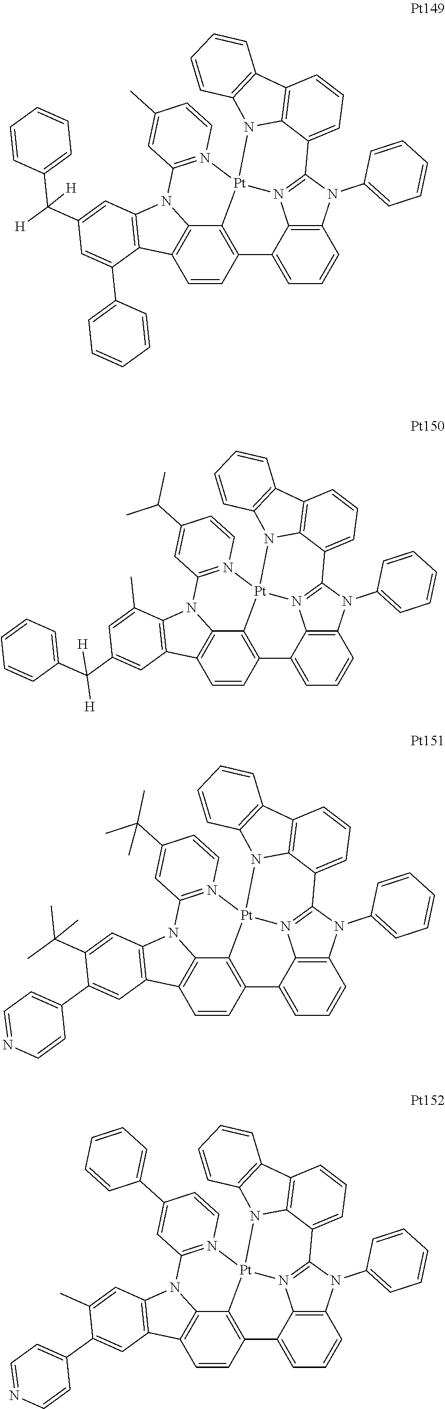

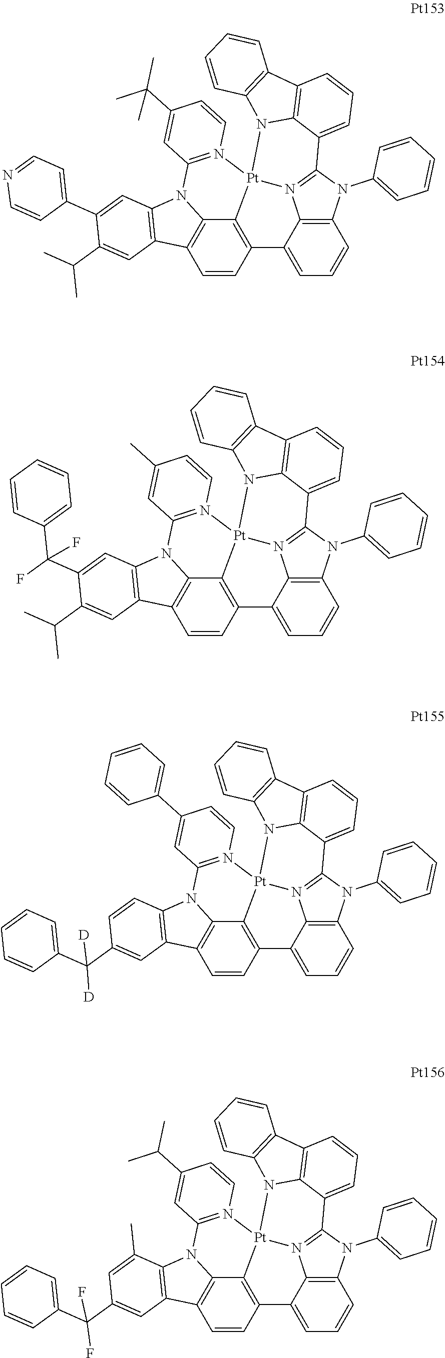

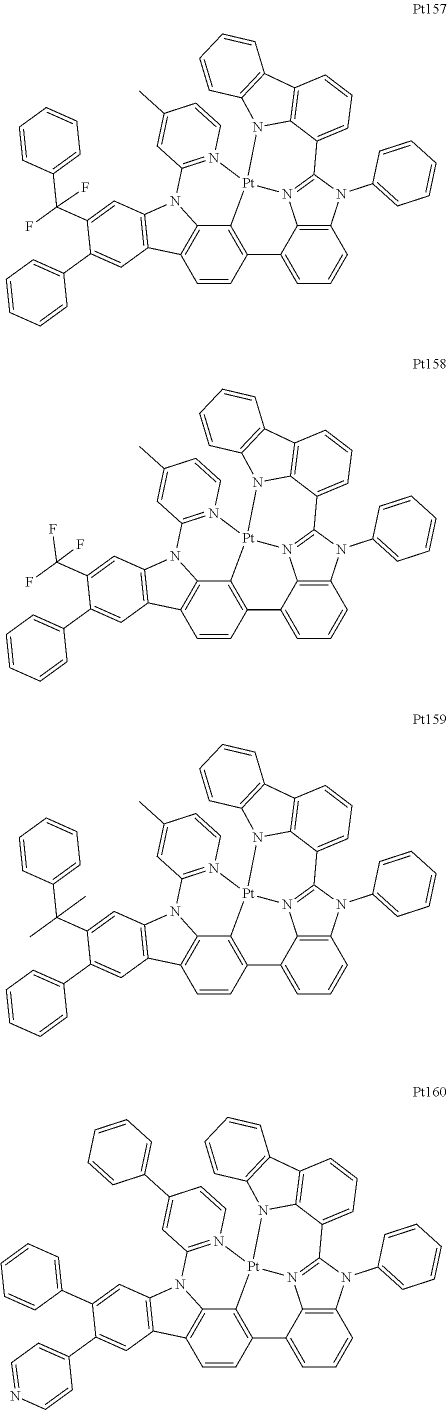

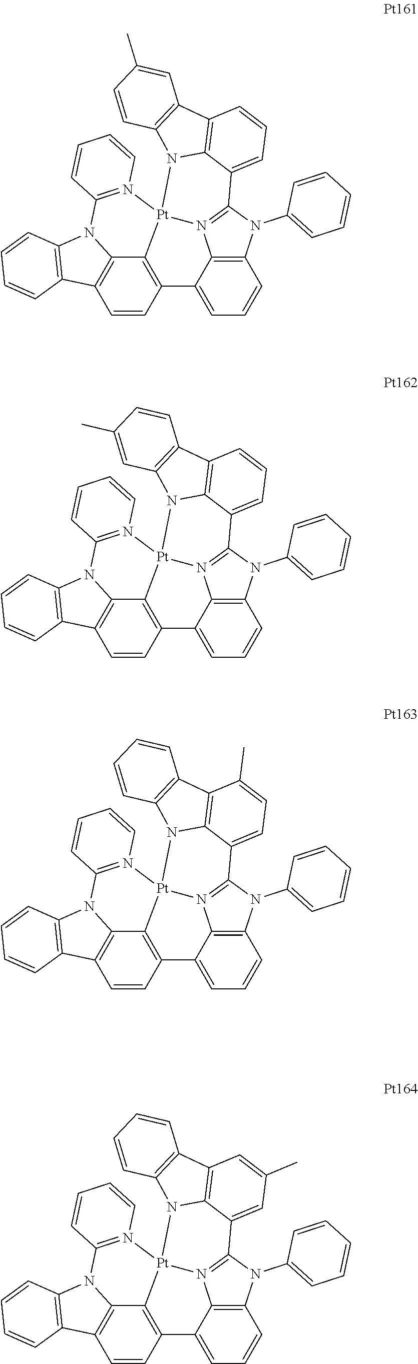

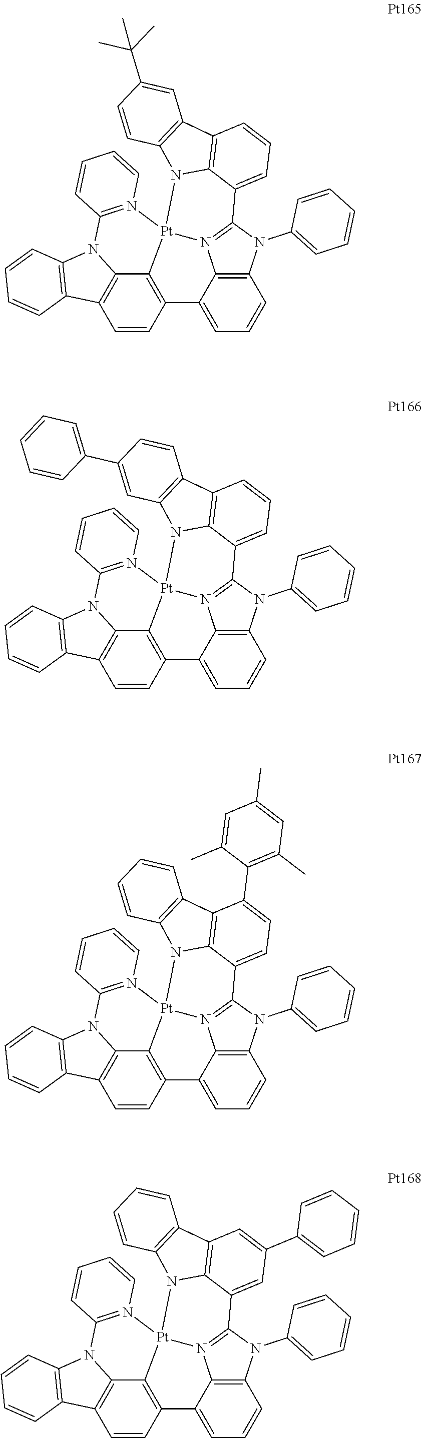

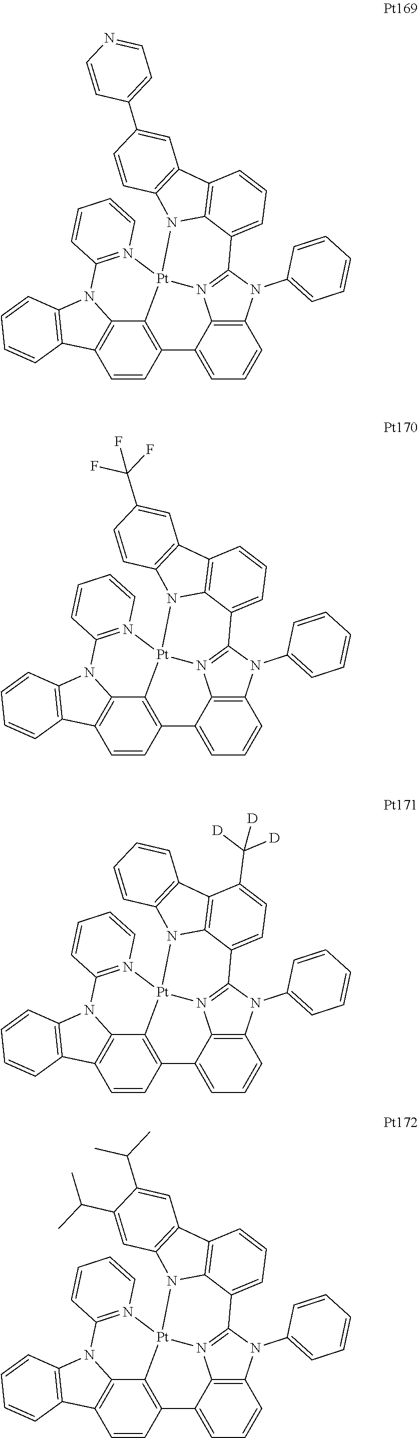

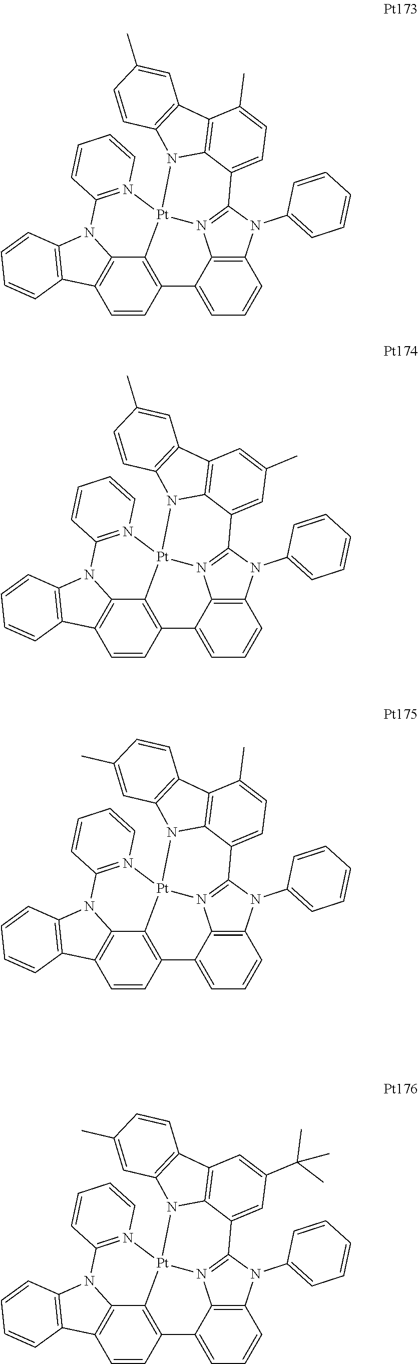

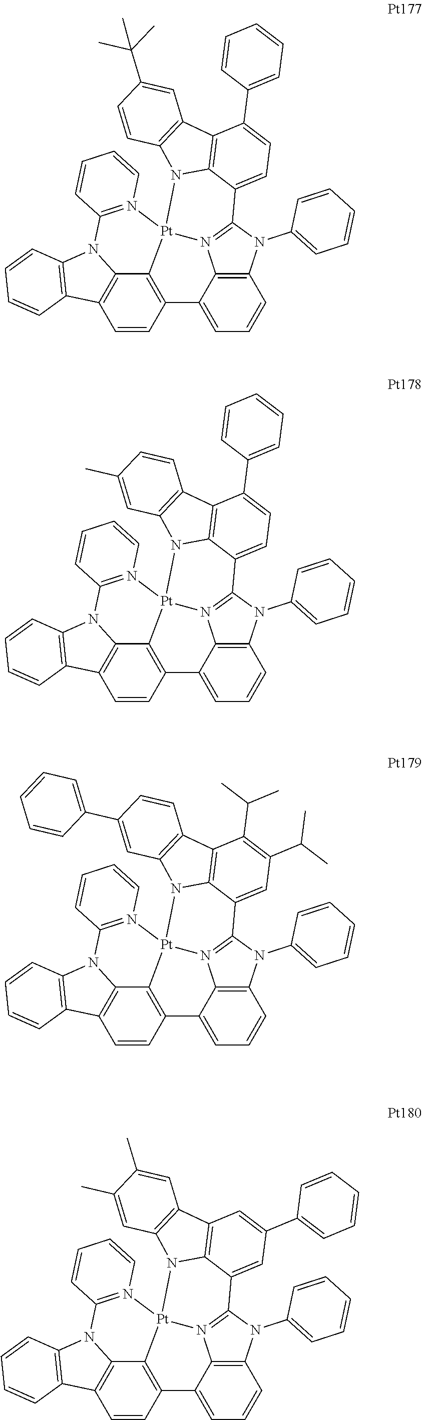

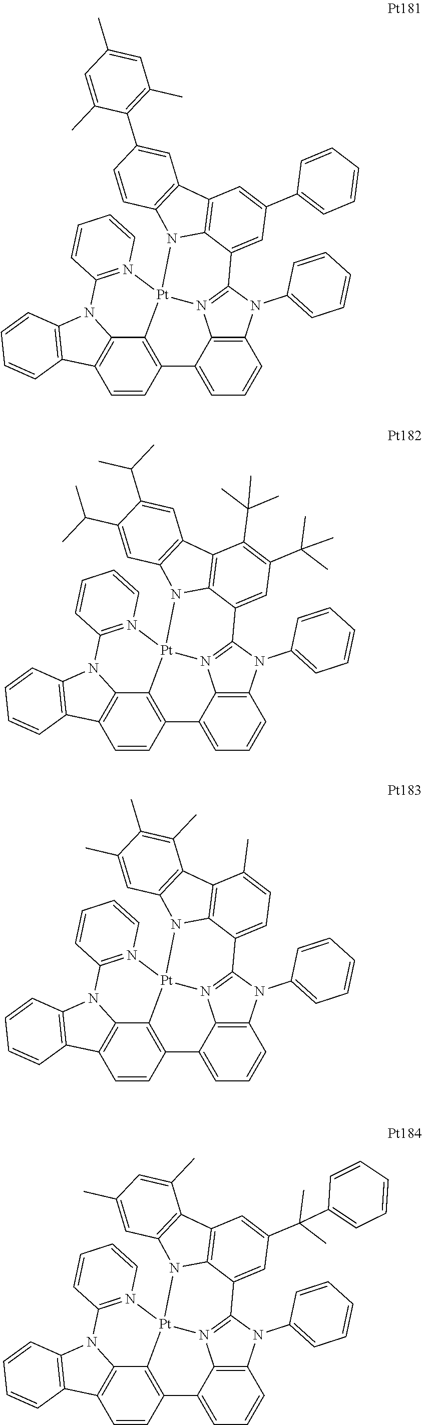

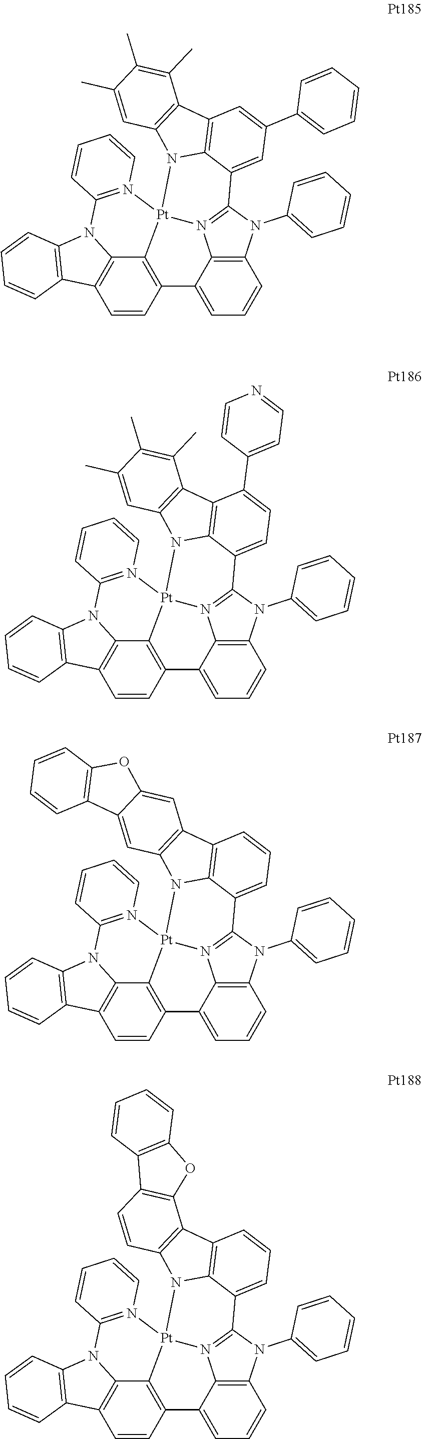

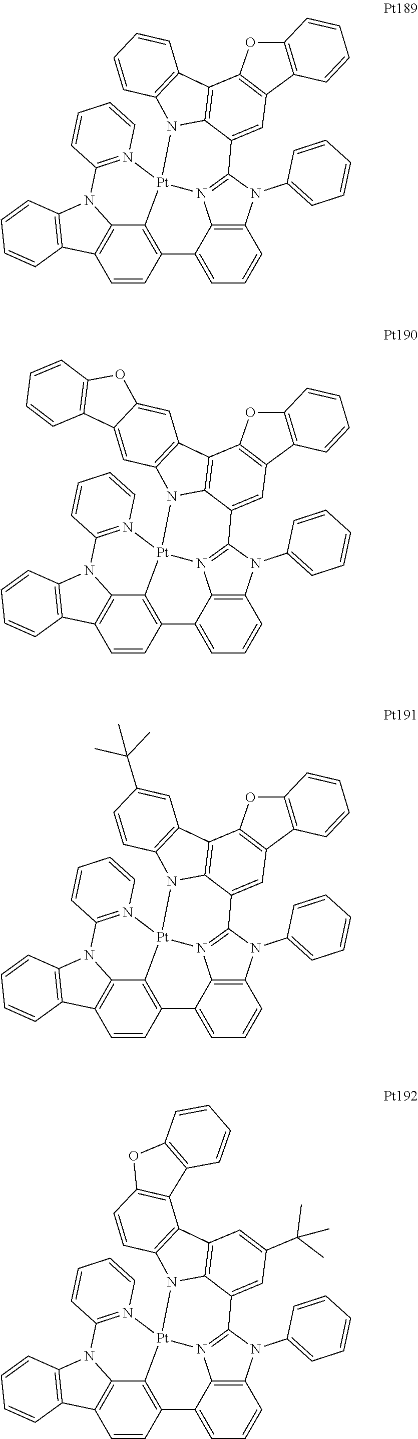

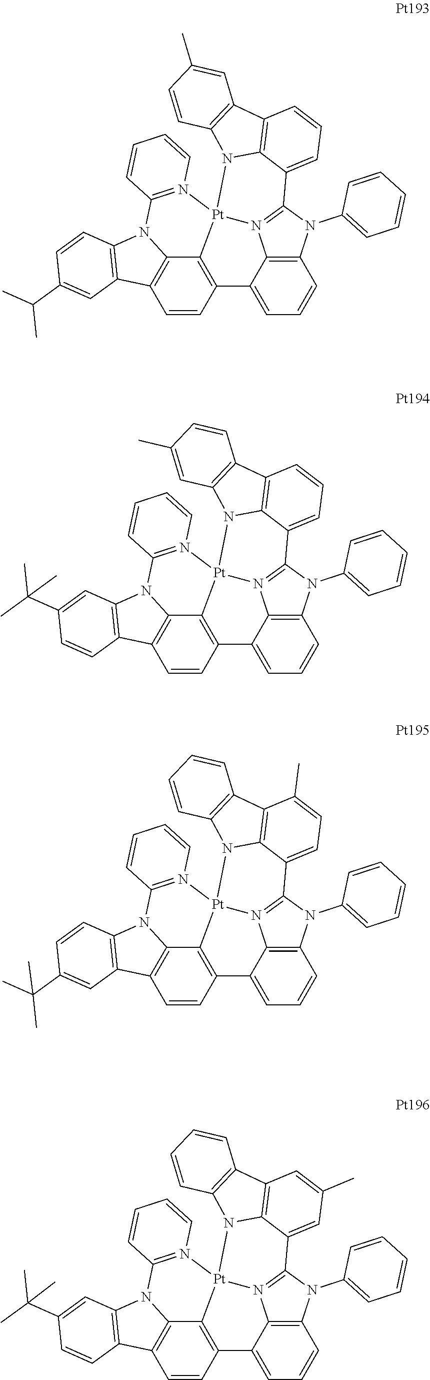

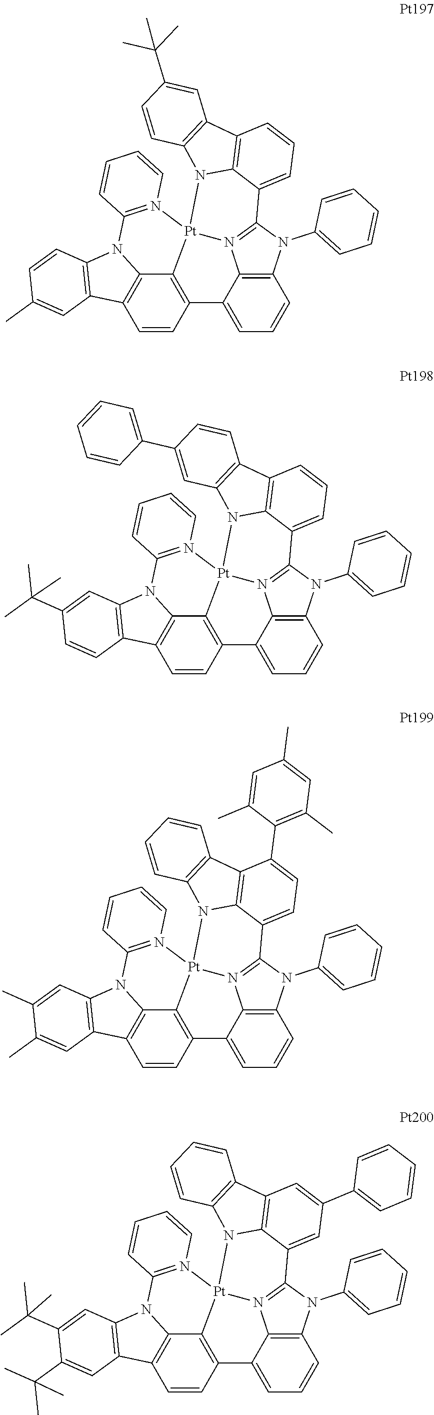

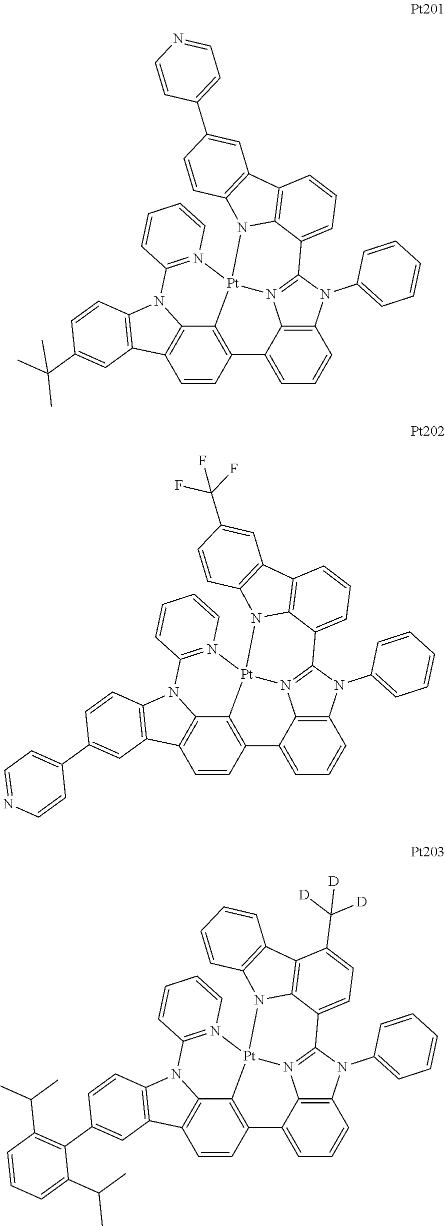

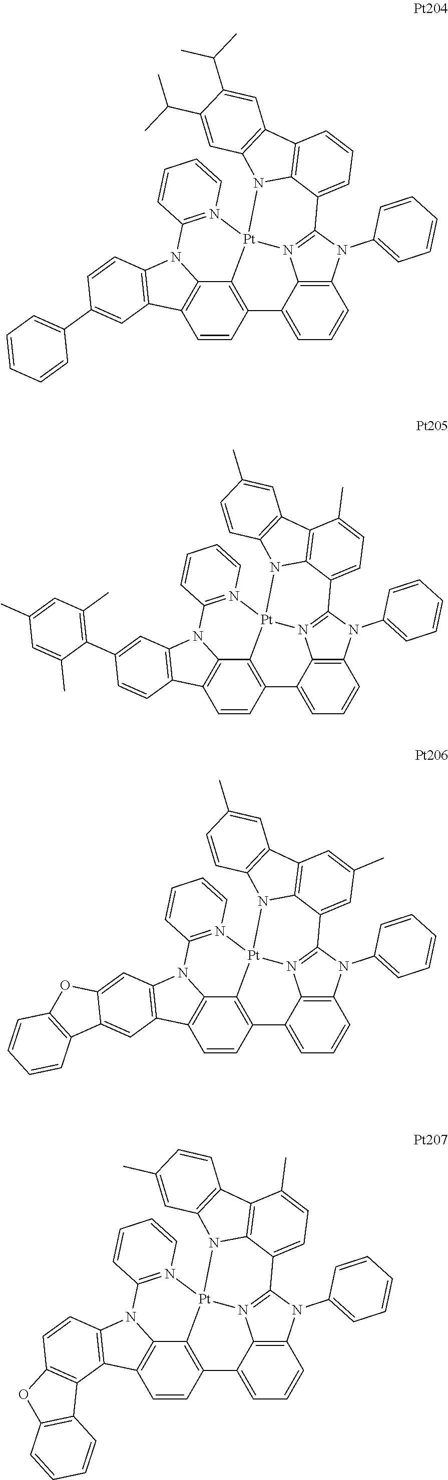

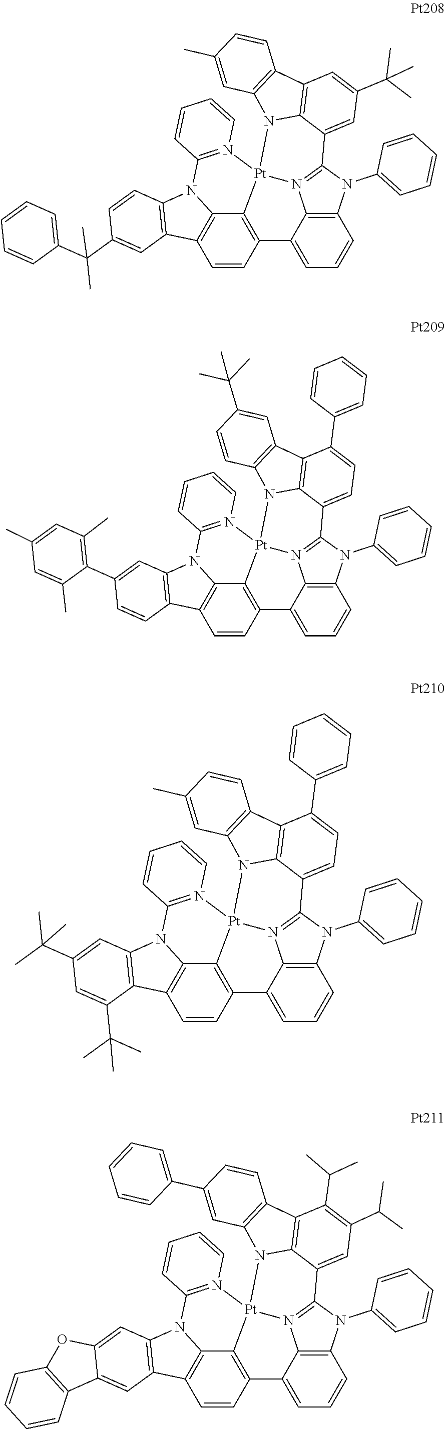

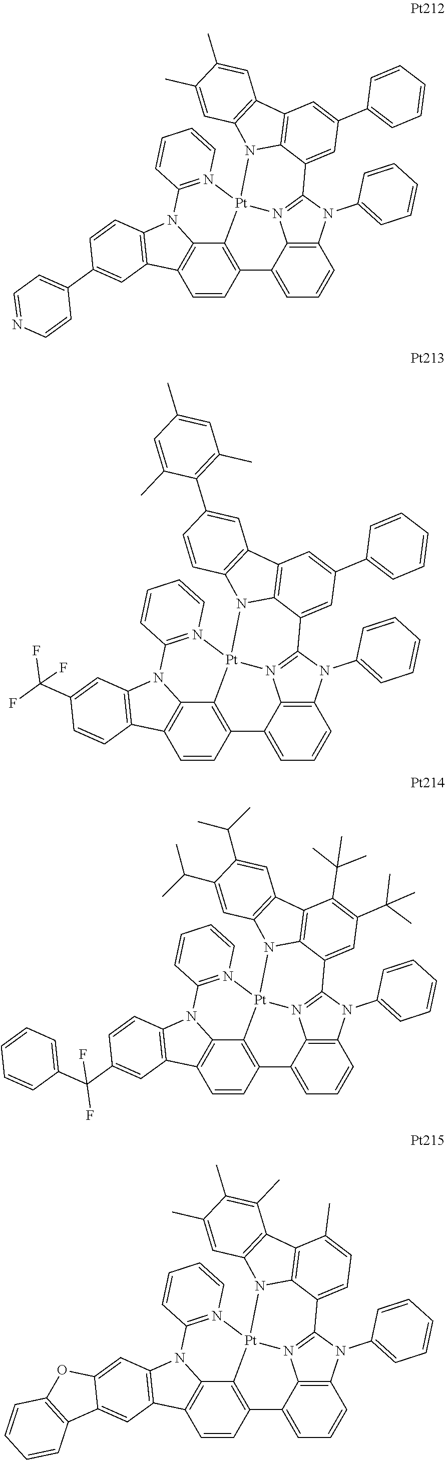

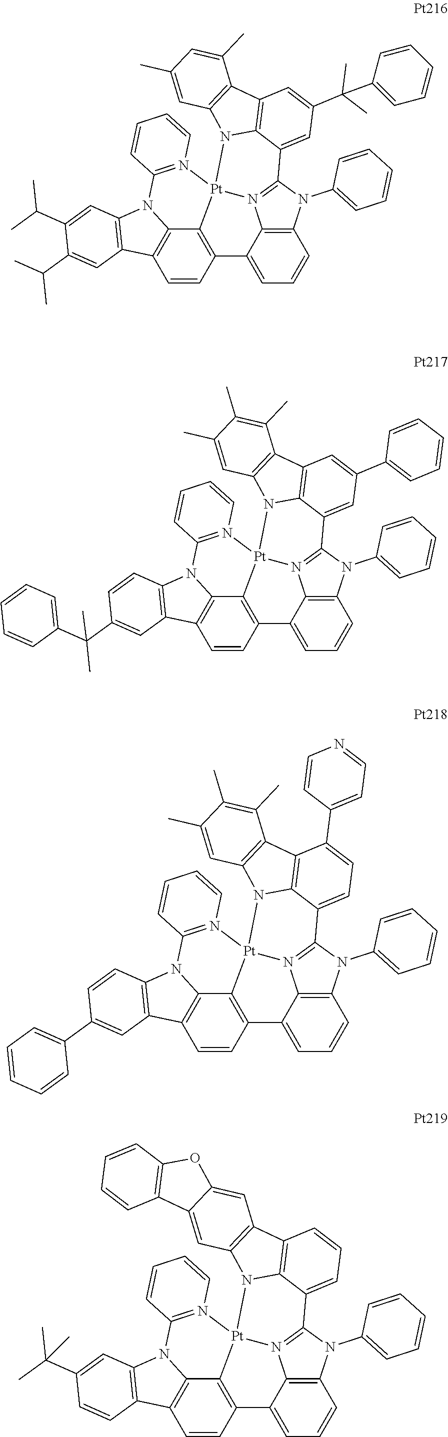

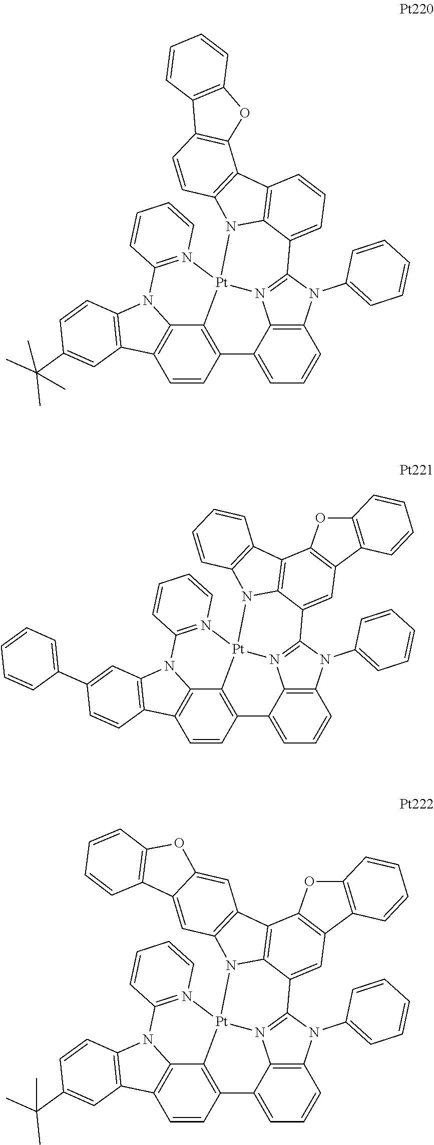

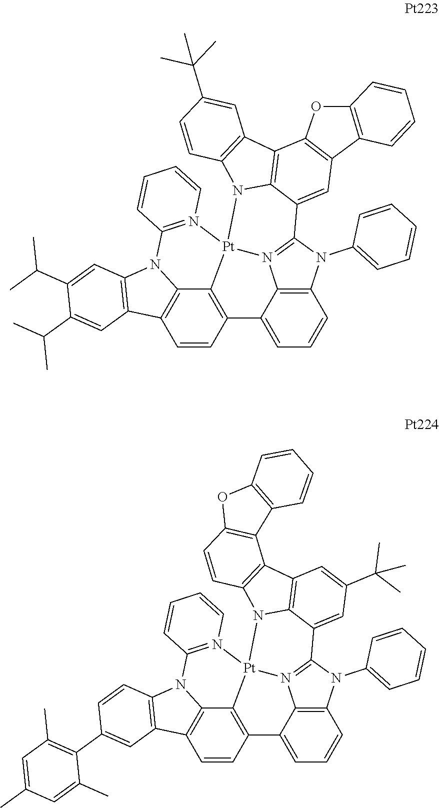

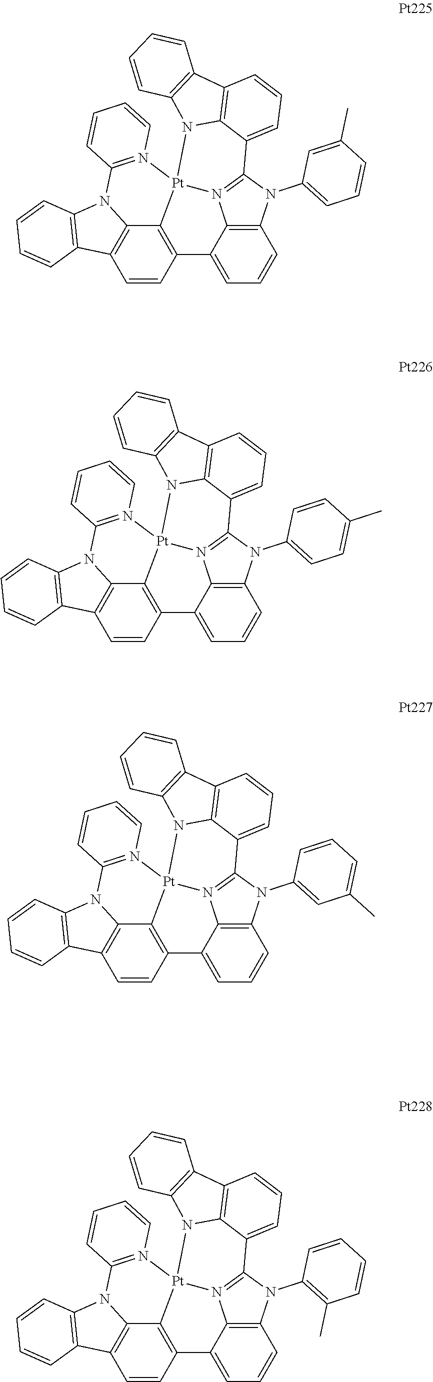

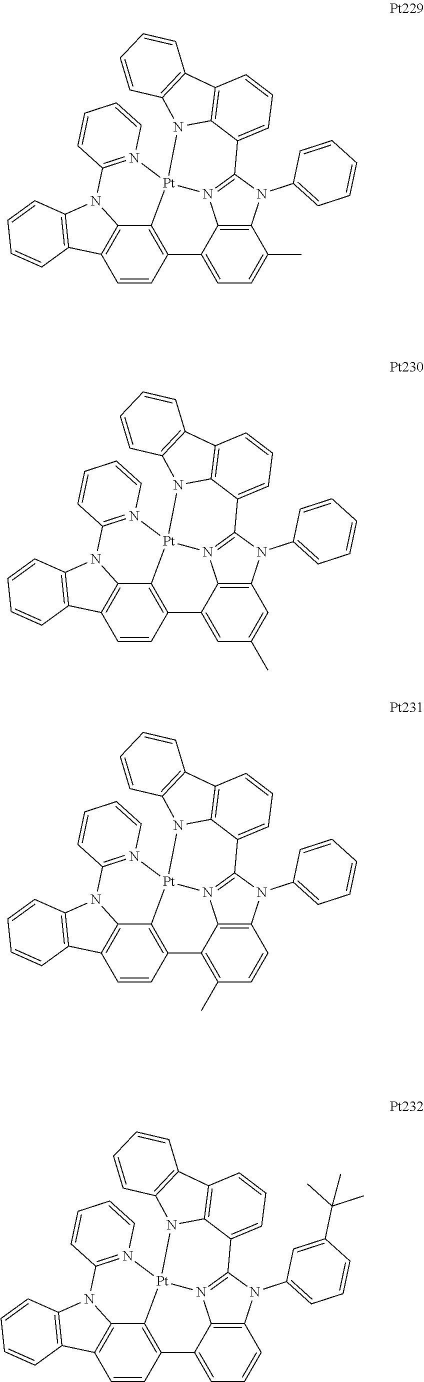

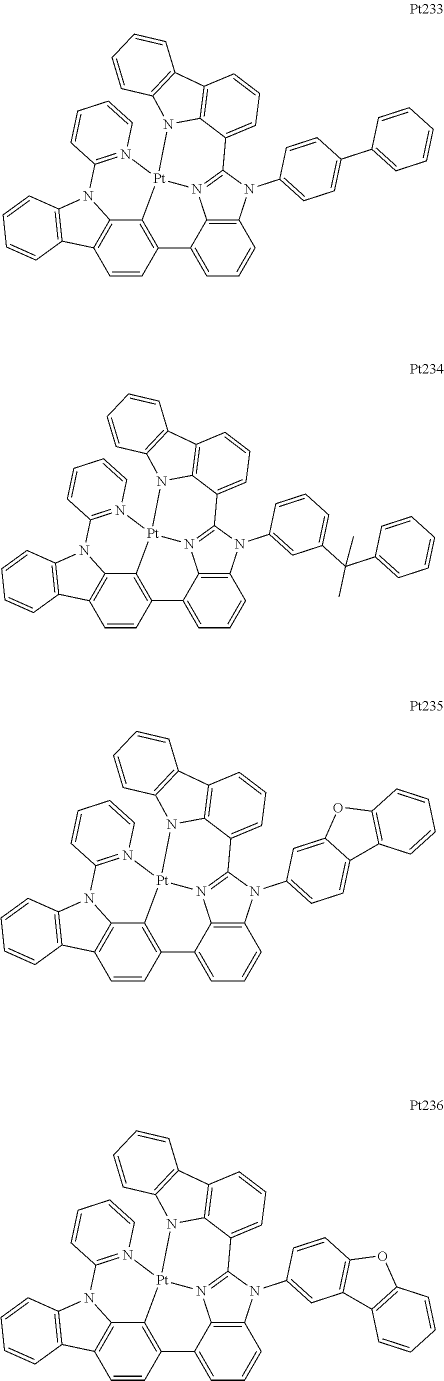

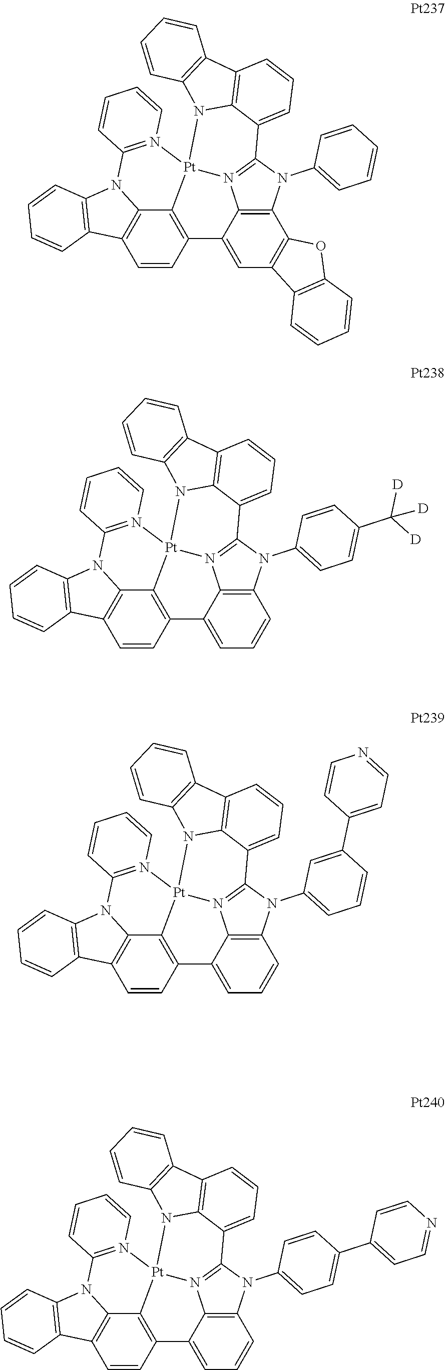

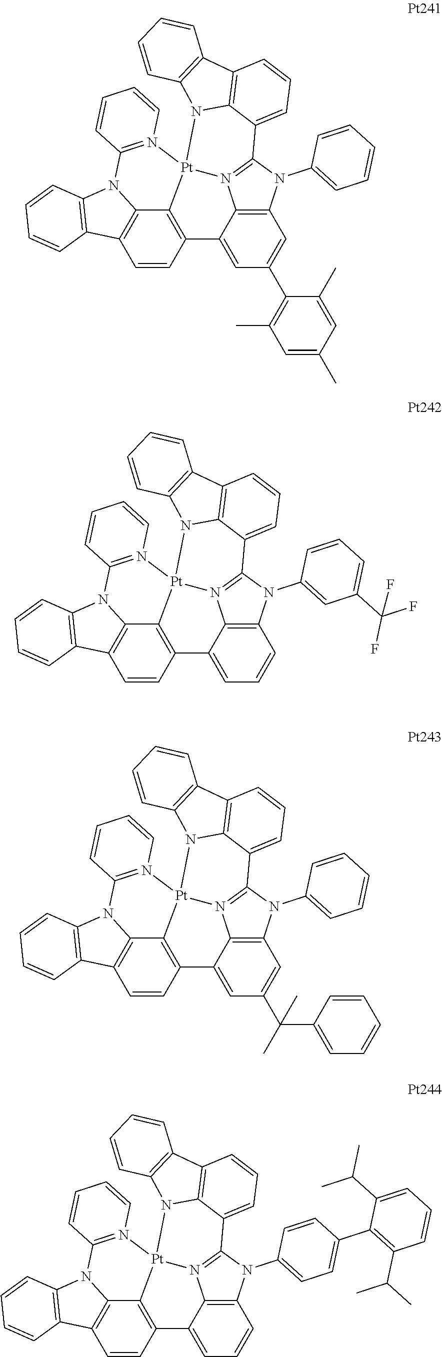

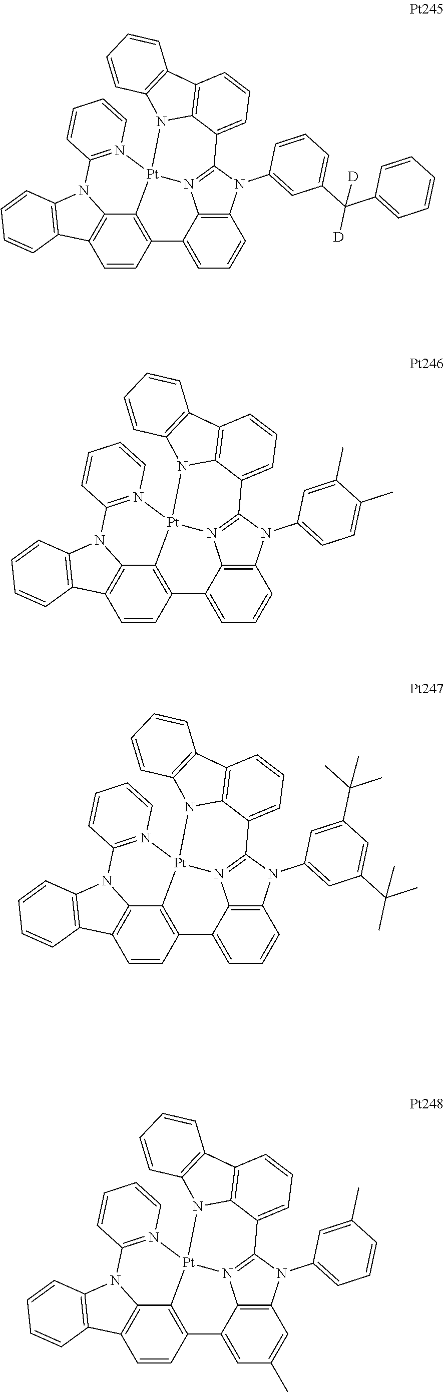

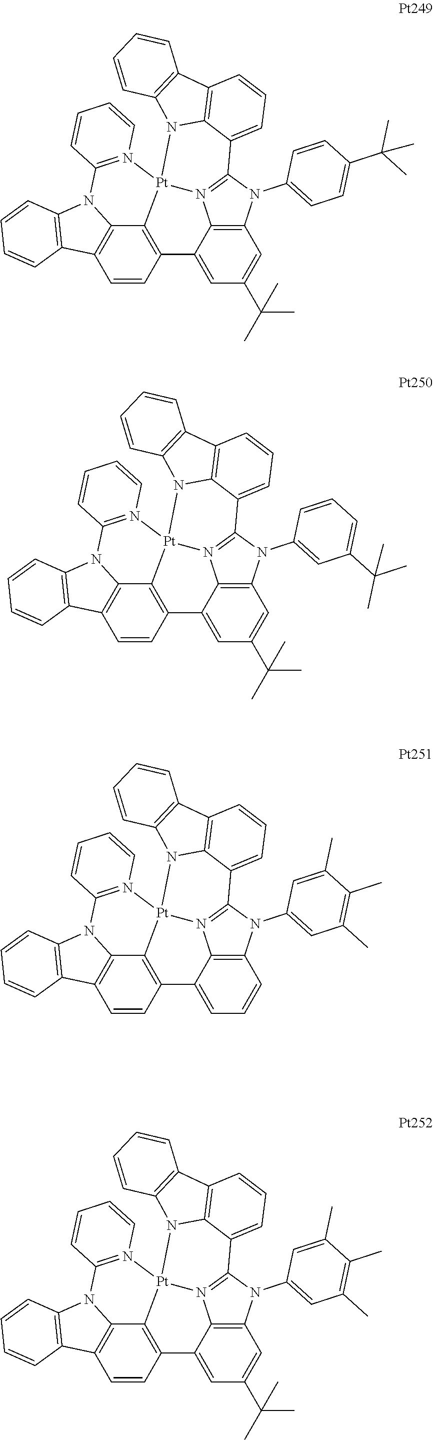

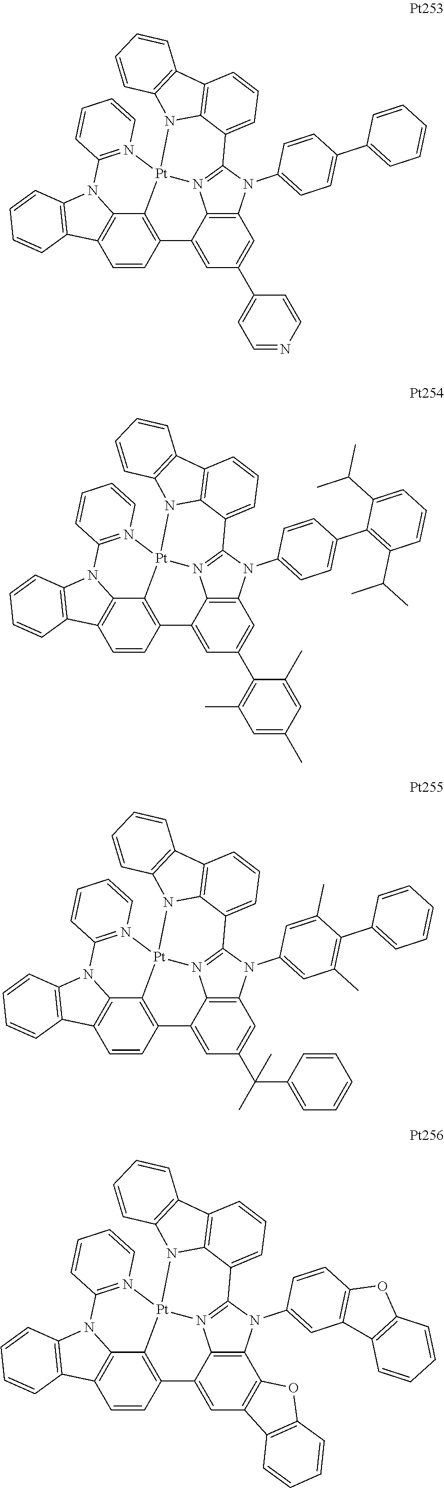

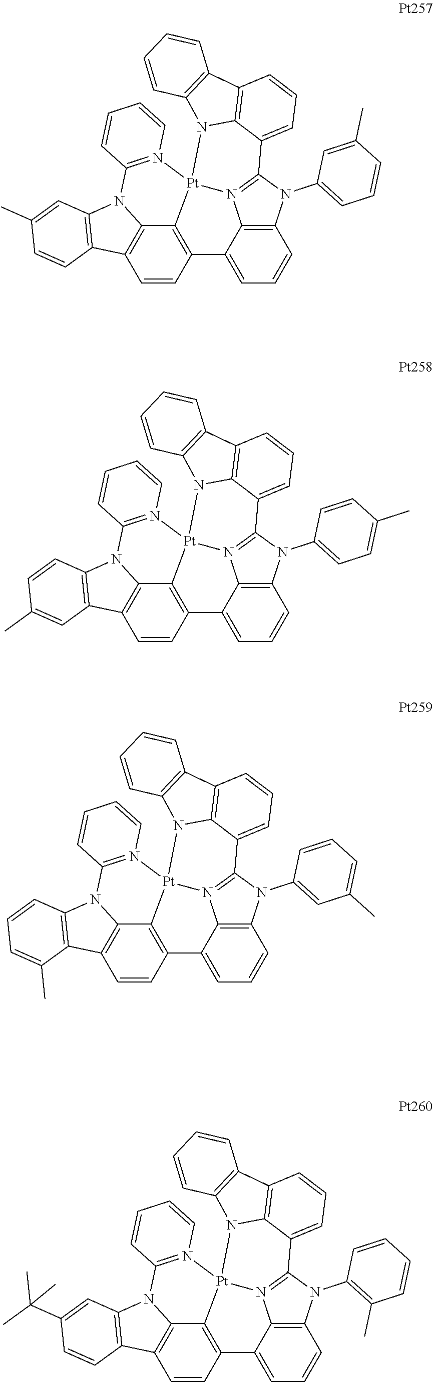

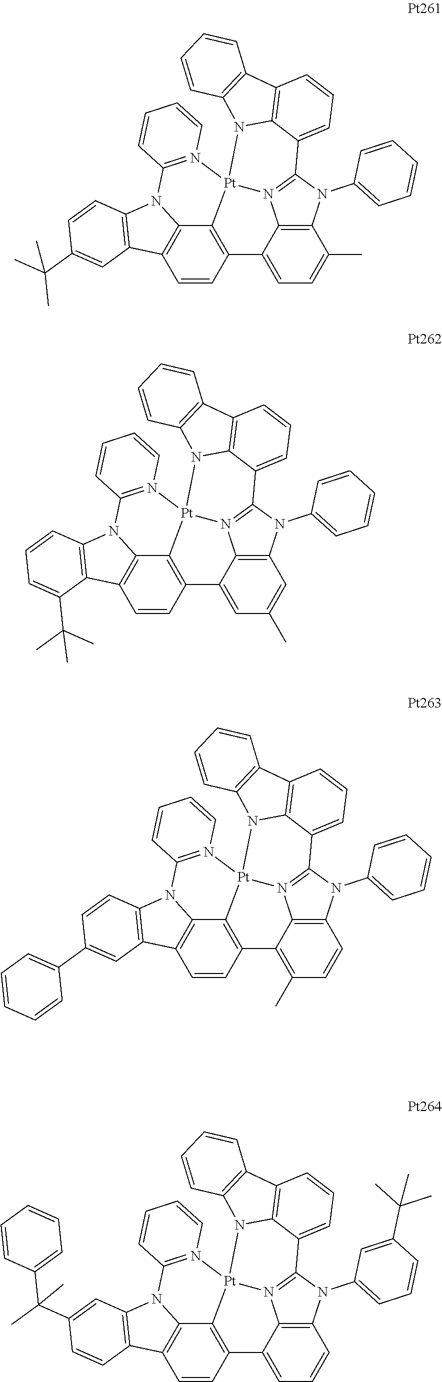

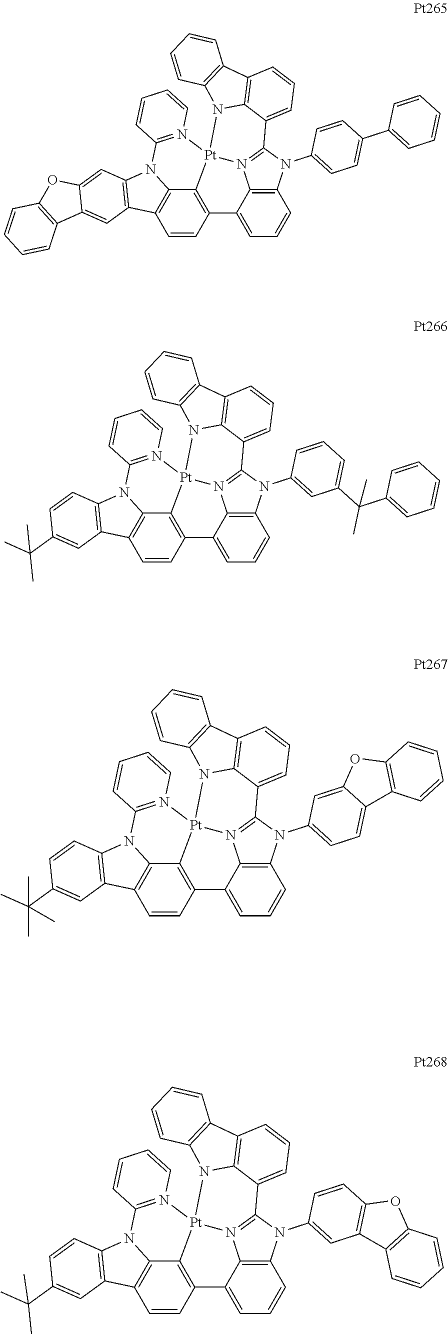

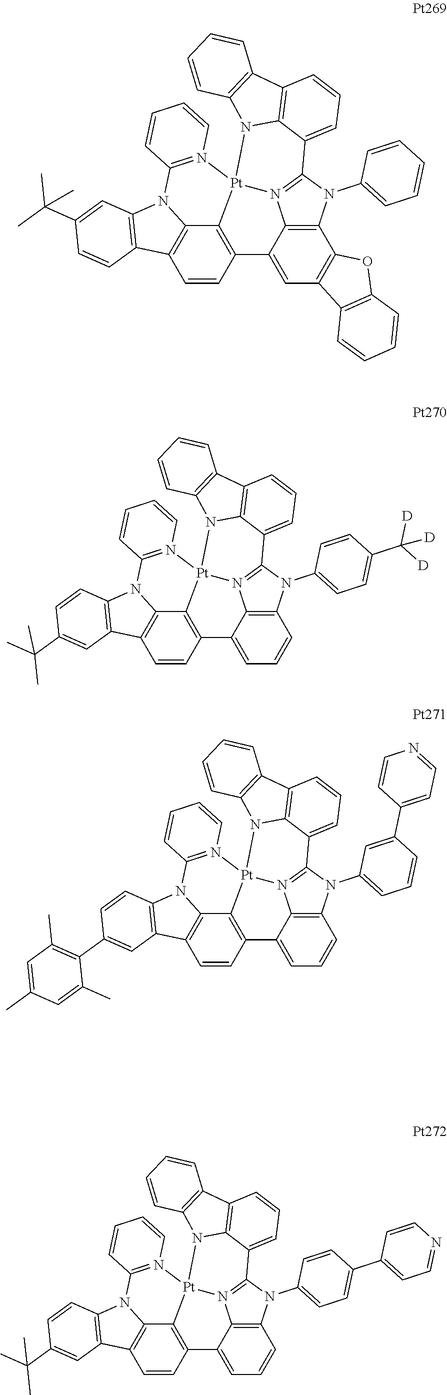

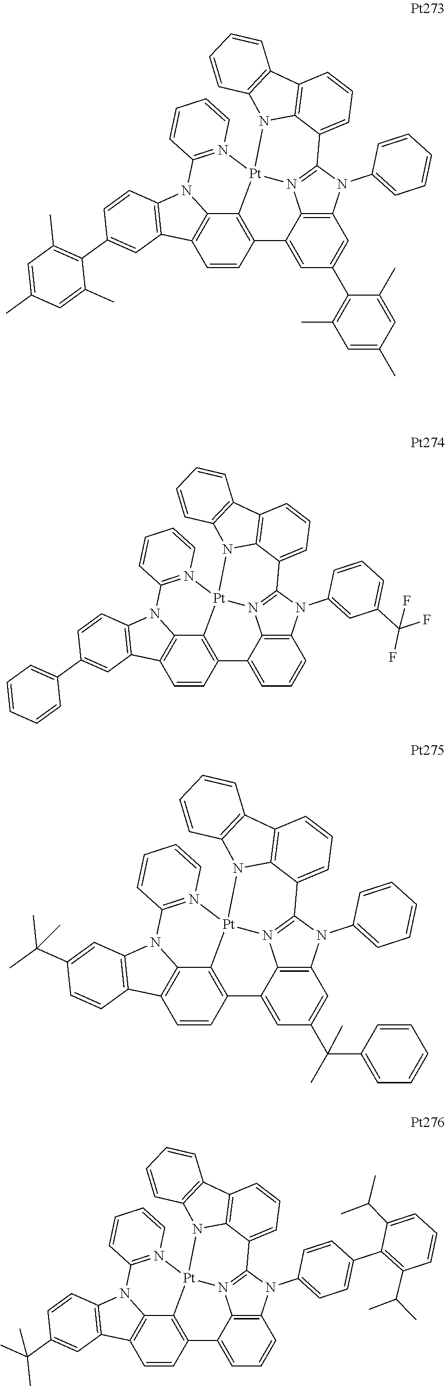

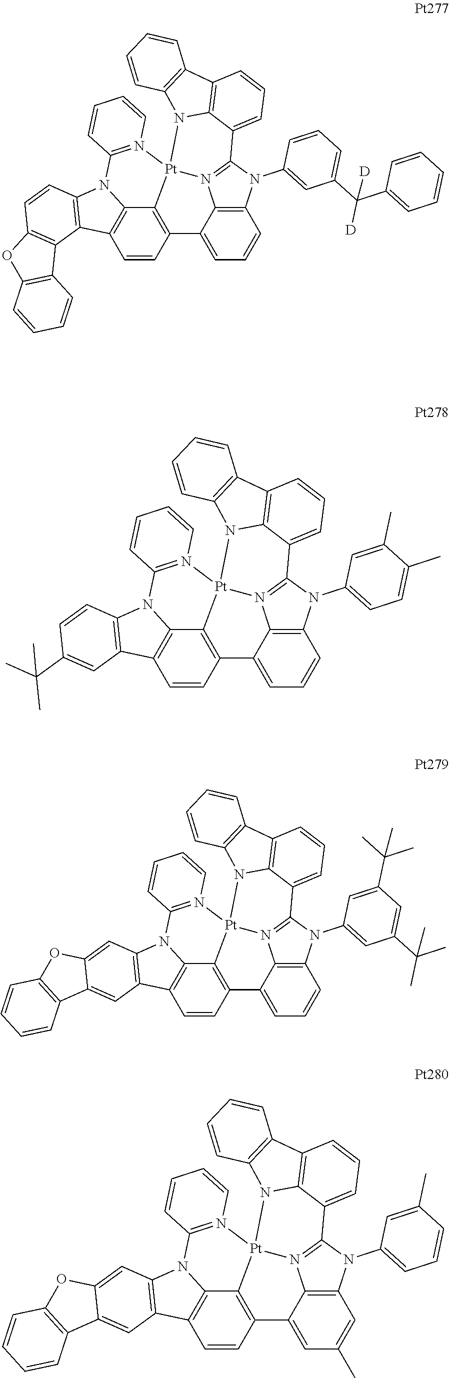

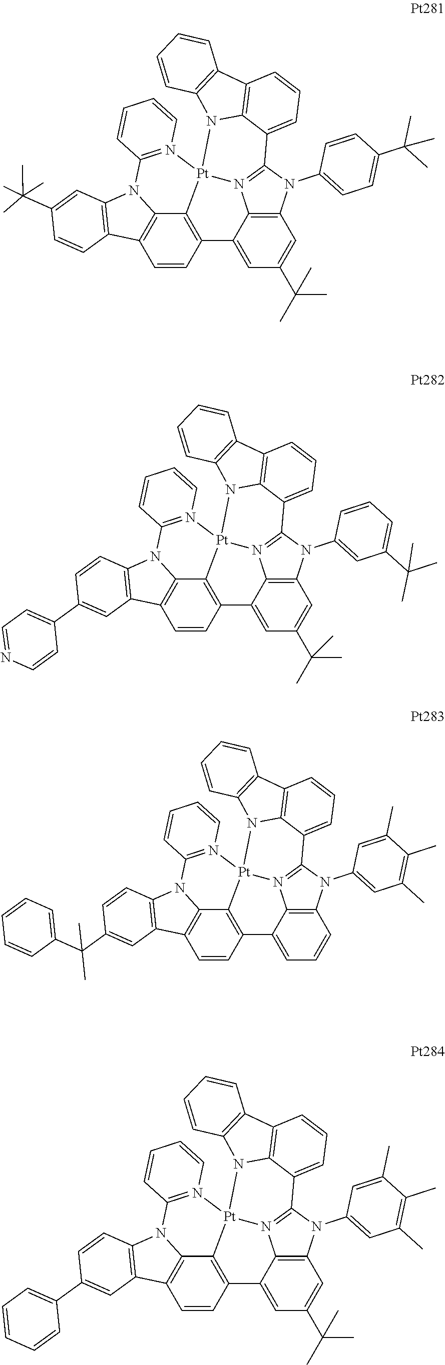

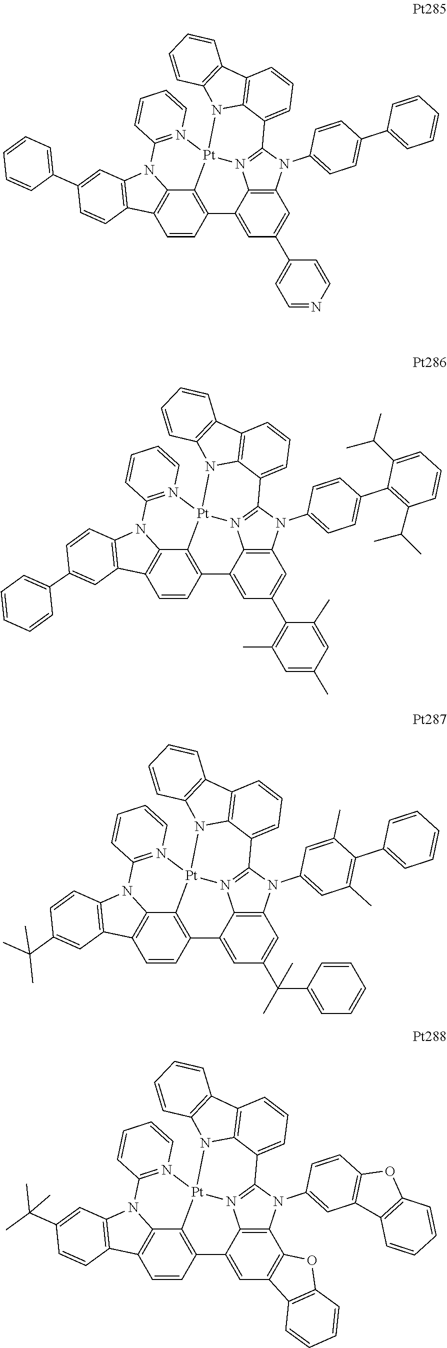

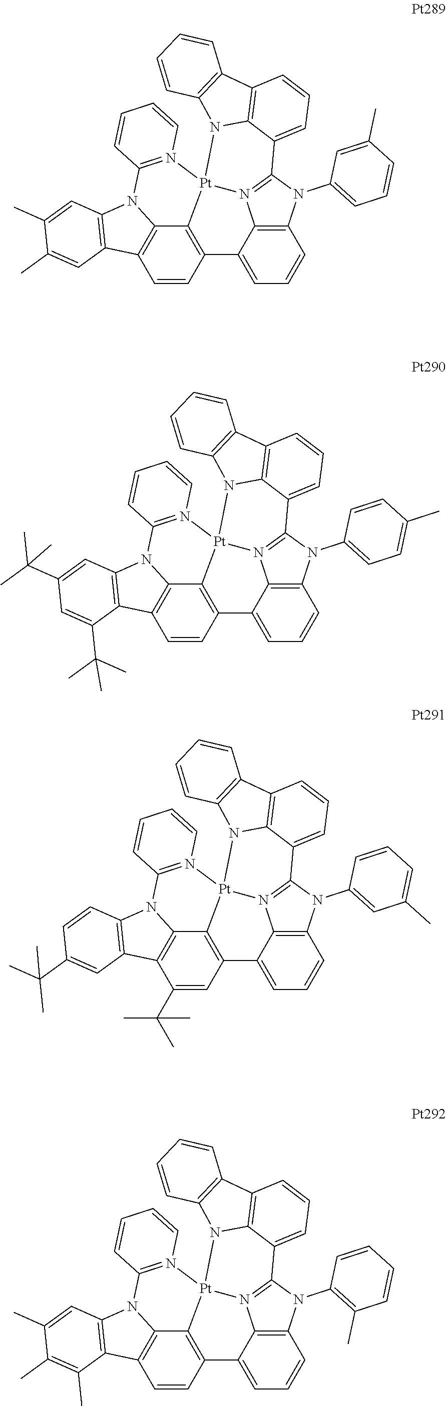

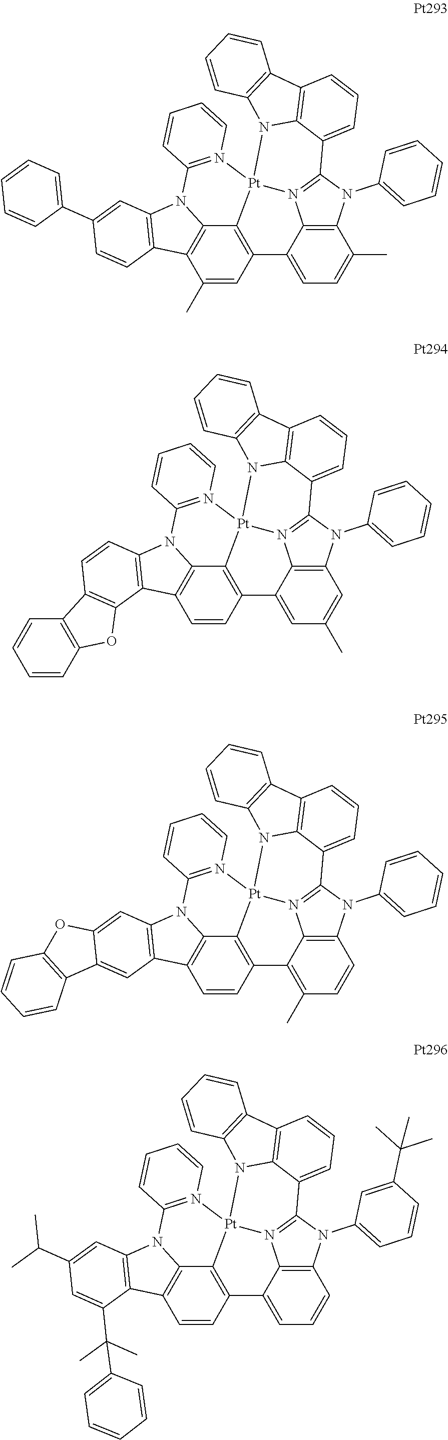

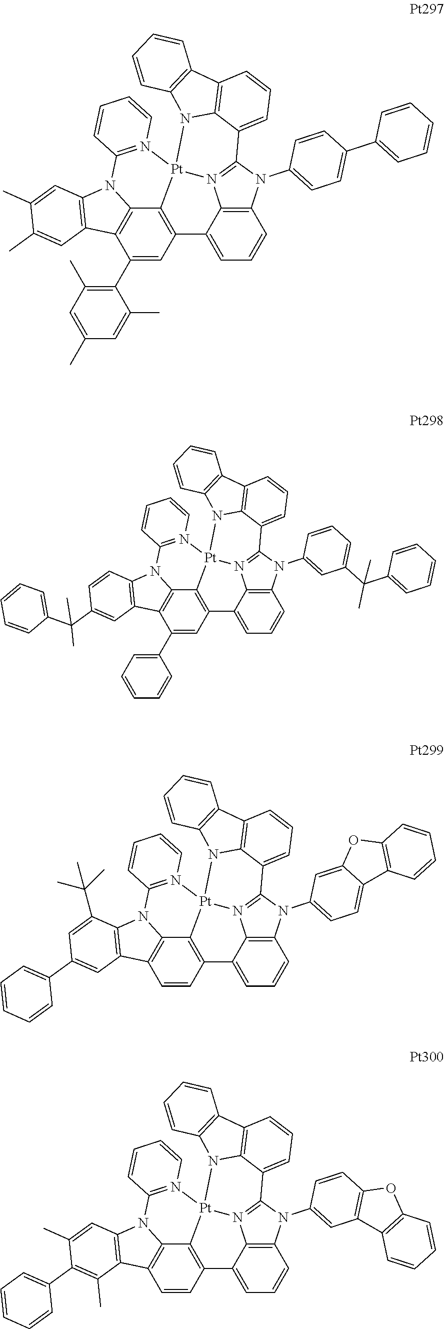

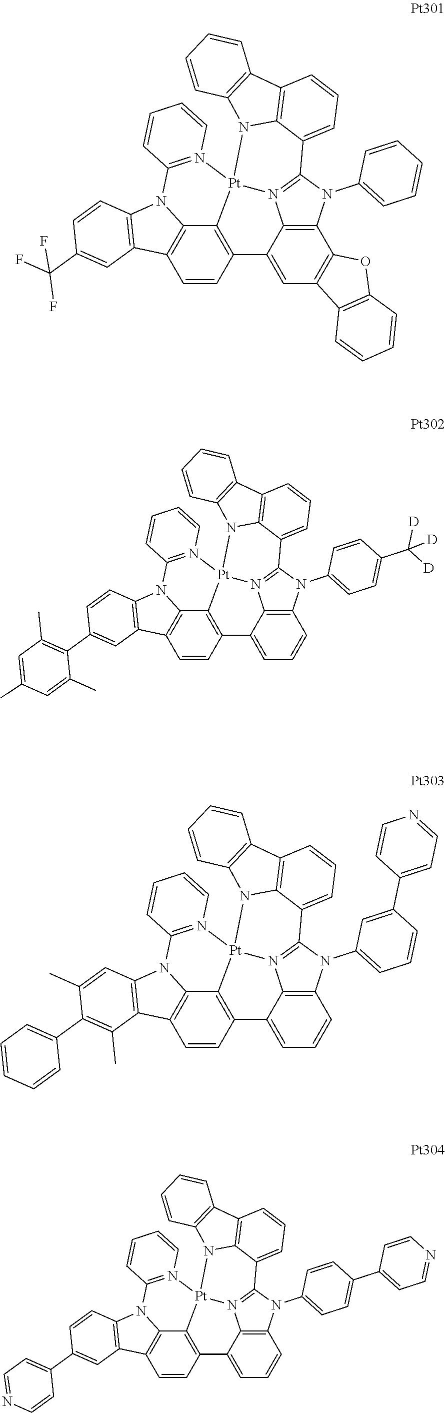

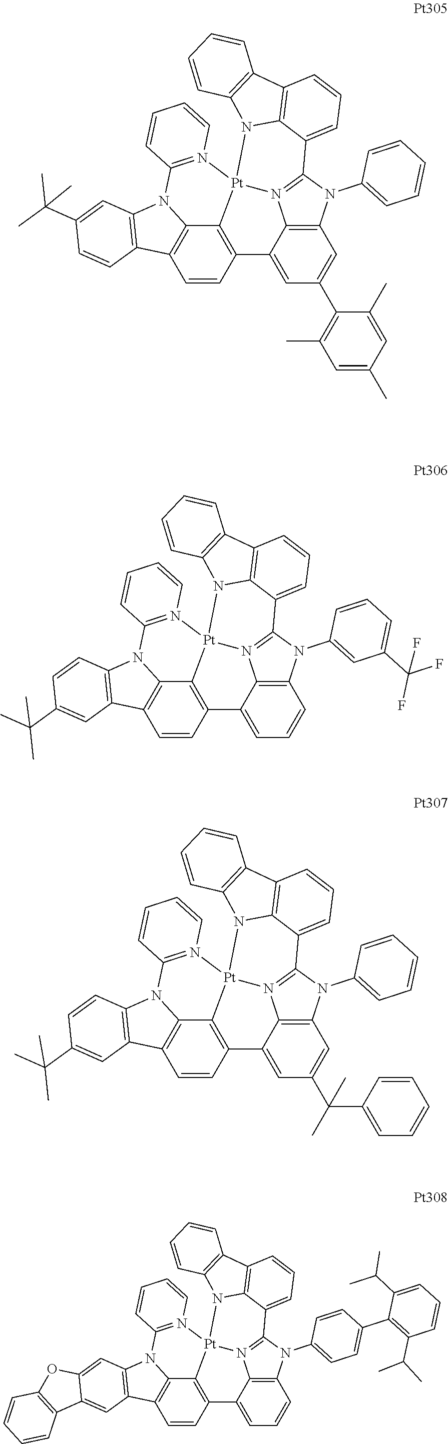

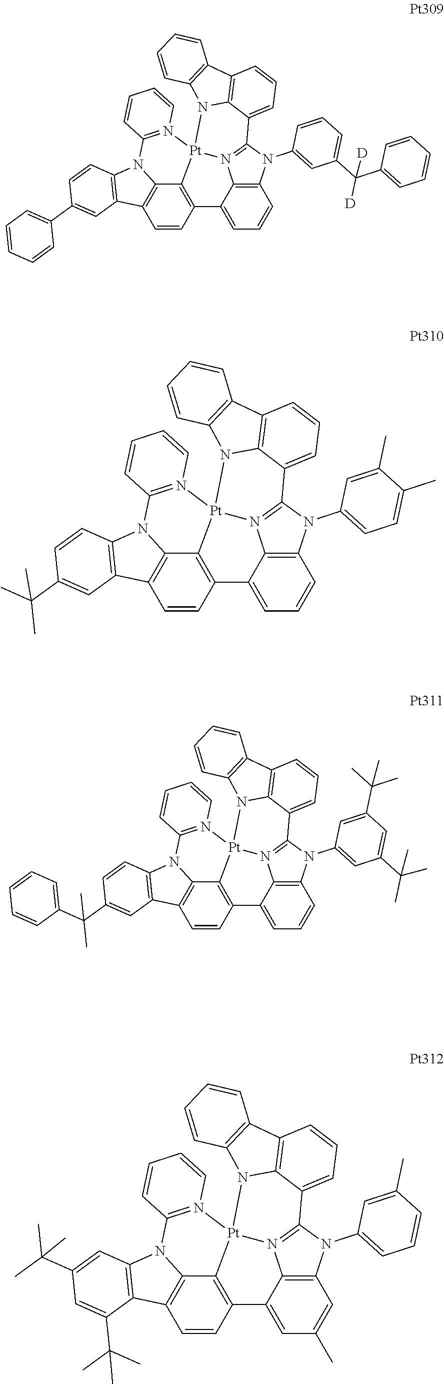

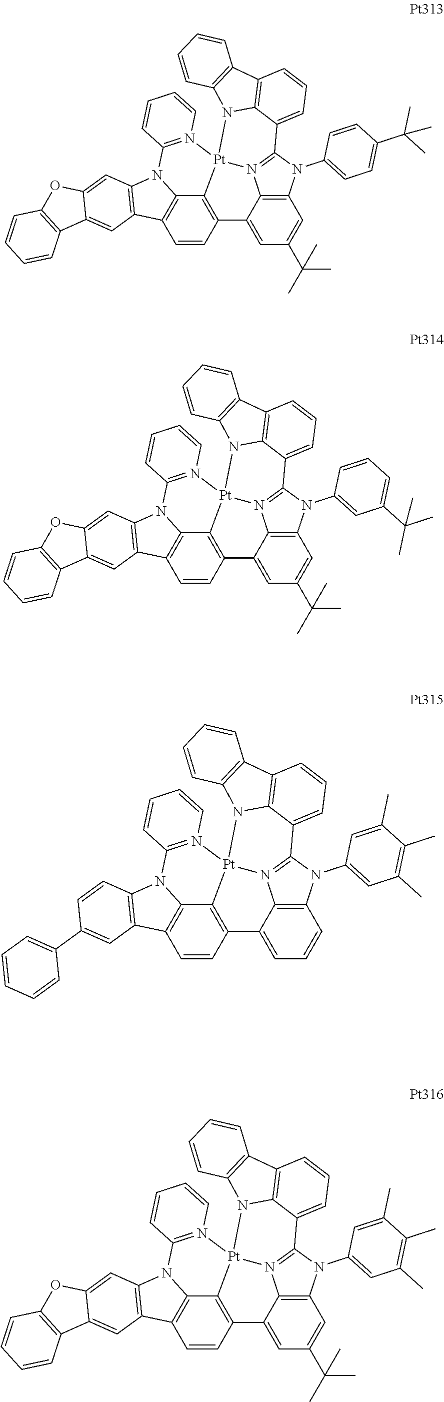

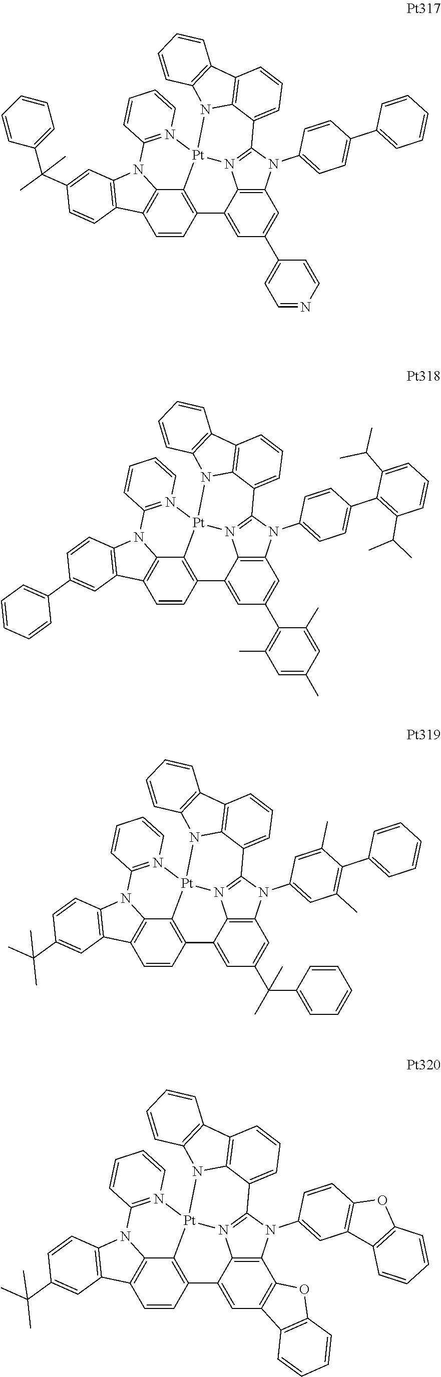

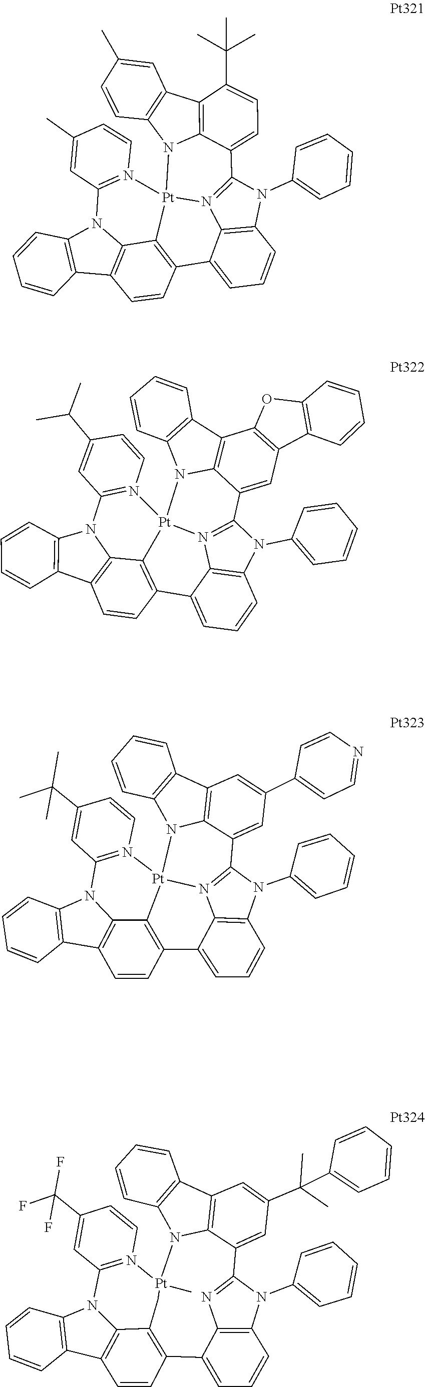

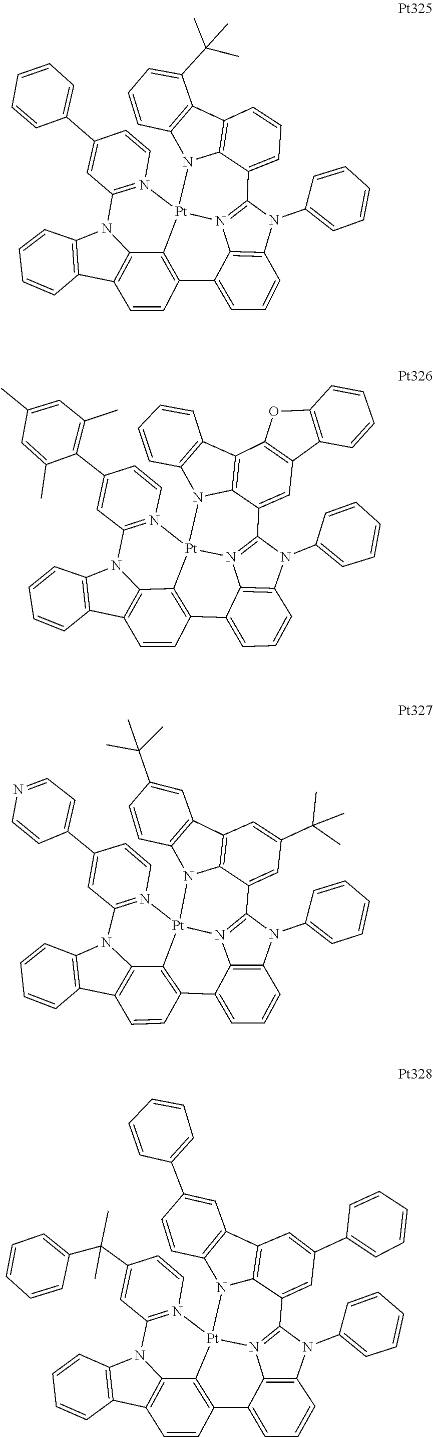

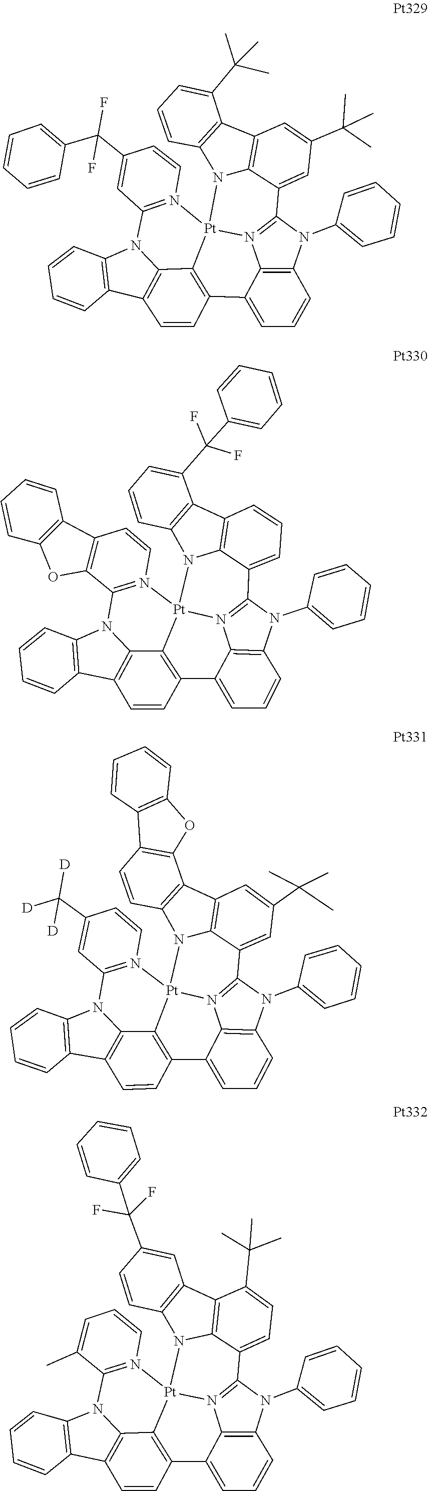

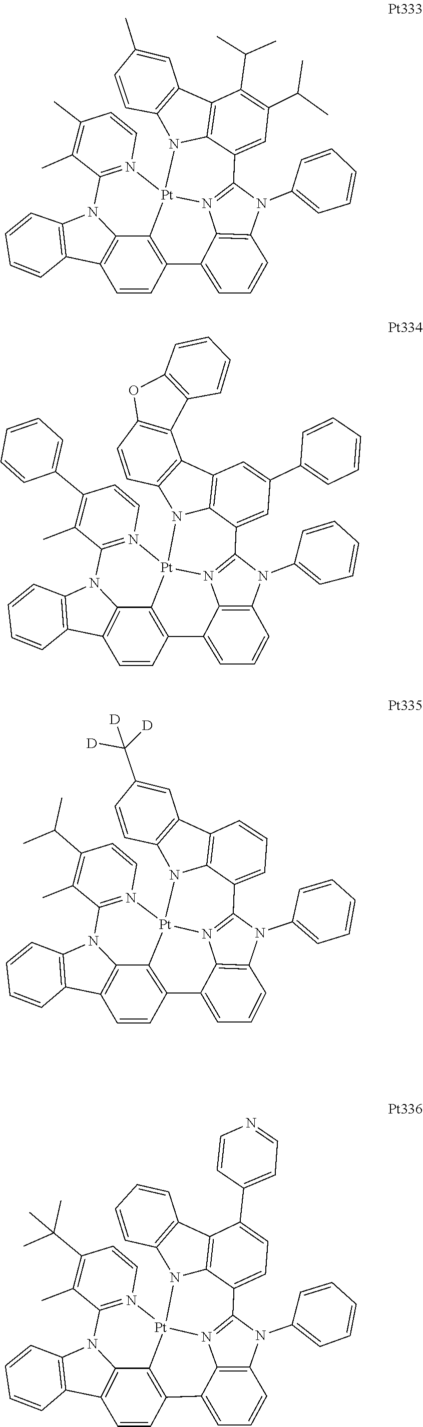

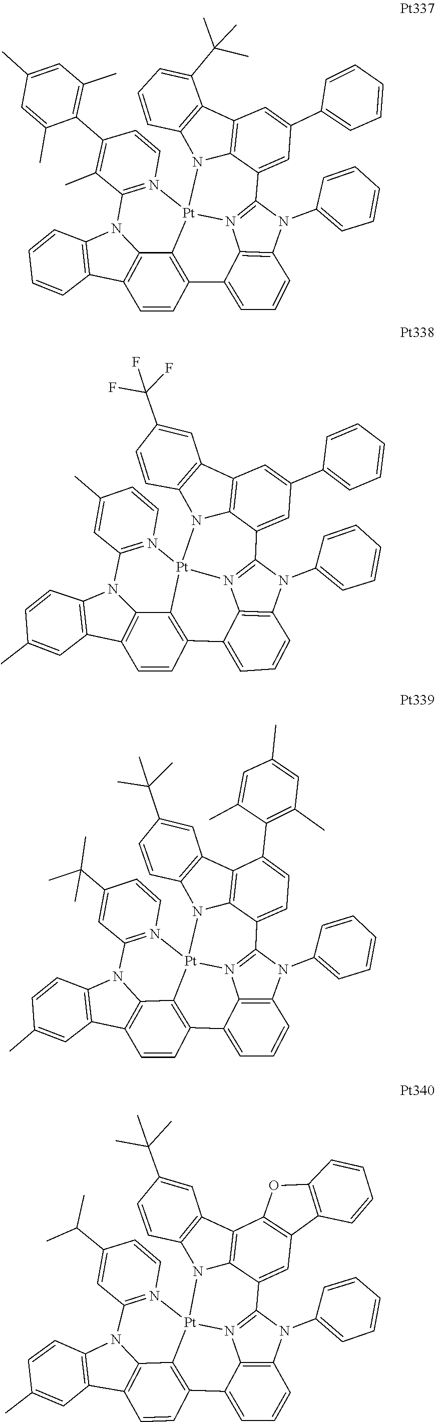

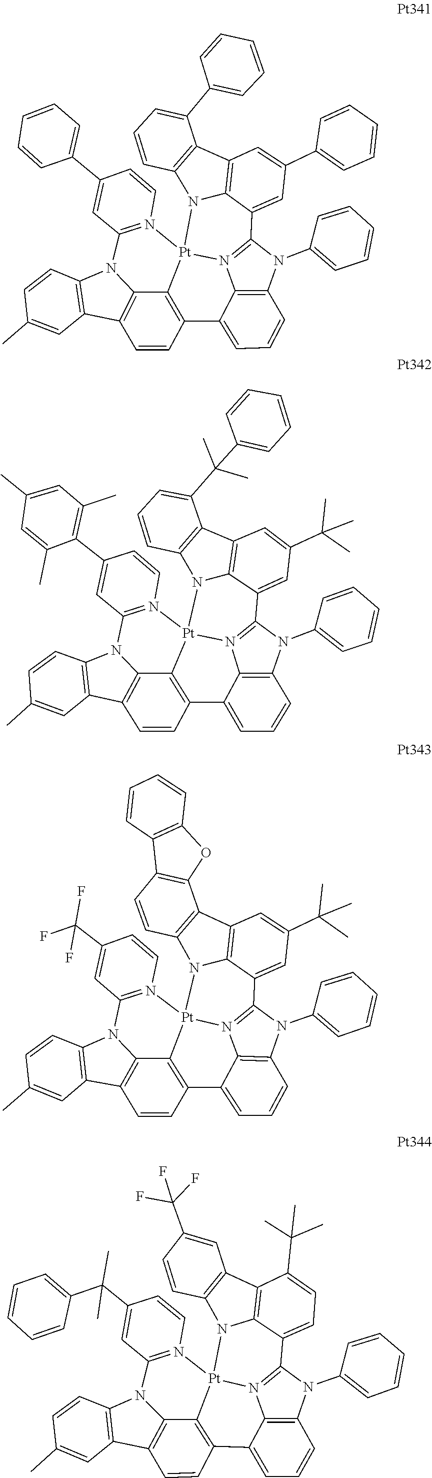

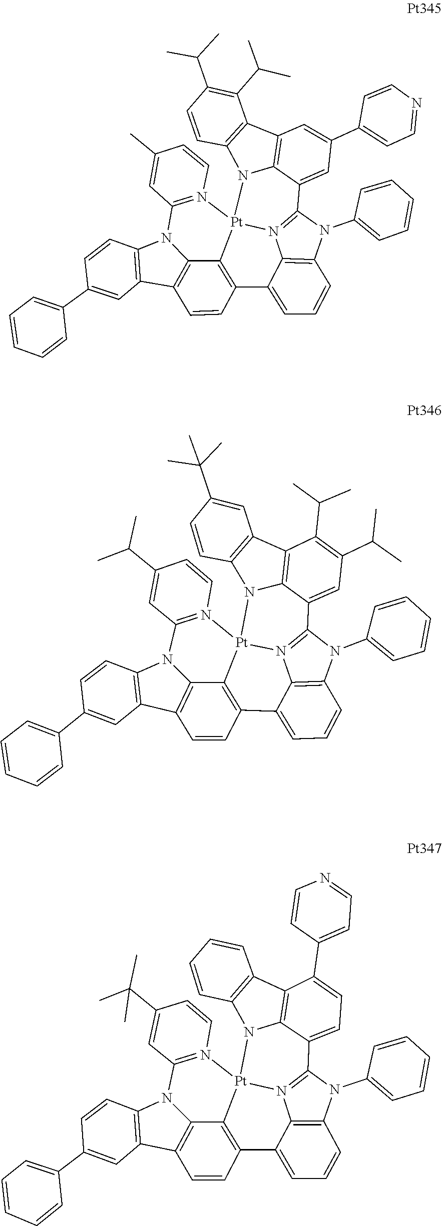

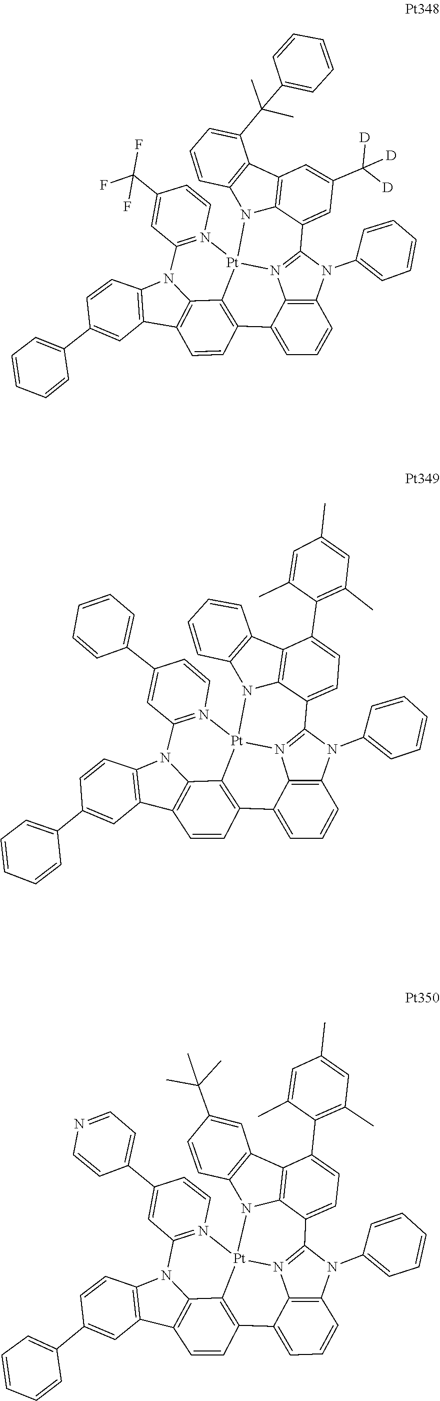

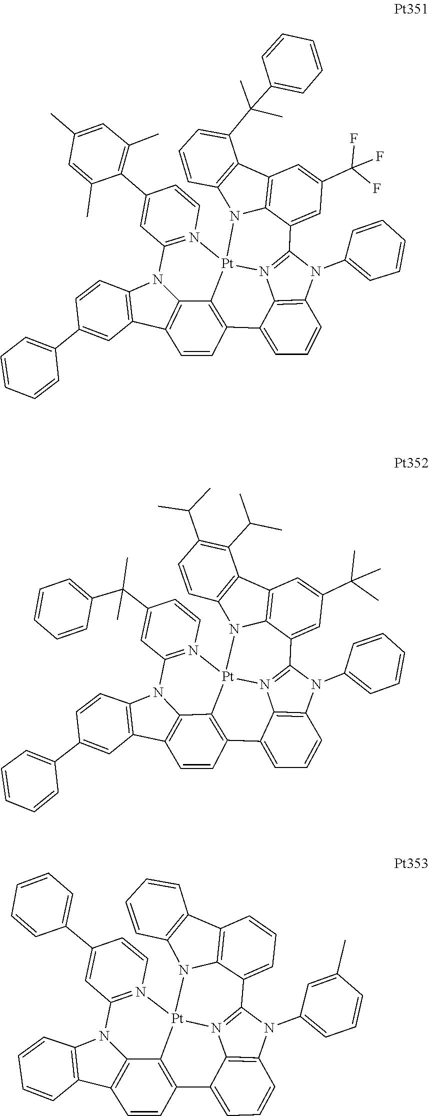

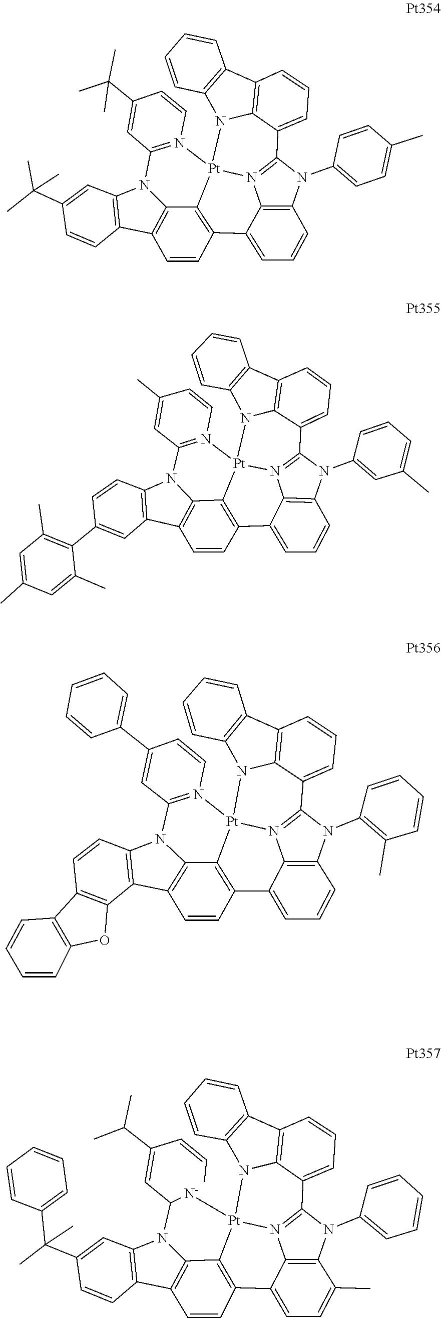

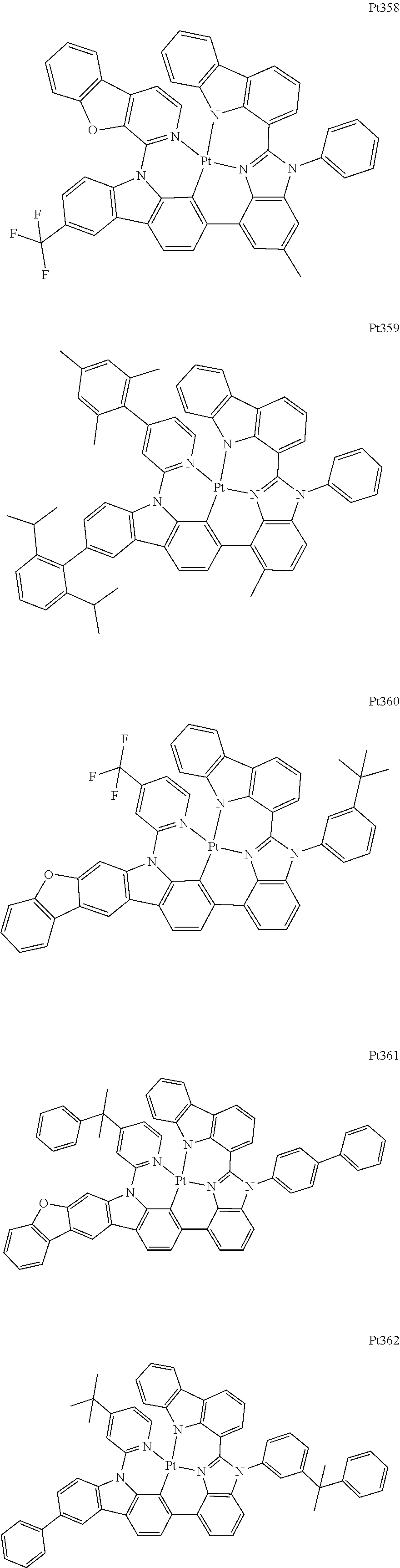

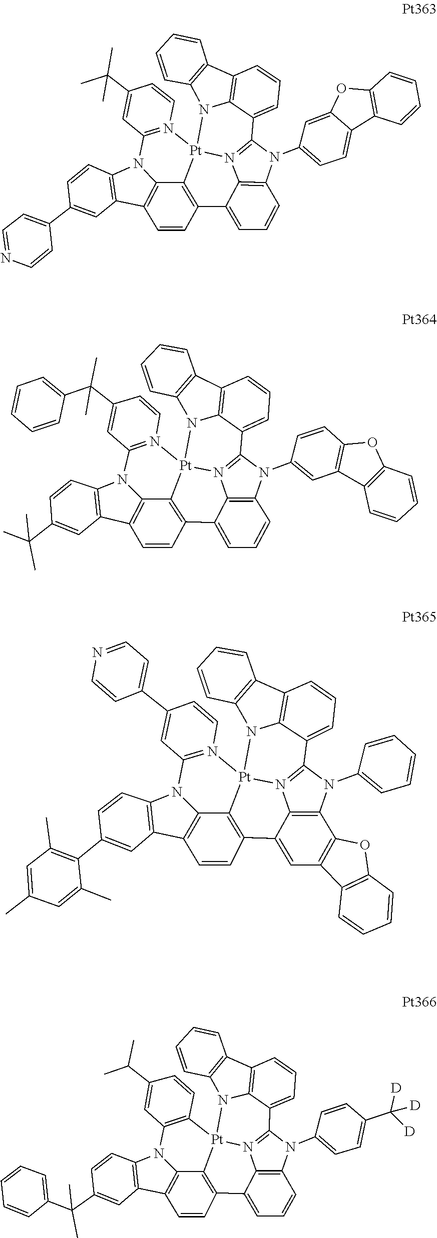

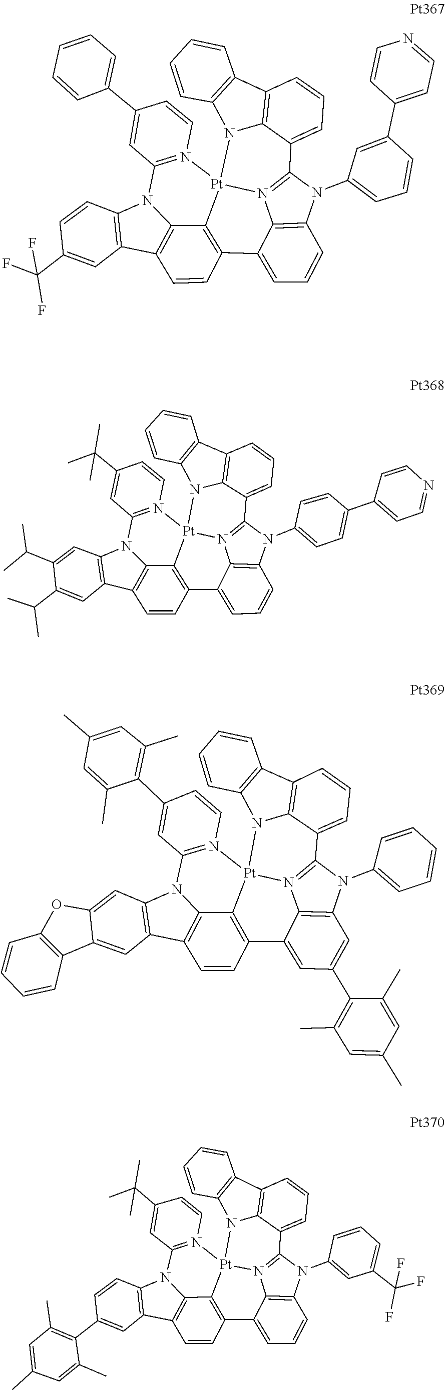

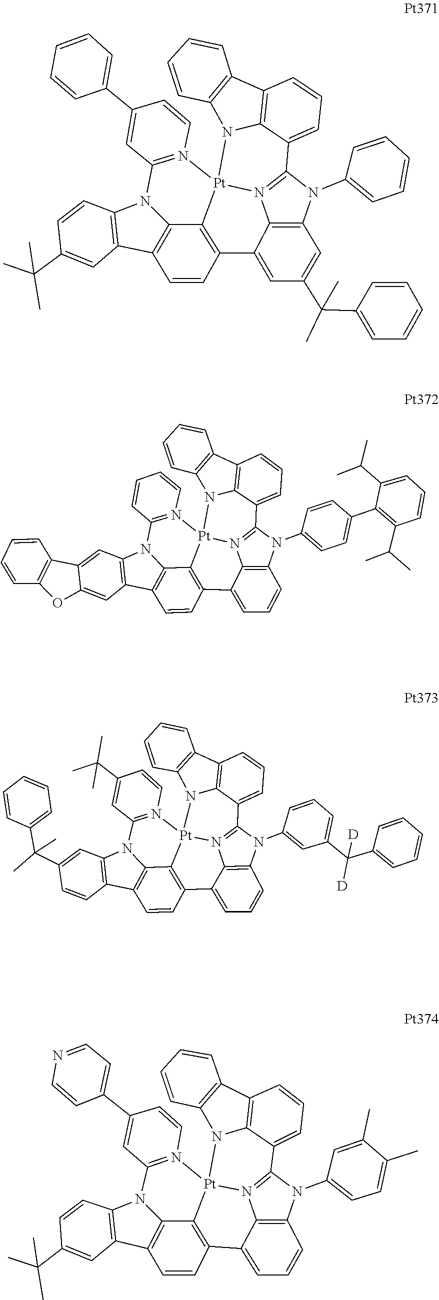

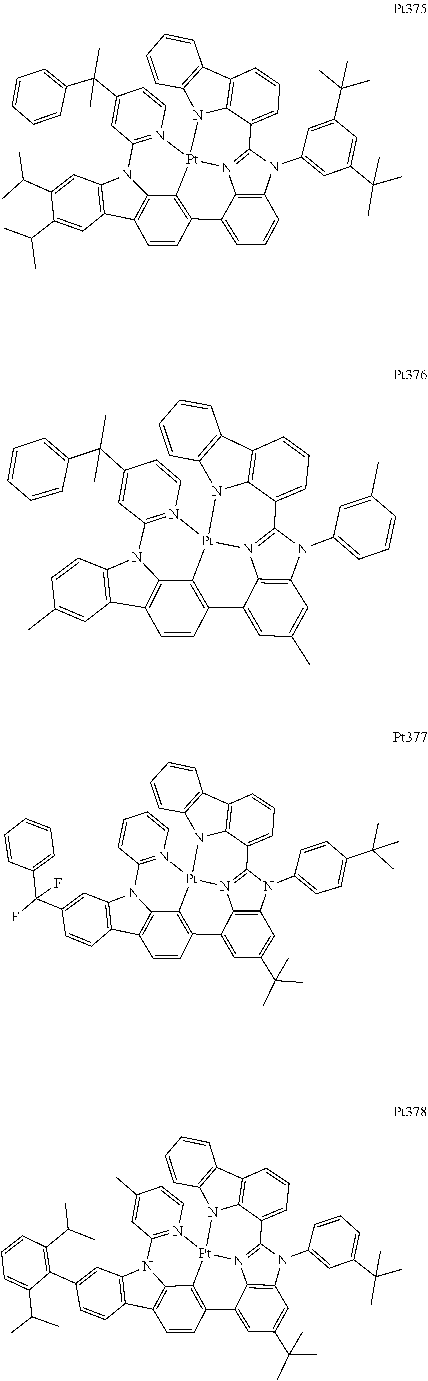

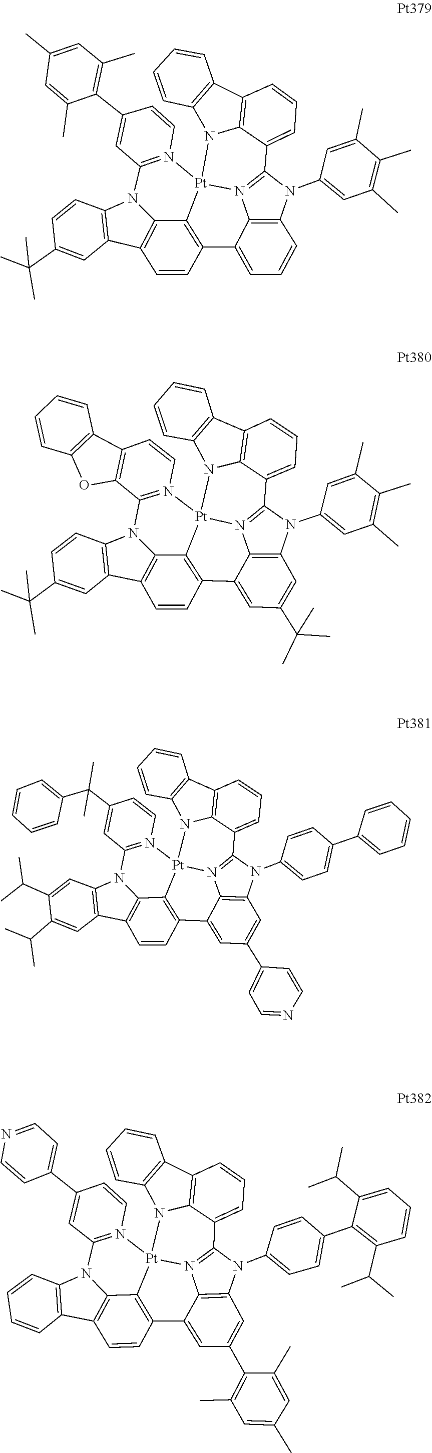

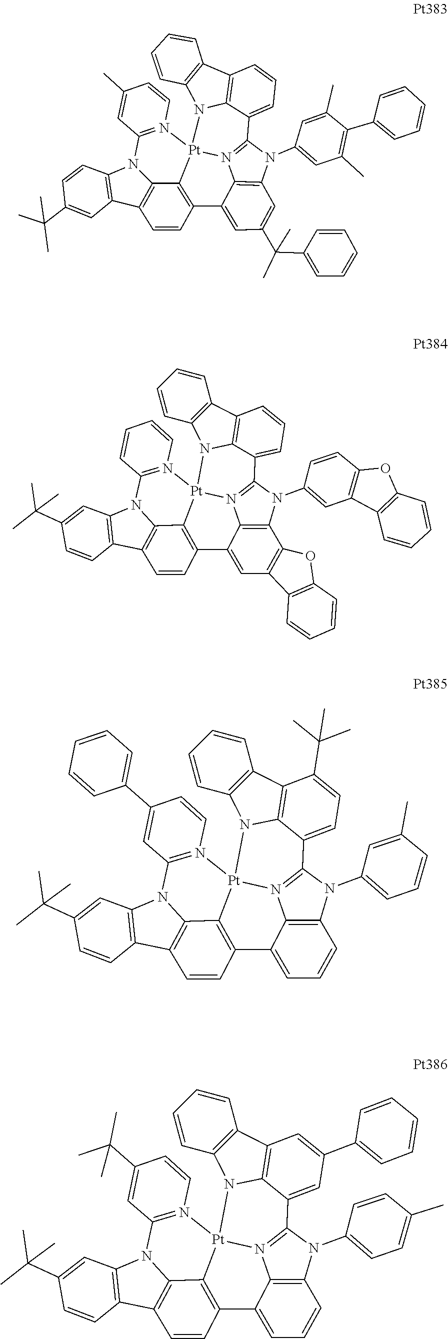

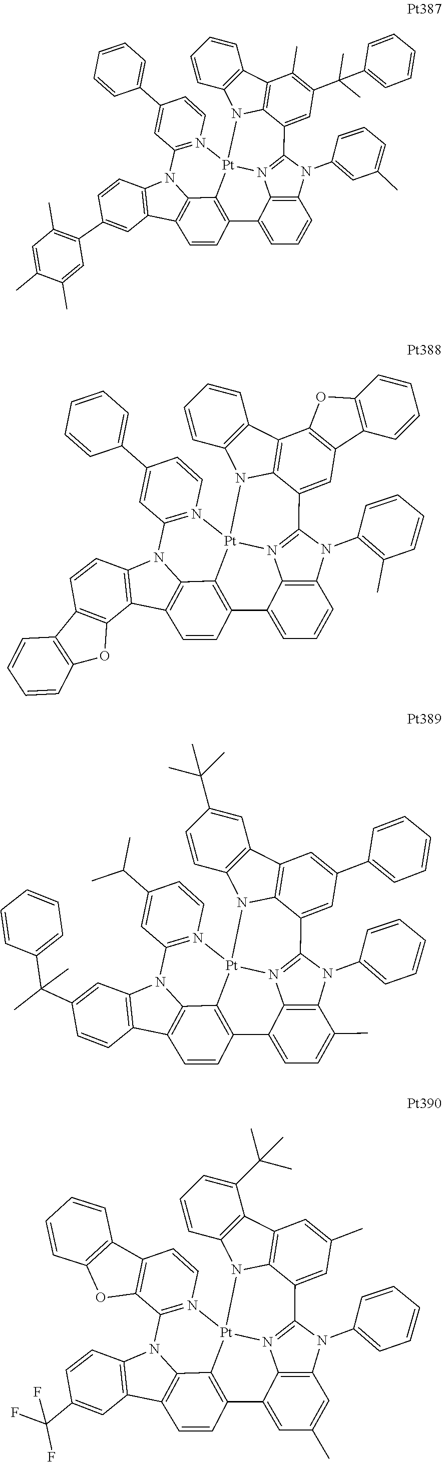

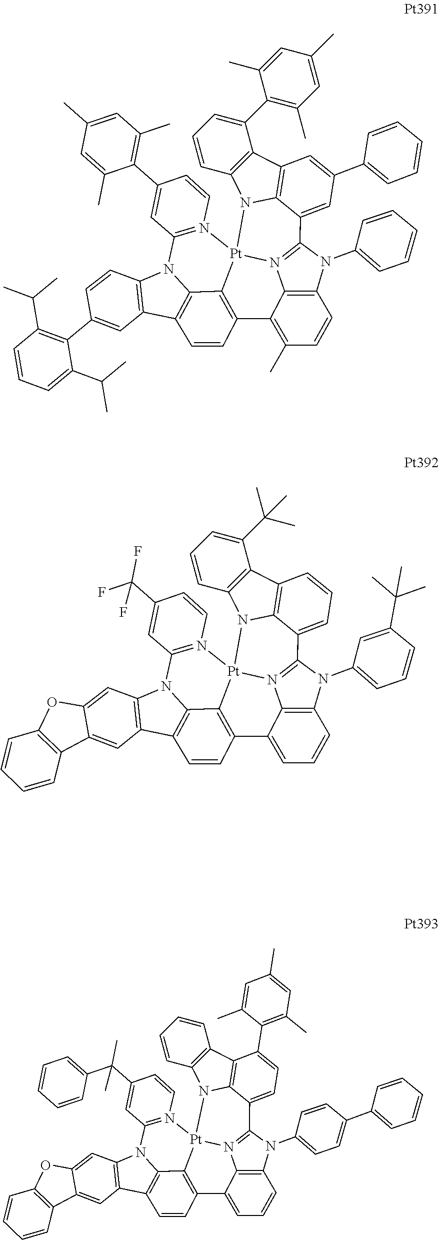

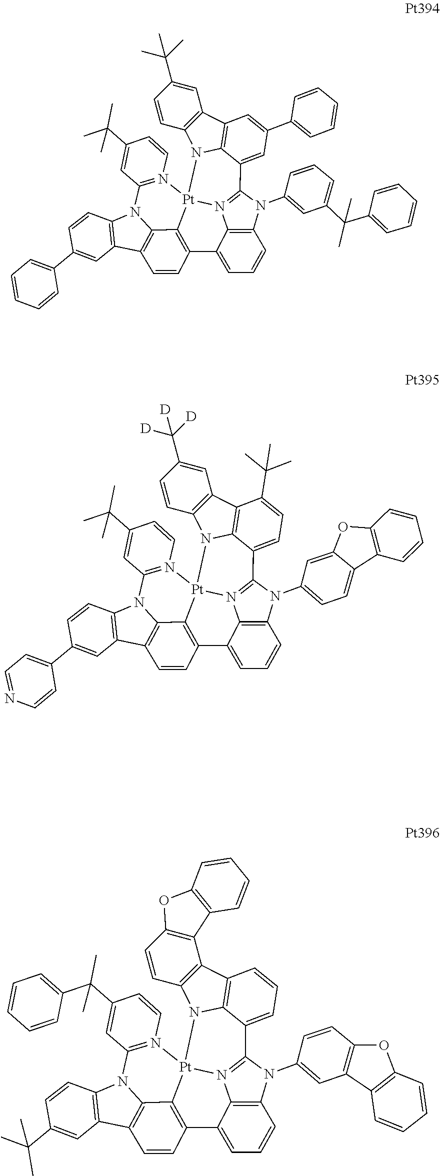

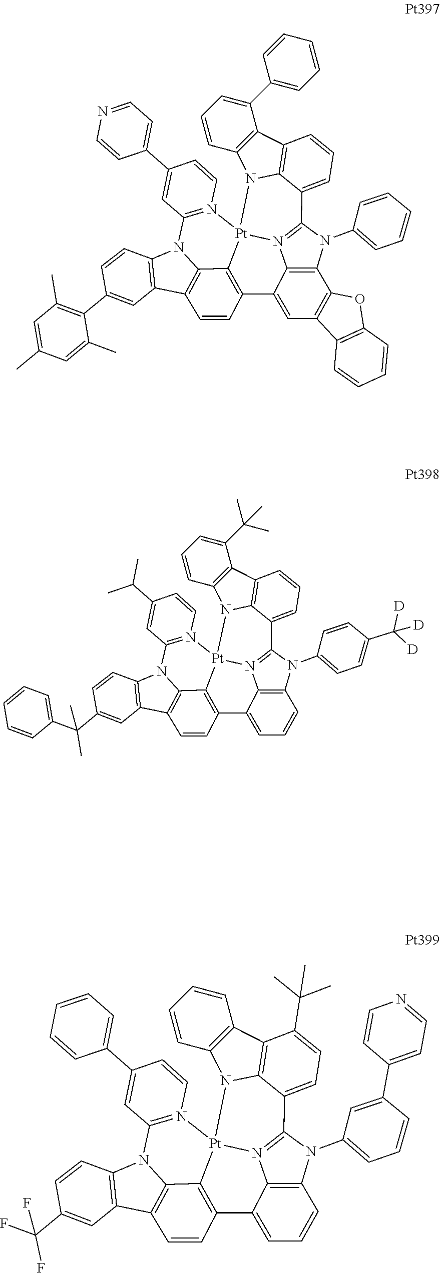

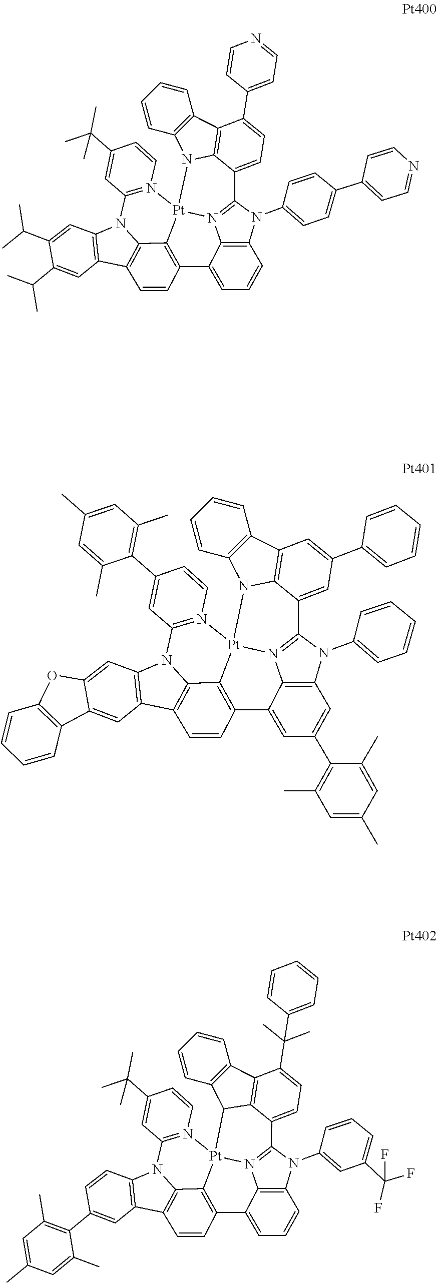

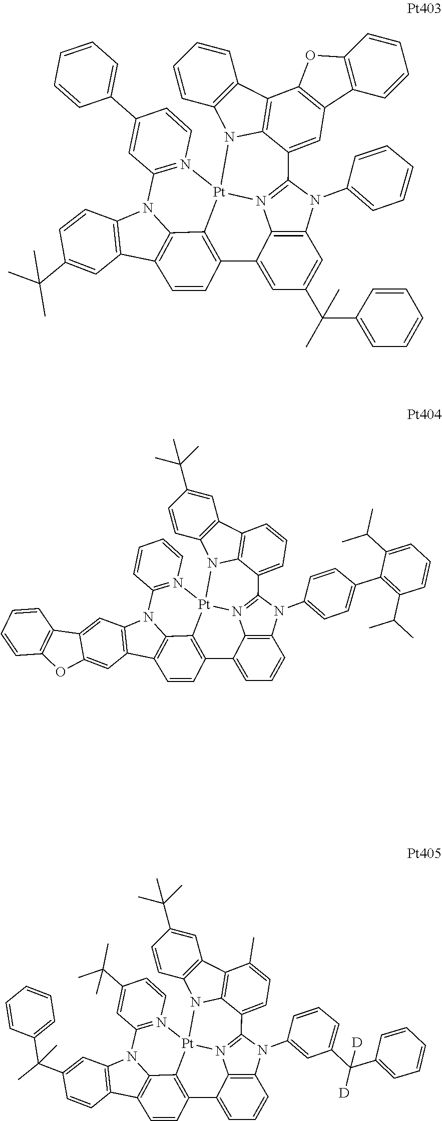

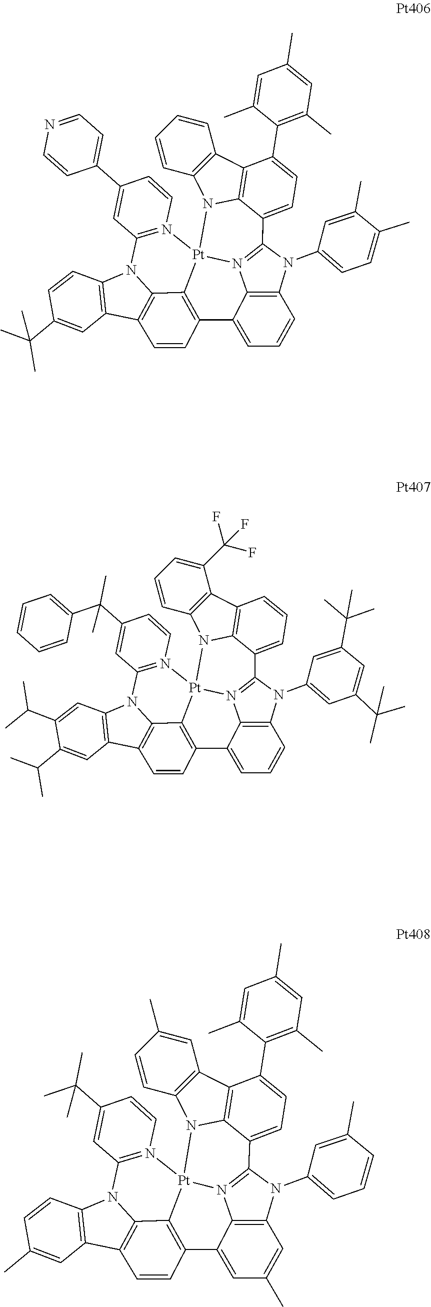

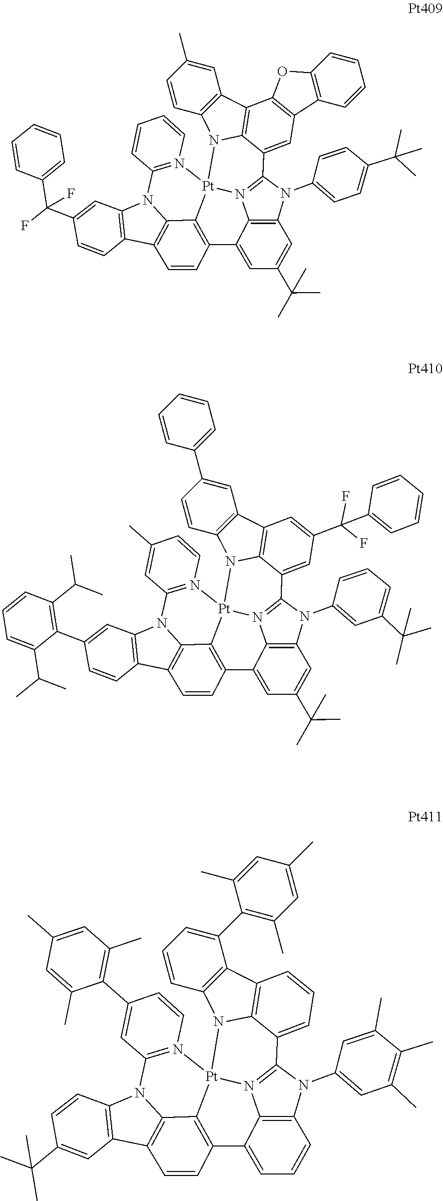

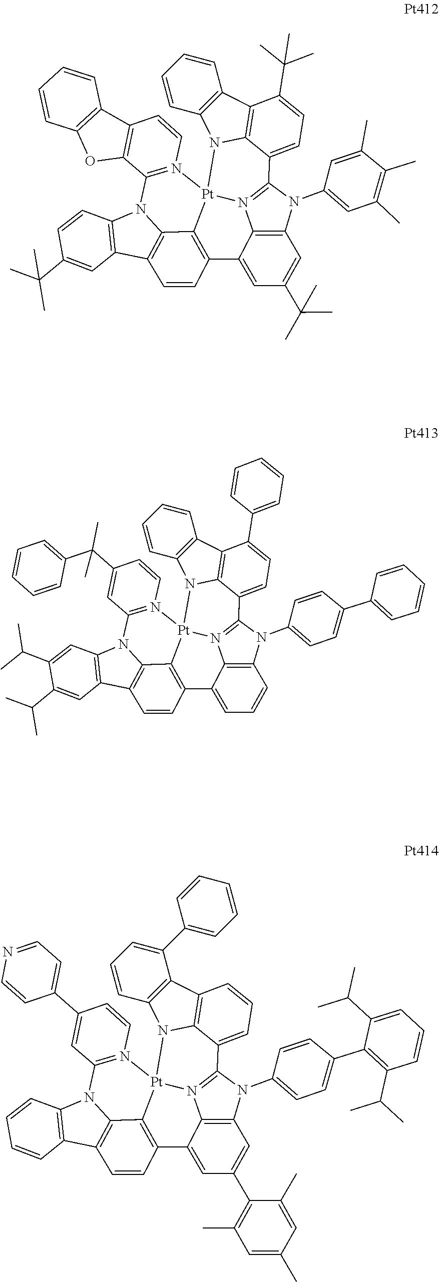

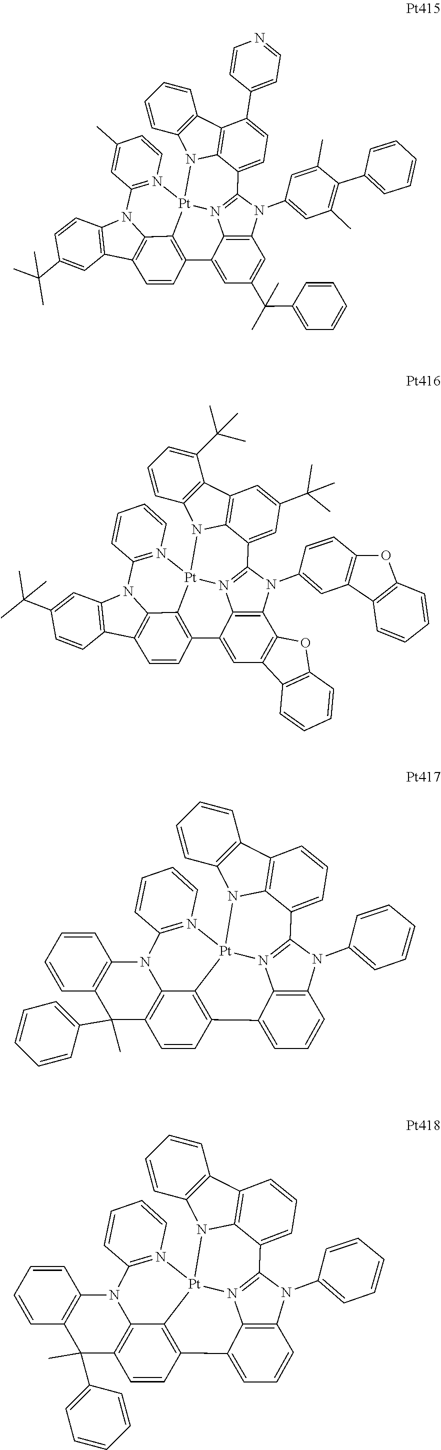

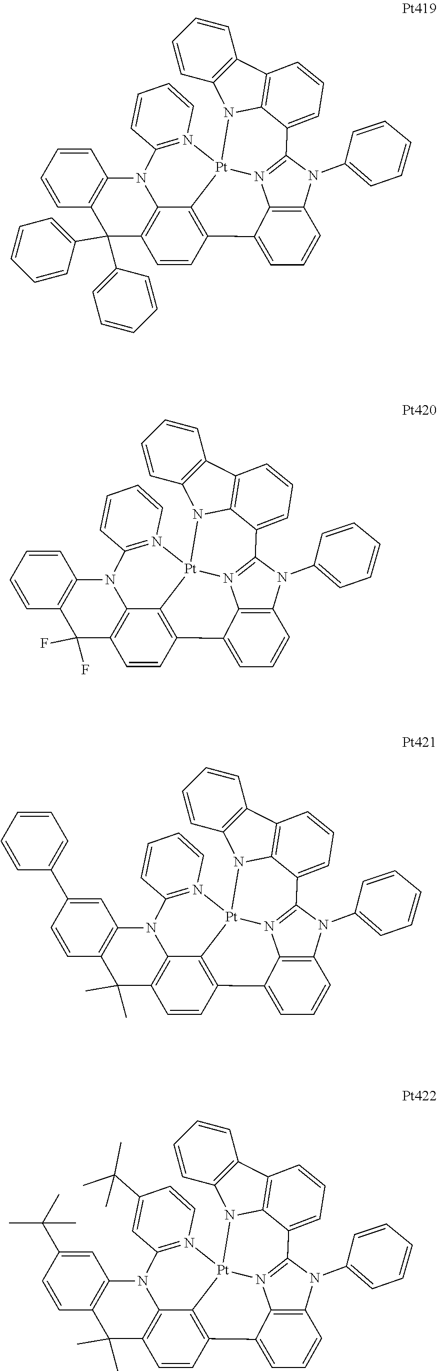

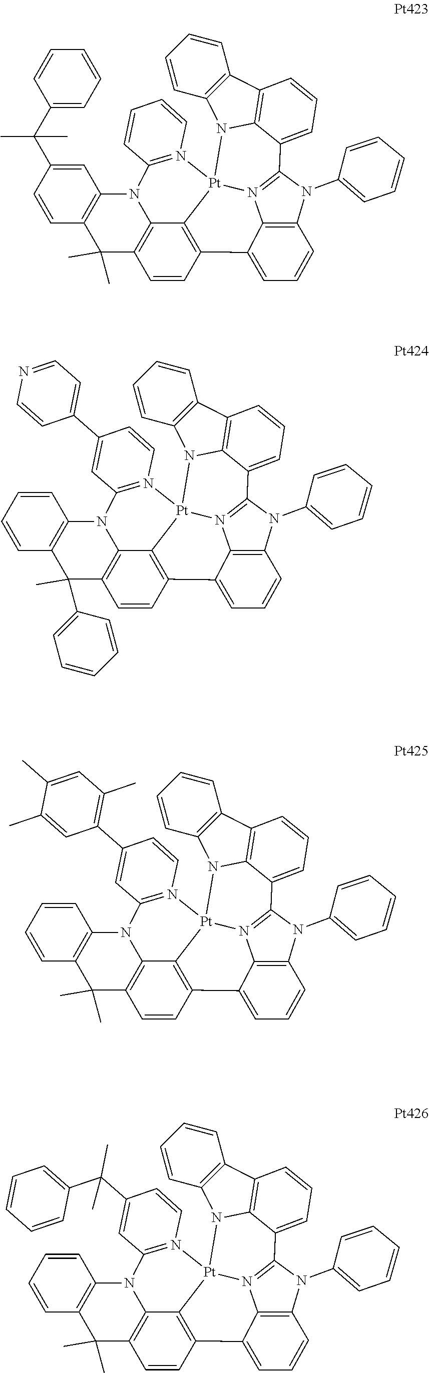

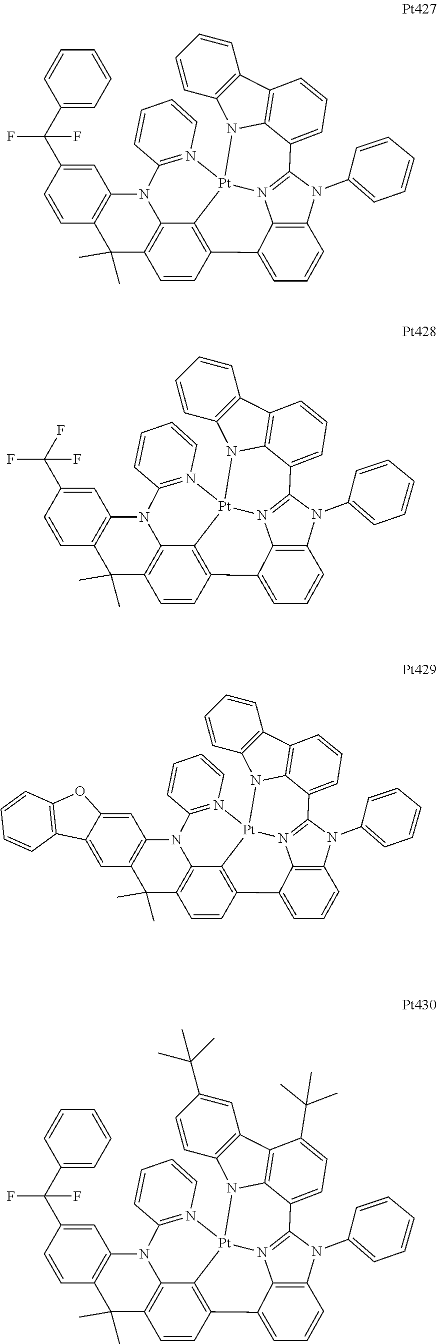

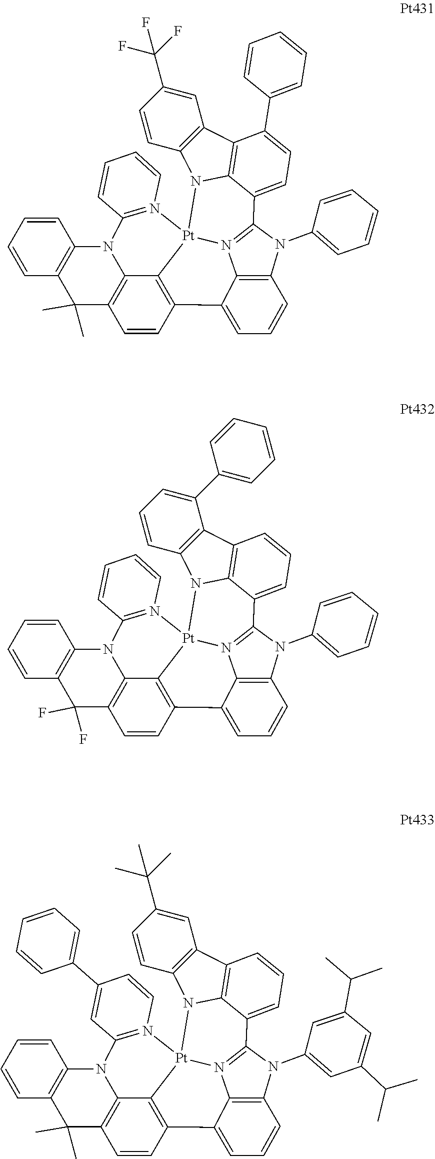

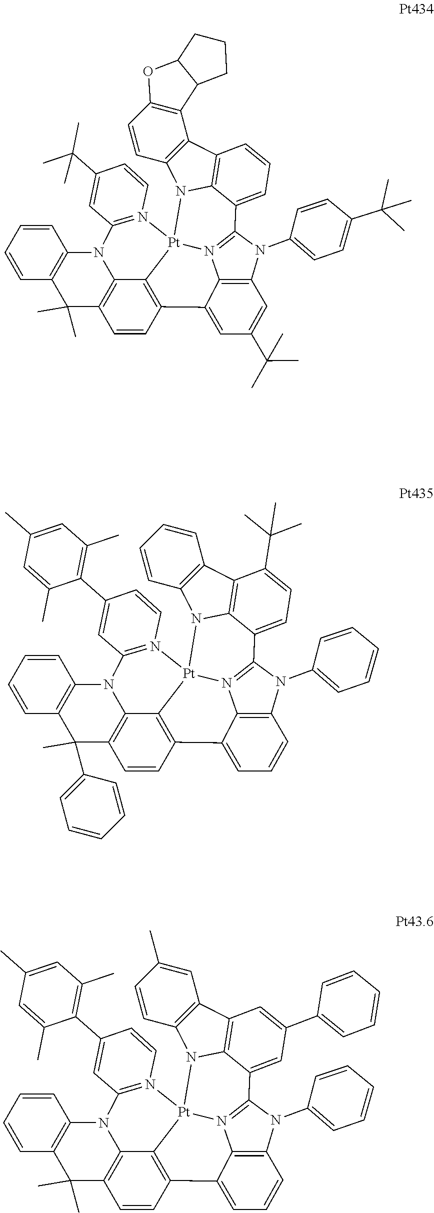

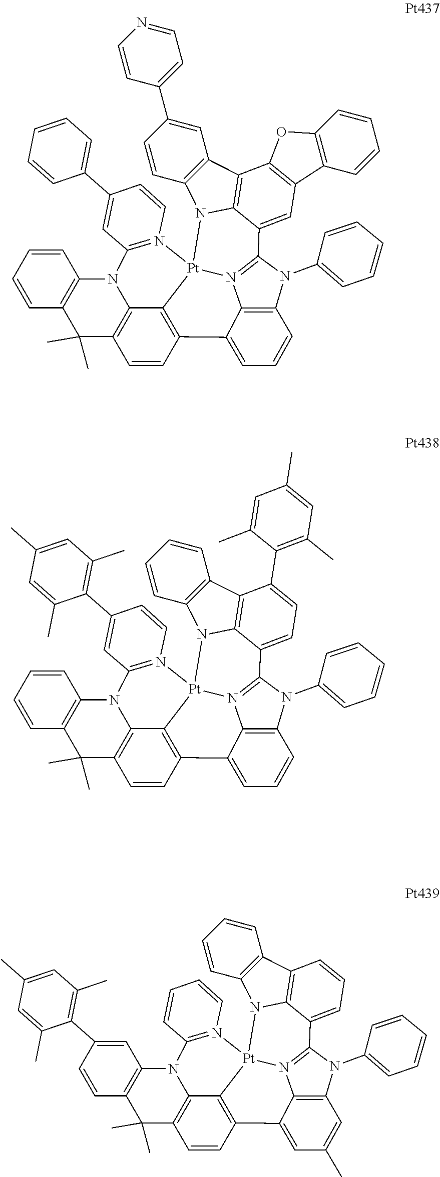

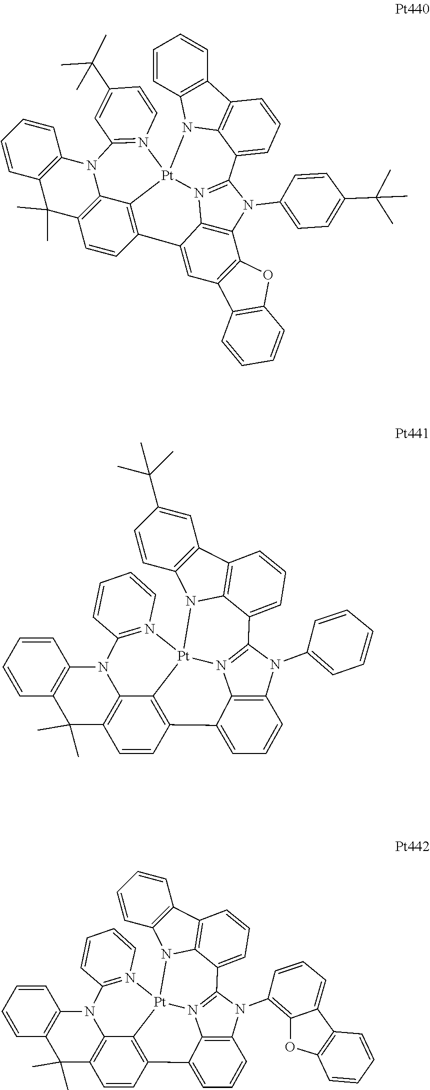

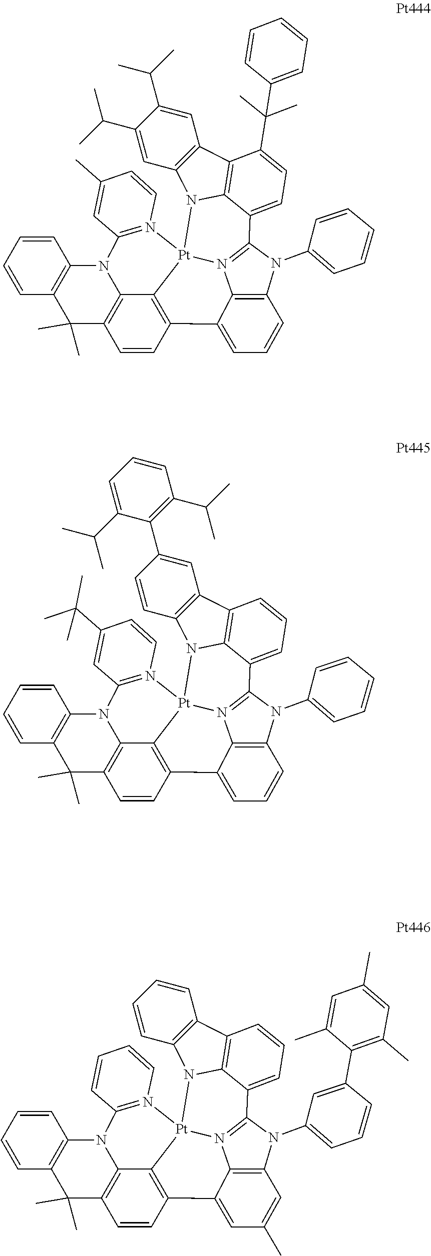

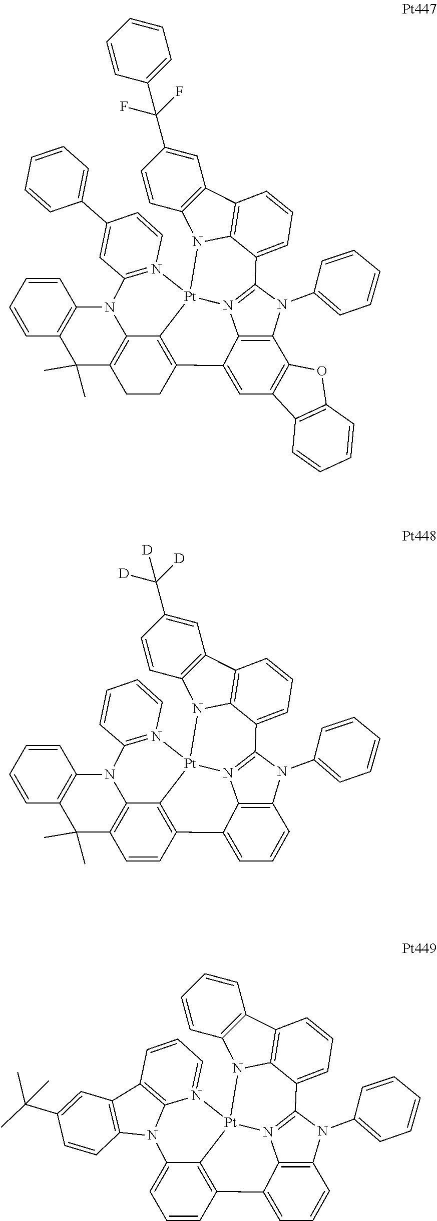

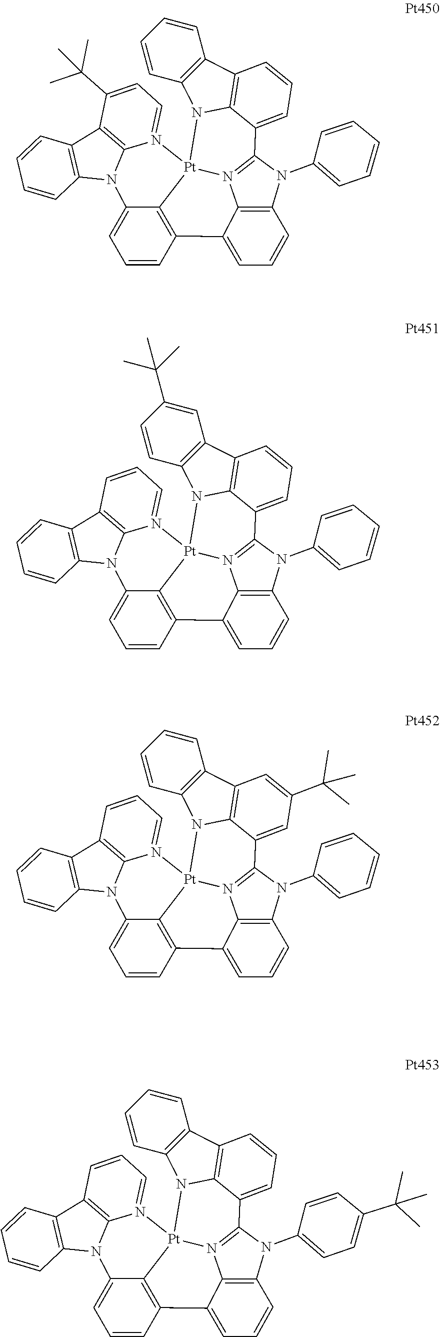

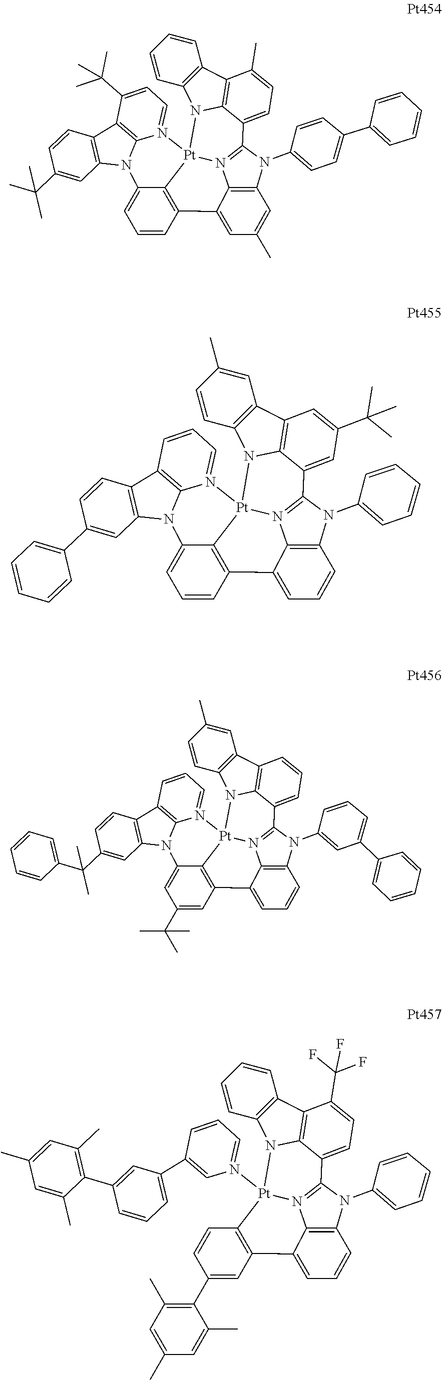

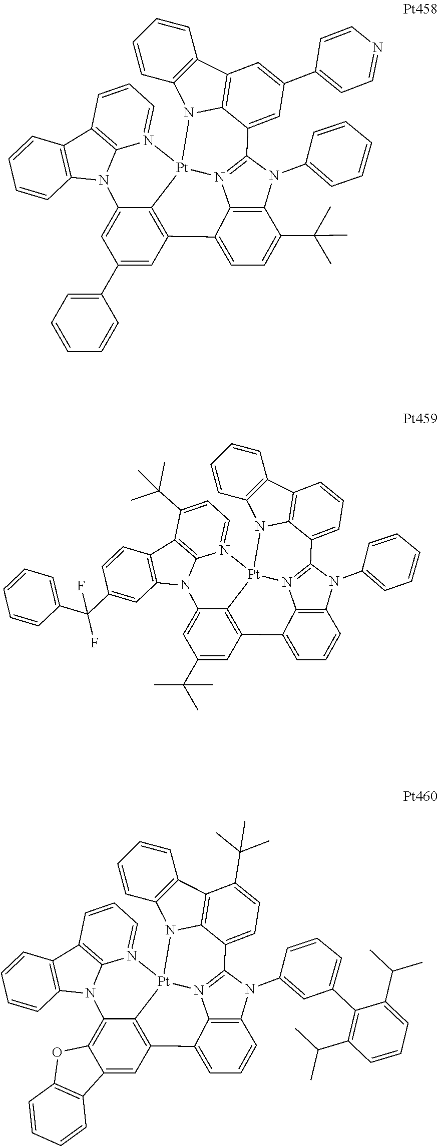

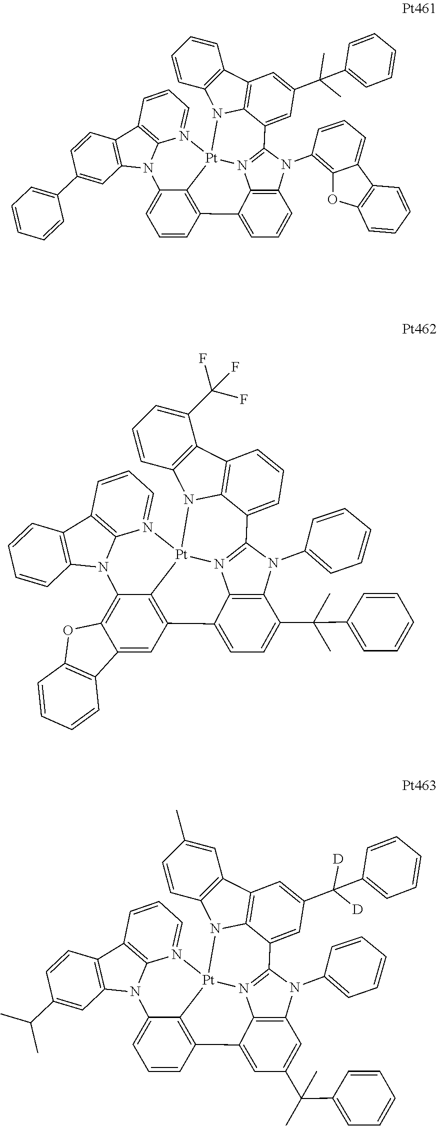

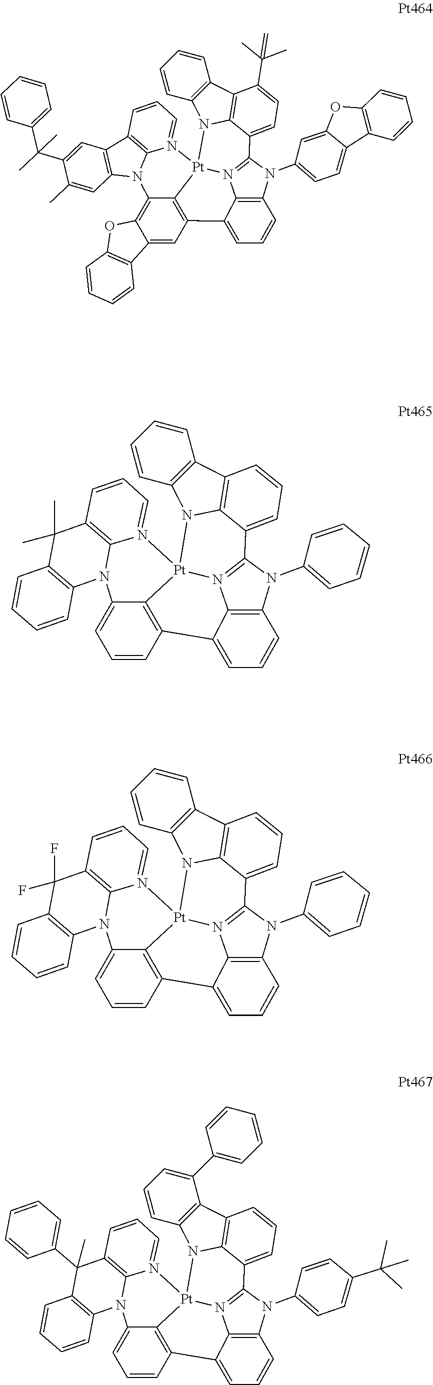

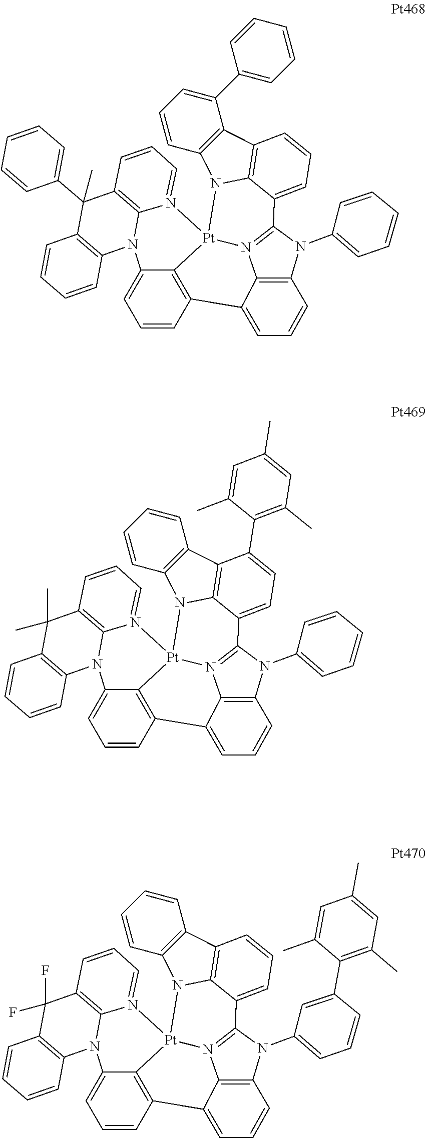

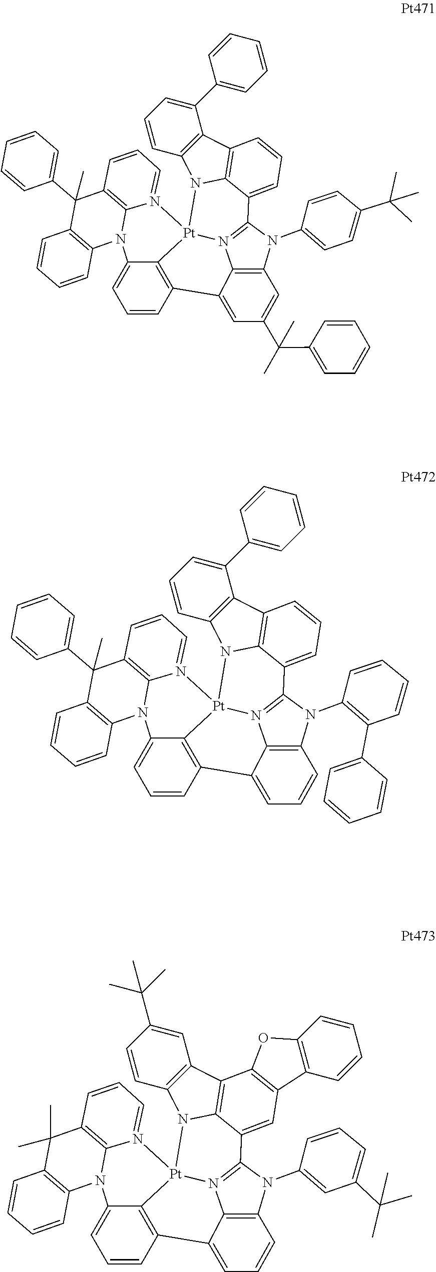

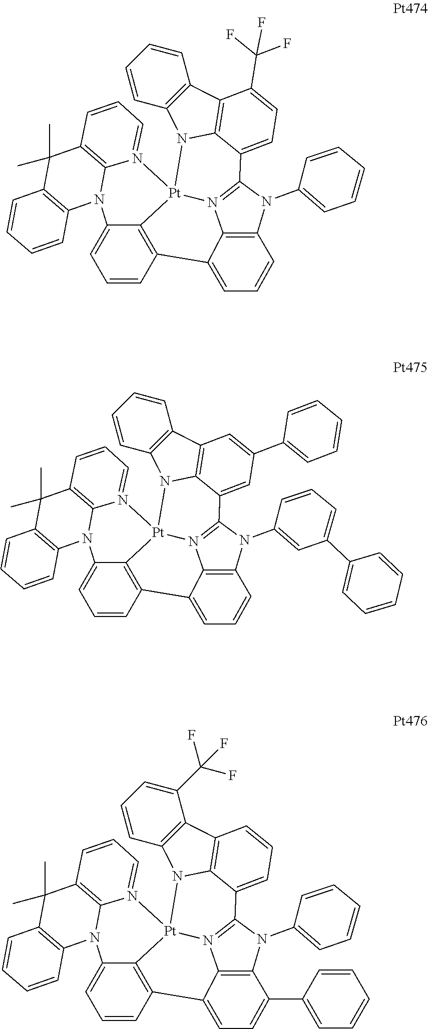

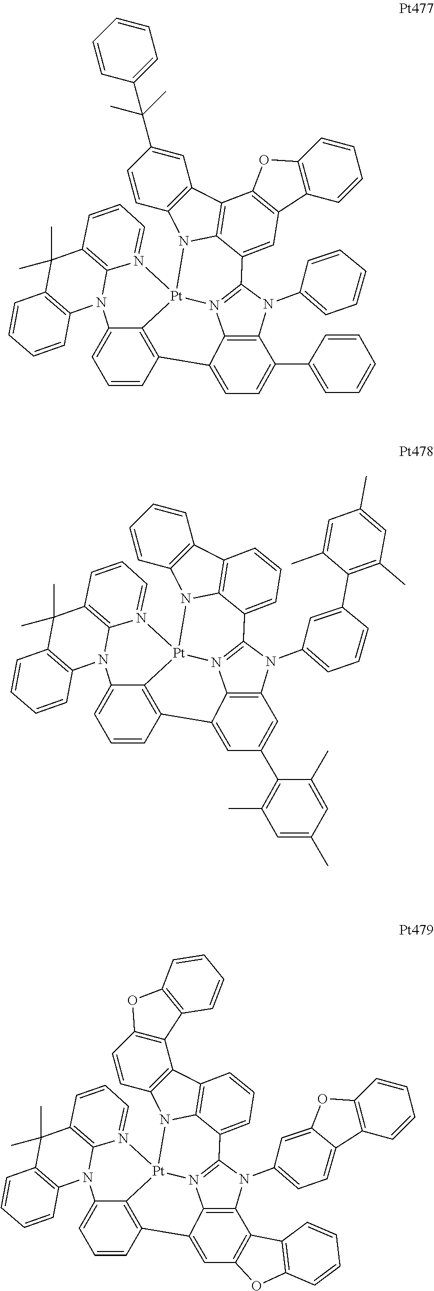

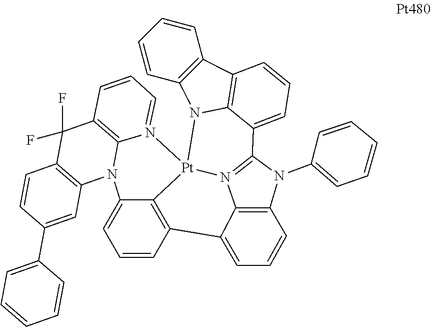

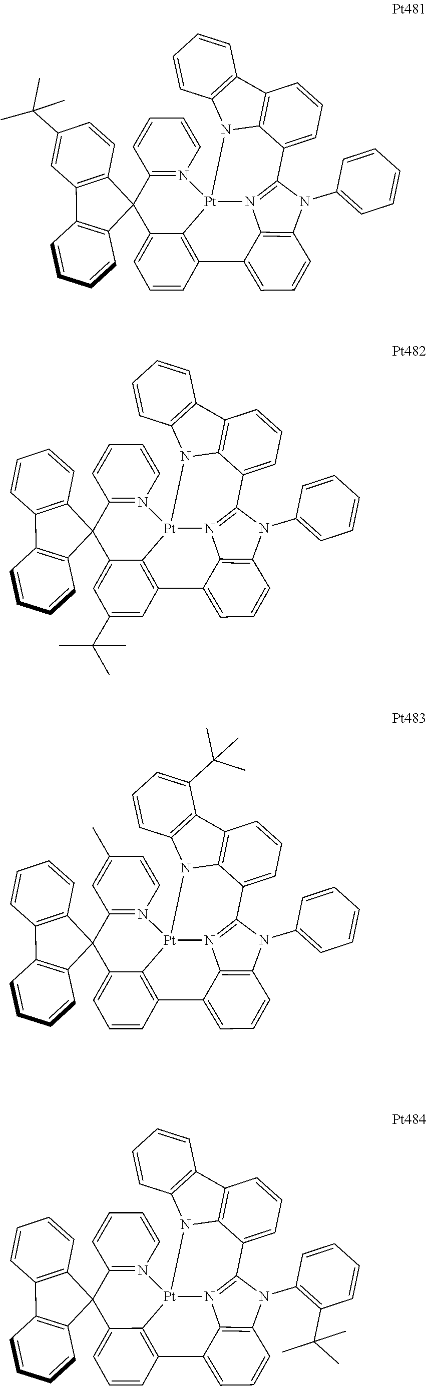

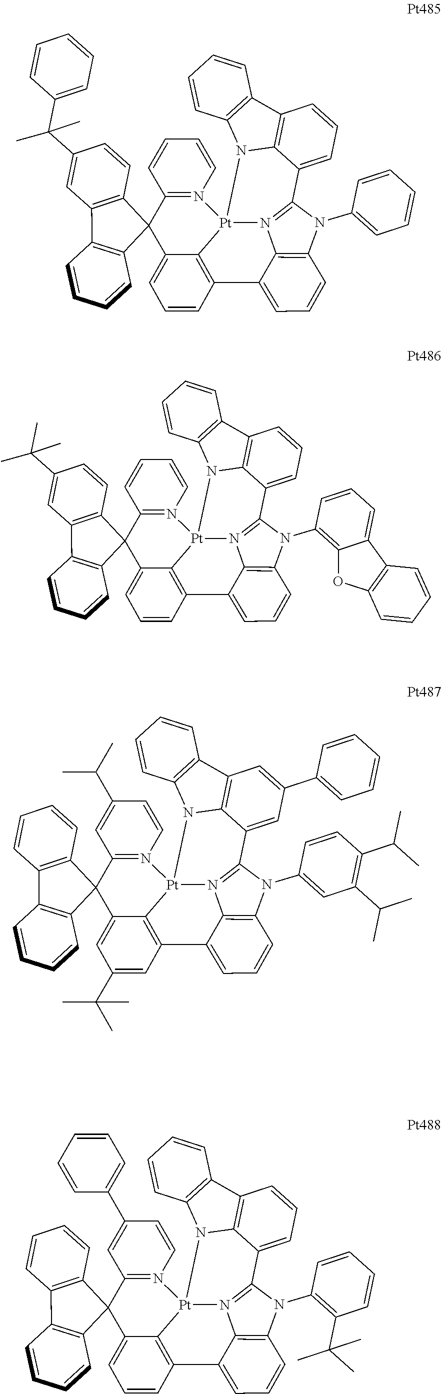

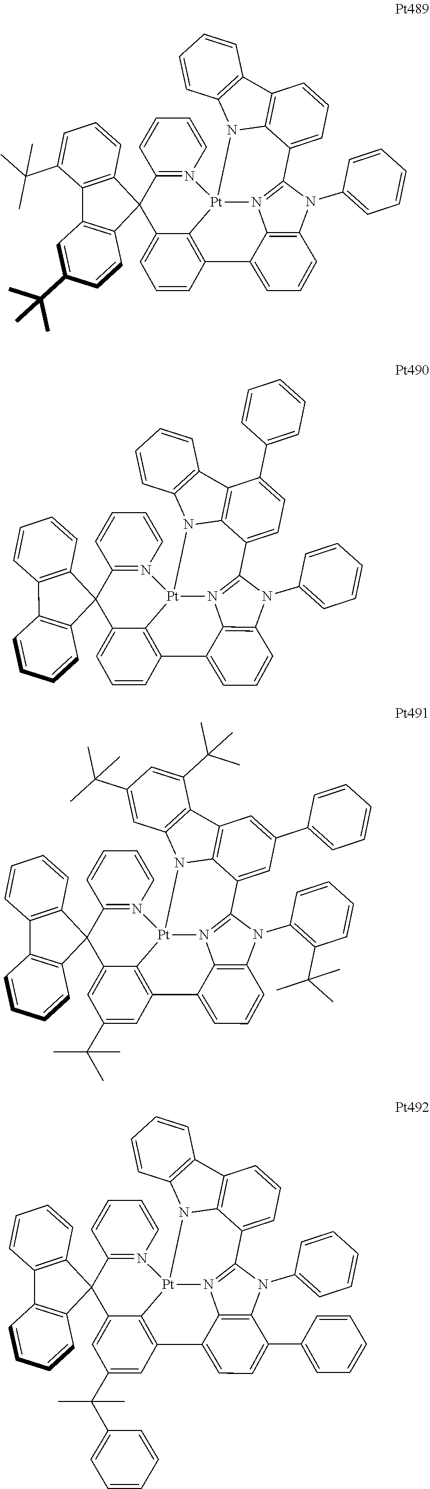

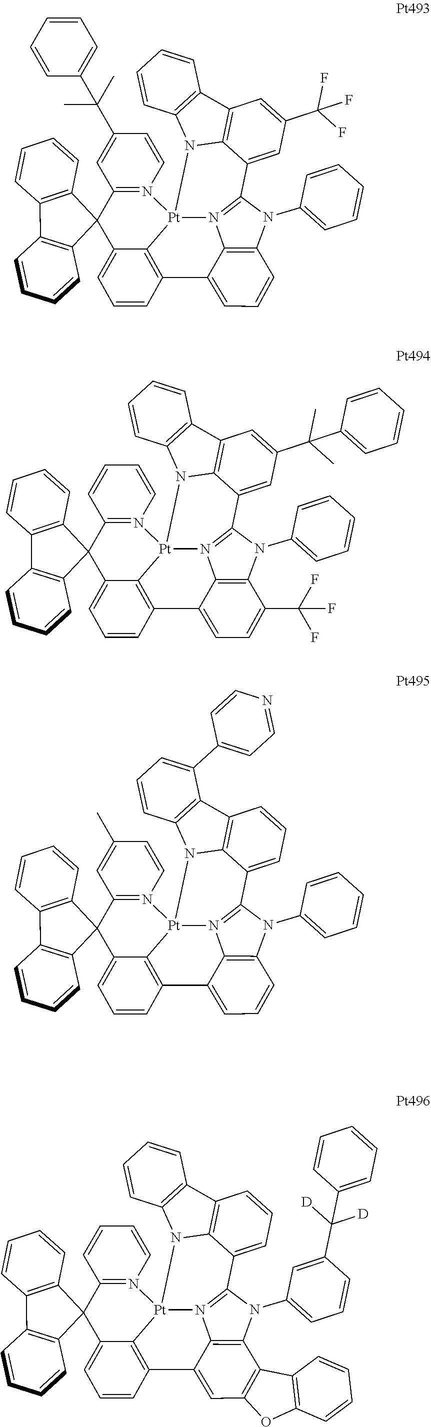

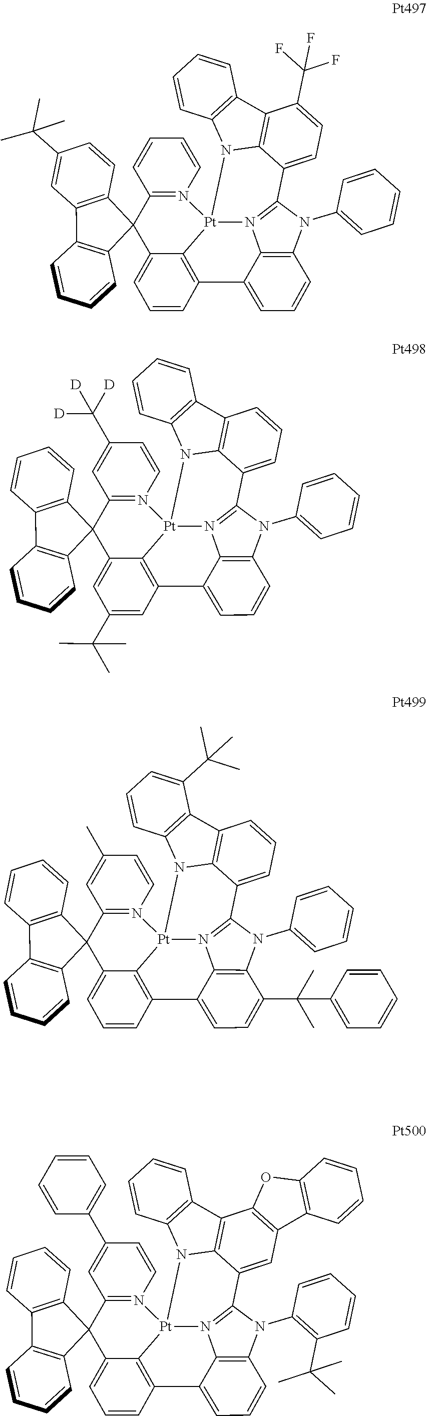

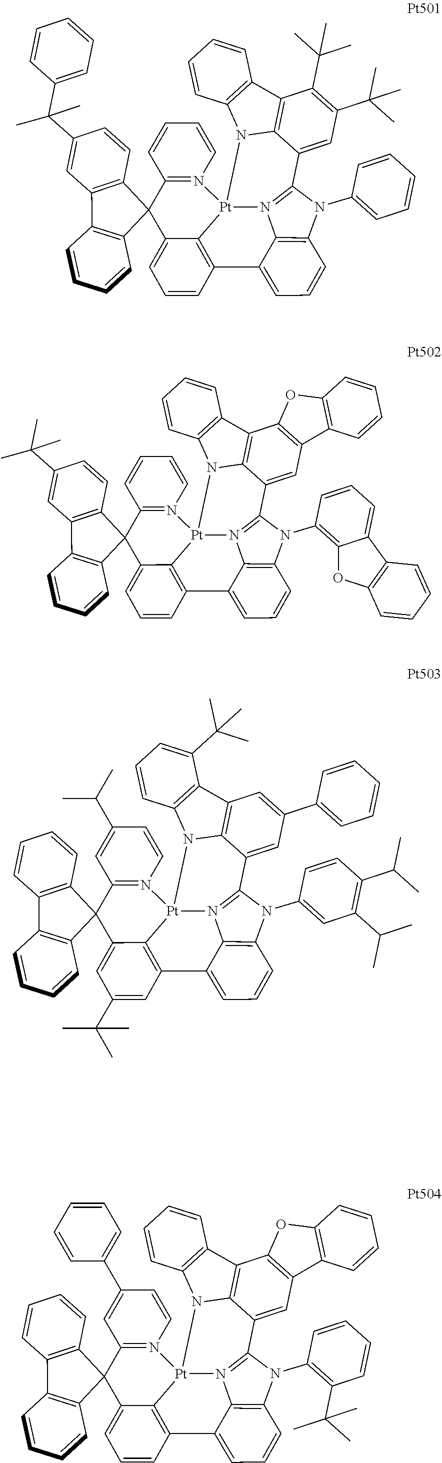

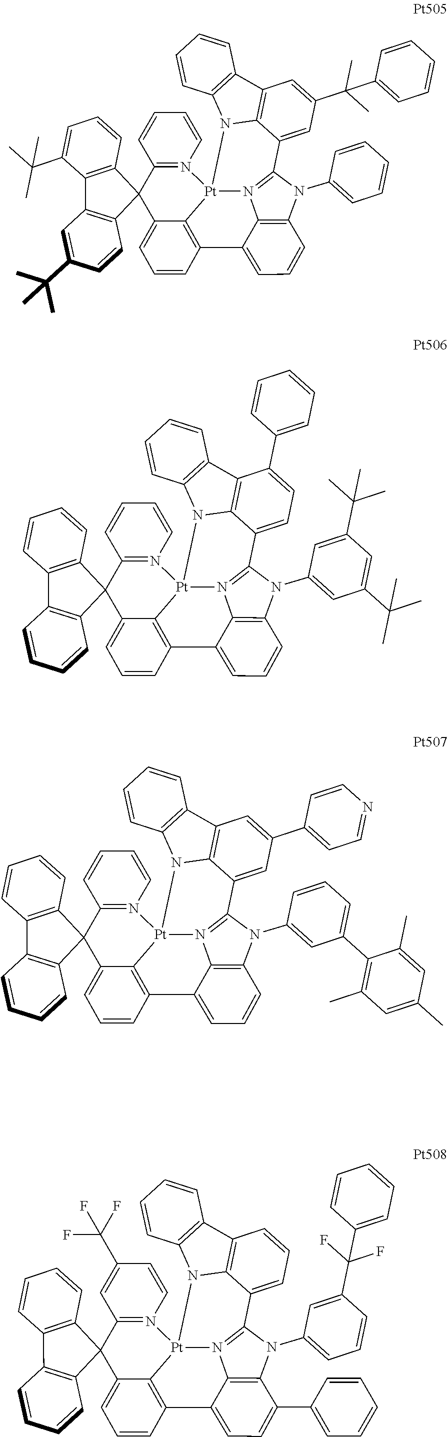

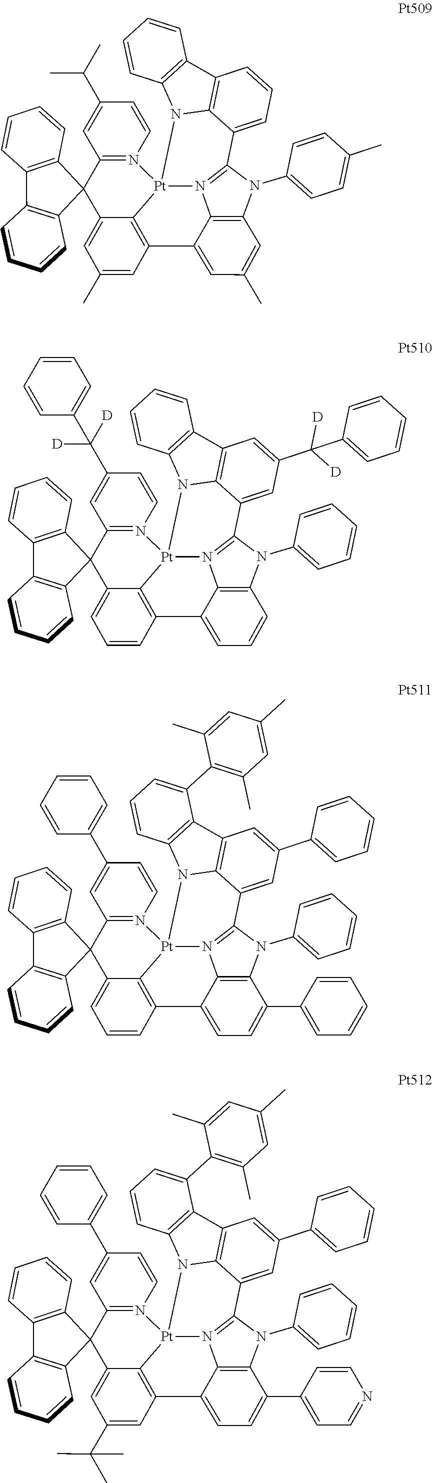

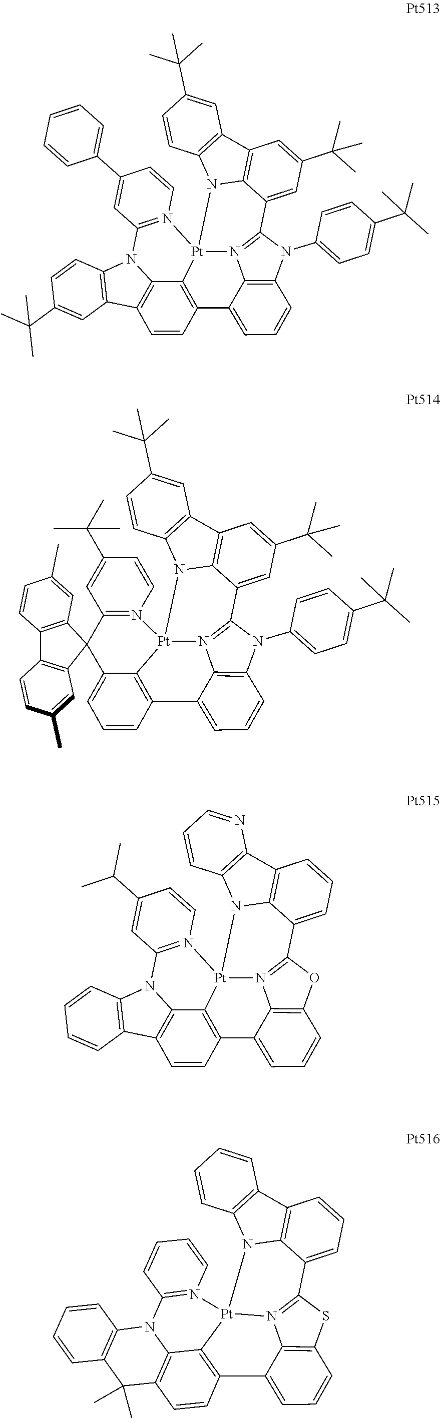

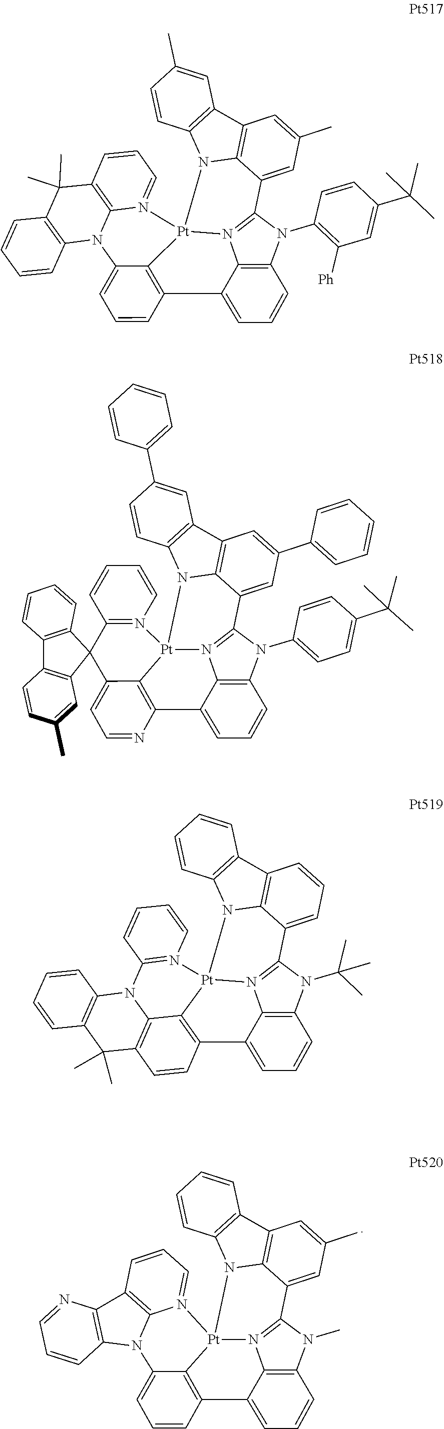

8. Use of the cyclic tetradentate metal platinum complex phosphorescent material according to claim 1 in an electronic device comprising one or more of an organic electroluminescent device, an organic integrated circuit, an organic field effect transistor, an organic thin film transistor, an organic light-emitting transistor, an organic solar cell, an organic optical detector, an organic photoreceptor, an organic field quench device, a light-emitting electrochemical cell, or an organic laser diode.

9. An organic electroluminescent device, comprising a cathode, an anode, and an organic functional layer therebetween; the organic functional layer comprising the cyclic tetradentate metal platinum complex phosphorescent material according to claim 1.

10. The organic electroluminescent device according to claim 9, wherein the organic functional layer comprises a light-emitting layer containing the cyclic tetradentate metal platinum complex phosphorescent material according to claim 1.

11. The organic electroluminescent device according to claim 10, wherein the light-emitting layer also comprises a host material, and the mass percentage of the cyclic tetradentate metal platinum complex phosphorescent material is between 1% and 50%.

12. An organic photoelectric device comprising: a substrate layer; a first electrode on the substrate; an organic light-emitting functional layer on the first electrode; a second electrode on the organic light-emitting functional layer; wherein the organic light-emitting functional layer comprises the cyclic tetradentate metal platinum complex phosphorescent material according to claim 1.

13. A composition comprising the cyclic tetradentate metal platinum complex phosphorescent material according to claim 1.

14. A formulation comprising the cyclic tetradentate metal platinum complex phosphorescent material according to claim 1.

15. A display or lighting device comprising one or more of the organic electroluminescent device according to claim 10.

16. A display or lighting device comprising one or more of the organic electroluminescent device according to claim 11.
